(19) United States
(12) Patent Application Publication
(10) Pub. No.: US 2019/0127529 A1
(43) Pub. Date: May 2, 2019

(54) POLYIMIDE FOR FLEXIBLE DISPLAYS, FLEXIBLE DISPLAYS, AND METHODS FOR MAKING FLEXIBLE DISPLAYS

(71) Applicant: Honeywell International Inc., Morris Plains, NJ (US)

(72) Inventors: Ya Qun Liu, Shanghai (CN); Ying Han, Shanghai (CN); Mingchang Lin, Shanghai (CN); Deguang Zhang, Shanghai (CN); Chunqing Liu, Arlington Heights, IL (US); Joseph T. Kennedy, San Jose, CA (US)

(21) Appl. No.: 16/173,090

(22) Filed: Oct. 29, 2018

Related U.S. Application Data
(60) Provisional application No. 62/580,532, filed on Nov. 2, 2017.
(60) Provisional application No. 62/639,687, filed on Mar. 7, 2018.

(51) Int. Cl. C08G 73/10; H01L 51/00; G09F 9/30; H01L 51/56

(52) U.S. Cl. CPC C08G 73/1067; H01L 51/0097; C08G 73/1085; H01L 2251/5338; G09F 9/301; H01L 51/56; H01L 51/0035

(57) ABSTRACT

A polyimide polymer includes one or more aromatic dianhydride monomers and one or more aromatic diamine monomers as recited herein. A method for making a flexible display device includes preparing a polyimide solution including a polyimide polymer dissolved in a solvent, coating a substrate with the polyimide solution, heating the coating to evaporate the solvent and form a polyimide layer, forming a display device layer on the polyimide layer, dicing through the display device layer and through the polyimide polymer layer, and delaminating the layer from the substrate to form the flexible display device. A flexible display device can include a polyimide polymer backing layer and a display device disposed on the polyimide polymer backing layer, the polyimide polymer including one or more aromatic dianhydride monomers and one or more aromatic diamine monomers as recited herein.

### CROSS REFERENCE TO RELATED APPLICATIONS

This application claims the benefit under Title 35, U.S.C. § 119(e) of U.S. Provisional Patent Application Ser. No. 62/580,532, filed Nov. 2, 2017, entitled THERMALLY STABLE POLYIMIDE, and U.S. Provisional Patent Application Ser. No. 62/639,687, filed Mar. 7, 2018, entitled POLYIMIDE FOR FLEXIBLE DISPLAYS, FLEXIBLE DISPLAYS, AND METHODS FOR MAKING FLEXIBLE DISPLAYS, the disclosures of which are incorporated by reference herein in their entirety.

### FIELD

The present disclosure relates to polyimide polymers, particularly for use as the substrate for electronic devices. The polyimide polymer can be used as a substrate in display devices, for example as a flexible substrate for use in making flexible display devices such as flexible OLEDs (Organic Light Emitting Devices), and the like. The disclosure also relates to methods for preparing the polyimide polymers. The disclosure further relates to methods of fabricating a film or substrate from the polyimide polymers.

### BACKGROUND

For flexible displays, organic polymer (or plastic) substrates are used to replace the glass substrates of rigid flat display. OLEDs, based on low-temperature polycrystalline silicon (LTPS) technology, are a main trend in display devices for their high resolution and high display quality, particularly for applications in mobile devices, such as mobile phones, wearable devices (watch, glass etc.), AR/VR devices, etc. However, the LTPS technology requires high temperature during the fabrication process and a polymer substrate has to be capable of withstanding high temperatures (the annealing temperature may be as high as 450-550° C.). For use in flexible display devices, the polymer substrate should also have the mechanical properties for flexibility, and also thermal stability. Polyimides are widely accepted in this area for high thermal stability and good mechanical properties.

### SUMMARY

A polyimide polymer includes one or more aromatic dianhydride monomers and one or more aromatic diamine monomers as recited herein. A method for making a flexible display device includes preparing a polyimide solution including a polyimide polymer dissolved in a solvent, coating a substrate with the polyimide solution, heating the coating to evaporate the solvent and form a cured polyimide layer, forming a display device layer on the cured polyimide layer, dicing through the display device layer and through the cured polyimide polymer layer, and delaminating the cured polyimide layer together with the display device layer from the substrate to form the flexible display device. A flexible display device can include a polyimide polymer backing layer and a display device disposed on the polyimide polymer backing layer, the polyimide polymer including one or more aromatic dianhydride monomers and one or more aromatic diamine monomers as recited herein.

Various embodiments concern a polyimide polymer including one or more aromatic dianhydride monomer and one or more aromatic diamine monomers. The one or more aromatic dianhydride monomers are according to a formula:

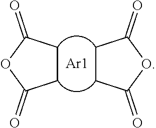

Ar1 is selected from the group consisting of:

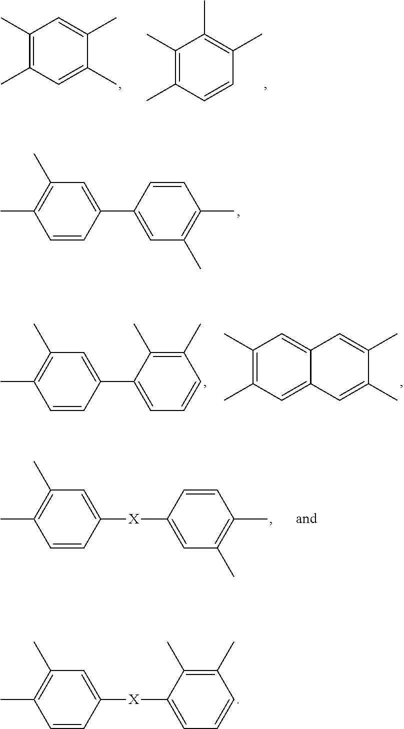

X is selected from the group consisting of —CH₂—, —C(CH₃)₂—, —C(CF₃)₂—, —O—, —C(═O)—, —SO₂—,

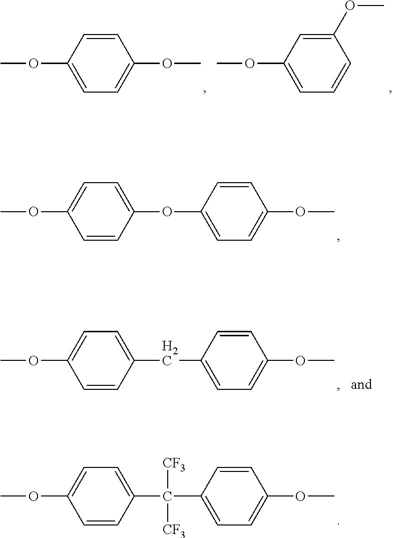

The one or more aromatic diamine monomers are according to at least one of: a formula:

H₂N-Ar6-NH₂

and a formula:

H₂N-Ar8-NH₂,

Ar6 is selected from the group consisting of:

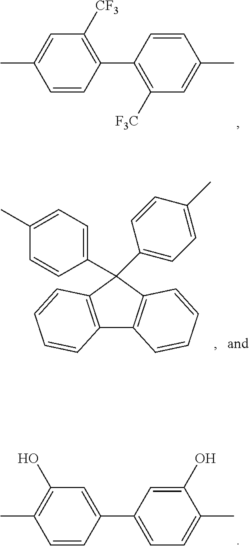

Ar8 is selected from the group consisting of:

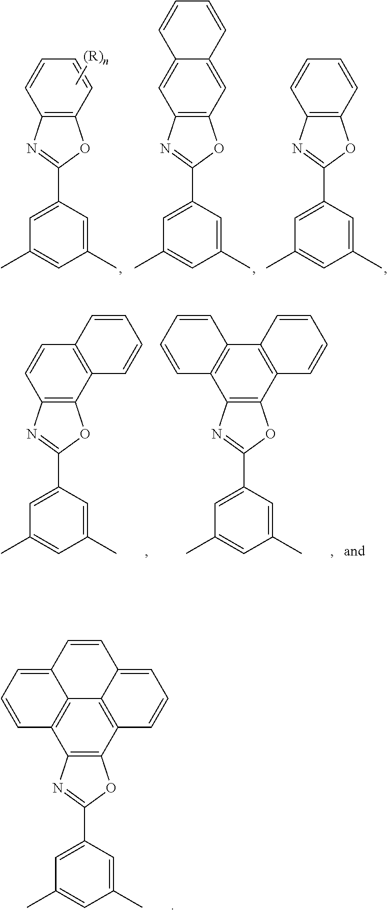

Each R is independently selected from the group consisting of F, Cl, and CF₃; and n is 0, 1 or 2. In some embodiment, the one or more aromatic diamine monomers have a formula of:

H₂N-Ar6-NH₂

in which Ar6 is selected from the group consisting of:

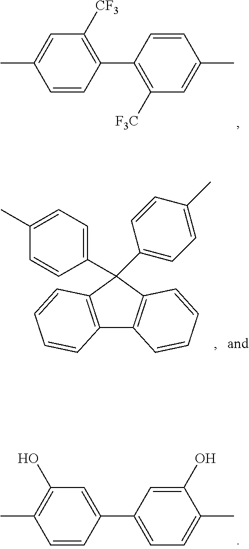

In some particular embodiments, the polyimide polymer further includes one or more aromatic diamine monomers have a formula of:

H₂N-Ar5-NH₂

in which Ar5 is selected from the group consisting of:

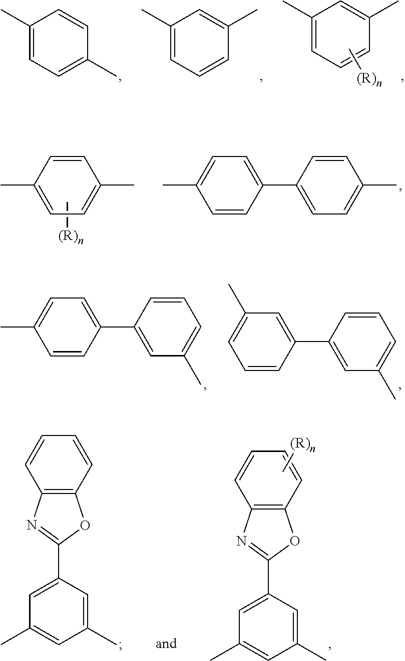

in which each R is independently selected from the group consisting of F, Cl, and CF₃; and n is 0, 1 or 2. In some particular embodiments, the aromatic diamine monomer includes at least one of: (4,4′-(9-fluorenylidene)dianiline and (2,2′-bis(trifluoromethyl)benzidine. In some embodiments, the one or more aromatic diamine monomers have a formula of:

H₂N-Ar8-NH₂

in which Ar8 is selected from the group consisting of:

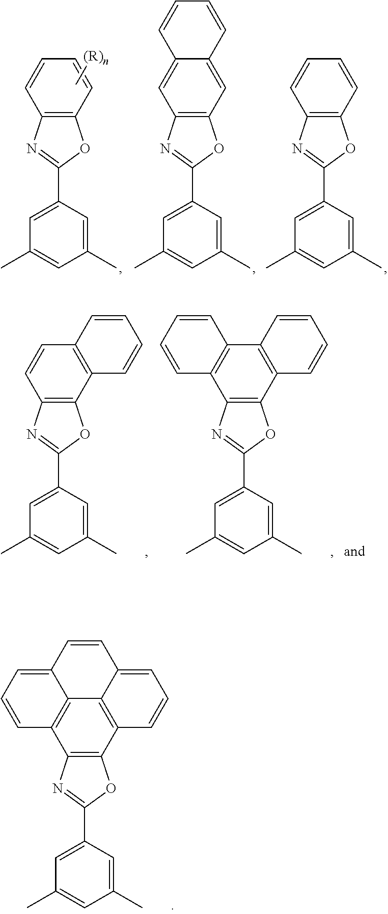

in which each R is independently selected from the group consisting of F, Cl, and CF₃; and n is 0, 1 or 2. In some particular embodiments, the polyimide polymer further includes one or more aromatic diamine monomers have a formula of:

H₂N-Ar4-NH₂

in which Ar4 is selected from the group consisting of:

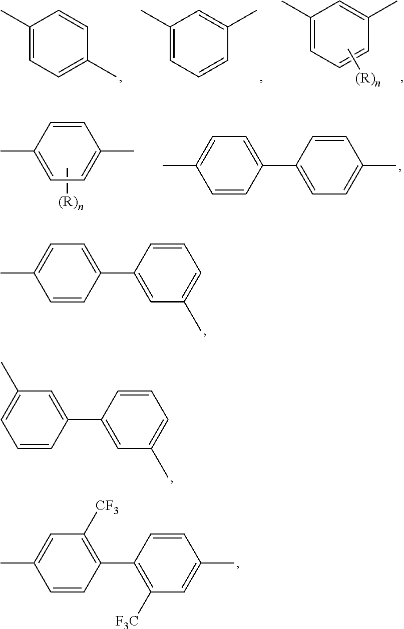

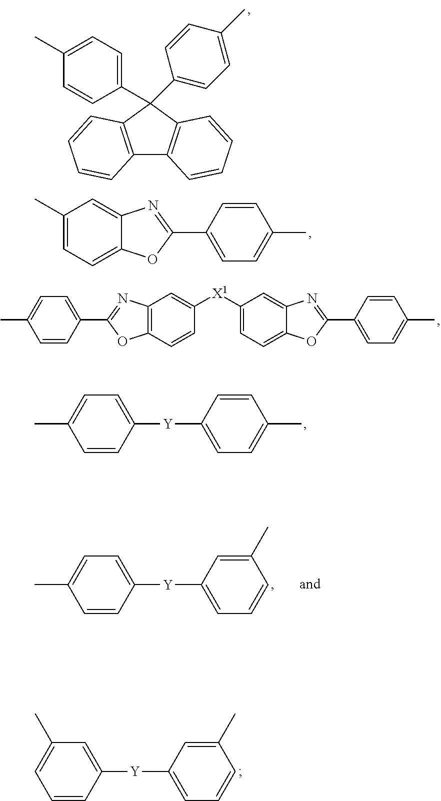

in which each R is independently selected from the group consisting of F, Cl, and CF₃; each n independently selected from is 0, 1 or 2; X₁ is selected from the group consisting of a chemical single bond, —CH₂—, and —O—; and each Y is independently selected from the group consisting of —CH₂—, —C(CH₃)₂—, —C(CF₃)₂—, —O—, —C(═O)—, —SO₂—,

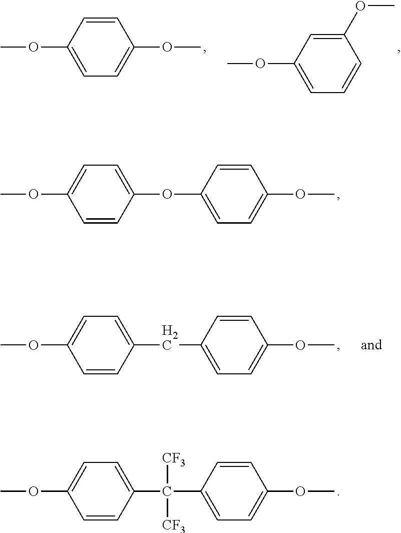

In some particular embodiments, the one or more aromatic diamine monomers having a formula of:

H₂N-Ar4-NH₂

includes 4,4′-diaminodiphenyl ether. In some embodiments, the polyimide polymer further includes one or more aromatic diamine monomers have a formula of:

H₂N-Ar7-NH₂

in which Ar7 is selected from the group consisting of:

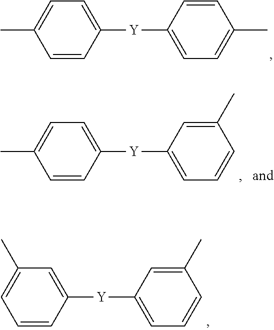

in which Y is selected from the group consisting of —CH₂—, —C(CH₃)₂—, —C(CF₃)₂—, —O—, —C(═O)—, —SO₂—,

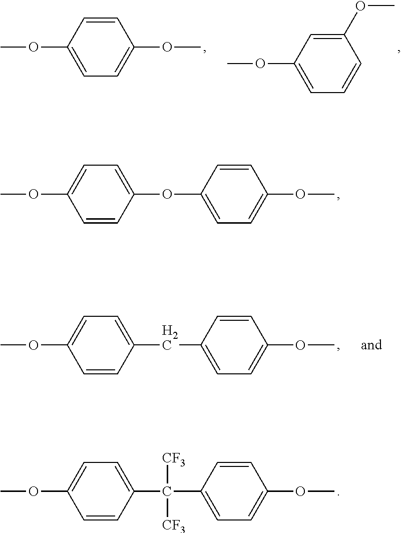

In some embodiments, the one or more aromatic dianhydride monomers include pyromellitic dianhydride and one or more additional aromatic dianhydride monomers having the formula:

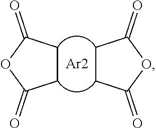

in which Ar2 is a selected from the group consisting of:

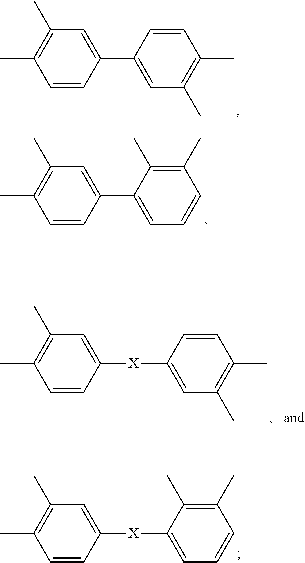

in which X is selected from the group consisting of —CH₂—, —C(CH₃)₂—, —C(CF₃)₂—, —O—, —C(═O)—, —SO₂—,

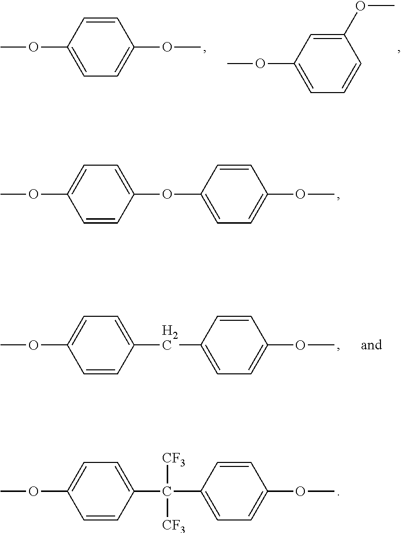

In some particular embodiments, the one or more additional aromatic dianhydride monomers are selected from the group consisting of: 3,3′,4,4′-biphenyltetracarboxylic dianhydride; 2,3,3′,4′-biphenyltetracarboxylic dianhydride; 3,3′,4,4′-benzophenone tetracarboxylic dianhydride; diphenyl ether tetracarboxylic acid dianhydride; hydroquinone diphthalic anhydride; 4,4′-(4,4′-isopropylidenediphenoxy)bis-(phthalic anhydride); 4,4′-(hexafluoroisopropylidene)diphthalic anhydride; and mixtures thereof.

Various embodiments concern a method for making a flexible display device. The method includes preparing a polyimide solution including a polyimide polymer dissolved in a solvent, coating a substrate with the polyimide solution, heating the coated substrate and the coating of polyimide solution to evaporate the solvent and form a cured polyimide layer, forming a display device layer on the cured polyimide layer, the display device layer defining at least one display device, dicing through the display device layer and through the cured polyimide layer, and delaminating the cured polyamide layer together with the display device layer from the substrate to form the flexible display device. In some embodiments, the solvent can be selected from the group consisting of: N-methyl-2-pyrrolidone, dimethylacetamide, dimethylformamide, dimethyl sulfoxide, tetrahydrofuran, acetone diethyl acetate, and mixtures thereof. In some embodiments, the heating is to a temperature not greater than 350° C. In some particular embodiments, the heating includes baking on a hot plate at a temperature of 75° C. to 80° C. for 25 to 35 minutes, baking in an oven at a temperature of 75° C. to 80° C. for 25 to 35 minutes, baking in the oven at a temperature of 95° C. to 105° C. for 55 to 65 minutes, baking in the oven at a temperature of 195° C. to 205° C. for 25 to 35 minutes, baking in the oven at a temperature of 245° C. to 255° C. for 25 to 35 minutes, baking in the oven at a temperature of 295° C. to 305° C. for 25 to 35 minutes, and baking in the oven at a temperature of 345° C. to 350° C. for 25 to 35 minutes. In some embodiments, the polyimide polymer includes one or more aromatic dianhydride monomers according to a formula:

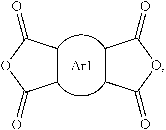

in which Ar1 is selected from the group consisting of:

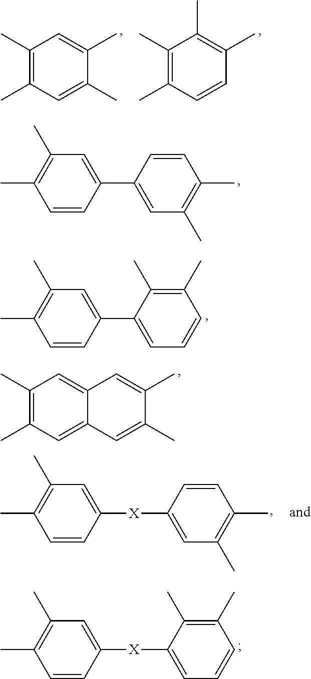

in which X is selected from the group consisting of —CH₂—, —C(CH₃)₂—, —C(CF₃)₂—, —O—, —C(═O)—, —SO₂—,

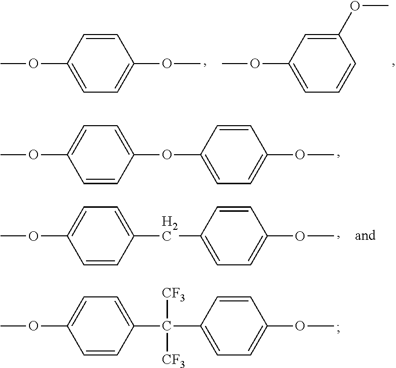

and
one or more aromatic diamine monomers according to at least one of: a formula:

H₂N-Ar6-NH₂

and a formula:

H₂N-Ar8-NH₂,

in which Ar6 is selected from the group consisting of:

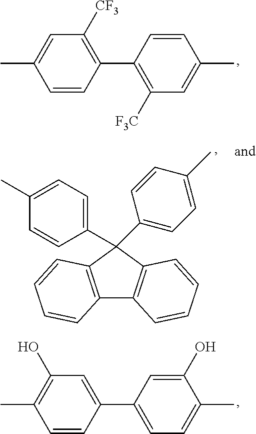

and Ar8 is selected from the group consisting of:

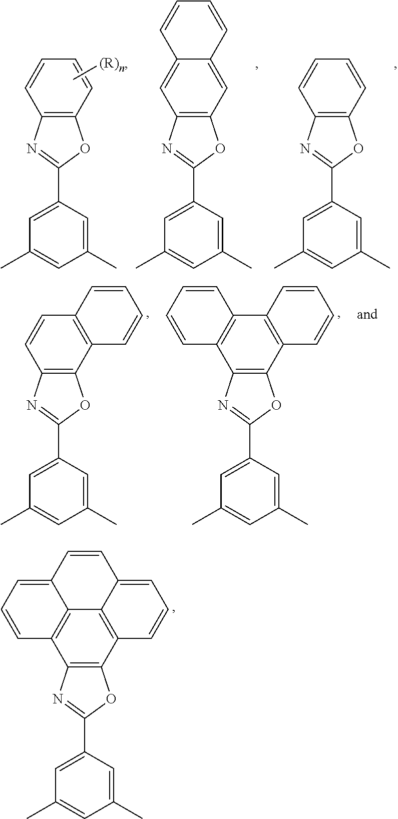

in which each R is independently selected from the group consisting of F, Cl, and CF₃; and n is 0, 1 or 2. In some particular embodiments, the one or more aromatic diamine monomers include at least one of: (4,4′-(9-fluorenylidene)dianiline and (2,2′-bis(trifluoromethyl)benzidine. In some particular embodiments, the one or more aromatic dianhydride monomers include pyromellitic dianhydride and one or more additional aromatic dianhydride monomers having the formula:

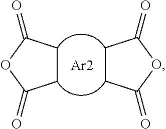

in which Ar2 is a selected from the group consisting of:

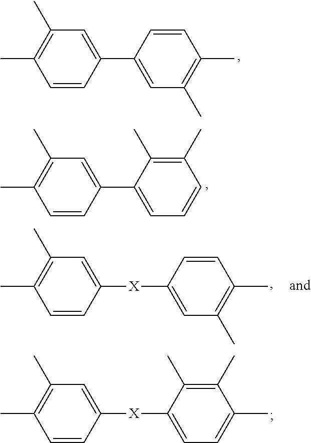

in which X is selected from the group consisting of —CH₂—, —C(CH₃)₂—, —C(CF₃)₂—, —O—, —C(═O)—, —SO₂—,

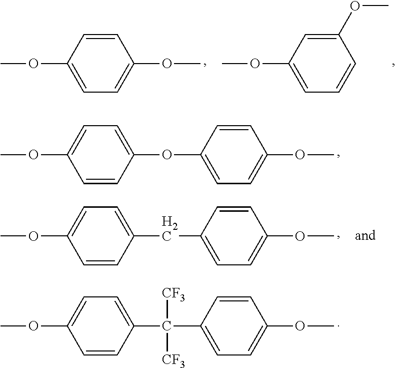

Various embodiments include a flexible display device including a polyimide polymer backing layer and a display device disposed on the polyimide backing layer. The polyimide polymer includes one or more aromatic dianhydride monomers and one or more aromatic diamine monomers. The one or more aromatic dianhydride monomers are according to a formula:

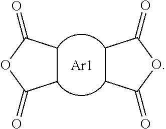

Ar1 is selected from the group consisting of:

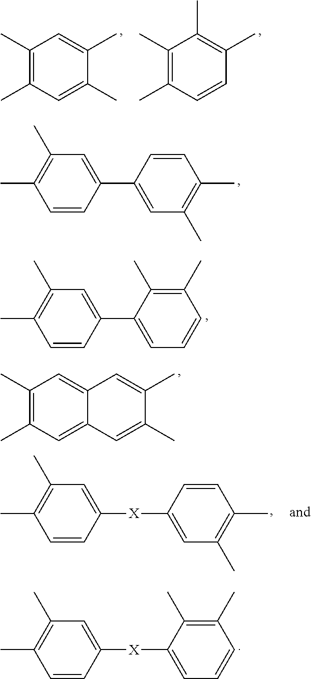

X is selected from the group consisting of —CH₂—, —C(CH₃)₂—, —C(CF₃)₂—, —O—, —C(═O)—, —SO₂—,

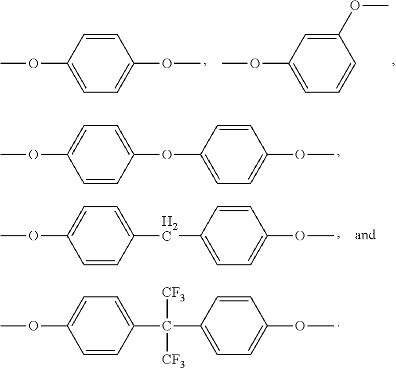

The one or more aromatic diamine monomers are according to at least one of: a formula:

H₂N-Ar6-NH₂

and a formula:

H₂N-Ar8-NH₂.

Ar6 is selected from the group consisting of:

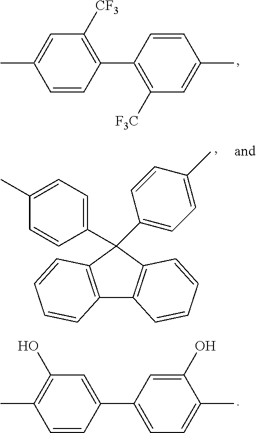

Ar8 is selected from the group consisting of:

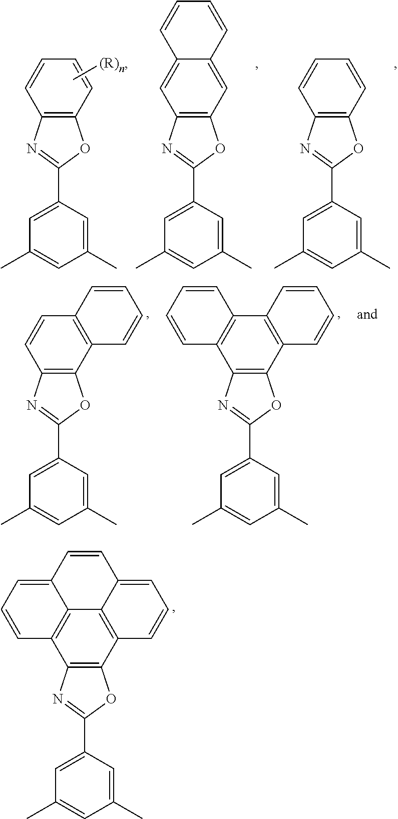

Each R is independently selected from the group consisting of F, Cl, and CF₃; and n is 0, 1 or 2. In some embodiments, the one or more aromatic diamine monomers include at least one of: (4,4′-(9-fluorenylidene)dianiline and (2,2′-bis(trifluoromethyl)benzidine. In some embodiments, the one or more aromatic dianhydride monomers include pyromellitic dianhydride and one or more additional aromatic dianhydride monomers having the formula:

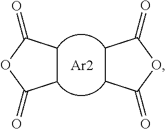

in which Ar2 is a selected from the group consisting of:

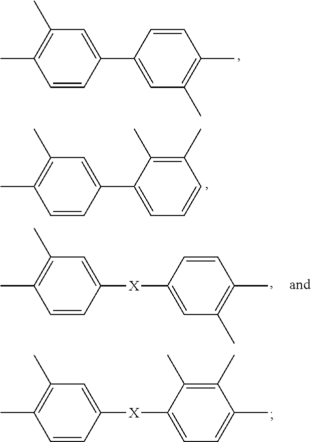

in which X is selected from the group consisting of —CH₂—, —C(CH₃)₂—, —C(CF₃)₂—, —O—, —C(═O)—, —SO₂—,

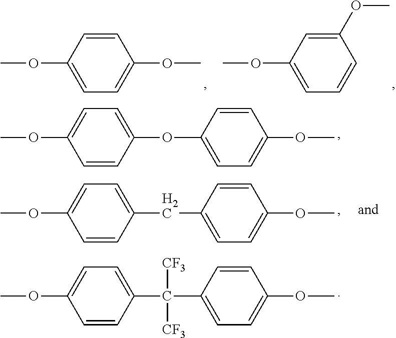

The above mentioned and other features, and the manner of attaining them, will become more apparent and the disclosure itself will be better understood by reference to the following description of embodiments taken in conjunction with the accompanying drawing.

### BRIEF DESCRIPTION OF THE DRAWINGS

FIG. 1 is a schematic cross-section illustrating a substrate for making a flexible display device, according to some embodiments of this disclosure.

FIG. 2 is a schematic cross-section illustrating a polyimide polymer layer on the substrate of FIG. 1, according to some embodiments of this disclosure.

FIG. 3 is a schematic cross-section illustrating a display device layer including a plurality of display devices on the polyimide polymer layer of FIG. 2, according to some embodiments of this disclosure.

FIG. 4 is a schematic cross-section illustrating the substrate, the polyimide polymer layer, and the display device layer of FIG. 3 after singulation of the plurality of display devices, according to some embodiments of this disclosure.

FIG. 5 is a schematic cross-section illustrating delamination of the polyimide polymer layer from the substrate to form a plurality of flexible display devices, according to some embodiments of this disclosure.

FIG. 6 is a stress-strain curve of a polyimide film, according to some embodiments of this disclosure.

FIG. 7 is a thermal gravimetric analysis profile of a polyimide film, according to some embodiments of this disclosure.

FIG. 8 is a thermal mechanical analysis profile of a polyimide film, according to some embodiments of this disclosure.

FIGS. 9A and 9B are micrographs of crosscut adhesion of a polyimide film, according to some embodiments of this disclosure.

FIG. 10 is a photograph of a bending radius test of a flexible display device, according to some embodiments of this disclosure.

### DETAILED DESCRIPTION

The present disclosure includes a polyimide polymer, as well as its preparation method, a flexible film or substrate prepared from the polyimide polymer and applications thereof. This disclosure also relates to a flexible display device including a polyimide polymer film. The polyimide polymer of the present disclosure is suitable for use in the production of electronic devices, including a flexible display board in an electronic device, such as an organic light emitting device (OLED), a liquid crystal display (LCD), an electronic paper or a solar cell.

Polyimide resins are highly heat resistant resins that are typically produced by solution polymerization of an aromatic dianhydride and an aromatic diamine to prepare an intermediate polyamic acid, which is followed by a separate dehydration ring-closure at a high temperature to imidize the polyamic acid derivative and provide the polyimide polymer. Although the intermediate polyamic acid may be soluble in many common solvents, the final polyimide polymers in use today are typically insoluble.

Polyimide polymers as a class present difficulties for processing into films and substrates for electronic devices. The polyimide polymers for such applications are insoluble in a wide range of solvents. This characteristic, along with the high softening temperature of the polymers, have made aromatic polyimide polymers difficult and costly to fabricate into useful products. Although polyimide polymers can meet the requirement of a flexible display, because of these properties, the polyimide polymers cannot be processed by a conventional casting process.

In order to synthesize a polyimide polymer, generally, a diamine monomer and a dianhydride monomer are polymerized in a polar organic solvent such as N-methyl-2-pyrolidone (NMP), dimethylacetamide (DMAc) and dimethylformamide (DMF) through a condensation polymerization to obtain a polyamic acid solution, and the obtained polyamic acid solution is coated on silicon wafer, glass, or the like, and then thermally treated at a high temperature so as to be cured (or hardened) to form the polyimide coating layer.

Commercial polyimide products for use in the fabrication of semiconductor devices are supplied as a polyimide precursor solution (i.e., as a solution of the intermediate polyamic acid). Accordingly, the fabrication of films, coatings and substrates from these insoluble aromatic polyimides generally requires elaborate production processes. For example, films are formed from the soluble intermediate polyamic acid precursor of the insoluble polyimide polymer. After excess solvent is removed, the film is thermally cured at high temperature to dehydrate the polyamic acid precursor film to form the cyclized polyimide film. It may take up to 5-6 hours and 4-5 curing steps with a special curing profile for the total curing process.

This two-step process has a number of significant disadvantages. Because the process involves two separate steps, and the curing step is performed at high temperature for an extended period, the throughput is low, which is costly. Additionally, the multistep coating and curing processes can affect the yield of the devices due to the higher contamination risk during the coating and curing process and also increase the difficulty of delaminating the cured polyimide layer from the substrate. Further, the conversion of polyamic acid to polyimide results in shrinkage of the film and can introduce stress into the device. Because preparing the polyimide polymer requires a high curing temperature (i.e., 300° C. or higher), it cannot be used in applications that are vulnerable to heat. Additionally, the high temperature curing of the polyamic acid precursor film can result in incomplete imidization in the final polyimide film.

The present disclosure addresses one or more of the disadvantages of current commercial aromatic polyimide polymers. The present disclosure provides polyimide polymers, which maintain high thermal stability, while providing improved solubility in organic solvents. The high solubility allows for improved processing characteristics and for the use of simplified processing techniques such as casting. Accordingly, the polyimide polymers may be used in cure-free processes, reducing processing time, saving energy costs, increasing the throughput, and increasing the device yield.

The polyimide is prepared from at least one aromatic dianhydride and at least one aromatic diamine. The polyimide is produced by the solution phase polycondensation reaction of the aromatic dianhydride and the aromatic diamine to form an intermediate polyamic acid solution. In the process of the present disclosure, the polyamic acid intermediate undergoes a solution-phase imidization to produce the polyimide polymer. The process provides a polyimide polymer with a very high degree of imidization.

### Dianhydride

The polyimide is prepared from at least one aromatic dianhydride. The aromatic dianhydride comprises an aromatic group and two cyclic carboxylic acid anhydride groups.

The aromatic dianhydride may be represented by the formula I:

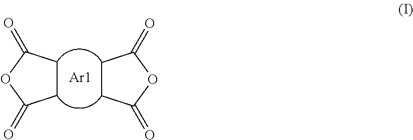

wherein Ar1 is a group comprising one or more aromatic rings. Preferably, Ar1 comprises one or more phenyl groups.

For aromatic dianhydrides according to Formula I, Ar1 may be selected from:

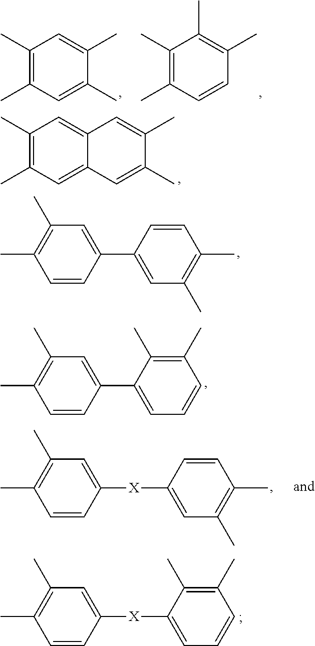

wherein X is selected from the group consisting of —CH₂—, —C(CH₃)₂—, —C(CF₃)₂—, —O—, —C(═O)—, —SO₂—,

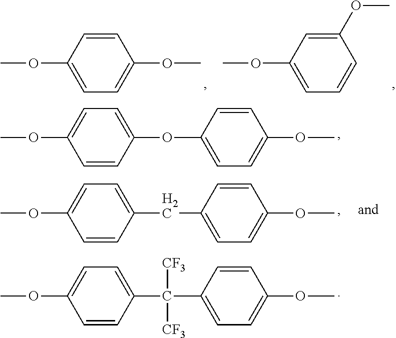

Examples of the aromatic dianhydrides that may be used in polyimide polymer include one or more of:

s-BPDA (3,3′,4,4′-biphenyltetracarboxylic dianhydride),
a-BPDA (2,3,3′,4′-biphenyltetracarboxylic dianhydride),
BPTA (3,3′,4,4′-benzophenone tetracarboxylic dianhydride),
PMDA (pyromellitic dianhydride),
ODPA (diphenyl ether tetracarboxylic acid dianhydride).
HQDA (hydroquinone diphthalic anhydride)
BPADA (4,4′-(4,4′-isopropylidenediphenoxy)bis-(phthalic anhydride))
HFPDPA (4,4′-(hexafluoroisopropylidene)diphthalic anhydride)

In certain embodiment of the disclosure, the polyimide polymer is prepared from two different aromatic dianhydrides.

The polyimide polymer may be prepared from one or more aromatic dianhydrides having the Formula II:

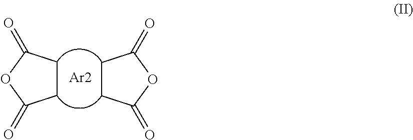

wherein Ar2 is a selected from the group consisting of:

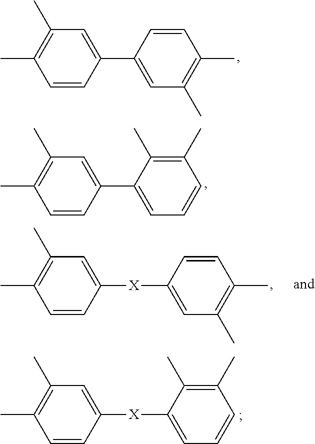

wherein X is selected from the group consisting of —CH₂—, —C(CH₃)₂—, —C(CF₃)₂—, —O—, —C(═O)—, —SO₂—,

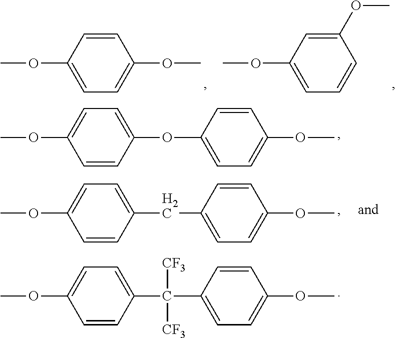

The polyimide polymer may be prepared from a combination of PMDA and an additional aromatic dianhydride having the Formula II:

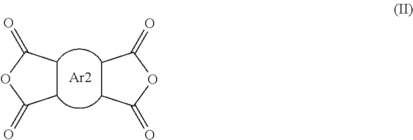

wherein Ar2 is a selected from the group consisting of:

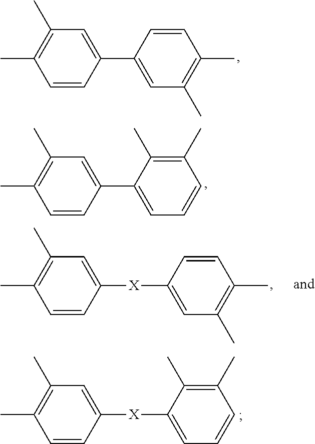

wherein X is selected from the group consisting of —CH₂—, —C(CH₃)₂—, —C(CF₃)₂—, —O—, —C(═O)—, —SO₂—,

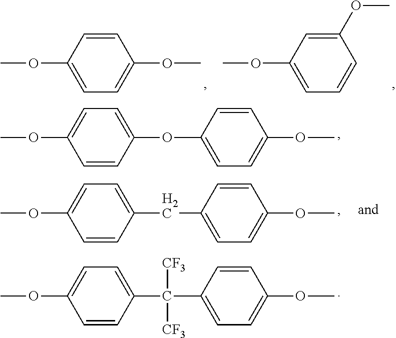

The aromatic dianhydride monomers may comprise from about 20 mol % to about 80 mol % PMDA and about 20 mol % to about 80 mol % of an aromatic dianhydride having the Formula II, based on the total amount of dianhydride in the polyimide; or from about 30 mol % to about 70 mol % PMDA and about 30 mol % to about 70 mol % of an aromatic dianhydride having the Formula II, based on the total amount of dianhydride in the polyimide; or from about 40 mol % to about 60 mol % PMDA and about 40 mol % to about 60 mol % of an aromatic dianhydride having the Formula II, based on the total amount of dianhydride in the polyimide; or from about 45 mol % to about 55 mol % PMDA and about 45 mol % to about 55 mol % of an aromatic dianhydride having the Formula II, based on the total amount of dianhydride in the polyimide.

The polyimide polymer may be prepared from a combination of two or more aromatic dianhydrides having the Formula II:

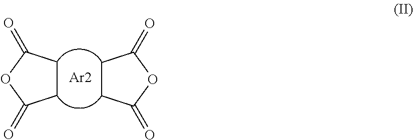

wherein Ar2 is a selected from the group consisting of:

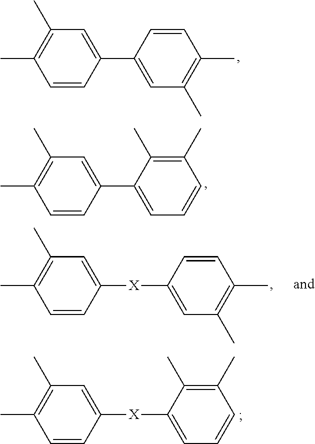

wherein X is selected from the group consisting of —CH₂—, —C(CH₃)₂—, —C(CF₃)₂—, —O—, —C(═O)—, —SO₂—,

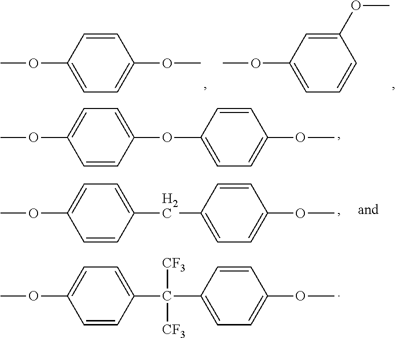

### Diamine

The polyimide is prepared from at least one aromatic diamine. The aromatic diamine comprises an aromatic group and two primary amine groups. The aromatic diamine may be represented by the formula III:

H₂N-Ar3-NH₂ (III)

wherein Ar3 is a group comprising one or more aromatic rings.

For aromatic diamines according to Formula III, Ar3 may be selected from:

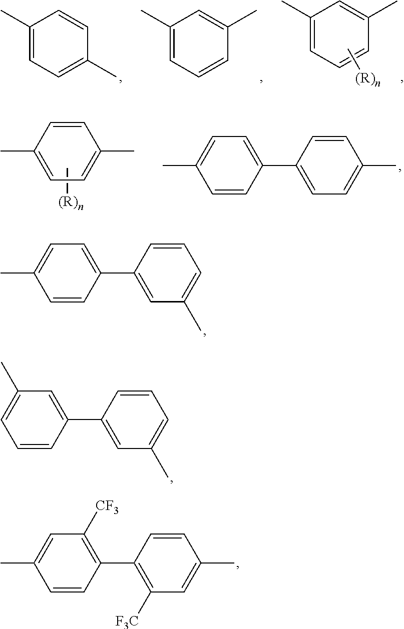

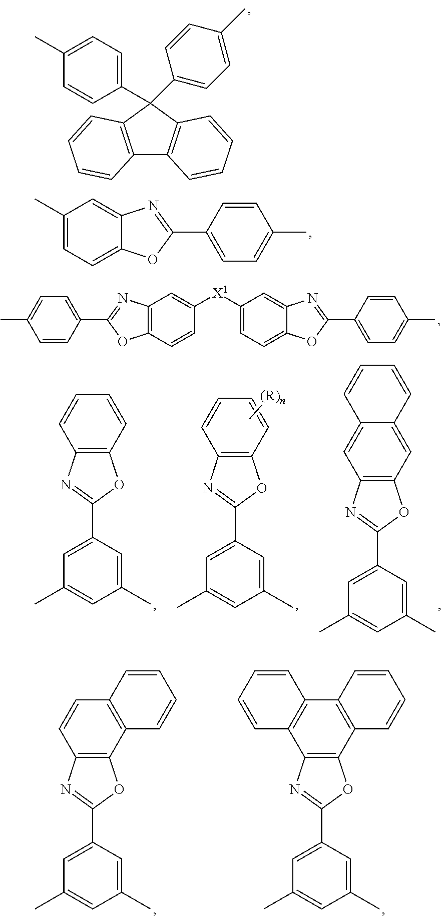

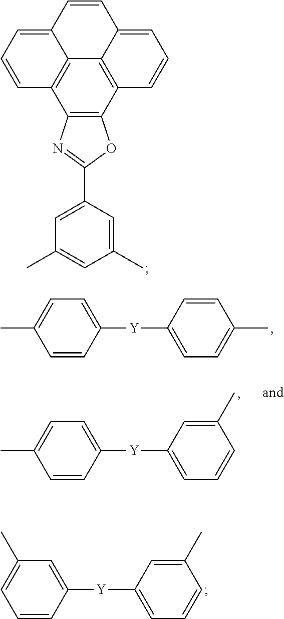

wherein
each R is independently selected from the group consisting of F, Cl, and CF₃;
each n independently selected from is 0, 1 or 2;
X₁ is selected from the group consisting of a chemical single bond, —CH₂—, and —O—;
each Y is independently selected from the group consisting of —CH₂—, —C(CH₃)₂—, —C(CF₃)₂—, —O—, —C(═O)—, —SO₂—,

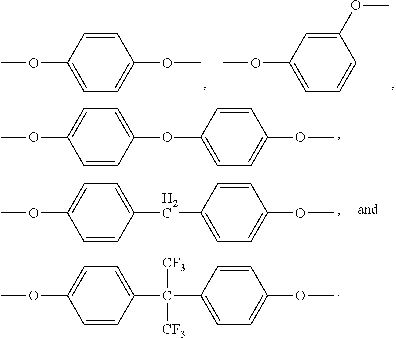

Examples of the aromatic diamines that may be used in polyimide polymer include:

FDA (4,4′-(9-fluorenylidene)dianiline
TFDB (2,2′-bis(trifluoromethyl)benzidine
BZDA (5-benzooxazol-2-yl-benzene-1,3-diamine
DHBZ (3,3′-dihydroxybenzidine)
p-PDA (p-phenylenediamine),
m-PDA (m-phenylenediamine),
4,4′-ODA (4,4′-oxybisbenzenamine),

### HFPDA (4,4′-(Hexafluoroisopropylidene)dianiline),

BAS (Bis-(3-amino-4-hydroxyphenyl)sulfone),
APAB 2-(4-aminophenyl)-5-amino-benzoxazole
DADPM (3,3′-diaminodiphenylmethane),
IDDA (4,4′-(4,4′-Isopropylidenediphenyl-1,1′-diyldioxy)-dianiline),

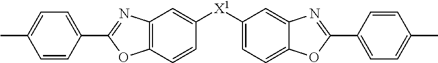

### DA1: X¹=“-”, 18330-82-0,

### DA2: X¹=—O—, 47733-92-6,

DA3: X¹=—CH₂—, 59941-53-6.

In preferred embodiments of the disclosure, at least one of the aromatic diamines used to prepare the polyimide polymer is selected from FDA and TFDB.

In certain embodiments of the disclosure, the polyimide polymer is prepared from two or more different aromatic diamines.

The polyimide polymer may be prepared from one or more aromatic diamines having the Formula IV:

H₂N-Ar4-NH₂ (IV)

wherein Ar4 is selected from the group consisting of:

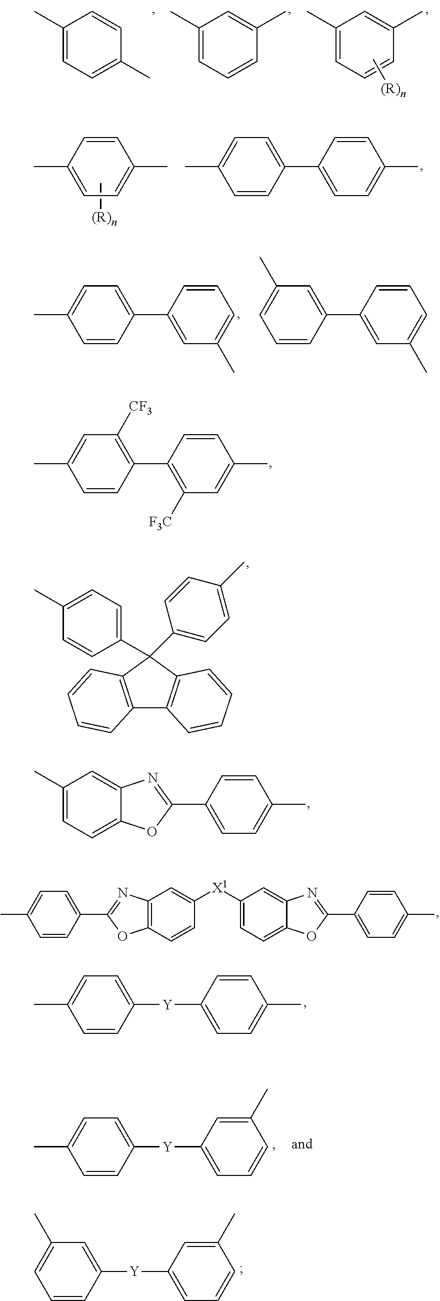

wherein
each R is independently selected from the group consisting of F, Cl, and CF₃;
each n independently selected from is 0, 1 or 2;
X₁ is selected from the group consisting of a chemical single bond, —CH₂—, and —O—;
each Y is independently selected from the group consisting of —CH₂—, —C(CH₃)₂—, —C(CF₃)₂—, —O—, —C(═O)—, —SO₂—,

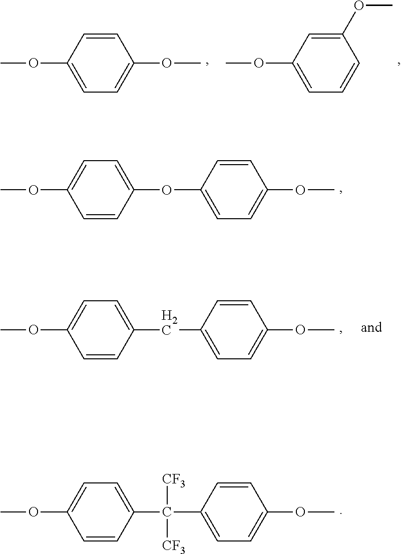

The polyimide polymer may be prepared from one or more aromatic diamines having the Formula V:

H₂N-Ar5-NH₂ (V)

wherein Ar5 is selected from the group consisting of:

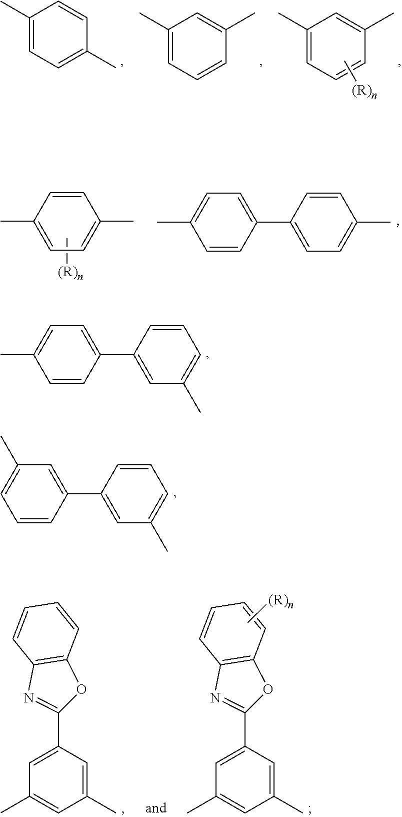

wherein
each R is independently selected from the group consisting of F, Cl, and CF₃; and
n is 0, 1 or 2.

The polyimide polymer may be prepared from one or more aromatic diamines having the Formula VI:

H₂N-Ar6-NH₂ (VI)

wherein Ar6 is selected from the group consisting of:

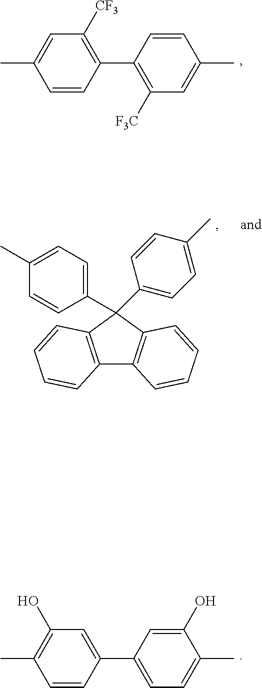

The polyimide polymer may be prepared from one or more aromatic diamines having the Formula VII:

H₂N-Ar7-NH₂ (VII)

wherein Ar7 is selected from the group consisting of:

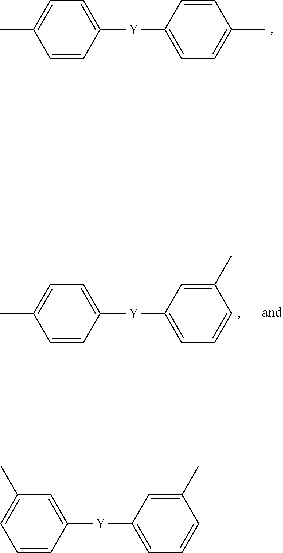

wherein
Y is selected from the group consisting of —CH₂—, —C(CH₃)₂—, —C(CF₃)₂—, —O—, —C(═O)—, —SO₂—,

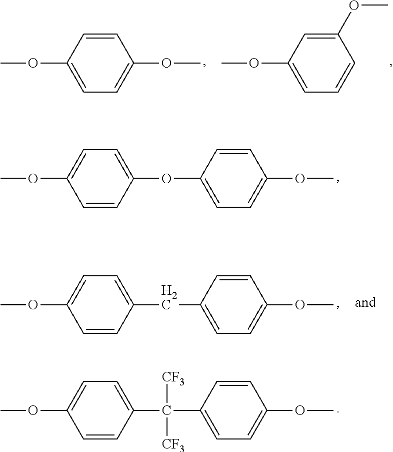

The aromatic diamine component of the polyimide polymer may comprise one or more aromatic diamines having the formula VIII:

H₂N-Ar8-NH₂ (VIII)

wherein Ar8 is selected from the group consisting of:

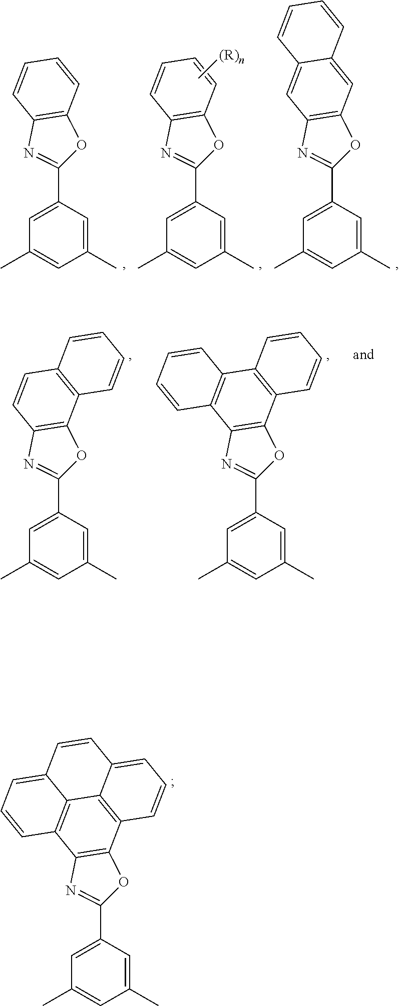

wherein
each R is independently selected from the group consisting of F, Cl, and CF₃; and
n is 0, 1 or 2.

The aromatic diamine component of the polyimide polymer may comprise the aromatic diamines (a), (b), and optionally (c):

(a) one or more aromatic diamines having the formula V:

H₂N-Ar5-NH₂ (V)

wherein Ar5 is selected from the group consisting of:

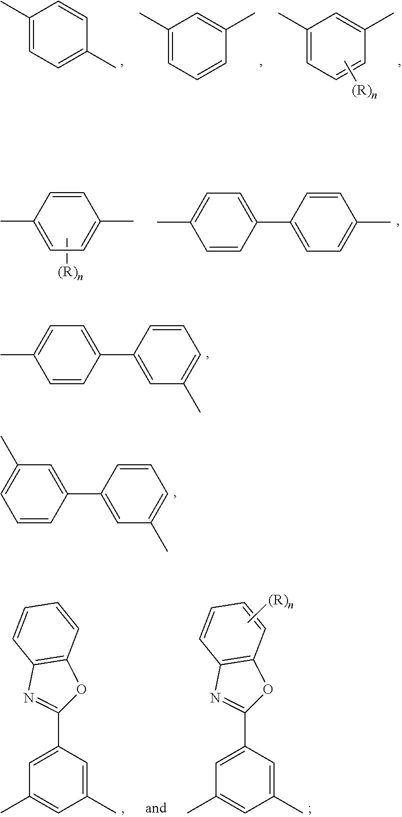

wherein
each R is independently selected from the group consisting of F, Cl, and CF₃; and
n is 0, 1 or 2;
(b) one or more aromatic diamines having the formula VI

H₂N-Ar6-NH₂ (VI)

wherein Ar6 is selected from the group consisting of:

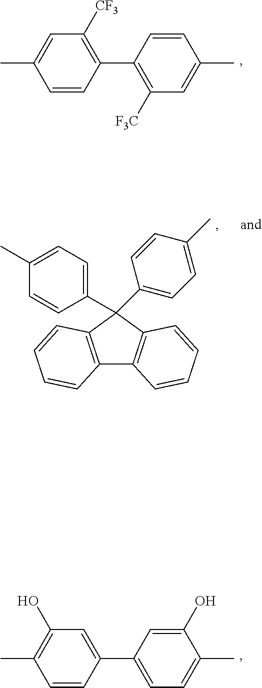

and
(c) optionally one or more aromatic diamines having the formula VII:

H₂N-Ar7-NH₂ (VII)

wherein Ar7 is selected from the group consisting of:

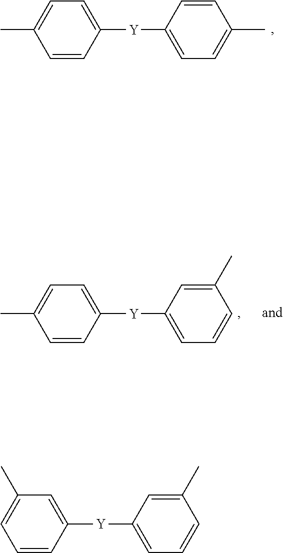

wherein
Y is selected from the group consisting of —CH₂—, —C(CH₃)₂—, —C(CF₃)₂—, —O—, —C(═O)—, —SO₂—,

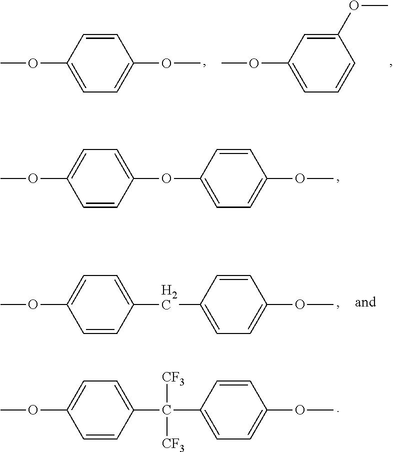

The aromatic diamine monomers may comprise from about 20 mol % to about 80 mol % of an aromatic diamine of Formula V and about 20 mol % to about 80 mol % of an aromatic diamine having the Formula VI, based on the total amount of diamine in the polyimide; or from about 30 mol % to about 70 mol % of an aromatic diamine of Formula V and about 30 mol % to about 70 mol % of an aromatic diamine having the Formula VI, based on the total amount of diamine in the polyimide; or from about 40 mol % to about 60 mol % of an aromatic diamine of Formula V and about 40 mol % to about 60 mol % of an aromatic diamine having the Formula VI, based on the total amount of diamine in the polyimide; or from about 45 mol % to about 55 mol % of an aromatic diamine of Formula V and about 45 mol % to about 55 mol % of an aromatic diamine having the Formula VI, based on the total amount of diamine in the polyimide.

Alternatively, the aromatic diamine monomers may comprise from about 10 mol % to about 50 mol % of an aromatic diamine of Formula V and about 50 mol % to about 90 mol % of an aromatic diamine having the Formula VI, based on the total amount of diamine in the polyimide; or from about 20 mol % to about 40 mol % of an aromatic diamine of Formula V and about 60 mol % to about 80 mol % of an aromatic diamine having the Formula VI, based on the total amount of diamine in the polyimide; or from about 15 mol % to about 25 mol % of an aromatic diamine of Formula V and about 75 mol % to about 85 mol % of an aromatic diamine having the Formula VI, based on the total amount of diamine in the polyimide; or from about 20 mol % to about 30 mol % of an aromatic diamine of Formula V and about 70 mol % to about 80 mol % of an aromatic diamine having the Formula VI, based on the total amount of diamine in the polyimide.

The aromatic diamine monomers may comprise from about 10 mol % to about 45 mol % of an aromatic diamine of Formula V, about 10 mol % to about 45 mol % of an aromatic diamine having the Formula VI, and about 10 mol % to about 45 mol % of an aromatic diamine having the Formula VII, based on the total amount of diamine in the polyimide; or from about 20 mol % to about 40 mol % of an aromatic diamine of Formula V, about 20 mol % to about 40 mol % of an aromatic diamine having the Formula VI, and about 20 mol % to about 40 mol % of an aromatic diamine having the Formula VII, based on the total amount of diamine in the polyimide.

The aromatic diamine monomers may comprise from about 10 mol % to about 30 mol % of an aromatic diamine of Formula V, about 40 mol % to about 80 mol % of an aromatic diamine having the Formula VI, about 10 mol % to about 30 mol % of an aromatic diamine having the Formula VII, based on the total amount of diamine in the polyimide; or from about 10 mol % to about 25 mol % of an aromatic diamine of Formula V, about 50 mol % to about 75 mol % of an aromatic diamine having the Formula VI, about 10 mol % to about 25 mol % of an aromatic diamine having the Formula VII, based on the total amount of diamine in the polyimide; or from about 10 mol % to about 20 mol % of an aromatic diamine of Formula V, about 60 mol % to about 70 mol % of an aromatic diamine having the Formula VI, about 10 mol % to about 20 mol % of an aromatic diamine having the Formula VII, based on the total amount of diamine in the polyimide.

The aromatic diamine component of the polyimide polymer may comprise the aromatic diamines (a) and (b):

(a) one or more aromatic diamines having the formula VI

H₂N-Ar6-NH₂ (VI)

wherein Ar6 is selected from the group consisting of:

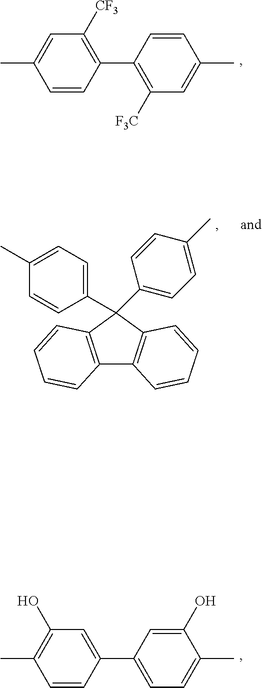

(b) one or more aromatic diamines having the formula VII:

H₂N-Ar7-NH₂ (VII)

wherein Ar7 is selected from the group consisting of:

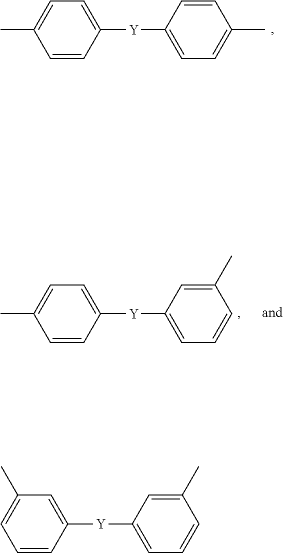

wherein
Y is selected from the group consisting of —CH₂—, —C(CH₃)₂—, —C(CF₃)₂—, —O—, —C(═O)—, —SO₂—,

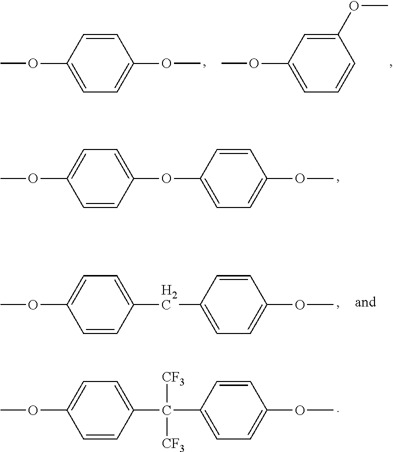

The aromatic diamine component of the polyimide polymer may comprise the aromatic diamines (a) and optionally (b):

(a) two or more aromatic diamines having the formula VI

H₂N-Ar6-NH₂ (VI)

wherein Ar6 is selected from the group consisting of:

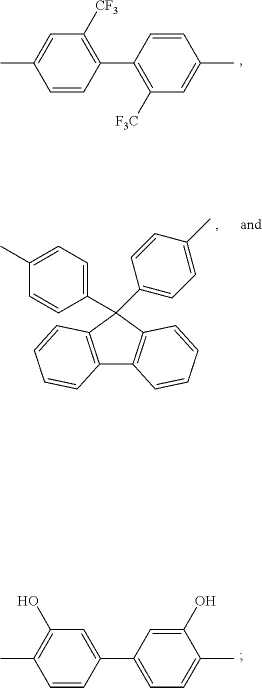

and
(b) optionally, one or more aromatic diamines having the formula VII:

H₂N-Ar7-NH₂ (VII)

wherein Ar7 is selected from the group consisting of:

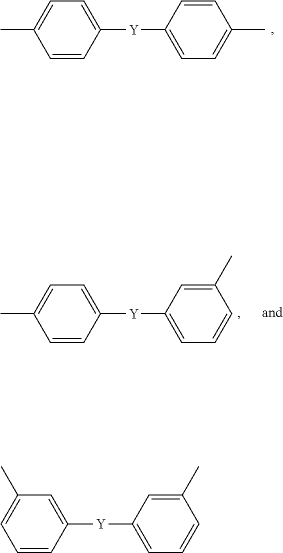

wherein
Y is selected from the group consisting of —CH₂—, —C(CH₃)₂—, —C(CF₃)₂—, —O—, —C(═O)—, —SO₂—,

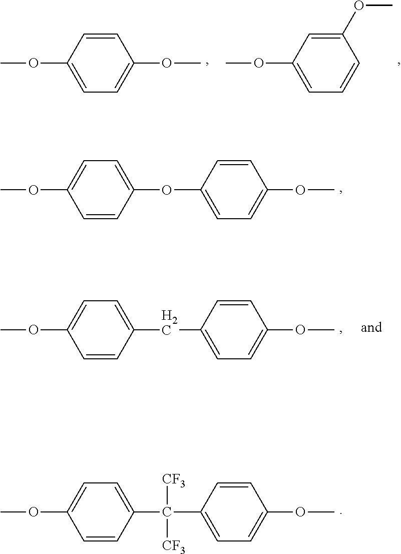

The aromatic diamine monomers may comprise from about 20 mol % to about 80 mol % of an aromatic diamine of Formula V and about 20 mol % to about 80 mol % of an aromatic diamine having the Formula VI, based on the total amount of diamine in the polyimide; or from about 30 mol % to about 70 mol % of an aromatic diamine of Formula V and about 30 mol % to about 70 mol % of an aromatic diamine having the Formula VI, based on the total amount of diamine in the polyimide; or from about 40 mol % to about 60 mol % of an aromatic diamine of Formula V and about 40 mol % to about 60 mol % of an aromatic diamine having the Formula VI, based on the total amount of diamine in the polyimide; or from about 45 mol % to about 55 mol % of an aromatic diamine of Formula V and about 45 mol % to about 55 mol % of an aromatic diamine having the Formula VI, based on the total amount of diamine in the polyimide.

Alternatively, the aromatic diamine monomers may comprise from about 10 mol % to about 50 mol % of an aromatic diamine of Formula V and about 50 mol % to about 90 mol % of aromatic diamine having the Formula VI, based on the total amount of diamine in the polyimide; or from about 20 mol % to about 40 mol % of an aromatic diamine of Formula V and about 60 mol % to about 80 mol % of an aromatic diamine having the Formula VI, based on the total amount of diamine in the polyimide; or from about 15 mol % to about 25 mol % of an aromatic diamine of Formula V and about 75 mol % to about 85 mol % of an aromatic diamine having the Formula VI, based on the total amount of diamine in the polyimide; or from about 20 mol % to about 30 mol % of an aromatic diamine of Formula V and about 70 mol % to about 80 mol % of an aromatic diamine having the Formula VI, based on the total amount of diamine in the polyimide.

The aromatic diamine component of the polyimide polymer may comprise the aromatic diamines (a) and optionally (b):

(a) one or more aromatic diamines having the formula VIII

H₂N-Ar8-NH₂ (VIII)

wherein Ar8 is selected from the group consisting of:

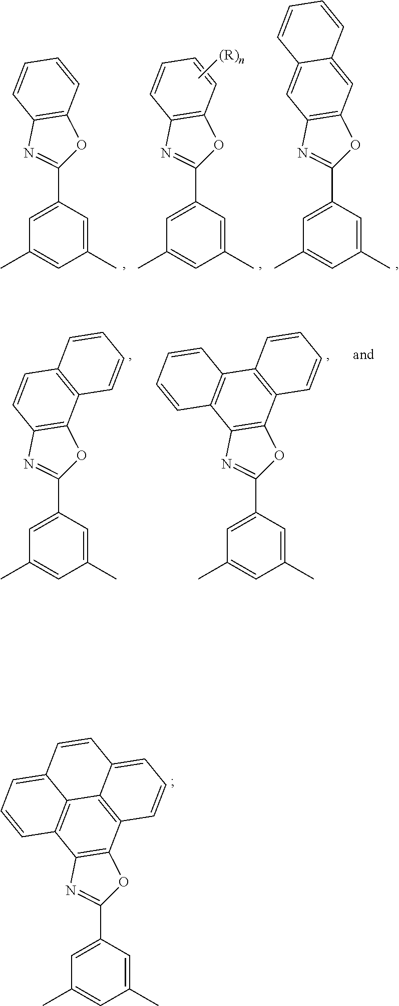

wherein
each R is independently selected from the group consisting of F, Cl, and CF₃; and
(b) optionally, one or more aromatic diamines having the formula IV:

H₂N-Ar4-NH₂ (IV)

wherein Ar4 is selected from the group consisting of:

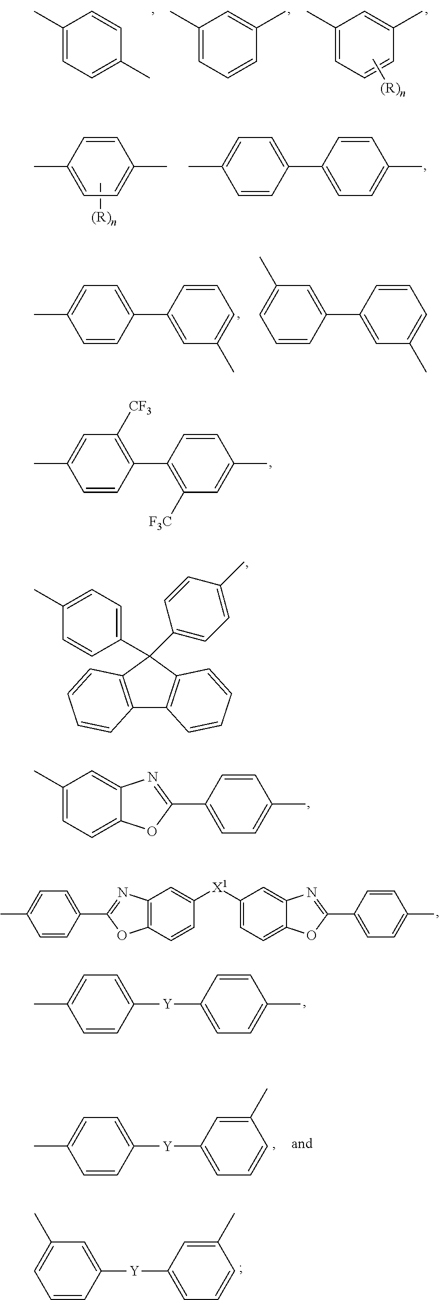

wherein
each R is independently selected from the group consisting of F, Cl, and CF₃;
each n is independently selected from 0, 1 or 2;
X₁ is selected from the group consisting of a chemical single bond, —CH₂—, and —O—;
each Y is independently selected from the group consisting of —CH₂—, —C(CH₃)₂—, —C(CF₃)₂—, —O—, —C(═O)—, —SO₂—,

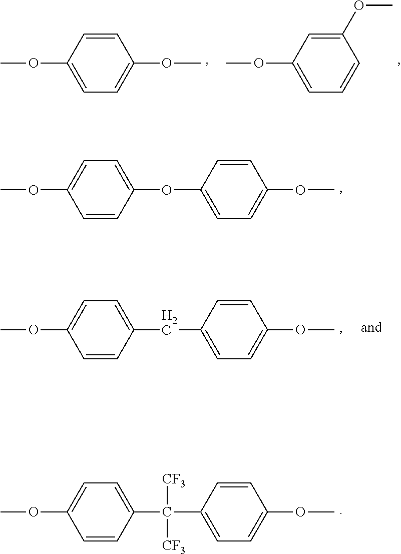

The aromatic diamine monomers may comprise from about 20 mol % to about 80 mol % of an aromatic diamine of Formula IV and about 20 mol % to about 80 mol % of an aromatic diamine having the Formula VIII, based on the total amount of diamine in the polyimide; or from about 30 mol % to about 70 mol % of an aromatic diamine of Formula IV and about 30 mol % to about 70 mol % of an aromatic diamine having the Formula VIII, based on the total amount of diamine in the polyimide; or from about 40 mol % to about 60 mol % of an aromatic diamine of Formula IV and about 40 mol % to about 60 mol % of an aromatic diamine having the Formula VIII, based on the total amount of diamine in the polyimide; or from about 45 mol % to about 55 mol % of an aromatic diamine of Formula IV and about 45 mol % to about 55 mol % of an aromatic diamine having the Formula VIII, based on the total amount of diamine in the polyimide.

Alternatively, the aromatic diamine monomers may comprise from about 10 mol % to about 50 mol % of an aromatic diamine of Formula VIII and about 50 mol % to about 90 mol % of an aromatic diamine having the Formula IV, based on the total amount of diamine in the polyimide; or from about 20 mol % to about 40 mol % of an aromatic diamine of Formula VIII and about 60 mol % to about 80 mol % of an aromatic diamine having the Formula IV, based on the total amount of diamine in the polyimide; or from about 15 mol % to about 25 mol % of an aromatic diamine of Formula VIII and about 75 mol % to about 85 mol % of an aromatic diamine having the Formula IV, based on the total amount of diamine in the polyimide; or from about 20 mol % to about 30 mol % of an aromatic diamine of Formula VIII and about 70 mol % to about 80 mol % of an aromatic diamine having the Formula IV, based on the total amount of diamine in the polyimide.

The aromatic diamine component of the polyimide polymer may comprise the aromatic diamines (a), optionally (b) and optionally (c):

(a) one or more aromatic diamines having the formula VIII

H₂N-Ar8-NH₂ (VIII)

wherein Ar8 is selected from the group consisting of:

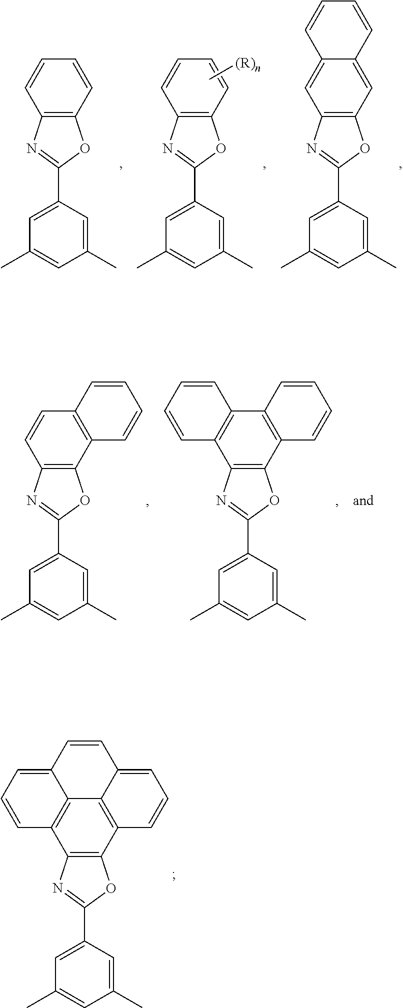

wherein
each R is independently selected from the group consisting of F, Cl, and CF₃; and
(b) optionally, one or more aromatic diamines having the formula VI

H₂N-Ar6-NH₂ (VI)

wherein Ar6 is selected from the group consisting of:

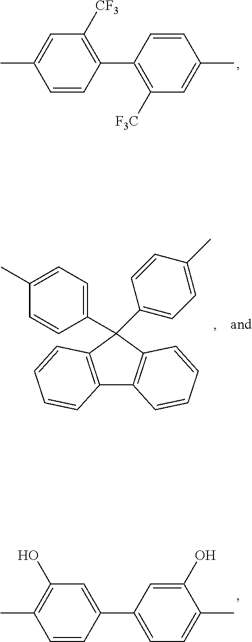

and
(c) optionally one or more aromatic diamines having the formula VII:

H₂N-Ar7-NH₂ (VII)

wherein Ar7 is selected from the group consisting of:

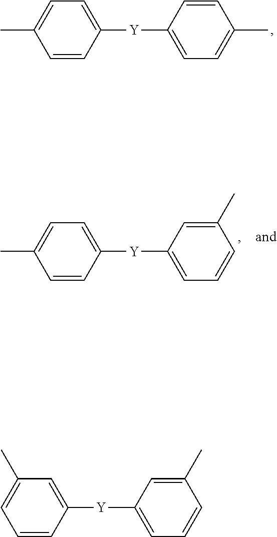

wherein
Y is selected from the group consisting of —CH₂—, —C(CH₃)₂—, —C(CF₃)₂—, —O—, —C(═O)—, —SO₂—,

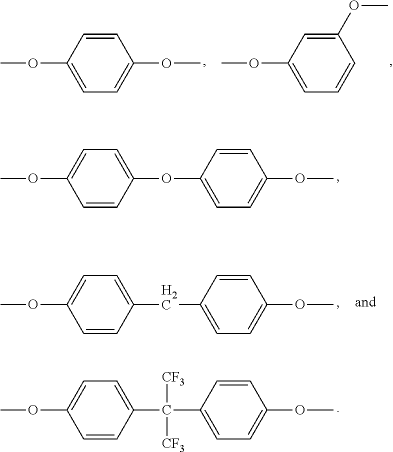

The aromatic diamine monomers may comprise from about 20 mol % to about 80 mol % of an aromatic diamine of Formula VI and about 20 mol % to about 80 mol % of an aromatic diamine having the Formula VIII, based on the total amount of diamine in the polyimide; or from about 30 mol % to about 70 mol % of an aromatic diamine of Formula VI and about 30 mol % to about 70 mol % of an aromatic diamine having the Formula VIII, based on the total amount of diamine in the polyimide; or from about 40 mol % to about 60 mol % of an aromatic diamine of Formula VI and about 40 mol % to about 60 mol % of an aromatic diamine having the Formula VIII, based on the total amount of diamine in the polyimide; or from about 45 mol % to about 55 mol % of an aromatic diamine of Formula VI and about 45 mol % to about 55 mol % of an aromatic diamine having the Formula VIII, based on the total amount of diamine in the polyimide.

Alternatively, the aromatic diamine monomers may comprise from about 10 mol % to about 50 mol % of an aromatic diamine of Formula VIII and about 50 mol % to about 90 mol % of an aromatic diamine having the Formula VI, based on the total amount of diamine in the polyimide; or from about 20 mol % to about 40 mol % of an aromatic diamine of Formula VIII and about 60 mol % to about 80 mol % of an aromatic diamine having the Formula VI, based on the total amount of diamine in the polyimide; or from about 15 mol % to about 25 mol % of an aromatic diamine of Formula VIII and about 75 mol % to about 85 mol % of an aromatic diamine having the Formula VI, based on the total amount of diamine in the polyimide; or from about 20 mol % to about 30 mol % of an aromatic diamine of Formula VIII and about 70 mol % to about 80 mol % of an aromatic diamine having the Formula VI, based on the total amount of diamine in the polyimide.

The aromatic diamine monomers may comprise from about 10 mol % to about 45 mol % of an aromatic diamine of Formula VIII, about 10 mol % to about 45 mol % of an aromatic diamine having the Formula VI, and about 10 mol % to about 45 mol % of an aromatic diamine having the Formula VII, based on the total amount of diamine in the polyimide; or from about 20 mol % to about 40 mol % of an aromatic diamine of Formula VIII, about 20 mol % to about 40 mol % of an aromatic diamine having the Formula VI, and about 20 mol % to about 40 mol % of an aromatic diamine having the Formula VII, based on the total amount of diamine in the polyimide.

The aromatic diamine monomers may comprise from about 10 mol % to about 30 mol % of an aromatic diamine of Formula VIII, about 40 mol % to about 80 mol % of an aromatic diamine having the Formula VI, and about 10 mol % to about 30 mol % of an aromatic diamine having the Formula VII, based on the total amount of diamine in the polyimide; or from about 10 mol % to about 25 mol % of an aromatic diamine of Formula VIII, about 50 mol % to about 75 mol % of an aromatic diamine having the Formula VI, and about 10 mol % to about 25 mol % of an aromatic diamine having the Formula VII, based on the total amount of diamine in the polyimide; or from about 10 mol % to about 20 mol % of an aromatic diamine of Formula VIII, about 60 mol % to about 70 mol % of an aromatic diamine having the Formula VI, and about 10 mol % to about 20 mol % of an aromatic diamine having the Formula VII, based on the total amount of diamine in the polyimide.

In preferred aspects of the polyimide polymer according to the preceding paragraphs, the polyimide polymer comprises at least one of TFDB and FDA. In other preferred aspects of the polyimide polymer according to the preceding paragraphs, the polyimide polymer comprises at both TFDB and FDA.

### Polyimide

The polyimide polymer has an alternating structure between monomers derived from the aromatic dianhydride(s) and monomers derived from the aromatic diamine(s).

The polyimide polymer may be prepared from a combination of aromatic dianhydrides and aromatic diamines comprising:

(a) one or more aromatic dianhydride represented by the formula I:

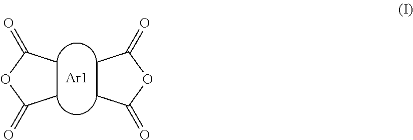

wherein
Ar1 is selected from the group consisting of:

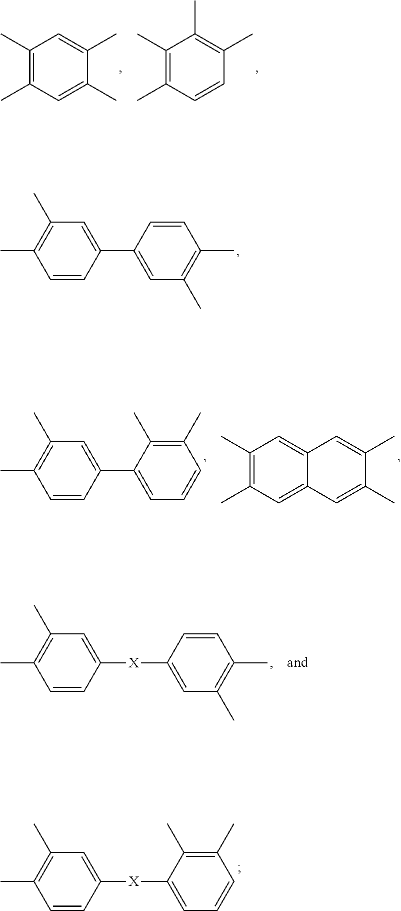

wherein X is selected from the group consisting of —CH₂—, —C(CH₃)₂—, —C(CF₃)₂—, —O—, —C(═O)—, —SO₂—,

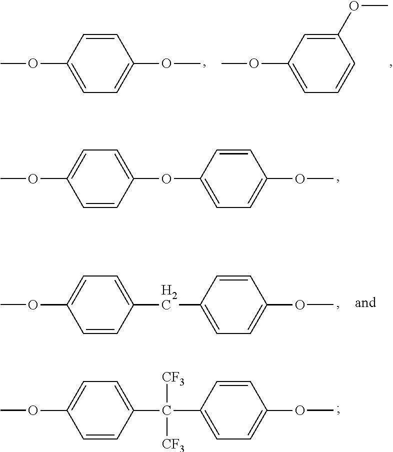

(b) one or more aromatic diamines having the formula V:

H₂N-Ar5-NH₂ (V)

wherein Ar5 is selected from the group consisting of:

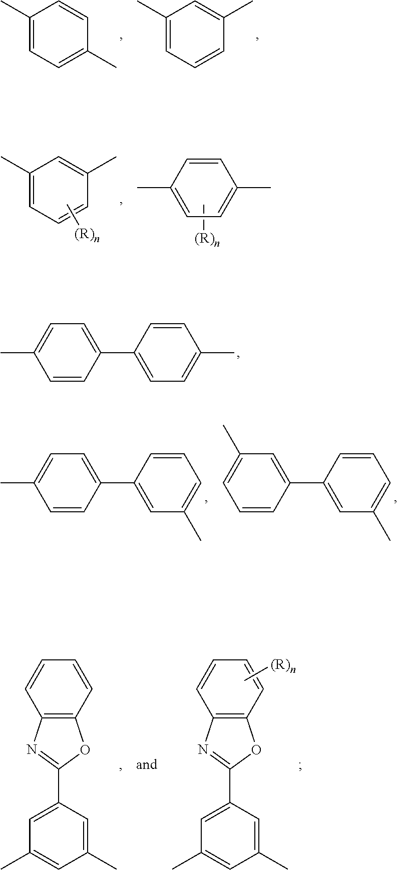

wherein
each R is independently selected from the group consisting of F, Cl, and CF₃; and
n is 0, 1 or 2;
(c) one or more aromatic diamines having the formula VI

H₂N-Ar6-NH₂ (VI)

wherein Ar6 is selected from the group consisting of:

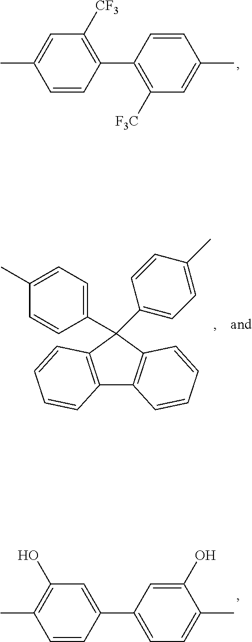

and
(d) optionally one or more aromatic diamines having the formula VII:

H₂N-Ar7-NH₂ (VII)

wherein Ar7 is selected from the group consisting of:

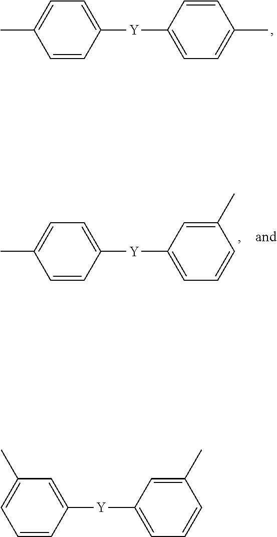

wherein
Y is selected from the group consisting of —CH₂—, —C(CH₃)₂—, —C(CF₃)₂—, —O—, —C(═O)—, —SO₂—,

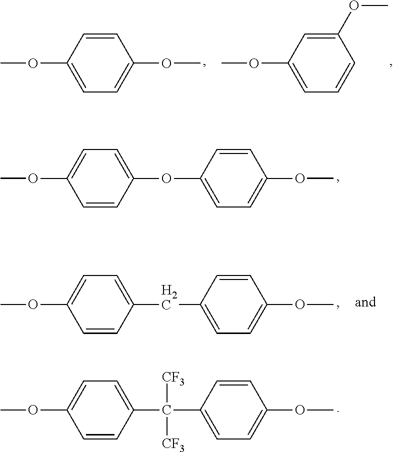

The polyimide polymer may be prepared from a combination of aromatic dianhydrides and aromatic diamines comprising:

(a) one or more aromatic dianhydride represented by the formula I:

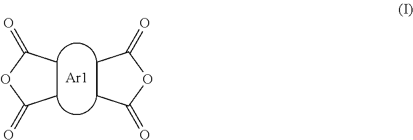

wherein
Ar1 is selected from the group consisting of:

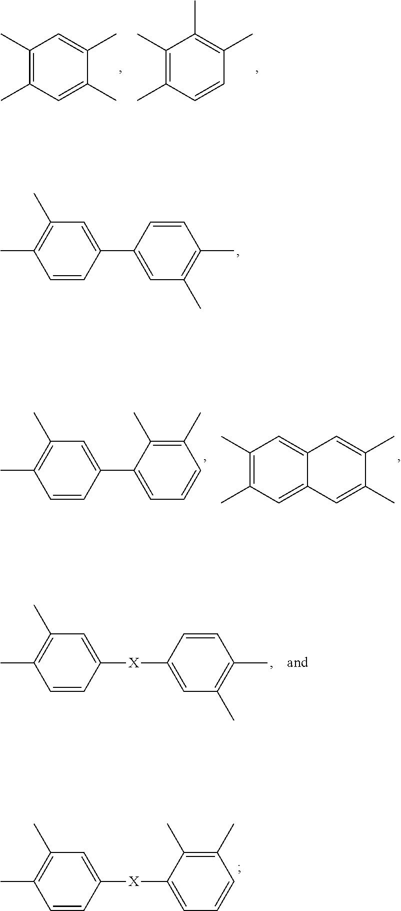

wherein X is selected from the group consisting of —CH₂—, —C(CH₃)₂—, —C(CF₃)₂—, —O—, —C(═O)—, —SO₂—,

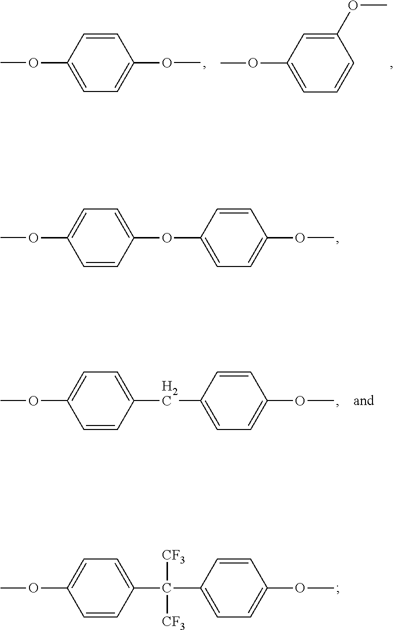

(b) one or more aromatic diamines having the formula VI

H₂N-Ar6-NH₂ (VI)

wherein Ar6 is selected from the group consisting of:

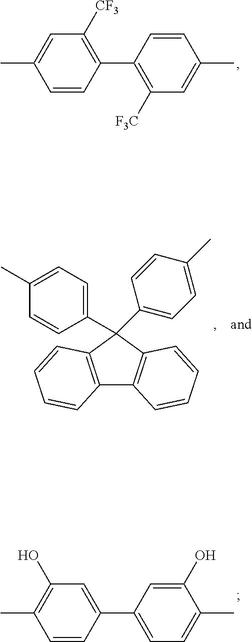

(c) optionally one or more aromatic diamines having the formula VII:

H₂N-Ar7-NH₂ (VII)

wherein Ar7 is selected from the group consisting of:

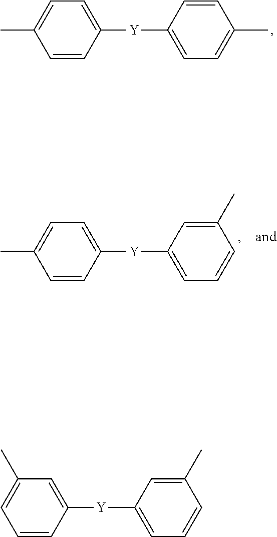

wherein
Y is selected from the group consisting of —CH₂—, —C(CH₃)₂—, —C(CF₃)₂—, —O—, —C(═O)—, —SO₂—,

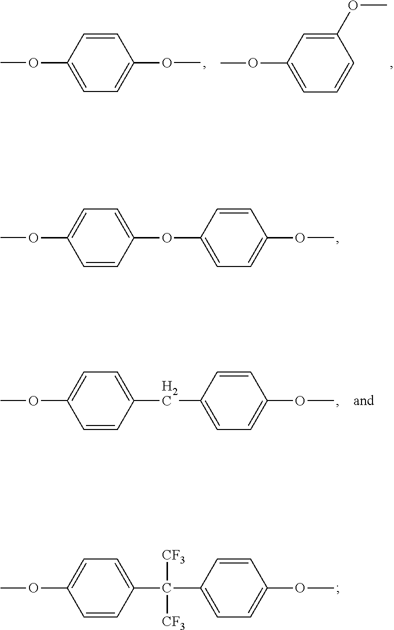

The polyimide polymer may be prepared from a combination of aromatic dianhydrides and aromatic diamines comprising:

(a) one or more aromatic dianhydrides represented by the formula I:

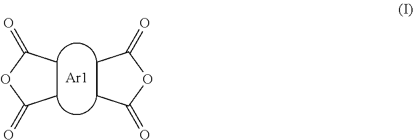

wherein
Ar1 is selected from the group consisting of:

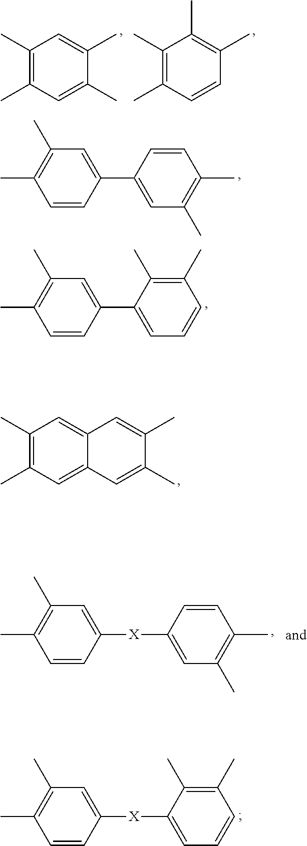

wherein X is selected from the group consisting of —CH₂—, —C(CH₃)₂—, —C(CF₃)₂—, —O—, —C(═O)—, —SO₂—,

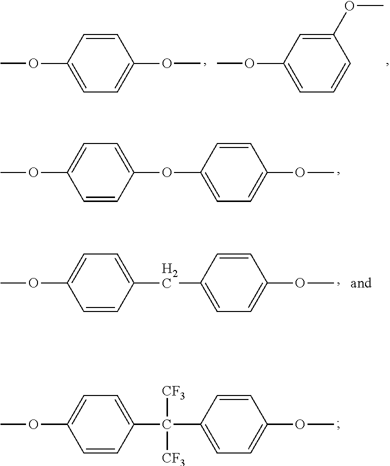

(b) two or more aromatic diamines having the formula VI

H₂N-Ar6-NH₂ (VI)

wherein Ar6 is selected from the group consisting of:

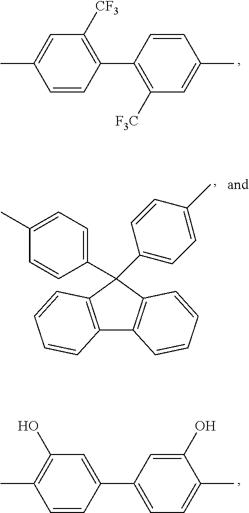

and
(c) optionally one or more aromatic diamines having the formula VII:

H₂N-Ar7-NH₂ (VII)

wherein Ar7 is selected from the group consisting of:

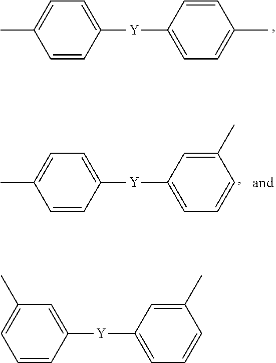

wherein
Y is selected from the group consisting of —CH₂—, —C(CH₃)₂—, —C(CF₃)₂—, —O—, —C(═O)—, —SO₂—,

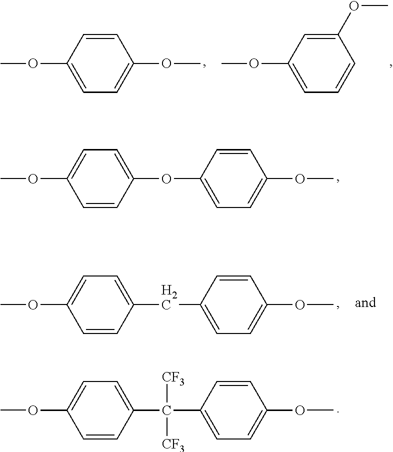

The polyimide polymer may be prepared from a combination of aromatic dianhydrides and aromatic diamines comprising:

(a) one or more aromatic dianhydrides represented by the formula I:

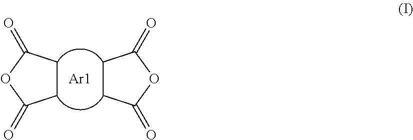

wherein
Ar1 is selected from the group consisting of:

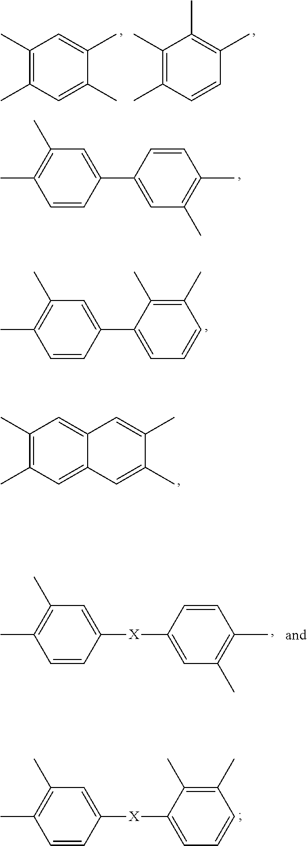

wherein X is selected from the group consisting of —CH₂—, —C(CH₃)₂—, —C(CF₃)₂—, —O—, —C(═O)—, —SO₂—,

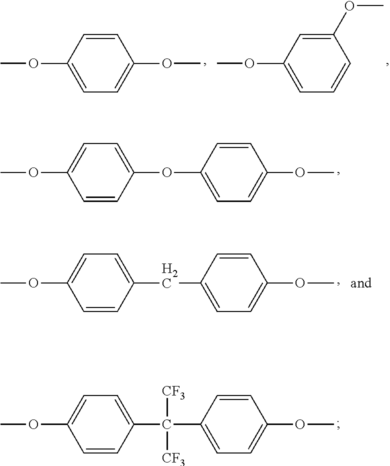

(b) one or more aromatic diamines having the formula VIII:

H₂N-Ar8-NH₂ (VIII)

wherein Ar8 is selected from the group consisting of:

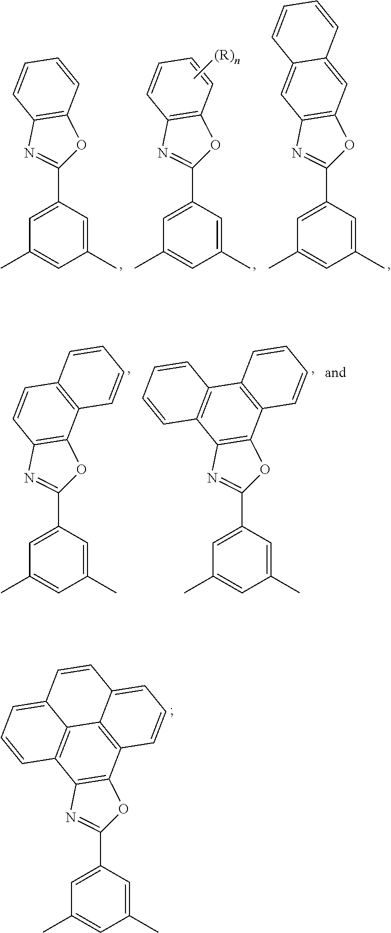

wherein
each R is independently selected from the group consisting of F, Cl, and CF₃; and
(c) optionally, one or more aromatic diamines having the formula IV:

H₂N-Ar4-NH₂ (IV)

wherein Ar4 is selected from the group consisting of:

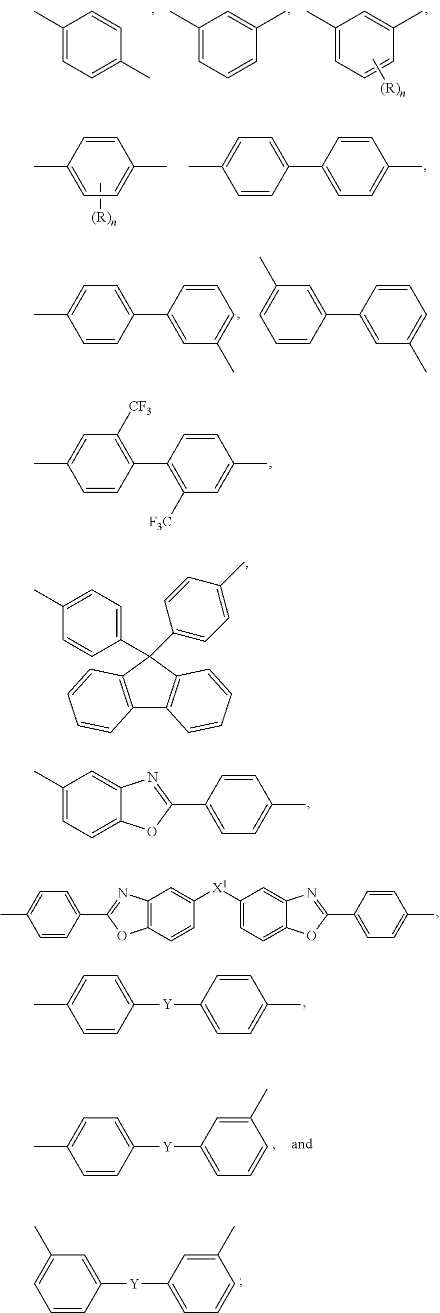

wherein
each R is independently selected from the group consisting of F, Cl, and CF₃;
each n is independently selected from 0, 1 or 2;
X₁ is selected from the group consisting of a chemical single bond, —CH₂—, and —O—;
each Y is independently selected from the group consisting of —CH₂—, —C(CH₃)₂—, —C(CF₃)₂—, —O—, —C(═O)—, —SO₂—,

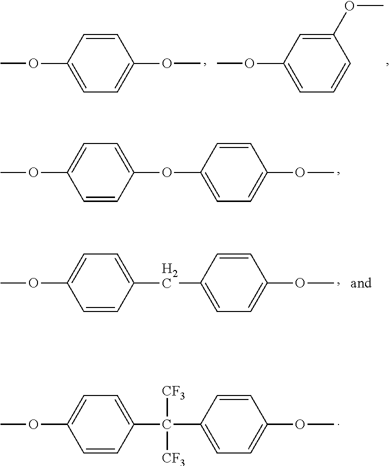

The polyimide polymer may be prepared from a combination of aromatic dianhydrides and aromatic diamines comprising:

(a) one or more aromatic dianhydrides represented by the formula I

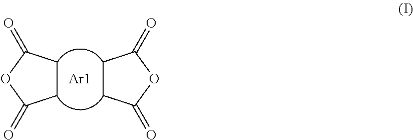

wherein
Ar1 is selected from the group consisting of:

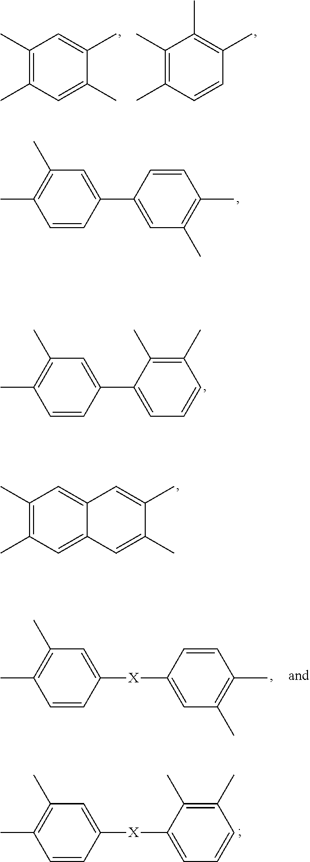

wherein X is selected from the group consisting of —CH₂—, —C(CH₃)₂—, —C(CF₃)₂—, —O—, —C(═O)—, —SO₂—,

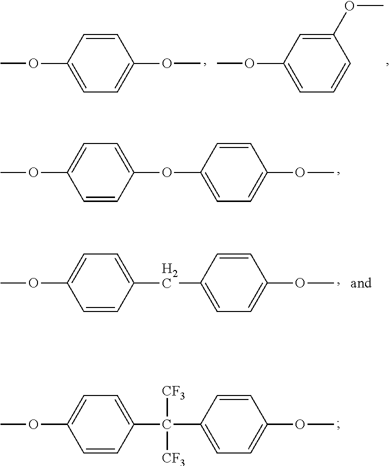

(b) one or more aromatic diamines having the formula VIII:

H₂N-Ar8-NH₂ (VIII)

wherein Ar8 is selected from the group consisting of:

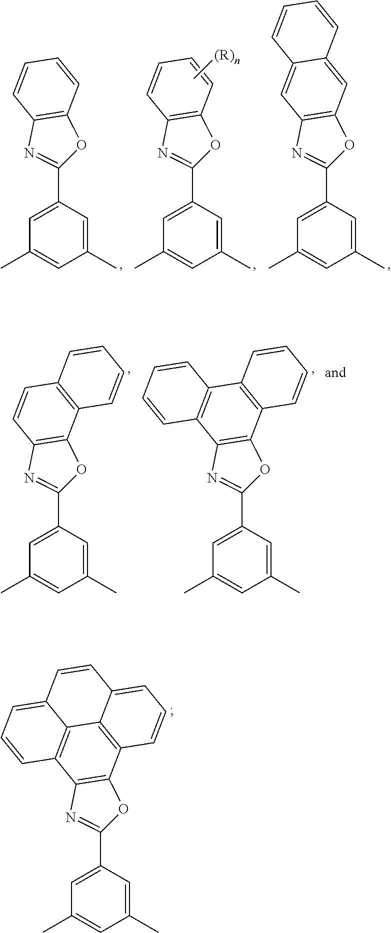

wherein
each R is independently selected from the group consisting of F, Cl, and CF₃;
(c) optionally, one or more aromatic diamines having the formula VI:

H₂N-Ar6-NH₂ (VI)

wherein Ar6 is selected from the group consisting of:

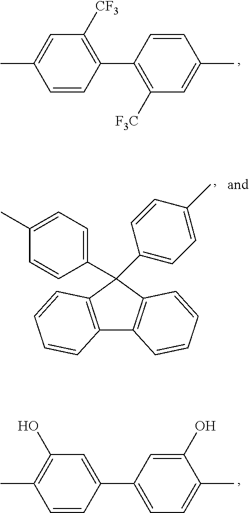

and
(d) optionally, one or more aromatic diamines having the formula VII:

H₂N-Ar7-NH₂ (VII)

wherein Ar7 is selected from the group consisting of:

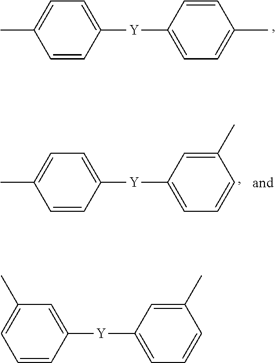

wherein
Y is selected from the group consisting of —CH₂—, —C(CH₃)₂—, —C(CF₃)₂—, —O—, —C(═O)—, —SO₂—,

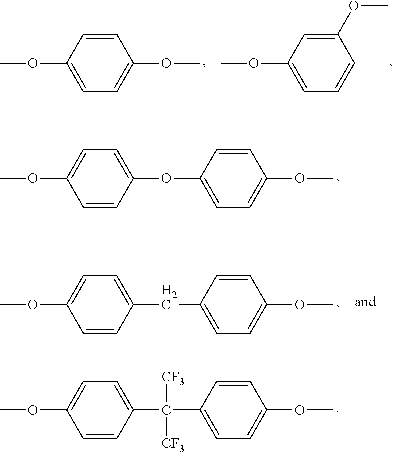

The present disclosure provides the polyimide polymers comprising the aromatic dianhydrides and aromatic diamines as listed in Table 1.

TABLE 1

| dianhydride | diamine |
|---|---|
| Formula I | Formula V |
| Formula I | Formula VIII |
| Formula II | Formula V |
| Formula II | Formula VIII |
| Formula I | TFDB |
| Formula I | FDA |
| Formula II | TFDB |
| Formula II | FDA |
| s-BPDA | TFDB |
| s-BPDA | FDA |
| a-BPDA | TFDB |
| a-BPDA | FDA |
| PMDA | TFDB |
| PMDA | FDA |
| ODPA | TFDB |
| ODPA | FDA |
| HQDA | TFDB |
| HQDA | FDA |
| BPADA | TFDB |
| BPADA | FDA |
| BPTA | TFDB |
| BPTA | FDA |
| HFPDPA | TFDB |
| HFPDPA | FDA |

The present disclosure provides the polyimide polymers comprising the aromatic dianhydrides and aromatic diamines as listed in Table 2.

TABLE 2

| Monomers in the polyimide | | | Relative mol % of each dianhydride | | |
|---|---|---|---|---|---|
| polymer | | | based on the total dianhydride in the | | |
| dianhydrides | | diamine | polyimide | | |
| PMDA | a-BPDA | TFDB | 25-75% | 35-65% | 45-55% |
| | | | PMDA | PMDA | PMDA |
| | | | 25-75% | 35-65% | 45-55% |
| | | | a-BPDA | a-BPDA | a-BPDA |
| PMDA | a-BPDA | FDA | 25-75% | 35-65% | 45-55% |
| | | | PMDA | PMDA | PMDA |
| | | | 25-75% | 35-65% | 45-55% |
| | | | a-BPDA | a-BPDA | a-BPDA |
| PMDA | s-BPDA | TFDB | 25-75% | 35-65% | 45-55% |
| | | | PMDA | PMDA | PMDA |
| | | | 25-75% | 35-65% | 45-55% |
| | | | s-BPDA | s-BPDA | s-BPDA |
| PMDA | s-BPDA | FDA | 25-75% | 35-65% | 45-55% |
| | | | PMDA | PMDA | PMDA |
| | | | 25-75% | 35-65% | 45-55% |
| | | | s-BPDA | s-BPDA | s-BPDA |
| PMDA | ODPA | TFDB | 25-75% | 35-65% | 45-55% |
| | | | PMDA | PMDA | PMDA |
| | | | 25-75% | 35-65% | 45-55% |
| | | | ODPA | ODPA | ODPA |
| PMDA | ODPA | FDA | 25-75% | 35-65% | 45-55% |
| | | | PMDA | PMDA | PMDA |
| | | | 25-75% | 35-65% | 45-55% |
| | | | ODPA | ODPA | ODPA |
| PMDA | HQDA | TFDB | 25-75% | 35-65% | 45-55% |
| | | | PMDA | PMDA | PMDA |
| | | | 25-75% | 35-65% | 45-55% |
| | | | HQDA | HQDA | HQDA |
| PMDA | HQDA | FDA | 25-75% | 35-65% | 45-55% |
| | | | PMDA | PMDA | PMDA |
| | | | 25-75% | 35-65% | 45-55% |
| | | | HQDA | HQDA | HQDA |
| PMDA | BPADA | TFDB | 25-75% | 35-65% | 45-55% |
| | | | PMDA | PMDA | PMDA |
| | | | 25-75% | 35-65% | 45-55% |
| | | | BPADA | BPADA | BPADA |
| PMDA | BPADA | FDA | 25-75% | 35-65% | 45-55% |
| | | | PMDA | PMDA | PMDA |
| | | | 25-75% | 35-65% | 45-55% |
| | | | BPADA | BPADA | BPADA |
| PMDA | BTDA | TFDB | 25-75% | 35-65% | 45-55% |
| | | | PMDA | PMDA | PMDA |
| | | | 25-75% | 35-65% | 45-55% |
| | | | BTDA | BTDA | BTDA |
| PMDA | BTDA | FDA | 25-75% | 35-65% | 45-55% |
| | | | PMDA | PMDA | PMDA |
| | | | 25-75% | 35-65% | 45-55% |
| | | | BTDA | BTDA | BTDA |
| PMDA | HFPDPA | TFDB | 25-75% | 35-65% | 45-55% |
| | | | PMDA | PMDA | PMDA |
| | | | 25-75% | 35-65% | 45-55% |
| | | | HFPDPA | HFPDPA | HFPDPA |
| PMDA | HFPDPA | FDA | 25-75% | 35-65% | 45-55% |
| | | | PMDA | PMDA | PMDA |
| | | | 25-75% | 35-65% | 45-55% |
| | | | HFPDPA | HFPDPA | HFPDPA |
| a-BPDA | s-BPDA | TFDB | 25-75% | 35-65% | 45-55% |
| | | | a-BPDA | a-BPDA | a-BPDA |
| | | | 25-75% | 35-65% | 45-55% |
| | | | s-BPDA | s-BPDA | s-BPDA |
| a-BPDA | s-BPDA | FDA | 25-75% | 35-65% | 45-55% |
| | | | a-BPDA | a-BPDA | a-BPDA |
| | | | 25-75% | 35-65% | 45-55% |
| | | | s-BPDA | s-BPDA | s-BPDA |
| a-BPDA | ODPA | TFDB | 25-75% | 35-65% | 45-55% |
| | | | a-BPDA | a-BPDA | a-BPDA |
| | | | 25-75% | 35-65% | 45-55% |
| | | | ODPA | ODPA | ODPA |
| a-BPDA | ODPA | FDA | 25-75% | 35-65% | 45-55% |
| | | | a-BPDA | a-BPDA | a-BPDA |
| | | | 25-75% | 35-65% | 45-55% |
| | | | ODPA | ODPA | ODPA |
| a-BPDA | HQDA | TFDB | 25-75% | 35-65% | 45-55% |
| | | | a-BPDA | a-BPDA | a-BPDA |
| | | | 25-75% | 35-65% | 45-55% |
| | | | HQDA | HQDA | HQDA |
| a-BPDA | HQDA | FDA | 25-75% | 35-65% | 45-55% |
| | | | a-BPDA | a-BPDA | a-BPDA |
| | | | 25-75% | 35-65% | 45-55% |
| | | | HQDA | HQDA | HQDA |
| a-BPDA | BPADA | TFDB | 25-75% | 35-65% | 45-55% |
| | | | a-BPDA | a-BPDA | a-BPDA |
| | | | 25-75% | 35-65% | 45-55% |
| | | | BPADA | BPADA | BPADA |
| a-BPDA | BPADA | FDA | 25-75% | 35-65% | 45-55% |
| | | | a-BPDA | a-BPDA | a-BPDA |
| | | | 25-75% | 35-65% | 45-55% |
| | | | BPADA | BPADA | BPADA |
| a-BPDA | BTDA | TFDB | 25-75% | 35-65% | 45-55% |
| | | | a-BPDA | a-BPDA | a-BPDA |
| | | | 25-75% | 35-65% | 45-55% |
| | | | BTDA | BTDA | BTDA |
| a-BPDA | BTDA | FDA | 25-75% | 35-65% | 45-55% |
| | | | a-BPDA | a-BPDA | a-BPDA |
| | | | 25-75% | 35-65% | 45-55% |
| | | | BTDA | BTDA | BTDA |
| a-BPDA | HFPDPA | TFDB | 25-75% | 35-65% | 45-55% |
| | | | a-BPDA | a-BPDA | a-BPDA |
| | | | 25-75% | 35-65% | 45-55% |
| | | | HFPDPA | HFPDPA | HFPDPA |
| a-BPDA | HFPDPA | FDA | 25-75% | 35-65% | 45-55% |
| | | | a-BPDA | a-BPDA | a-BPDA |
| | | | 25-75% | 35-65% | 45-55% |
| | | | HFPDPA | HFPDPA | HFPDPA |
| s-BPDA | ODPA | TFDB | 25-75% | 35-65% | 45-55% |
| | | | s-BPDA | s-BPDA | s-BPDA |
| | | | 25-75% | 35-65% | 45-55% |
| | | | ODPA | ODPA | ODPA |
| s-BPDA | ODPA | FDA | 25-75% | 35-65% | 45-55% |
| | | | s-BPDA | s-BPDA | s-BPDA |
| | | | 25-75% | 35-65% | 45-55% |
| | | | ODPA | ODPA | ODPA |
| s-BPDA | HQDA | TFDB | 25-75% | 35-65% | 45-55% |
| | | | s-BPDA | s-BPDA | s-BPDA |
| | | | 25-75% | 35-65% | 45-55% |
| | | | HQDA | HQDA | HQDA |
| s-BPDA | HQDA | FDA | 25-75% | 35-65% | 45-55% |
| | | | s-BPDA | s-BPDA | s-BPDA |
| | | | 25-75% | 35-65% | 45-55% |
| | | | HQDA | HQDA | HQDA |
| s-BPDA | BPADA | TFDB | 25-75% | 35-65% | 45-55% |
| | | | s-BPDA | s-BPDA | s-BPDA |
| | | | 25-75% | 35-65% | 45-55% |
| | | | BPADA | BPADA | BPADA |
| s-BPDA | BPADA | FDA | 25-75% | 35-65% | 45-55% |
| | | | s-BPDA | s-BPDA | s-BPDA |
| | | | 25-75% | 35-65% | 45-55% |
| | | | BPADA | BPADA | BPADA |
| s-BPDA | BTDA | TFDB | 25-75% | 35-65% | 45-55% |
| | | | s-BPDA | s-BPDA | s-BPDA |
| | | | 25-75% | 35-65% | 45-55% |
| | | | BTDA | BTDA | BTDA |
| s-BPDA | BTDA | FDA | 25-75% | 35-65% | 45-55% |
| | | | s-BPDA | s-BPDA | s-BPDA |
| | | | 25-75% | 35-65% | 45-55% |
| | | | BTDA | BTDA | BTDA |
| s-BPDA | HFPDPA | TFDB | 25-75% | 35-65% | 45-55% |
| | | | s-BPDA | s-BPDA | s-BPDA |
| | | | 25-75% | 35-65% | 45-55% |
| | | | HFPDPA | HFPDPA | HFPDPA |
| s-BPDA | HFPDPA | FDA | 25-75% | 35-65% | 45-55% |
| | | | s-BPDA | s-BPDA | s-BPDA |
| | | | 25-75% | 35-65% | 45-55% |
| | | | HFPDPA | HFPDPA | HFPDPA |
| ODPA | HQDA | TFDB | 25-75% | 35-65% | 45-55% |
| | | | ODPA | ODPA | ODPA |
| | | | 25-75% | 35-65% | 45-55% |
| | | | HQDA | HQDA | HQDA |
| ODPA | HQDA | FDA | 25-75% | 35-65% | 45-55% |
| | | | ODPA | ODPA | ODPA |
| | | | 25-75% | 35-65% | 45-55% |
| | | | HQDA | HQDA | HQDA |
| ODPA | BPADA | TFDB | 25-75% | 35-65% | 45-55% |
| | | | ODPA | ODPA | ODPA |
| | | | 25-75% | 35-65% | 45-55% |
| | | | BPADA | BPADA | BPADA |
| ODPA | BPADA | FDA | 25-75% | 35-65% | 45-55% |
| | | | ODPA | ODPA | ODPA |
| | | | 25-75% | 35-65% | 45-55% |
| | | | BPADA | BPADA | BPADA |
| ODPA | BTDA | TFDB | 25-75% | 35-65% | 45-55% |
| | | | ODPA | ODPA | ODPA |
| | | | 25-75% | 35-65% | 45-55% |
| | | | BTDA | BTDA | BTDA |
| ODPA | BTDA | FDA | 25-75% | 35-65% | 45-55% |
| | | | ODPA | ODPA | ODPA |
| | | | 25-75% | 35-65% | 45-55% |
| | | | BTDA | BTDA | BTDA |
| ODPA | HFPDPA | TFDB | 25-75% | 35-65% | 45-55% |
| | | | ODPA | ODPA | ODPA |
| | | | 25-75% | 35-65% | 45-55% |
| | | | HFPDPA | HFPDPA | HFPDPA |
| ODPA | HFPDPA | FDA | 25-75% | 35-65% | 45-55% |
| | | | ODPA | ODPA | ODPA |
| | | | 25-75% | 35-65% | 45-55% |
| | | | HFPDPA | HFPDPA | HFPDPA |
| HQDA | BPADA | TFDB | 25-75% | 35-65% | 45-55% |
| | | | HQDA | HQDA | HQDA |
| | | | 25-75% | 35-65% | 45-55% |
| | | | BPADA | BPADA | BPADA |
| HQDA | BPADA | FDA | 25-75% | 35-65% | 45-55% |
| | | | HQDA | HQDA | HQDA |
| | | | 25-75% | 35-65% | 45-55% |
| | | | BPADA | BPADA | BPADA |
| HQDA | BTDA | TFDB | 25-75% | 35-65% | 45-55% |
| | | | HQDA | HQDA | HQDA |
| | | | 25-75% | 35-65% | 45-55% |
| | | | BTDA | BTDA | BTDA |
| HQDA | BTDA | FDA | 25-75% | 35-65% | 45-55% |
| | | | HQDA | HQDA | HQDA |
| | | | 25-75% | 35-65% | 45-55% |
| | | | BTDA | BTDA | BTDA |
| HQDA | HFPDPA | TFDB | 25-75% | 35-65% | 45-55% |
| | | | HQDA | HQDA | HQDA |
| | | | 25-75% | 35-65% | 45-55% |
| | | | HFPDPA | HFPDPA | HFPDPA |
| HQDA | HFPDPA | FDA | 25-75% | 35-65% | 45-55% |
| | | | HQDA | HQDA | HQDA |
| | | | 25-75% | 35-65% | 45-55% |
| | | | HFPDPA | HFPDPA | HFPDPA |
| BPADA | BTDA | TFDB | 25-75% | 35-65% | 45-55% |
| | | | BPADA | BPADA | BPADA |
| | | | 25-75% | 35-65% | 45-55% |
| | | | BTDA | BTDA | BTDA |
| BPADA | BTDA | FDA | 25-75% | 35-65% | 45-55% |
| | | | BPADA | BPADA | BPADA |
| | | | 25-75% | 35-65% | 45-55% |
| | | | BTDA | BTDA | BTDA |
| BPADA | HFPDPA | TFDB | 25-75% | 35-65% | 45-55% |
| | | | BPADA | BPADA | BPADA |
| | | | 25-75% | 35-65% | 45-55% |
| | | | HFPDPA | HFPDPA | HFPDPA |
| BPADA | HFPDPA | FDA | 25-75% | 35-65% | 45-55% |
| | | | BPADA | BPADA | BPADA |
| | | | 25-75% | 35-65% | 45-55% |
| | | | HFPDPA | HFPDPA | HFPDPA |
| BTDA | HFPDPA | TFDB | 25-75% | 35-65% | 45-55% |
| | | | BTDA | BTDA | BTDA |
| | | | 25-75% | 35-65% | 45-55% |
| | | | HFPDPA | HFPDPA | HFPDPA |
| BTDA | HFPDPA | FDA | 25-75% | 35-65% | 45-55% |
| | | | BTDA | BTDA | BTDA |
| | | | 25-75% | 35-65% | 45-55% |
| | | | HFPDPA | HFPDPA | HFPDPA |

The present disclosure provides the polyimide polymers comprising the aromatic dianhydrides and aromatic diamines as listed in Table 3.

TABLE 3

| Monomers in the polyimide | | | Relative mol % of each dianhydride | | |
|---|---|---|---|---|---|
| polymer | | | based on the total dianhydride in the | | |
| dianhydrides | | diamine | polyimide | | |
| PMDA | a-BPDA | Form. VIII | 25-75% | 35-65% | 45-55% |
| | | | PMDA | PMDA | PMDA |
| | | | 25-75% | 35-65% | 45-55% |
| | | | a-BPDA | a-BPDA | a-BPDA |
| PMDA | s-BPDA | Form. VIII | 25-75% | 35-65% | 45-55% |
| | | | PMDA | PMDA | PMDA |
| | | | 25-75% | 35-65% | 45-55% |
| | | | s-BPDA | s-BPDA | s-BPDA |
| PMDA | ODPA | Form. VIII | 25-75% | 35-65% | 45-55% |
| | | | PMDA | PMDA | PMDA |
| | | | 25-75% | 35-65% | 45-55% |
| | | | ODPA | ODPA | ODPA |
| PMDA | HQDA | Form. VIII | 25-75% | 35-65% | 45-55% |
| | | | PMDA | PMDA | PMDA |
| | | | 25-75% | 35-65% | 45-55% |
| | | | HQDA | HQDA | HQDA |
| PMDA | BPADA | Form. VIII | 25-75% | 35-65% | 45-55% |
| | | | PMDA | PMDA | PMDA |
| | | | 25-75% | 35-65% | 45-55% |
| | | | BPADA | BPADA | BPADA |
| PMDA | BTDA | Form. VIII | 25-75% | 35-65% | 45-55% |
| | | | PMDA | PMDA | PMDA |
| | | | 25-75% | 35-65% | 45-55% |
| | | | BTDA | BTDA | BTDA |
| PMDA | HFPDPA | Form. VIII | 25-75% | 35-65% | 45-55% |
| | | | PMDA | PMDA | PMDA |
| | | | 25-75% | 35-65% | 45-55% |
| | | | HFPDPA | HFPDPA | HFPDPA |
| a-BPDA | s-BPDA | Form. VIII | 25-75% | 35-65% | 45-55% |
| | | | a-BPDA | a-BPDA | a-BPDA |
| | | | 25-75% | 35-65% | 45-55% |
| | | | s-BPDA | s-BPDA | s-BPDA |
| a-BPDA | ODPA | Form. VIII | 25-75% | 35-65% | 45-55% |
| | | | a-BPDA | a-BPDA | a-BPDA |
| | | | 25-75% | 35-65% | 45-55% |
| | | | ODPA | ODPA | ODPA |
| a-BPDA | HQDA | Form. VIII | 25-75% | 35-65% | 45-55% |
| | | | a-BPDA | a-BPDA | a-BPDA |
| | | | 25-75% | 35-65% | 45-55% |
| | | | HQDA | HQDA | HQDA |
| a-BPDA | BPADA | Form. VIII | 25-75% | 35-65% | 45-55% |
| | | | a-BPDA | a-BPDA | a-BPDA |
| | | | 25-75% | 35-65% | 45-55% |
| | | | BPADA | BPADA | BPADA |
| a-BPDA | BTDA | Form. VIII | 25-75% | 35-65% | 45-55% |
| | | | a-BPDA | a-BPDA | a-BPDA |
| | | | 25-75% | 35-65% | 45-55% |
| | | | BTDA | BTDA | BTDA |
| a-BPDA | HFPDPA | Form. VIII | 25-75% | 35-65% | 45-55% |
| | | | a-BPDA | a-BPDA | a-BPDA |
| | | | 25-75% | 35-65% | 45-55% |
| | | | HFPDPA | HFPDPA | HFPDPA |
| s-BPDA | ODPA | Form. VIII | 25-75% | 35-65% | 45-55% |
| | | | s-BPDA | s-BPDA | s-BPDA |
| | | | 25-75% | 35-65% | 45-55% |
| | | | ODPA | ODPA | ODPA |
| s-BPDA | HQDA | Form. VIII | 25-75% | 35-65% | 45-55% |
| | | | s-BPDA | s-BPDA | s-BPDA |
| | | | 25-75% | 35-65% | 45-55% |
| | | | HQDA | HQDA | HQDA |
| s-BPDA | BPADA | Form. VIII | 25-75% | 35-65% | 45-55% |
| | | | s-BPDA | s-BPDA | s-BPDA |
| | | | 25-75% | 35-65% | 45-55% |
| | | | BPADA | BPADA | BPADA |
| s-BPDA | BTDA | Form. VIII | 25-75% | 35-65% | 45-55% |
| | | | s-BPDA | s-BPDA | s-BPDA |
| | | | 25-75% | 35-65% | 45-55% |
| | | | BTDA | BTDA | BTDA |
| s-BPDA | HFPDPA | Form. VIII | 25-75% | 35-65% | 45-55% |
| | | | s-BPDA | s-BPDA | s-BPDA |
| | | | 25-75% | 35-65% | 45-55% |
| | | | HFPDPA | HFPDPA | HFPDPA |
| ODPA | HQDA | Form. VIII | 25-75% | 35-65% | 45-55% |
| | | | ODPA | ODPA | ODPA |
| | | | 25-75% | 35-65% | 45-55% |
| | | | HQDA | HQDA | HQDA |
| ODPA | BPADA | Form. VIII | 25-75% | 35-65% | 45-55% |
| | | | ODPA | ODPA | ODPA |
| | | | 25-75% | 35-65% | 45-55% |
| | | | BPADA | BPADA | BPADA |
| ODPA | BTDA | Form. VIII | 25-75% | 35-65% | 45-55% |
| | | | ODPA | ODPA | ODPA |
| | | | 25-75% | 35-65% | 45-55% |
| | | | BTDA | BTDA | BTDA |
| ODPA | HFPDPA | Form. VIII | 25-75% | 35-65% | 45-55% |
| | | | ODPA | ODPA | ODPA |
| | | | 25-75% | 35-65% | 45-55% |
| | | | HFPDPA | HFPDPA | HFPDPA |
| HQDA | BPADA | Form. VIII | 25-75% | 35-65% | 45-55% |
| | | | HQDA | HQDA | HQDA |
| | | | 25-75% | 35-65% | 45-55% |
| | | | BPADA | BPADA | BPADA |
| HQDA | BTDA | Form. VIII | 25-75% | 35-65% | 45-55% |
| | | | HQDA | HQDA | HQDA |
| | | | 25-75% | 35-65% | 45-55% |
| | | | BTDA | BTDA | BTDA |
| HQDA | HFPDPA | Form. VIII | 25-75% | 35-65% | 45-55% |
| | | | HQDA | HQDA | HQDA |
| | | | 25-75% | 35-65% | 45-55% |
| | | | HFPDPA | HFPDPA | HFPDPA |
| BPADA | BTDA | Form. VIII | 25-75% | 35-65% | 45-55% |
| | | | BPADA | BPADA | BPADA |
| | | | 25-75% | 35-65% | 45-55% |
| | | | BTDA | BTDA | BTDA |
| BPADA | HFPDPA | Form. VIII | 25-75% | 35-65% | 45-55% |
| | | | BPADA | BPADA | BPADA |
| | | | 25-75% | 35-65% | 45-55% |
| | | | HFPDPA | HFPDPA | HFPDPA |
| BTDA | HFPDPA | Form. VIII | 25-75% | 35-65% | 45-55% |
| | | | BTDA | BTDA | BTDA |
| | | | 25-75% | 35-65% | 45-55% |
| | | | HFPDPA | HFPDPA | HFPDPA |

The present disclosure also provides the polyimide polymers as listed in Table 4.

TABLE 4

| Monomers in the polyimide | | | Relative mol % of each diamine | | |
|---|---|---|---|---|---|
| polymer | | | based on the total diamine in the | | |
| dianhydride | diamines | | polyimide | | |
| Formula I | Formula | Formula | 25-75% | 35-65% | 45-55% |
| | VI | V | Form V | Form V | Form V |
| | | | 25-75% | 35-65% | 45-55% |
| | | | Form IV | Form IV | Form IV |
| Formula I | Formula | Formula | 25-75% | 35-65% | 45-55% |
| | VI | VII | Form V | Form V | Form V |
| | | | 25-75% | 35-65% | 45-55% |
| | | | Form VI | Form VI | Form VI |
| Formula I | Formula | Formula | 50-90% | 60-80% | 70-80% |
| | VI | V | Form V | Form V | Form V |
| | | | 10-50% | 20-40% | 20-30% |
| | | | Form IV | Form IV | Form IV |
| Formula I | Formula | Formula | 50-90% | 60-80% | 70-80% |
| | VI | VII | Form V | Form V | Form V |
| | | | 10-50% | 20-40% | 20-30% |
| | | | Form VI | Form VI | Form VI |
| Formula I | Formula | Formula | 25-75% | 35-65% | 45-55% |
| | IV | VIII | Form IV | Form IV | Form IV |
| | | | 25-75% | 35-65% | 45-55% |
| | | | Form VIII | Form VIII | Form VIII |
| Formula I | Formula | Formula | 50-90% | 60-80% | 70-80% |
| | IV | VIII | Form IV | Form IV | Form IV |
| | | | 10-50% | 20-40% | 20-30% |
| | | | Form VIII | Form VIII | Form VIII |
| Formula I | Formula | Formula | 25-75% | 35-65% | 45-55% |
| | VI | VIII | Form VI | Form VI | Form VI |
| | | | 25-75% | 35-65% | 45-55% |
| | | | Form VIII | Form VIII | Form VIII |
| Formula I | Formula | Formula | 50-90% | 60-80% | 70-80% |
| | VI | VIII | Form VI | Form VI | Form VI |
| | | | 10-50% | 20-40% | 20-30% |
| | | | Form VIII | Form VIII | Form VIII |
| Formula I | Formula | Formula | 25-75% | 35-65% | 45-55% |
| | VII | VIII | Form VII | Form VII | Form VII |
| | | | 25-75% | 35-65% | 45-55% |
| | | | Form VIII | Form VIII | Form VIII |
| Formula I | Formula | Formula | 50-90% | 60-80% | 70-80% |
| | VII | VIII | Form VII | Form VII | Form VII |
| | | | 10-50% | 20-40% | 20-30% |
| | | | Form VIII | Form VIII | Form VIII |
| Formula I | TFDB | FDA | 25-75% | 35-65% | 45-55% |
| | | | TFDB | TFDB | TFDB |
| | | | 25-75% | 35-65% | 45-55% |
| | | | FDA | FDA | FDA |
| Formula I | TFDB | BZDA | 25-75% | 35-65% | 45-55% |
| | | | TFDB | TFDB | TFDB |
| | | | 25-75% | 35-65% | 45-55% |
| | | | BZDA | BZDA | BZDA |
| Formula I | TFDB | DHBZ | 25-75% | 35-65% | 45-55% |
| | | | TFDB | TFDB | TFDB |
| | | | 25-75% | 35-65% | 45-55% |
| | | | DHBZ | DHBZ | DHBZ |
| Formula I | TFDB | p-PDA | 25-75% | 35-65% | 45-55% |
| | | | TFDB | TFDB | TFDB |
| | | | 25-75% | 35-65% | 45-55% |
| | | | p-PDA | p-PDA | p-PDA |
| Formula I | TFDB | m-PDA | 25-75% | 35-65% | 45-55% |
| | | | TFDB | TFDB | TFDB |
| | | | 25-75% | 35-65% | 45-55% |
| | | | m-PDA | m-PDA | m-PDA |
| Formula I | TFDB | 4,4′- | 25-75% | 35-65% | 45-55% |
| | | ODA | TFDB | TFDB | TFDB |
| | | | 25-75% | 35-65% | 45-55% |
| | | | 4,4′-ODA | 4,4′-ODA | 4,4′-ODA |
| Formula I | TFDB | HFPDA | 25-75% | 35-65% | 45-55% |
| | | | TFDB | TFDB | TFDB |
| | | | 25-75% | 35-65% | 45-55% |
| | | | HFPDA | HFPDA | HFPDA |
| Formula I | TFDB | FDA | 50-90% | 60-80% | 70-80% |
| | | | TFDB | TFDB | TFDB |
| | | | 10-50% | 20-40% | 20-30% |
| | | | FDA | FDA | FDA |
| Formula I | TFDB | BZDA | 50-90% | 60-80% | 70-80% |
| | | | TFDB | TFDB | TFDB |
| | | | 10-50% | 20-40% | 20-30% |
| | | | BZDA | BZDA | BZDA |
| Formula I | TFDB | DHBZ | 50-90% | 60-80% | 70-80% |
| | | | TFDB | TFDB | TFDB |
| | | | 10-50% | 20-40% | 20-30% |
| | | | DHBZ | DHBZ | DHBZ |
| Formula I | TFDB | p-PDA | 50-90% | 60-80% | 70-80% |
| | | | TFDB | TFDB | TFDB |
| | | | 10-50% | 20-40% | 20-30% |
| | | | p-PDA | p-PDA | p-PDA |
| Formula I | TFDB | m-PDA | 50-90% | 60-80% | 70-80% |
| | | | TFDB | TFDB | TFDB |
| | | | 10-50% | 20-40% | 20-30% |
| | | | m-PDA | m-PDA | m-PDA |
| Formula I | TFDB | 4,4′- | 50-90% | 60-80% | 70-80% |
| | | ODA | TFDB | TFDB | TFDB |
| | | | 10-50% | 20-40% | 20-30% |
| | | | 4,4′-ODA | 4,4′-ODA | 4,4′-ODA |
| Formula I | TFDB | HFPDA | 50-90% | 60-80% | 70-80% |
| | | | TFDB | TFDB | TFDB |
| | | | 10-50% | 20-40% | 20-30% |
| | | | HFPDA | HFPDA | HFPDA |
| Formula I | FDA | BZDA | 25-75% | 35-65% | 45-55% |
| | | | FDA | FDA | FDA |
| | | | 25-75% | 35-65% | 45-55% |
| | | | BZDA | BZDA | BZDA |
| Formula I | FDA | DHBZ | 25-75% | 35-65% | 45-55% |
| | | | FDA | FDA | FDA |
| | | | 25-75% | 35-65% | 45-55% |
| | | | DHBZ | DHBZ | DHBZ |
| Formula I | FDA | p-PDA | 25-75% | 35-65% | 45-55% |
| | | | FDA | FDA | FDA |
| | | | 25-75% | 35-65% | 45-55% |
| | | | p-PDA | p-PDA | p-PDA |
| Formula I | FDA | m-PDA | 25-75% | 35-65% | 45-55% |
| | | | FDA | FDA | FDA |
| | | | 25-75% | 35-65% | 45-55% |
| | | | m-PDA | m-PDA | m-PDA |
| Formula I | FDA | 4,4′- | 25-75% | 35-65% | 45-55% |
| | | ODA | FDA | FDA | FDA |
| | | | 25-75% | 35-65% | 45-55% |
| | | | 4,4′-ODA | 4,4′-ODA | 4,4′-ODA |
| Formula I | FDA | HFPDA | 25-75% | 35-65% | 45-55% |
| | | | FDA | FDA | FDA |
| | | | 25-75% | 35-65% | 45-55% |
| | | | HFPDA | HFPDA | HFPDA |
| s-BPDA | TFDB | FDA | 25-75% | 35-65% | 45-55% |
| | | | TFDB | TFDB | TFDB |
| | | | 25-75% | 35-65% | 45-55% |
| | | | FDA | FDA | FDA |
| s-BPDA | TFDB | BZDA | 25-75% | 35-65% | 45-55% |
| | | | TFDB | TFDB | TFDB |
| | | | 25-75% | 35-65% | 45-55% |
| | | | BZDA | BZDA | BZDA |
| s-BPDA | TFDB | DHBZ | 25-75% | 35-65% | 45-55% |
| | | | TFDB | TFDB | TFDB |
| | | | 25-75% | 35-65% | 45-55% |
| | | | DHBZ | DHBZ | DHBZ |
| s-BPDA | TFDB | p-PDA | 25-75% | 35-65% | 45-55% |
| | | | TFDB | TFDB | TFDB |
| | | | 25-75% | 35-65% | 45-55% |
| | | | p-PDA | p-PDA | p-PDA |
| s-BPDA | TFDB | m-PDA | 25-75% | 35-65% | 45-55% |
| | | | TFDB | TFDB | TFDB |
| | | | 25-75% | 35-65% | 45-55% |
| | | | m-PDA | m-PDA | m-PDA |
| s-BPDA | TFDB | 4,4′- | 25-75% | 35-65% | 45-55% |
| | | | TFDB | TFDB | TFDB |
| | | ODA | 25-75% | 35-65% | 45-55% |
| | | | 4,4′-ODA | 4,4′-ODA | 4,4′-ODA |
| s-BPDA | TFDB | HFPDA | 25-75% | 35-65% | 45-55% |
| | | | TFDB | TFDB | TFDB |
| | | | 25-75% | 35-65% | 45-55% |
| | | | HFPDA | HFPDA | HFPDA |
| s-BPDA | TFDB | FDA | 50-90% | 60-80% | 70-80% |
| | | | TFDB | TFDB | TFDB |
| | | | 10-50% | 20-40% | 20-30% |
| | | | FDA | FDA | FDA |
| s-BPDA | TFDB | BZDA | 50-90% | 60-80% | 70-80% |
| | | | TFDB | TFDB | TFDB |
| | | | 10-50% | 20-40% | 20-30% |
| | | | BZDA | BZDA | BZDA |
| s-BPDA | TFDB | DHBZ | 50-90% | 60-80% | 70-80% |
| | | | TFDB | TFDB | TFDB |
| | | | 10-50% | 20-40% | 20-30% |
| | | | DHBZ | DHBZ | DHBZ |
| s-BPDA | TFDB | p-PDA | 50-90% | 60-80% | 70-80% |
| | | | TFDB | TFDB | TFDB |
| | | | 10-50% | 20-40% | 20-30% |
| | | | p-PDA | p-PDA | p-PDA |
| s-BPDA | TFDB | m-PDA | 50-90% | 60-80% | 70-80% |
| | | | TFDB | TFDB | TFDB |
| | | | 10-50% | 20-40% | 20-30% |
| | | | m-PDA | m-PDA | m-PDA |
| s-BPDA | TFDB | 4,4′- | 50-90% | 60-80% | 70-80% |
| | | ODA | TFDB | TFDB | TFDB |
| | | | 10-50% | 20-40% | 20-30% |
| | | | 4,4′-ODA | 4,4′-ODA | 4,4′-ODA |
| s-BPDA | TFDB | HFPDA | 50-90% | 60-80% | 70-80% |
| | | | TFDB | TFDB | TFDB |
| | | | 10-50% | 20-40% | 20-30% |
| | | | HFPDA | HFPDA | HFPDA |
| s-BPDA | FDA | BZDA | 25-75% | 35-65% | 45-55% |
| | | | FDA | FDA | FDA |
| | | | 25-75% | 35-65% | 45-55% |
| | | | BZDA | BZDA | BZDA |
| s-BPDA | FDA | DHBZ | 25-75% | 35-65% | 45-55% |
| | | | FDA | FDA | FDA |
| | | | 25-75% | 35-65% | 45-55% |
| | | | DHBZ | DHBZ | DHBZ |
| s-BPDA | FDA | p-PDA | 25-75% | 35-65% | 45-55% |
| | | | FDA | FDA | FDA |
| | | | 25-75% | 35-65% | 45-55% |
| | | | p-PDA | p-PDA | p-PDA |
| s-BPDA | FDA | m-PDA | 25-75% | 35-65% | 45-55% |
| | | | FDA | FDA | FDA |
| | | | 25-75% | 35-65% | 45-55% |
| | | | m-PDA | m-PDA | m-PDA |
| s-BPDA | FDA | 4,4′- | 25-75% | 35-65% | 45-55% |
| | | ODA | FDA | FDA | FDA |
| | | | 25-75% | 35-65% | 45-55% |
| | | | 4,4′-ODA | 4,4′-ODA | 4,4′-ODA |
| s-BPDA | FDA | HFPDA | 25-75% | 35-65% | 45-55% |
| | | | FDA | FDA | FDA |
| | | | 25-75% | 35-65% | 45-55% |
| | | | HFPDA | HFPDA | HFPDA |
| a-BPDA | TFDB | FDA | 25-75% | 35-65% | 45-55% |
| | | | TFDB | TFDB | TFDB |
| | | | 25-75% | 35-65% | 45-55% |
| | | | FDA | FDA | FDA |
| a-BPDA | TFDB | BZDA | 25-75% | 35-65% | 45-55% |
| | | | TFDB | TFDB | TFDB |
| | | | 25-75% | 35-65% | 45-55% |
| | | | BZDA | BZDA | BZDA |
| a-BPDA | TFDB | DHBZ | 25-75% | 35-65% | 45-55% |
| | | | TFDB | TFDB | TFDB |
| | | | 25-75% | 35-65% | 45-55% |
| | | | DHBZ | DHBZ | DHBZ |
| a-BPDA | TFDB | p-PDA | 25-75% | 35-65% | 45-55% |
| | | | TFDB | TFDB | TFDB |
| | | | 25-75% | 35-65% | 45-55% |
| | | | p-PDA | p-PDA | p-PDA |
| a-BPDA | TFDB | m-PDA | 25-75% | 35-65% | 45-55% |
| | | | TFDB | TFDB | TFDB |
| | | | 25-75% | 35-65% | 45-55% |
| | | | m-PDA | m-PDA | m-PDA |
| a-BPDA | TFDB | 4,4′- | 25-75% | 35-65% | 45-55% |
| | | ODA | TFDB | TFDB | TFDB |
| | | | 25-75% | 35-65% | 45-55% |
| | | | 4,4′-ODA | 4,4′-ODA | 4,4′-ODA |
| a-BPDA | TFDB | HFPDA | 25-75% | 35-65% | 45-55% |
| | | | TFDB | TFDB | TFDB |
| | | | 25-75% | 35-65% | 45-55% |
| | | | HFPDA | HFPDA | HFPDA |
| a-BPDA | TFDB | FDA | 50-90% | 60-80% | 70-80% |
| | | | TFDB | TFDB | TFDB |
| | | | 10-50% | 20-40% | 20-30% |
| | | | FDA | FDA | FDA |
| a-BPDA | TFDB | BZDA | 50-90% | 60-80% | 70-80% |
| | | | TFDB | TFDB | TFDB |
| | | | 10-50% | 20-40% | 20-30% |
| | | | BZDA | BZDA | BZDA |
| a-BPDA | TFDB | DHBZ | 50-90% | 60-80% | 70-80% |
| | | | TFDB | TFDB | TFDB |
| | | | 10-50% | 20-40% | 20-30% |
| | | | DHBZ | DHBZ | DHBZ |
| a-BPDA | TFDB | p-PDA | 50-90% | 60-80% | 70-80% |
| | | | TFDB | TFDB | TFDB |
| | | | 10-50% | 20-40% | 20-30% |
| | | | p-PDA | p-PDA | p-PDA |
| a-BPDA | TFDB | m-PDA | 50-90% | 60-80% | 70-80% |
| | | | TFDB | TFDB | TFDB |
| | | | 10-50% | 20-40% | 20-30% |
| | | | m-PDA | m-PDA | m-PDA |
| a-BPDA | TFDB | 4,4′- | 50-90% | 60-80% | 70-80% |
| | | ODA | TFDB | TFDB | TFDB |
| | | | 10-50% | 20-40% | 20-30% |
| | | | 4,4′-ODA | 4,4′-ODA | 4,4′-ODA |
| a-BPDA | TFDB | HFPDA | 50-90% | 60-80% | 70-80% |
| | | | TFDB | TFDB | TFDB |
| | | | 10-50% | 20-40% | 20-30% |
| | | | HFPDA | HFPDA | HFPDA |
| a-BPDA | FDA | BZDA | 25-75% | 35-65% | 45-55% |
| | | | FDA | FDA | FDA |
| | | | 25-75% | 35-65% | 45-55% |
| | | | BZDA | BZDA | BZDA |
| a-BPDA | FDA | DHBZ | 25-75% | 35-65% | 45-55% |
| | | | FDA | FDA | FDA |
| | | | 25-75% | 35-65% | 45-55% |
| | | | DHBZ | DHBZ | DHBZ |
| a-BPDA | FDA | p-PDA | 25-75% | 35-65% | 45-55% |
| | | | FDA | FDA | FDA |
| | | | 25-75% | 35-65% | 45-55% |
| | | | p-PDA | p-PDA | p-PDA |
| a-BPDA | FDA | m-PDA | 25-75% | 35-65% | 45-55% |
| | | | FDA | FDA | FDA |
| | | | 25-75% | 35-65% | 45-55% |
| | | | m-PDA | m-PDA | m-PDA |
| a-BPDA | FDA | 4,4′- | 25-75% | 35-65% | 45-55% |
| | | ODA | FDA | FDA | FDA |
| | | | 25-75% | 35-65% | 45-55% |
| | | | 4,4′-ODA | 4,4′-ODA | 4,4′-ODA |
| a-BPDA | FDA | HFPDA | 25-75% | 35-65% | 45-55% |
| | | | FDA | FDA | FDA |
| | | | 25-75% | 35-65% | 45-55% |
| | | | HFPDA | HFPDA | HFPDA |
| PMDA | TFDB | FDA | 25-75% | 35-65% | 45-55% |
| | | | TFDB | TFDB | TFDB |
| | | | 25-75% | 35-65% | 45-55% |
| | | | FDA | FDA | FDA |
| PMDA | TFDB | BZDA | 25-75% | 35-65% | 45-55% |
| | | | TFDB | TFDB | TFDB |
| | | | 25-75% | 35-65% | 45-55% |
| | | | BZDA | BZDA | BZDA |
| PMDA | TFDB | DHBZ | 25-75% | 35-65% | 45-55% |
| | | | TFDB | TFDB | TFDB |
| | | | 25-75% | 35-65% | 45-55% |
| | | | DHBZ | DHBZ | DHBZ |
| PMDA | TFDB | p-PDA | 25-75% | 35-65% | 45-55% |
| | | | TFDB | TFDB | TFDB |
| | | | 25-75% | 35-65% | 45-55% |
| | | | p-PDA | p-PDA | p-PDA |
| PMDA | TFDB | m-PDA | 25-75% | 35-65% | 45-55% |
| | | | TFDB | TFDB | TFDB |
| | | | 25-75% | 35-65% | 45-55% |
| | | | m-PDA | m-PDA | m-PDA |
| PMDA | TFDB | 4,4′- | 25-75% | 35-65% | 45-55% |
| | | ODA | TFDB | TFDB | TFDB |
| | | | 25-75% | 35-65% | 45-55% |
| | | | 4,4′-ODA | 4,4′-ODA | 4,4′-ODA |
| PMDA | TFDB | HFPDA | 25-75% | 35-65% | 45-55% |
| | | | TFDB | TFDB | TFDB |
| | | | 25-75% | 35-65% | 45-55% |
| | | | HFPDA | HFPDA | HFPDA |
| PMDA | TFDB | FDA | 50-90% | 60-80% | 70-80% |
| | | | TFDB | TFDB | TFDB |
| | | | 10-50% | 20-40% | 20-30% |
| | | | FDA | FDA | FDA |
| PMDA | TFDB | BZDA | 50-90% | 60-80% | 70-80% |
| | | | TFDB | TFDB | TFDB |
| | | | 10-50% | 20-40% | 20-30% |
| | | | BZDA | BZDA | BZDA |
| PMDA | TFDB | DHBZ | 50-90% | 60-80% | 70-80% |
| | | | TFDB | TFDB | TFDB |
| | | | 10-50% | 20-40% | 20-30% |
| | | | DHBZ | DHBZ | DHBZ |
| PMDA | TFDB | p-PDA | 50-90% | 60-80% | 70-80% |
| | | | TFDB | TFDB | TFDB |
| | | | 10-50% | 20-40% | 20-30% |
| | | | p-PDA | p-PDA | p-PDA |
| PMDA | TFDB | m-PDA | 50-90% | 60-80% | 70-80% |
| | | | TFDB | TFDB | TFDB |
| | | | 10-50% | 20-40% | 20-30% |
| | | | m-PDA | m-PDA | m-PDA |
| PMDA | TFDB | 4,4′- | 50-90% | 60-80% | 70-80% |
| | | ODA | TFDB | TFDB | TFDB |
| | | | 10-50% | 20-40% | 20-30% |
| | | | 4,4′-ODA | 4,4′-ODA | 4,4′-ODA |
| PMDA | TFDB | HFPDA | 50-90% | 60-80% | 70-80% |
| | | | TFDB | TFDB | TFDB |
| | | | 10-50% | 20-40% | 20-30% |
| | | | HFPDA | HFPDA | HFPDA |
| PMDA | FDA | BZDA | 25-75% | 35-65% | 45-55% |
| | | | FDA | FDA | FDA |
| | | | 25-75% | 35-65% | 45-55% |
| | | | BZDA | BZDA | BZDA |
| PMDA | FDA | DHBZ | 25-75% | 35-65% | 45-55% |
| | | | FDA | FDA | FDA |
| | | | 25-75% | 35-65% | 45-55% |
| | | | DHBZ | DHBZ | DHBZ |
| PMDA | FDA | p-PDA | 25-75% | 35-65% | 45-55% |
| | | | FDA | FDA | FDA |
| | | | 25-75% | 35-65% | 45-55% |
| | | | p-PDA | p-PDA | p-PDA |
| PMDA | FDA | m-PDA | 25-75% | 35-65% | 45-55% |
| | | | FDA | FDA | FDA |
| | | | 25-75% | 35-65% | 45-55% |
| | | | m-PDA | m-PDA | m-PDA |
| PMDA | FDA | 4,4′- | 25-75% | 35-65% | 45-55% |
| | | ODA | FDA | FDA | FDA |
| | | | 25-75% | 35-65% | 45-55% |
| | | | 4,4′- | 4,4′- | 4,4′- |
| | | | ODA | ODA | ODA |
| PMDA | FDA | HFPDA | 25-75% | 35-65% | 45-55% |
| | | | FDA | FDA | FDA |
| | | | 25-75% | 35-65% | 45-55% |
| | | | HFPDA | HFPDA | HFPDA |
| ODPA | TFDB | FDA | 25-75% | 35-65% | 45-55% |
| | | | TFDB | TFDB | TFDB |
| | | | 25-75% | 35-65% | 45-55% |
| | | | FDA | FDA | FDA |
| ODPA | TFDB | BZDA | 25-75% | 35-65% | 45-55% |
| | | | TFDB | TFDB | TFDB |
| | | | 25-75% | 35-65% | 45-55% |
| | | | BZDA | BZDA | BZDA |
| ODPA | TFDB | DHBZ | 25-75% | 35-65% | 45-55% |
| | | | TFDB | TFDB | TFDB |
| | | | 25-75% | 35-65% | 45-55% |
| | | | DHBZ | DHBZ | DHBZ |
| ODPA | TFDB | p-PDA | 25-75% | 35-65% | 45-55% |
| | | | TFDB | TFDB | TFDB |
| | | | 25-75% | 35-65% | 45-55% |
| | | | p-PDA | p-PDA | p-PDA |
| ODPA | TFDB | m-PDA | 25-75% | 35-65% | 45-55% |
| | | | TFDB | TFDB | TFDB |
| | | | 25-75% | 35-65% | 45-55% |
| | | | m-PDA | m-PDA | m-PDA |
| ODPA | TFDB | 4,4′- | 25-75% | 35-65% | 45-55% |
| | | ODA | TFDB | TFDB | TFDB |
| | | | 25-75% | 35-65% | 45-55% |
| | | | 4,4′-ODA | 4,4′-ODA | 4,4′-ODA |
| ODPA | TFDB | HFPDA | 25-75% | 35-65% | 45-55% |
| | | | TFDB | TFDB | TFDB |
| | | | 25-75% | 35-65% | 45-55% |
| | | | HFPDA | HFPDA | HFPDA |
| ODPA | TFDB | FDA | 50-90% | 60-80% | 70-80% |
| | | | TFDB | TFDB | TFDB |
| | | | 10-50% | 20-40% | 20-30% |
| | | | FDA | FDA | FDA |
| ODPA | TFDB | BZDA | 50-90% | 60-80% | 70-80% |
| | | | TFDB | TFDB | TFDB |
| | | | 10-50% | 20-40% | 20-30% |
| | | | BZDA | BZDA | BZDA |
| ODPA | TFDB | DHBZ | 50-90% | 60-80% | 70-80% |
| | | | TFDB | TFDB | TFDB |
| | | | 10-50% | 20-40% | 20-30% |
| | | | DHBZ | DHBZ | DHBZ |
| ODPA | TFDB | p-PDA | 50-90% | 60-80% | 70-80% |
| | | | TFDB | TFDB | TFDB |
| | | | 10-50% | 20-40% | 20-30% |
| | | | p-PDA | p-PDA | p-PDA |
| ODPA | TFDB | m-PDA | 50-90% | 60-80% | 70-80% |
| | | | TFDB | TFDB | TFDB |
| | | | 10-50% | 20-40% | 20-30% |
| | | | m-PDA | m-PDA | m-PDA |
| ODPA | TFDB | 4,4′- | 50-90% | 60-80% | 70-80% |
| | | ODA | TFDB | TFDB | TFDB |
| | | | 10-50% | 20-40% | 20-30% |
| | | | 4,4′-ODA | 4,4′-ODA | 4,4′-ODA |
| ODPA | TFDB | HFPDA | 50-90% | 60-80% | 70-80% |
| | | | TFDB | TFDB | TFDB |
| | | | 10-50% | 20-40% | 20-30% |
| | | | HFPDA | HFPDA | HFPDA |
| ODPA | FDA | BZDA | 25-75% | 35-65% | 45-55% |
| | | | FDA | FDA | FDA |
| | | | 25-75% | 35-65% | 45-55% |
| | | | BZDA | BZDA | BZDA |
| ODPA | FDA | DHBZ | 25-75% | 35-65% | 45-55% |
| | | | FDA | FDA | FDA |
| | | | 25-75% | 35-65% | 45-55% |
| | | | DHBZ | DHBZ | DHBZ |
| ODPA | FDA | p-PDA | 25-75% | 35-65% | 45-55% |
| | | | FDA | FDA | FDA |
| | | | 25-75% | 35-65% | 45-55% |
| | | | p-PDA | p-PDA | p-PDA |
| ODPA | FDA | m-PDA | 25-75% | 35-65% | 45-55% |
| | | | FDA | FDA | FDA |
| | | | 25-75% | 35-65% | 45-55% |
| | | | m-PDA | m-PDA | m-PDA |
| ODPA | FDA | 4,4′- | 25-75% | 35-65% | 45-55% |
| | | ODA | FDA | FDA | FDA |
| | | | 25-75% | 35-65% | 45-55% |
| | | | 4,4′- | 4,4′- | 4,4′- |
| | | | ODA | ODA | ODA |
| ODPA | FDA | HFPDA | 25-75% | 35-65% | 45-55% |
| | | | FDA | FDA | FDA |
| | | | 25-75% | 35-65% | 45-55% |
| | | | HFPDA | HFPDA | HFPDA |
| HQDA | TFDB | FDA | 25-75% | 35-65% | 45-55% |
| | | | TFDB | TFDB | TFDB |
| | | | 25-75% | 35-65% | 45-55% |
| | | | FDA | FDA | FDA |
| HQDA | TFDB | BZDA | 25-75% | 35-65% | 45-55% |
| | | | TFDB | TFDB | TFDB |
| | | | 25-75% | 35-65% | 45-55% |
| | | | BZDA | BZDA | BZDA |
| HQDA | TFDB | DHBZ | 25-75% | 35-65% | 45-55% |
| | | | TFDB | TFDB | TFDB |
| | | | 25-75% | 35-65% | 45-55% |
| | | | DHBZ | DHBZ | DHBZ |
| HQDA | TFDB | p-PDA | 25-75% | 35-65% | 45-55% |
| | | | TFDB | TFDB | TFDB |
| | | | 25-75% | 35-65% | 45-55% |
| | | | p-PDA | p-PDA | p-PDA |
| HQDA | TFDB | m-PDA | 25-75% | 35-65% | 45-55% |
| | | | TFDB | TFDB | TFDB |
| | | | 25-75% | 35-65% | 45-55% |
| | | | m-PDA | m-PDA | m-PDA |
| HQDA | TFDB | 4,4′- | 25-75% | 35-65% | 45-55% |
| | | ODA | TFDB | TFDB | TFDB |
| | | | 25-75% | 35-65% | 45-55% |
| | | | 4,4′- | 4,4′- | 4,4′- |
| | | | ODA | ODA | ODA |
| HQDA | TFDB | HFPDA | 25-75% | 35-65% | 45-55% |
| | | | TFDB | TFDB | TFDB |
| | | | 25-75% | 35-65% | 45-55% |
| | | | HFPDA | HFPDA | HFPDA |
| HQDA | TFDB | FDA | 50-90% | 60-80% | 70-80% |
| | | | TFDB | TFDB | TFDB |
| | | | 10-50% | 20-40% | 20-30% |
| | | | FDA | FDA | FDA |
| HQDA | TFDB | BZDA | 50-90% | 60-80% | 70-80% |
| | | | TFDB | TFDB | TFDB |
| | | | 10-50% | 20-40% | 20-30% |
| | | | BZDA | BZDA | BZDA |
| HQDA | TFDB | DHBZ | 50-90% | 60-80% | 70-80% |
| | | | TFDB | TFDB | TFDB |
| | | | 10-50% | 20-40% | 20-30% |
| | | | DHBZ | DHBZ | DHBZ |
| HQDA | TFDB | p-PDA | 50-90% | 60-80% | 70-80% |
| | | | TFDB | TFDB | TFDB |
| | | | 10-50% | 20-40% | 20-30% |
| | | | p-PDA | p-PDA | p-PDA |
| HQDA | TFDB | m-PDA | 50-90% | 60-80% | 70-80% |
| | | | TFDB | TFDB | TFDB |
| | | | 10-50% | 20-40% | 20-30% |
| | | | m-PDA | m-PDA | m-PDA |
| HQDA | TFDB | 4,4′- | 50-90% | 60-80% | 70-80% |
| | | ODA | TFDB | TFDB | TFDB |
| | | | 10-50% | 20-40% | 20-30% |
| | | | 4,4′-ODA | 4,4′-ODA | 4,4′-ODA |
| HQDA | TFDB | HFPDA | 50-90% | 60-80% | 70-80% |
| | | | TFDB | TFDB | TFDB |
| | | | 10-50% | 20-40% | 20-30% |
| | | | HFPDA | HFPDA | HFPDA |
| HQDA | FDA | BZDA | 25-75% | 35-65% | 45-55% |
| | | | FDA | FDA | FDA |
| | | | 25-75% | 35-65% | 45-55% |
| | | | BZDA | BZDA | BZDA |
| HQDA | FDA | DHBZ | 25-75% | 35-65% | 45-55% |
| | | | FDA | FDA | FDA |
| | | | 25-75% | 35-65% | 45-55% |
| | | | DHBZ | DHBZ | DHBZ |
| HQDA | FDA | p-PDA | 25-75% | 35-65% | 45-55% |
| | | | FDA | FDA | FDA |
| | | | 25-75% | 35-65% | 45-55% |
| | | | p-PDA | p-PDA | p-PDA |
| HQDA | FDA | m-PDA | 25-75% | 35-65% | 45-55% |
| | | | FDA | FDA | FDA |
| | | | 25-75% | 35-65% | 45-55% |
| | | | m-PDA | m-PDA | m-PDA |
| HQDA | FDA | 4,4′- | 25-75% | 35-65% | 45-55% |
| | | ODA | FDA | FDA | FDA |
| | | | 25-75% | 35-65% | 45-55% |
| | | | 4,4′-ODA | 4,4′-ODA | 4,4′-ODA |
| HQDA | FDA | HFPDA | 25-75% | 35-65% | 45-55% |
| | | | FDA | FDA | FDA |
| | | | 25-75% | 35-65% | 45-55% |
| | | | HFPDA | HFPDA | HFPDA |
| BPADA | TFDB | FDA | 25-75% | 35-65% | 45-55% |
| | | | TFDB | TFDB | TFDB |
| | | | 25-75% | 35-65% | 45-55% |
| | | | FDA | FDA | FDA |
| BPADA | TFDB | BZDA | 25-75% | 35-65% | 45-55% |
| | | | TFDB | TFDB | TFDB |
| | | | 25-75% | 35-65% | 45-55% |
| | | | BZDA | BZDA | BZDA |
| BPADA | TFDB | DHBZ | 25-75% | 35-65% | 45-55% |
| | | | TFDB | TFDB | TFDB |
| | | | 25-75% | 35-65% | 45-55% |
| | | | DHBZ | DHBZ | DHBZ |
| BPADA | TFDB | p-PDA | 25-75% | 35-65% | 45-55% |
| | | | TFDB | TFDB | TFDB |
| | | | 25-75% | 35-65% | 45-55% |
| | | | p-PDA | p-PDA | p-PDA |
| BPADA | TFDB | m-PDA | 25-75% | 35-65% | 45-55% |
| | | | TFDB | TFDB | TFDB |
| | | | 25-75% | 35-65% | 45-55% |
| | | | m-PDA | m-PDA | m-PDA |
| BPADA | TFDB | 4,4′- | 25-75% | 35-65% | 45-55% |
| | | ODA | TFDB | TFDB | TFDB |
| | | | 25-75% | 35-65% | 45-55% |
| | | | 4,4′-ODA | 4,4′-ODA | 4,4′-ODA |
| BPADA | TFDB | HFPDA | 25-75% | 35-65% | 45-55% |
| | | | TFDB | TFDB | TFDB |
| | | | 25-75% | 35-65% | 45-55% |
| | | | HFPDA | HFPDA | HFPDA |
| BPADA | TFDB | FDA | 50-90% | 60-80% | 70-80% |
| | | | TFDB | TFDB | TFDB |
| | | | 10-50% | 20-40% | 20-30% |
| | | | FDA | FDA | FDA |
| BPADA | TFDB | BZDA | 50-90% | 60-80% | 70-80% |
| | | | TFDB | TFDB | TFDB |
| | | | 10-50% | 20-40% | 20-30% |
| | | | BZDA | BZDA | BZDA |
| BPADA | TFDB | DHBZ | 50-90% | 60-80% | 70-80% |
| | | | TFDB | TFDB | TFDB |
| | | | 10-50% | 20-40% | 20-30% |
| | | | DHBZ | DHBZ | DHBZ |
| BPADA | TFDB | p-PDA | 50-90% | 60-80% | 70-80% |
| | | | TFDB | TFDB | TFDB |
| | | | 10-50% | 20-40% | 20-30% |
| | | | p-PDA | p-PDA | p-PDA |
| BPADA | TFDB | m-PDA | 50-90% | 60-80% | 70-80% |
| | | | TFDB | TFDB | TFDB |
| | | | 10-50% | 20-40% | 20-30% |
| | | | m-PDA | m-PDA | m-PDA |
| BPADA | TFDB | 4,4′- | 50-90% | 60-80% | 70-80% |
| | | ODA | TFDB | TFDB | TFDB |
| | | | 10-50% | 20-40% | 20-30% |
| | | | 4,4′-ODA | 4,4′-ODA | 4,4′-ODA |
| BPADA | TFDB | HFPDA | 50-90% | 60-80% | 70-80% |
| | | | TFDB | TFDB | TFDB |
| | | | 10-50% | 20-40% | 20-30% |
| | | | HFPDA | HFPDA | HFPDA |
| BPADA | FDA | BZDA | 25-75% | 35-65% | 45-55% |
| | | | FDA | FDA | FDA |
| | | | 25-75% | 35-65% | 45-55% |
| | | | BZDA | BZDA | BZDA |
| BPADA | FDA | DHBZ | 25-75% | 35-65% | 45-55% |
| | | | FDA | FDA | FDA |
| | | | 25-75% | 35-65% | 45-55% |
| | | | DHBZ | DHBZ | DHBZ |
| BPADA | FDA | p-PDA | 25-75% | 35-65% | 45-55% |
| | | | FDA | FDA | FDA |
| | | | 25-75% | 35-65% | 45-55% |
| | | | p-PDA | p-PDA | p-PDA |
| BPADA | FDA | m-PDA | 25-75% | 35-65% | 45-55% |
| | | | FDA | FDA | FDA |
| | | | 25-75% | 35-65% | 45-55% |
| | | | m-PDA | m-PDA | m-PDA |
| BPADA | FDA | 4,4′- | 25-75% | 35-65% | 45-55% |
| | | ODA | FDA | FDA | FDA |
| | | | 25-75% | 35-65% | 45-55% |
| | | | 4,4′-ODA | 4,4′-ODA | 4,4′-ODA |
| BPADA | FDA | HFPDA | 25-75% | 35-65% | 45-55% |
| | | | FDA | FDA | FDA |
| | | | 25-75% | 35-65% | 45-55% |
| | | | HFPDA | HFPDA | HFPDA |
| BTDA | TFDB | FDA | 25-75% | 35-65% | 45-55% |
| | | | TFDB | TFDB | TFDB |
| | | | 25-75% | 35-65% | 45-55% |
| | | | FDA | FDA | FDA |
| BTDA | TFDB | BZDA | 25-75% | 35-65% | 45-55% |
| | | | TFDB | TFDB | TFDB |
| | | | 25-75% | 35-65% | 45-55% |
| | | | BZDA | BZDA | BZDA |
| BTDA | TFDB | DHBZ | 25-75% | 35-65% | 45-55% |
| | | | TFDB | TFDB | TFDB |
| | | | 25-75% | 35-65% | 45-55% |
| | | | DHBZ | DHBZ | DHBZ |
| BTDA | TFDB | p-PDA | 25-75% | 35-65% | 45-55% |
| | | | TFDB | TFDB | TFDB |
| | | | 25-75% | 35-65% | 45-55% |
| | | | p-PDA | p-PDA | p-PDA |
| BTDA | TFDB | m-PDA | 25-75% | 35-65% | 45-55% |
| | | | TFDB | TFDB | TFDB |
| | | | 25-75% | 35-65% | 45-55% |
| | | | m-PDA | m-PDA | m-PDA |
| BTDA | TFDB | 4,4′- | 25-75% | 35-65% | 45-55% |
| | | ODA | TFDB | TFDB | TFDB |
| | | | 25-75% | 35-65% | 45-55% |
| | | | 4,4′-ODA | 4,4′-ODA | 4,4′-ODA |
| BTDA | TFDB | HFPDA | 25-75% | 35-65% | 45-55% |
| | | | TFDB | TFDB | TFDB |
| | | | 25-75% | 35-65% | 45-55% |
| | | | HFPDA | HFPDA | HFPDA |
| BTDA | TFDB | FDA | 50-90% | 60-80% | 70-80% |
| | | | TFDB | TFDB | TFDB |
| | | | 10-50% | 20-40% | 20-30% |
| | | | FDA | FDA | FDA |
| BTDA | TFDB | BZDA | 50-90% | 60-80% | 70-80% |
| | | | TFDB | TFDB | TFDB |
| | | | 10-50% | 20-40% | 20-30% |
| | | | BZDA | BZDA | BZDA |
| BTDA | TFDB | DHBZ | 50-90% | 60-80% | 70-80% |
| | | | TFDB | TFDB | TFDB |
| | | | 10-50% | 20-40% | 20-30% |
| | | | DHBZ | DHBZ | DHBZ |
| BTDA | TFDB | p-PDA | 50-90% | 60-80% | 70-80% |
| | | | TFDB | TFDB | TFDB |
| | | | 10-50% | 20-40% | 20-30% |
| | | | p-PDA | p-PDA | p-PDA |
| BTDA | TFDB | m-PDA | 50-90% | 60-80% | 70-80% |
| | | | TFDB | TFDB | TFDB |
| | | | 10-50% | 20-40% | 20-30% |
| | | | m-PDA | m-PDA | m-PDA |
| BTDA | TFDB | 4,4′- | 50-90% | 60-80% | 70-80% |
| | | ODA | TFDB | TFDB | TFDB |
| | | | 10-50% | 20-40% | 20-30% |
| | | | 4,4′-ODA | 4,4′-ODA | 4,4′-ODA |
| BTDA | TFDB | HFPDA | 50-90% | 60-80% | 70-80% |
| | | | TFDB | TFDB | TFDB |
| | | | 10-50% | 20-40% | 20-30% |
| | | | HFPDA | HFPDA | HFPDA |
| BTDA | FDA | BZDA | 25-75% | 35-65% | 45-55% |
| | | | FDA | FDA | FDA |
| | | | 25-75% | 35-65% | 45-55% |
| | | | BZDA | BZDA | BZDA |
| BTDA | FDA | DHBZ | 25-75% | 35-65% | 45-55% |
| | | | FDA | FDA | FDA |
| | | | 25-75% | 35-65% | 45-55% |
| | | | DHBZ | DHBZ | DHBZ |
| BTDA | FDA | p-PDA | 25-75% | 35-65% | 45-55% |
| | | | FDA | FDA | FDA |
| | | | 25-75% | 35-65% | 45-55% |
| | | | p-PDA | p-PDA | p-PDA |
| BTDA | FDA | m-PDA | 25-75% | 35-65% | 45-55% |
| | | | FDA | FDA | FDA |
| | | | 25-75% | 35-65% | 45-55% |
| | | | m-PDA | m-PDA | m-PDA |
| BTDA | FDA | 4,4′- | 25-75% | 35-65% | 45-55% |
| | | ODA | FDA | FDA | FDA |
| | | | 25-75% | 35-65% | 45-55% |
| | | | 4,4′-ODA | 4,4′-ODA | 4,4′-ODA |
| BTDA | FDA | HFPDA | 25-75% | 35-65% | 45-55% |
| | | | FDA | FDA | FDA |
| | | | 25-75% | 35-65% | 45-55% |
| | | | HFPDA | HFPDA | HFPDA |

The present disclosure also provides the polyimide polymers as listed in Table 5.

TABLE 5

| | | | | Relative mol % of each | | | Relative mol % of each | | |
|---|---|---|---|---|---|---|---|---|---|
| Monomers in the polyimide polymer | | | | dianhydride based on the total | | | diamine based on the total | | |
| dianhydrides | | diamines | | dianhydride in the polyimide | | | diamine in the polyimide | | |
| PMDA | a-BPDA | Form. VI | Form. IV | 25-75% | 35-65% | 45-55% | 25-75% | 35-65% | 45-55% |
| | | | | PMDA | PMDA | PMDA | Form VI | Form VI | Form VI |
| | | | | 25-75% | 35-65% | 45-55% | 25-75% | 35-65% | 45-55% |
| | | | | a-BPDA | a-BPDA | a-BPDA | Form IV | Form IV | Form IV |
| PMDA | a-BPDA | Form. VI | Form. IV | 25-75% | 35-65% | 45-55% | 50-90% | 60-80% | 70-80% |
| | | | | PMDA | PMDA | PMDA | Form VI | Form VI | Form VI |
| | | | | 25-75% | 35-65% | 45-55% | 10-50% | 20-40% | 20-30% |
| | | | | a-BPDA | a-BPDA | a-BPDA | Form IV | Form IV | Form IV |
| PMDA | a-BPDA | Form. VI | Form. VII | 25-75% | 35-65% | 45-55% | 25-75% | 35-65% | 45-55% |
| | | | | PMDA | PMDA | PMDA | Form VI | Form VI | Form VI |
| | | | | 25-75% | 35-65% | 45-55% | 25-75% | 35-65% | 45-55% |
| | | | | a-BPDA | a-BPDA | a-BPDA | Form VII | Form VII | Form VII |
| PMDA | a-BPDA | Form. VI | Form. VII | 25-75% | 35-65% | 45-55% | 50-90% | 60-80% | 70-80% |
| | | | | PMDA | PMDA | PMDA | Form VI | Form VI | Form VI |
| | | | | 25-75% | 35-65% | 45-55% | 10-50% | 20-40% | 20-30% |
| | | | | a-BPDA | a-BPDA | a-BPDA | Form VII | Form VII | Form VII |
| PMDA | a-BPDA | TFDB | FDA | 25-75% | 35-65% | 45-55% | 25-75% | 35-65% | 45-55% |
| | | | | PMDA | PMDA | PMDA | TFDB | TFDB | TFDB |
| | | | | 25-75% | 35-65% | 45-55% | 25-75% | 35-65% | 45-55% |
| | | | | a-BPDA | a-BPDA | a-BPDA | FDA | FDA | FDA |
| PMDA | a-BPDA | TFDB | BZDA | 25-75% | 35-65% | 45-55% | 25-75% | 35-65% | 45-55% |
| | | | | PMDA | PMDA | PMDA | TFDB | TFDB | TFDB |
| | | | | 25-75% | 35-65% | 45-55% | 25-75% | 35-65% | 45-55% |
| | | | | a-BPDA | a-BPDA | a-BPDA | BZDA | BZDA | BZDA |
| PMDA | a-BPDA | TFDB | DHBZ | 25-75% | 35-65% | 45-55% | 25-75% | 35-65% | 45-55% |
| | | | | PMDA | PMDA | PMDA | TFDB | TFDB | TFDB |
| | | | | 25-75% | 35-65% | 45-55% | 25-75% | 35-65% | 45-55% |
| | | | | a-BPDA | a-BPDA | a-BPDA | DHBZ | DHBZ | DHBZ |
| PMDA | a-BPDA | TFDB | p-PDA | 25-75% | 35-65% | 45-55% | 25-75% | 35-65% | 45-55% |
| | | | | PMDA | PMDA | PMDA | TFDB | TFDB | TFDB |
| | | | | 25-75% | 35-65% | 45-55% | 25-75% | 35-65% | 45-55% |
| | | | | a-BPDA | a-BPDA | a-BPDA | p-PDA | p-PDA | p-PDA |
| PMDA | a-BPDA | TFDB | m-PDA | 25-75% | 35-65% | 45-55% | 25-75% | 35-65% | 45-55% |
| | | | | PMDA | PMDA | PMDA | TFDB | TFDB | TFDB |
| | | | | 25-75% | 35-65% | 45-55% | 25-75% | 35-65% | 45-55% |
| | | | | a-BPDA | a-BPDA | a-BPDA | m-PDA | m-PDA | m-PDA |
| PMDA | a-BPDA | TFDB | 4,4′-ODA | 25-75% | 35-65% | 45-55% | 25-75% | 35-65% | 45-55% |
| | | | | PMDA | PMDA | PMDA | TFDB | TFDB | TFDB |
| | | | | 25-75% | 35-65% | 45-55% | 25-75% | 35-65% | 45-55% |
| | | | | a-BPDA | a-BPDA | a-BPDA | 4,4′-ODA | 4,4′-ODA | 4,4′-ODA |
| PMDA | a-BPDA | TFDB | HFPDA | 25-75% | 35-65% | 45-55% | 25-75% | 35-65% | 45-55% |
| | | | | PMDA | PMDA | PMDA | TFDB | TFDB | TFDB |
| | | | | 25-75% | 35-65% | 45-55% | 25-75% | 35-65% | 45-55% |
| | | | | a-BPDA | a-BPDA | a-BPDA | HFPDA | HFPDA | HFPDA |
| PMDA | a-BPDA | TFDB | FDA | 25-75% | 35-65% | 45-55% | 50-90% | 60-80% | 70-80% |
| | | | | PMDA | PMDA | PMDA | TFDB | TFDB | TFDB |
| | | | | 25-75% | 35-65% | 45-55% | 10-50% | 20-40% | 20-30% |
| | | | | a-BPDA | a-BPDA | a-BPDA | FDA | FDA | FDA |
| PMDA | a-BPDA | TFDB | BZDA | 25-75% | 35-65% | 45-55% | 50-90% | 60-80% | 70-80% |
| | | | | PMDA | PMDA | PMDA | TFDB | TFDB | TFDB |
| | | | | 25-75% | 35-65% | 45-55% | 10-50% | 20-40% | 20-30% |
| | | | | a-BPDA | a-BPDA | a-BPDA | BZDA | BZDA | BZDA |
| PMDA | a-BPDA | TFDB | DHBZ | 25-75% | 35-65% | 45-55% | 50-90% | 60-80% | 70-80% |
| | | | | PMDA | PMDA | PMDA | TFDB | TFDB | TFDB |
| | | | | 25-75% | 35-65% | 45-55% | 10-50% | 20-40% | 20-30% |
| | | | | a-BPDA | a-BPDA | a-BPDA | DHBZ | DHBZ | DHBZ |
| PMDA | a-BPDA | TFDB | p-PDA | 25-75% | 35-65% | 45-55% | 50-90% | 60-80% | 70-80% |
| | | | | PMDA | PMDA | PMDA | TFDB | TFDB | TFDB |
| | | | | 25-75% | 35-65% | 45-55% | 10-50% | 20-40% | 20-30% |
| | | | | a-BPDA | a-BPDA | a-BPDA | p-PDA | p-PDA | p-PDA |
| PMDA | a-BPDA | TFDB | m-PDA | 25-75% | 35-65% | 45-55% | 50-90% | 60-80% | 70-80% |
| | | | | PMDA | PMDA | PMDA | TFDB | TFDB | TFDB |
| | | | | 25-75% | 35-65% | 45-55% | 10-50% | 20-40% | 20-30% |
| | | | | a-BPDA | a-BPDA | a-BPDA | m-PDA | m-PDA | m-PDA |
| PMDA | a-BPDA | TFDB | 4,4′-ODA | 25-75% | 35-65% | 45-55% | 50-90% | 60-80% | 70-80% |
| | | | | PMDA | PMDA | PMDA | TFDB | TFDB | TFDB |
| | | | | 25-75% | 35-65% | 45-55% | 10-50% | 20-40% | 20-30% |
| | | | | a-BPDA | a-BPDA | a-BPDA | 4,4′-ODA | 4,4′-ODA | 4,4′-ODA |
| PMDA | a-BPDA | TFDB | HFPDA | 25-75% | 35-65% | 45-55% | 50-90% | 60-80% | 70-80% |
| | | | | PMDA | PMDA | PMDA | TFDB | TFDB | TFDB |
| | | | | 25-75% | 35-65% | 45-55% | 10-50% | 20-40% | 20-30% |
| | | | | a-BPDA | a-BPDA | a-BPDA | HFPDA | HFPDA | HFPDA |
| PMDA | a-BPDA | FDA | BZDA | 25-75% | 35-65% | 45-55% | 25-75% | 35-65% | 45-55% |
| | | | | PMDA | PMDA | PMDA | FDA | FDA | FDA |
| | | | | 25-75% | 35-65% | 45-55% | 25-75% | 35-65% | 45-55% |
| | | | | a-BPDA | a-BPDA | a-BPDA | BZDA | BZDA | BZDA |
| PMDA | a-BPDA | FDA | DHBZ | 25-75% | 35-65% | 45-55% | 25-75% | 35-65% | 45-55% |
| | | | | PMDA | PMDA | PMDA | FDA | FDA | FDA |
| | | | | 25-75% | 35-65% | 45-55% | 25-75% | 35-65% | 45-55% |
| | | | | a-BPDA | a-BPDA | a-BPDA | DHBZ | DHBZ | DHBZ |
| PMDA | a-BPDA | FDA | p-PDA | 25-75% | 35-65% | 45-55% | 25-75% | 35-65% | 45-55% |
| | | | | PMDA | PMDA | PMDA | FDA | FDA | FDA |
| | | | | 25-75% | 35-65% | 45-55% | 25-75% | 35-65% | 45-55% |
| | | | | a-BPDA | a-BPDA | a-BPDA | p-PDA | p-PDA | p-PDA |
| PMDA | a-BPDA | FDA | m-PDA | 25-75% | 35-65% | 45-55% | 25-75% | 35-65% | 45-55% |
| | | | | PMDA | PMDA | PMDA | FDA | FDA | FDA |
| | | | | 25-75% | 35-65% | 45-55% | 25-75% | 35-65% | 45-55% |
| | | | | a-BPDA | a-BPDA | a-BPDA | m-PDA | m-PDA | m-PDA |
| PMDA | a-BPDA | FDA | 4,4′-ODA | 25-75% | 35-65% | 45-55% | 25-75% | 35-65% | 45-55% |
| | | | | PMDA | PMDA | PMDA | FDA | FDA | FDA |
| | | | | 25-75% | 35-65% | 45-55% | 25-75% | 35-65% | 45-55% |
| | | | | a-BPDA | a-BPDA | a-BPDA | 4,4′-ODA | 4,4′-ODA | 4,4′-ODA |
| PMDA | a-BPDA | FDA | HFPDA | 25-75% | 35-65% | 45-55% | 25-75% | 35-65% | 45-55% |
| | | | | PMDA | PMDA | PMDA | FDA | FDA | FDA |
| | | | | 25-75% | 35-65% | 45-55% | 25-75% | 35-65% | 45-55% |
| | | | | a-BPDA | a-BPDA | a-BPDA | HFPDA | HFPDA | HFPDA |
| PMDA | s-BPDA | Form. VI | Form. IV | 25-75% | 35-65% | 45-55% | 25-75% | 35-65% | 45-55% |
| | | | | PMDA | PMDA | PMDA | Form VI | Form VI | Form VI |
| | | | | 25-75% | 35-65% | 45-55% | 25-75% | 35-65% | 45-55% |
| | | | | s-BPDA | s-BPDA | s-BPDA | Form IV | Form IV | Form IV |
| PMDA | s-BPDA | Form. VI | Form. IV | 25-75% | 35-65% | 45-55% | 50-90% | 60-80% | 70-80% |
| | | | | PMDA | PMDA | PMDA | Form VI | Form VI | Form VI |
| | | | | 25-75% | 35-65% | 45-55% | 10-50% | 20-40% | 20-30% |
| | | | | s-BPDA | s-BPDA | s-BPDA | Form IV | Form IV | Form IV |
| PMDA | s-BPDA | Form. VI | Form. VII | 25-75% | 35-65% | 45-55% | 25-75% | 35-65% | 45-55% |
| | | | | PMDA | PMDA | PMDA | Form VI | Form VI | Form VI |
| | | | | 25-75% | 35-65% | 45-55% | 25-75% | 35-65% | 45-55% |
| | | | | s-BPDA | s-BPDA | s-BPDA | Form VII | Form VII | Form VII |
| PMDA | s-BPDA | Form. VI | Form. VII | 25-75% | 35-65% | 45-55% | 50-90% | 60-80% | 70-80% |
| | | | | PMDA | PMDA | PMDA | Form VI | Form VI | Form VI |
| | | | | 25-75% | 35-65% | 45-55% | 10-50% | 20-40% | 20-30% |
| | | | | s-BPDA | s-BPDA | s-BPDA | Form VII | Form VII | Form VII |
| PMDA | s-BPDA | TFDB | FDA | 25-75% | 35-65% | 45-55% | 25-75% | 35-65% | 45-55% |
| | | | | PMDA | PMDA | PMDA | TFDB | TFDB | TFDB |
| | | | | 25-75% | 35-65% | 45-55% | 25-75% | 35-65% | 45-55% |
| | | | | s-BPDA | s-BPDA | s-BPDA | FDA | FDA | FDA |
| PMDA | s-BPDA | TFDB | BZDA | 25-75% | 35-65% | 45-55% | 25-75% | 35-65% | 45-55% |
| | | | | PMDA | PMDA | PMDA | TFDB | TFDB | TFDB |
| | | | | 25-75% | 35-65% | 45-55% | 25-75% | 35-65% | 45-55% |
| | | | | s-BPDA | s-BPDA | s-BPDA | BZDA | BZDA | BZDA |
| PMDA | s-BPDA | TFDB | DHBZ | 25-75% | 35-65% | 45-55% | 25-75% | 35-65% | 45-55% |
| | | | | PMDA | PMDA | PMDA | TFDB | TFDB | TFDB |
| | | | | 25-75% | 35-65% | 45-55% | 25-75% | 35-65% | 45-55% |
| | | | | s-BPDA | s-BPDA | s-BPDA | DHBZ | DHBZ | DHBZ |
| PMDA | s-BPDA | TFDB | p-PDA | 25-75% | 35-65% | 45-55% | 25-75% | 35-65% | 45-55% |
| | | | | PMDA | PMDA | PMDA | TFDB | TFDB | TFDB |
| | | | | 25-75% | 35-65% | 45-55% | 25-75% | 35-65% | 45-55% |
| | | | | s-BPDA | s-BPDA | s-BPDA | p-PDA | p-PDA | p-PDA |
| PMDA | s-BPDA | TFDB | m-PDA | 25-75% | 35-65% | 45-55% | 25-75% | 35-65% | 45-55% |
| | | | | PMDA | PMDA | PMDA | TFDB | TFDB | TFDB |
| | | | | 25-75% | 35-65% | 45-55% | 25-75% | 35-65% | 45-55% |
| | | | | s-BPDA | s-BPDA | s-BPDA | m-PDA | m-PDA | m-PDA |
| PMDA | s-BPDA | TFDB | 4,4′-ODA | 25-75% | 35-65% | 45-55% | 25-75% | 35-65% | 45-55% |
| | | | | PMDA | PMDA | PMDA | TFDB | TFDB | TFDB |
| | | | | 25-75% | 35-65% | 45-55% | 25-75% | 35-65% | 45-55% |
| | | | | s-BPDA | s-BPDA | s-BPDA | 4,4′-ODA | 4,4′-ODA | 4,4′-ODA |
| PMDA | s-BPDA | TFDB | HFPDA | 25-75% | 35-65% | 45-55% | 25-75% | 35-65% | 45-55% |
| | | | | PMDA | PMDA | PMDA | TFDB | TFDB | TFDB |
| | | | | 25-75% | 35-65% | 45-55% | 25-75% | 35-65% | 45-55% |
| | | | | s-BPDA | s-BPDA | s-BPDA | HFPDA | HFPDA | HFPDA |
| PMDA | s-BPDA | TFDB | FDA | 25-75% | 35-65% | 45-55% | 50-90% | 60-80% | 70-80% |
| | | | | PMDA | PMDA | PMDA | TFDB | TFDB | TFDB |
| | | | | 25-75% | 35-65% | 45-55% | 10-50% | 20-40% | 20-30% |
| | | | | s-BPDA | s-BPDA | s-BPDA | FDA | FDA | FDA |
| PMDA | s-BPDA | TFDB | BZDA | 25-75% | 35-65% | 45-55% | 50-90% | 60-80% | 70-80% |
| | | | | PMDA | PMDA | PMDA | TFDB | TFDB | TFDB |
| | | | | 25-75% | 35-65% | 45-55% | 10-50% | 20-40% | 20-30% |
| | | | | s-BPDA | s-BPDA | s-BPDA | BZDA | BZDA | BZDA |
| PMDA | s-BPDA | TFDB | DHBZ | 25-75% | 35-65% | 45-55% | 50-90% | 60-80% | 70-80% |
| | | | | PMDA | PMDA | PMDA | TFDB | TFDB | TFDB |
| | | | | 25-75% | 35-65% | 45-55% | 10-50% | 20-40% | 20-30% |
| | | | | s-BPDA | s-BPDA | s-BPDA | DHBZ | DHBZ | DHBZ |
| PMDA | s-BPDA | TFDB | p-PDA | 25-75% | 35-65% | 45-55% | 50-90% | 60-80% | 70-80% |
| | | | | PMDA | PMDA | PMDA | TFDB | TFDB | TFDB |
| | | | | 25-75% | 35-65% | 45-55% | 10-50% | 20-40% | 20-30% |
| | | | | s-BPDA | s-BPDA | s-BPDA | p-PDA | p-PDA | p-PDA |
| PMDA | s-BPDA | TFDB | m-PDA | 25-75% | 35-65% | 45-55% | 50-90% | 60-80% | 70-80% |
| | | | | PMDA | PMDA | PMDA | TFDB | TFDB | TFDB |
| | | | | 25-75% | 35-65% | 45-55% | 10-50% | 20-40% | 20-30% |
| | | | | s-BPDA | s-BPDA | s-BPDA | m-PDA | m-PDA | m-PDA |
| PMDA | s-BPDA | TFDB | 4,4′-ODA | 25-75% | 35-65% | 45-55% | 50-90% | 60-80% | 70-80% |
| | | | | PMDA | PMDA | PMDA | TFDB | TFDB | TFDB |
| | | | | 25-75% | 35-65% | 45-55% | 10-50% | 20-40% | 20-30% |
| | | | | s-BPDA | s-BPDA | s-BPDA | 4,4′-ODA | 4,4′-ODA | 4,4′-ODA |
| PMDA | s-BPDA | TFDB | HFPDA | 25-75% | 35-65% | 45-55% | 50-90% | 60-80% | 70-80% |
| | | | | PMDA | PMDA | PMDA | TFDB | TFDB | TFDB |
| | | | | 25-75% | 35-65% | 45-55% | 10-50% | 20-40% | 20-30% |
| | | | | s-BPDA | s-BPDA | s-BPDA | HFPDA | HFPDA | HFPDA |
| PMDA | s-BPDA | FDA | BZDA | 25-75% | 35-65% | 45-55% | 25-75% | 35-65% | 45-55% |
| | | | | PMDA | PMDA | PMDA | FDA | FDA | FDA |
| | | | | 25-75% | 35-65% | 45-55% | 25-75% | 35-65% | 45-55% |
| | | | | s-BPDA | s-BPDA | s-BPDA | BZDA | BZDA | BZDA |
| PMDA | s-BPDA | FDA | DHBZ | 25-75% | 35-65% | 45-55% | 25-75% | 35-65% | 45-55% |
| | | | | PMDA | PMDA | PMDA | FDA | FDA | FDA |
| | | | | 25-75% | 35-65% | 45-55% | 25-75% | 35-65% | 45-55% |
| | | | | s-BPDA | s-BPDA | s-BPDA | DHBZ | DHBZ | DHBZ |
| PMDA | s-BPDA | FDA | p-PDA | 25-75% | 35-65% | 45-55% | 25-75% | 35-65% | 45-55% |
| | | | | PMDA | PMDA | PMDA | FDA | FDA | FDA |
| | | | | 25-75% | 35-65% | 45-55% | 25-75% | 35-65% | 45-55% |
| | | | | s-BPDA | s-BPDA | s-BPDA | p-PDA | p-PDA | p-PDA |
| PMDA | s-BPDA | FDA | m-PDA | 25-75% | 35-65% | 45-55% | 25-75% | 35-65% | 45-55% |
| | | | | PMDA | PMDA | PMDA | FDA | FDA | FDA |
| | | | | 25-75% | 35-65% | 45-55% | 25-75% | 35-65% | 45-55% |
| | | | | s-BPDA | s-BPDA | s-BPDA | m-PDA | m-PDA | m-PDA |
| PMDA | s-BPDA | FDA | 4,4′-ODA | 25-75% | 35-65% | 45-55% | 25-75% | 35-65% | 45-55% |
| | | | | PMDA | PMDA | PMDA | FDA | FDA | FDA |
| | | | | 25-75% | 35-65% | 45-55% | 25-75% | 35-65% | 45-55% |
| | | | | s-BPDA | s-BPDA | s-BPDA | 4,4′-ODA | 4,4′-ODA | 4,4′-ODA |
| PMDA | s-BPDA | FDA | HFPDA | 25-75% | 35-65% | 45-55% | 25-75% | 35-65% | 45-55% |
| | | | | PMDA | PMDA | PMDA | FDA | FDA | FDA |
| | | | | 25-75% | 35-65% | 45-55% | 25-75% | 35-65% | 45-55% |
| | | | | s-BPDA | s-BPDA | s-BPDA | HFPDA | HFPDA | HFPDA |
| PMDA | OPDA | Form. VI | Form. V | 25-75% | 35-65% | 45-55% | 25-75% | 35-65% | 45-55% |
| | | | | PMDA | PMDA | PMDA | Form VI | Form VI | Form VI |
| | | | | 25-75% | 35-65% | 45-55% | 25-75% | 35-65% | 45-55% |
| | | | | OPDA | OPDA | OPDA | Form V | Form V | Form V |
| PMDA | OPDA | Form. VI | Form. V | 25-75% | 35-65% | 45-55% | 50-90% | 60-80% | 70-80% |
| | | | | PMDA | PMDA | PMDA | Form VI | Form VI | Form VI |
| | | | | 25-75% | 35-65% | 45-55% | 10-50% | 20-40% | 20-30% |
| | | | | OPDA | OPDA | OPDA | Form V | Form V | Form V |
| PMDA | OPDA | Form. VI | Form. VII | 25-75% | 35-65% | 45-55% | 25-75% | 35-65% | 45-55% |
| | | | | PMDA | PMDA | PMDA | Form VI | Form VI | Form VI |
| | | | | 25-75% | 35-65% | 45-55% | 25-75% | 35-65% | 45-55% |
| | | | | OPDA | OPDA | OPDA | Form VII | Form VII | Form VII |
| PMDA | OPDA | Form. VI | Form. VII | 25-75% | 35-65% | 45-55% | 50-90% | 60-80% | 70-80% |
| | | | | PMDA | PMDA | PMDA | Form VI | Form VI | Form VI |
| | | | | 25-75% | 35-65% | 45-55% | 10-50% | 20-40% | 20-30% |
| | | | | OPDA | OPDA | OPDA | Form VII | Form VII | Form VII |
| PMDA | OPDA | TFDB | FDA | 25-75% | 35-65% | 45-55% | 25-75% | 35-65% | 45-55% |
| | | | | PMDA | PMDA | PMDA | TFDB | TFDB | TFDB |
| | | | | 25-75% | 35-65% | 45-55% | 25-75% | 35-65% | 45-55% |
| | | | | OPDA | OPDA | OPDA | FDA | FDA | FDA |
| PMDA | OPDA | TFDB | BZDA | 25-75% | 35-65% | 45-55% | 25-75% | 35-65% | 45-55% |
| | | | | PMDA | PMDA | PMDA | TFDB | TFDB | TFDB |
| | | | | 25-75% | 35-65% | 45-55% | 25-75% | 35-65% | 45-55% |
| | | | | OPDA | OPDA | OPDA | BZDA | BZDA | BZDA |
| PMDA | OPDA | TFDB | DHBZ | 25-75% | 35-65% | 45-55% | 25-75% | 35-65% | 45-55% |
| | | | | PMDA | PMDA | PMDA | TFDB | TFDB | TFDB |
| | | | | 25-75% | 35-65% | 45-55% | 25-75% | 35-65% | 45-55% |
| | | | | OPDA | OPDA | OPDA | DHBZ | DHBZ | DHBZ |
| PMDA | OPDA | TFDB | p-PDA | 25-75% | 35-65% | 45-55% | 25-75% | 35-65% | 45-55% |
| | | | | PMDA | PMDA | PMDA | TFDB | TFDB | TFDB |
| | | | | 25-75% | 35-65% | 45-55% | 25-75% | 35-65% | 45-55% |
| | | | | OPDA | OPDA | OPDA | p-PDA | p-PDA | p-PDA |
| PMDA | OPDA | TFDB | m-PDA | 25-75% | 35-65% | 45-55% | 25-75% | 35-65% | 45-55% |
| | | | | PMDA | PMDA | PMDA | TFDB | TFDB | TFDB |
| | | | | 25-75% | 35-65% | 45-55% | 25-75% | 35-65% | 45-55% |
| | | | | OPDA | OPDA | OPDA | m-PDA | m-PDA | m-PDA |
| PMDA | OPDA | TFDB | 4,4′-ODA | 25-75% | 35-65% | 45-55% | 25-75% | 35-65% | 45-55% |
| | | | | PMDA | PMDA | PMDA | TFDB | TFDB | TFDB |
| | | | | 25-75% | 35-65% | 45-55% | 25-75% | 35-65% | 45-55% |
| | | | | OPDA | OPDA | OPDA | 4,4′-ODA | 4,4′-ODA | 4,4′-ODA |
| PMDA | OPDA | TFDB | HFPDA | 25-75% | 35-65% | 45-55% | 25-75% | 35-65% | 45-55% |
| | | | | PMDA | PMDA | PMDA | TFDB | TFDB | TFDB |
| | | | | 25-75% | 35-65% | 45-55% | 25-75% | 35-65% | 45-55% |
| | | | | OPDA | OPDA | OPDA | HFPDA | HFPDA | HFPDA |
| PMDA | OPDA | TFDB | FDA | 25-75% | 35-65% | 45-55% | 50-90% | 60-80% | 70-80% |
| | | | | PMDA | PMDA | PMDA | TFDB | TFDB | TFDB |
| | | | | 25-75% | 35-65% | 45-55% | 10-50% | 20-40% | 20-30% |
| | | | | OPDA | OPDA | OPDA | FDA | FDA | FDA |
| PMDA | OPDA | TFDB | BZDA | 25-75% | 35-65% | 45-55% | 50-90% | 60-80% | 70-80% |
| | | | | PMDA | PMDA | PMDA | TFDB | TFDB | TFDB |
| | | | | 25-75% | 35-65% | 45-55% | 10-50% | 20-40% | 20-30% |
| | | | | OPDA | OPDA | OPDA | BZDA | BZDA | BZDA |
| PMDA | OPDA | TFDB | DHBZ | 25-75% | 35-65% | 45-55% | 50-90% | 60-80% | 70-80% |
| | | | | PMDA | PMDA | PMDA | TFDB | TFDB | TFDB |
| | | | | 25-75% | 35-65% | 45-55% | 10-50% | 20-40% | 20-30% |
| | | | | OPDA | OPDA | OPDA | DHBZ | DHBZ | DHBZ |
| PMDA | OPDA | TFDB | p-PDA | 25-75% | 35-65% | 45-55% | 50-90% | 60-80% | 70-80% |
| | | | | PMDA | PMDA | PMDA | TFDB | TFDB | TFDB |
| | | | | 25-75% | 35-65% | 45-55% | 10-50% | 20-40% | 20-30% |
| | | | | OPDA | OPDA | OPDA | p-PDA | p-PDA | p-PDA |
| PMDA | OPDA | TFDB | m-PDA | 25-75% | 35-65% | 45-55% | 50-90% | 60-80% | 70-80% |
| | | | | PMDA | PMDA | PMDA | TFDB | TFDB | TFDB |
| | | | | 25-75% | 35-65% | 45-55% | 10-50% | 20-40% | 20-30% |
| | | | | OPDA | OPDA | OPDA | m-PDA | m-PDA | m-PDA |
| PMDA | OPDA | TFDB | 4,4′-ODA | 25-75% | 35-65% | 45-55% | 50-90% | 60-80% | 70-80% |
| | | | | PMDA | PMDA | PMDA | TFDB | TFDB | TFDB |
| | | | | 25-75% | 35-65% | 45-55% | 10-50% | 20-40% | 20-30% |
| | | | | OPDA | OPDA | OPDA | 4,4′-ODA | 4,4′-ODA | 4,4′-ODA |
| PMDA | OPDA | TFDB | HFPDA | 25-75% | 35-65% | 45-55% | 50-90% | 60-80% | 70-80% |
| | | | | PMDA | PMDA | PMDA | TFDB | TFDB | TFDB |
| | | | | 25-75% | 35-65% | 45-55% | 10-50% | 20-40% | 20-30% |
| | | | | OPDA | OPDA | OPDA | HFPDA | HFPDA | HFPDA |
| PMDA | OPDA | FDA | BZDA | 25-75% | 35-65% | 45-55% | 25-75% | 35-65% | 45-55% |
| | | | | PMDA | PMDA | PMDA | FDA | FDA | FDA |
| | | | | 25-75% | 35-65% | 45-55% | 25-75% | 35-65% | 45-55% |
| | | | | OPDA | OPDA | OPDA | BZDA | BZDA | BZDA |
| PMDA | OPDA | FDA | DHBZ | 25-75% | 35-65% | 45-55% | 25-75% | 35-65% | 45-55% |
| | | | | PMDA | PMDA | PMDA | FDA | FDA | FDA |
| | | | | 25-75% | 35-65% | 45-55% | 25-75% | 35-65% | 45-55% |
| | | | | OPDA | OPDA | OPDA | DHBZ | DHBZ | DHBZ |
| PMDA | OPDA | FDA | p-PDA | 25-75% | 35-65% | 45-55% | 25-75% | 35-65% | 45-55% |
| | | | | PMDA | PMDA | PMDA | FDA | FDA | FDA |
| | | | | 25-75% | 35-65% | 45-55% | 25-75% | 35-65% | 45-55% |
| | | | | OPDA | OPDA | OPDA | p-PDA | p-PDA | p-PDA |
| PMDA | OPDA | FDA | m-PDA | 25-75% | 35-65% | 45-55% | 25-75% | 35-65% | 45-55% |
| | | | | PMDA | PMDA | PMDA | FDA | FDA | FDA |
| | | | | 25-75% | 35-65% | 45-55% | 25-75% | 35-65% | 45-55% |
| | | | | OPDA | OPDA | OPDA | m-PDA | m-PDA | m-PDA |
| PMDA | OPDA | FDA | 4,4′-ODA | 25-75% | 35-65% | 45-55% | 25-75% | 35-65% | 45-55% |
| | | | | PMDA | PMDA | PMDA | FDA | FDA | FDA |
| | | | | 25-75% | 35-65% | 45-55% | 25-75% | 35-65% | 45-55% |
| | | | | OPDA | OPDA | OPDA | 4,4′-ODA | 4,4′-ODA | 4,4′-ODA |
| PMDA | OPDA | FDA | HFPDA | 25-75% | 35-65% | 45-55% | 25-75% | 35-65% | 45-55% |
| | | | | PMDA | PMDA | PMDA | FDA | FDA | FDA |
| | | | | 25-75% | 35-65% | 45-55% | 25-75% | 35-65% | 45-55% |
| | | | | OPDA | OPDA | OPDA | HFPDA | HFPDA | HFPDA |
| PMDA | HQDA | Form. VI | Form. V | 25-75% | 35-65% | 45-55% | 25-75% | 35-65% | 45-55% |
| | | | | PMDA | PMDA | PMDA | Form VI | Form VI | Form VI |
| | | | | 25-75% | 35-65% | 45-55% | 25-75% | 35-65% | 45-55% |
| | | | | HQDA | HQDA | HQDA | Form V | Form V | Form V |
| PMDA | HQDA | Form. VI | Form. V | 25-75% | 35-65% | 45-55% | 50-90% | 60-80% | 70-80% |
| | | | | PMDA | PMDA | PMDA | Form VI | Form VI | Form VI |
| | | | | 25-75% | 35-65% | 45-55% | 10-50% | 20-40% | 20-30% |
| | | | | HQDA | HQDA | HQDA | Form V | Form V | Form V |
| PMDA | HQDA | Form. VI | Form. VII | 25-75% | 35-65% | 45-55% | 25-75% | 35-65% | 45-55% |
| | | | | PMDA | PMDA | PMDA | Form VI | Form VI | Form VI |
| | | | | 25-75% | 35-65% | 45-55% | 25-75% | 35-65% | 45-55% |
| | | | | HQDA | HQDA | HQDA | Form VII | Form VII | Form VII |
| PMDA | HQDA | Form. VI | Form. VII | 25-75% | 35-65% | 45-55% | 50-90% | 60-80% | 70-80% |
| | | | | PMDA | PMDA | PMDA | Form VI | Form VI | Form VI |
| | | | | 25-75% | 35-65% | 45-55% | 10-50% | 20-40% | 20-30% |
| | | | | HQDA | HQDA | HQDA | Form VII | Form VII | Form VII |
| PMDA | HQDA | TFDB | FDA | 25-75% | 35-65% | 45-55% | 25-75% | 35-65% | 45-55% |
| | | | | PMDA | PMDA | PMDA | TFDB | TFDB | TFDB |
| | | | | 25-75% | 35-65% | 45-55% | 25-75% | 35-65% | 45-55% |
| | | | | HQDA | HQDA | HQDA | FDA | FDA | FDA |
| PMDA | HQDA | TFDB | BZDA | 25-75% | 35-65% | 45-55% | 25-75% | 35-65% | 45-55% |
| | | | | PMDA | PMDA | PMDA | TFDB | TFDB | TFDB |
| | | | | 25-75% | 35-65% | 45-55% | 25-75% | 35-65% | 45-55% |
| | | | | HQDA | HQDA | HQDA | BZDA | BZDA | BZDA |
| PMDA | HQDA | TFDB | DHBZ | 25-75% | 35-65% | 45-55% | 25-75% | 35-65% | 45-55% |
| | | | | PMDA | PMDA | PMDA | TFDB | TFDB | TFDB |
| | | | | 25-75% | 35-65% | 45-55% | 25-75% | 35-65% | 45-55% |
| | | | | HQDA | HQDA | HQDA | DHBZ | DHBZ | DHBZ |
| PMDA | HQDA | TFDB | p-PDA | 25-75% | 35-65% | 45-55% | 25-75% | 35-65% | 45-55% |
| | | | | PMDA | PMDA | PMDA | TFDB | TFDB | TFDB |
| | | | | 25-75% | 35-65% | 45-55% | 25-75% | 35-65% | 45-55% |
| | | | | HQDA | HQDA | HQDA | p-PDA | p-PDA | p-PDA |
| PMDA | HQDA | TFDB | m-PDA | 25-75% | 35-65% | 45-55% | 25-75% | 35-65% | 45-55% |
| | | | | PMDA | PMDA | PMDA | TFDB | TFDB | TFDB |
| | | | | 25-75% | 35-65% | 45-55% | 25-75% | 35-65% | 45-55% |
| | | | | HQDA | HQDA | HQDA | m-PDA | m-PDA | m-PDA |
| PMDA | HQDA | TFDB | 4,4′-ODA | 25-75% | 35-65% | 45-55% | 25-75% | 35-65% | 45-55% |
| | | | | PMDA | PMDA | PMDA | TFDB | TFDB | TFDB |
| | | | | 25-75% | 35-65% | 45-55% | 25-75% | 35-65% | 45-55% |
| | | | | HQDA | HQDA | HQDA | 4,4′-ODA | 4,4′-ODA | 4,4′-ODA |
| PMDA | HQDA | TFDB | HFPDA | 25-75% | 35-65% | 45-55% | 25-75% | 35-65% | 45-55% |
| | | | | PMDA | PMDA | PMDA | TFDB | TFDB | TFDB |
| | | | | 25-75% | 35-65% | 45-55% | 25-75% | 35-65% | 45-55% |
| | | | | HQDA | HQDA | HQDA | HFPDA | HFPDA | HFPDA |
| PMDA | HQDA | TFDB | FDA | 25-75% | 35-65% | 45-55% | 50-90% | 60-80% | 70-80% |
| | | | | PMDA | PMDA | PMDA | TFDB | TFDB | TFDB |
| | | | | 25-75% | 35-65% | 45-55% | 10-50% | 20-40% | 20-30% |
| | | | | HQDA | HQDA | HQDA | FDA | FDA | FDA |
| PMDA | HQDA | TFDB | BZDA | 25-75% | 35-65% | 45-55% | 50-90% | 60-80% | 70-80% |
| | | | | PMDA | PMDA | PMDA | TFDB | TFDB | TFDB |
| | | | | 25-75% | 35-65% | 45-55% | 10-50% | 20-40% | 20-30% |
| | | | | HQDA | HQDA | HQDA | BZDA | BZDA | BZDA |
| PMDA | HQDA | TFDB | DHBZ | 25-75% | 35-65% | 45-55% | 50-90% | 60-80% | 70-80% |
| | | | | PMDA | PMDA | PMDA | TFDB | TFDB | TFDB |
| | | | | 25-75% | 35-65% | 45-55% | 10-50% | 20-40% | 20-30% |
| | | | | HQDA | HQDA | HQDA | DHBZ | DHBZ | DHBZ |
| PMDA | HQDA | TFDB | p-PDA | 25-75% | 35-65% | 45-55% | 50-90% | 60-80% | 70-80% |
| | | | | PMDA | PMDA | PMDA | TFDB | TFDB | TFDB |
| | | | | 25-75% | 35-65% | 45-55% | 10-50% | 20-40% | 20-30% |
| | | | | HQDA | HQDA | HQDA | p-PDA | p-PDA | p-PDA |
| PMDA | HQDA | TFDB | m-PDA | 25-75% | 35-65% | 45-55% | 50-90% | 60-80% | 70-80% |
| | | | | PMDA | PMDA | PMDA | TFDB | TFDB | TFDB |
| | | | | 25-75% | 35-65% | 45-55% | 10-50% | 20-40% | 20-30% |
| | | | | HQDA | HQDA | HQDA | m-PDA | m-PDA | m-PDA |
| PMDA | HQDA | TFDB | 4,4′-ODA | 25-75% | 35-65% | 45-55% | 50-90% | 60-80% | 70-80% |
| | | | | PMDA | PMDA | PMDA | TFDB | TFDB | TFDB |
| | | | | 25-75% | 35-65% | 45-55% | 10-50% | 20-40% | 20-30% |
| | | | | HQDA | HQDA | HQDA | 4,4′-ODA | 4,4′-ODA | 4,4′-ODA |
| PMDA | HQDA | TFDB | HFPDA | 25-75% | 35-65% | 45-55% | 50-90% | 60-80% | 70-80% |
| | | | | PMDA | PMDA | PDA | TFDB | TFDB | TFDB |
| | | | | 25-75% | 35-65% | 45-55% | 1050% | 20-40% | 20-30% |
| | | | | HQDA | HQDA | HQDA | HFPDA | HFPDA | HFPDA |
| PMDA | HQDA | FDA | BZDA | 25-75% | 35-65% | 45-55% | 25-75% | 35-65% | 45-55% |
| | | | | PMDA | PMDA | PMDA | FDA | FDA | FDA |
| | | | | 25-75% | 35-65% | 45-55% | 25-75% | 35-65% | 45-55% |
| | | | | HQDA | HQDA | HQDA | BZDA | BZDA | BZDA |
| PMDA | HQDA | FDA | DHBZ | 25-75% | 35-65% | 45-55% | 25-75% | 35-65% | 45-55% |
| | | | | PMDA | PMDA | PMDA | FDA | FDA | FDA |
| | | | | 25-75% | 35-65% | 45-55% | 25-75% | 35-65% | 45-55% |
| | | | | HQDA | HQDA | HQDA | DHBZ | DHBZ | DHBZ |
| PMDA | HQDA | FDA | p-PDA | 25-75% | 35-65% | 45-55% | 25-75% | 35-65% | 45-55% |
| | | | | PMDA | PMDA | PMDA | FDA | FDA | FDA |
| | | | | 25-75% | 35-65% | 45-55% | 25-75% | 35-65% | 45-55% |
| | | | | HQDA | HQDA | HQDA | p-PDA | p-PDA | p-PDA |
| PMDA | HQDA | FDA | m-PDA | 25-75% | 35-65% | 45-55% | 25-75% | 35-65% | 45-55% |
| | | | | PMDA | PMDA | PMDA | FDA | FDA | FDA |
| | | | | 25-75% | 35-65% | 45-55% | 25-75% | 35-65% | 45-55% |
| | | | | HQDA | HQDA | HQDA | m-PDA | m-PDA | m-PDA |
| PMDA | HQDA | FDA | 4,4′-ODA | 25-75% | 35-65% | 45-55% | 25-75% | 35-65% | 45-55% |
| | | | | PMDA | PMDA | PMDA | FDA | FDA | FDA |
| | | | | 25-75% | 35-65% | 45-55% | 25-75% | 35-65% | 45-55% |
| | | | | HQDA | HQDA | HQDA | 4,4′-ODA | 4,4′-ODA | 4,4′-ODA |
| PMDA | HQDA | FDA | HFPDA | 25-75% | 35-65% | 45-55% | 25-75% | 35-65% | 45-55% |
| | | | | PMDA | PMDA | PMDA | FDA | FDA | FDA |
| | | | | 25-75% | 35-65% | 45-55% | 25-75% | 35-65% | 45-55% |
| | | | | HQDA | HQDA | HQDA | HFPDA | HFPDA | HFPDA |
| PMDA | BPADA | Form. VI | Form. V | 25-75% | 35-65% | 45-55% | 25-75% | 35-65% | 45-55% |
| | | | | PMDA | PMDA | PMDA | Form VI | Form VI | Form VI |
| | | | | 25-75% | 35-65% | 45-55% | 25-75% | 35-65% | 45-55% |
| | | | | BPADA | BPADA | BPADA | Form V | Form V | Form V |
| PMDA | BPADA | Form. VI | Form. V | 25-75% | 35-65% | 45-55% | 50-90% | 60-80% | 70-80% |
| | | | | PMDA | PMDA | PMDA | Form VI | Form VI | Form VI |
| | | | | 25-75% | 35-65% | 45-55% | 10-50% | 20-40% | 20-30% |
| | | | | BPADA | BPADA | BPADA | Form V | Form V | Form V |
| PMDA | BPADA | Form. VI | Form. VII | 25-75% | 35-65% | 45-55% | 25-75% | 35-65% | 45-55% |
| | | | | PMDA | PMDA | PMDA | Form VI | Form VI | Form VI |
| | | | | 25-75% | 35-65% | 45-55% | 25-75% | 35-65% | 45-55% |
| | | | | BPADA | BPADA | BPADA | Form VII | Form VII | Form VII |
| PMDA | BPADA | Form. VI | Form. VII | 25-75% | 35-65% | 45-55% | 50-90% | 60-80% | 70-80% |
| | | | | PMDA | PMDA | PMDA | Form VI | Form VI | Form VI |
| | | | | 25-75% | 35-65% | 45-55% | 10-50% | 20-40% | 20-30% |
| | | | | BPADA | BPADA | BPADA | Form VII | Form VII | Form VII |
| PMDA | BPADA | TFDB | FDA | 25-75% | 35-65% | 45-55% | 25-75% | 35-65% | 45-55% |
| | | | | PMDA | PMDA | PMDA | TFDB | TFDB | TFDB |
| | | | | 25-75% | 35-65% | 45-55% | 25-75% | 35-65% | 45-55% |
| | | | | BPADA | BPADA | BPADA | FDA | FDA | FDA |
| PMDA | BPADA | TFDB | BZDA | 25-75% | 35-65% | 45-55% | 25-75% | 35-65% | 45-55% |
| | | | | PMDA | PMDA | PMDA | TFDB | TFDB | TFDB |
| | | | | 25-75% | 35-65% | 45-55% | 25-75% | 35-65% | 45-55% |
| | | | | BPADA | BPADA | BPADA | BZDA | BZDA | BZDA |
| PMDA | BPADA | TFDB | DHBZ | 25-75% | 35-65% | 45-55% | 25-75% | 35-65% | 45-55% |
| | | | | PMDA | PMDA | PMDA | TFDB | TFDB | TFDB |
| | | | | 25-75% | 35-65% | 45-55% | 25-75% | 35-65% | 45-55% |
| | | | | BPADA | BPADA | BPADA | DHBZ | DHBZ | DHBZ |
| PMDA | BPADA | TFDB | p-PDA | 25-75% | 35-65% | 45-55% | 25-75% | 35-65% | 45-55% |
| | | | | PMDA | PMDA | PMDA | TFDB | TFDB | TFDB |
| | | | | 25-75% | 35-65% | 45-55% | 25-75% | 35-65% | 45-55% |
| | | | | BPADA | BPADA | BPADA | p-PDA | p-PDA | p-PDA |
| PMDA | BPADA | TFDB | m-PDA | 25-75% | 35-65% | 45-55% | 25-75% | 35-65% | 45-55% |
| | | | | PMDA | PMDA | PMDA | TFDB | TFDB | TFDB |
| | | | | 25-75% | 35-65% | 45-55% | 25-75% | 35-65% | 45-55% |
| | | | | BPADA | BPADA | BPADA | m-PDA | m-PDA | m-PDA |
| PMDA | BPADA | TFDB | 4,4′-ODA | 25-75% | 35-65% | 45-55% | 25-75% | 35-65% | 45-55% |
| | | | | PMDA | PMDA | PMDA | TFDB | TFDB | TFDB |
| | | | | 25-75% | 35-65% | 45-55% | 25-75% | 35-65% | 45-55% |
| | | | | BPADA | BPADA | BPADA | 4,4′-ODA | 4,4′-ODA | 4,4′-ODA |
| PMDA | BPADA | TFDB | HFPDA | 25-75% | 35-65% | 45-55% | 25-75% | 35-65% | 45-55% |
| | | | | PMDA | PMDA | PMDA | TFDB | TFDB | TFDB |
| | | | | 25-75% | 35-65% | 45-55% | 25-75% | 35-65% | 45-55% |
| | | | | BPADA | BPADA | BPADA | HFPDA | HFPDA | HFPDA |
| PMDA | BPADA | TFDB | FDA | 25-75% | 35-65% | 45-55% | 50-90% | 60-80% | 70-80% |
| | | | | PMDA | PMDA | PMDA | TFDB | TFDB | TFDB |
| | | | | 25-75% | 35-65% | 45-55% | 10-50% | 20-40% | 20-30% |
| | | | | BPADA | BPADA | BPADA | FDA | FDA | FDA |
| PMDA | BPADA | TFDB | BZDA | 25-75% | 35-65% | 45-55% | 50-90% | 60-80% | 70-80% |
| | | | | PMDA | PMDA | PMDA | TFDB | TFDB | TFDB |
| | | | | 25-75% | 35-65% | 45-55% | 10-50% | 20-40% | 20-30% |
| | | | | BPADA | BPADA | BPADA | BZDA | BZDA | BZDA |
| PMDA | BPADA | TFDB | DHBZ | 25-75% | 35-65% | 45-55% | 50-90% | 60-80% | 70-80% |
| | | | | PMDA | PMDA | PMDA | TFDB | TFDB | TFDB |
| | | | | 25-75% | 35-65% | 45-55% | 10-50% | 20-40% | 20-30% |
| | | | | BPADA | BPADA | BPADA | DHBZ | DHBZ | DHBZ |
| PMDA | BPADA | TFDB | p-PDA | 25-75% | 35-65% | 45-55% | 50-90% | 60-80% | 70-80% |
| | | | | PMDA | PMDA | PMDA | TFDB | TFDB | TFDB |
| | | | | 25-75% | 35-65% | 45-55% | 10-50% | 20-40% | 20-30% |
| | | | | BPADA | BPADA | BPADA | p-PDA | p-PDA | p-PDA |
| PMDA | BPADA | TFDB | m-PDA | 25-75% | 35-65% | 45-55% | 50-90% | 60-80% | 70-80% |
| | | | | PMDA | PMDA | PMDA | TFDB | TFDB | TFDB |
| | | | | 25-75% | 35-65% | 45-55% | 10-50% | 20-40% | 20-30% |
| | | | | BPADA | BPADA | BPADA | m-PDA | m-PDA | m-PDA |
| PMDA | BPADA | TFDB | 4,4′-ODA | 25-75% | 35-65% | 45-55% | 50-90% | 60-80% | 70-80% |
| | | | | PMDA | PMDA | PMDA | TFDB | TFDB | TFDB |
| | | | | 25-75% | 35-65% | 45-55% | 10-50% | 20-40% | 20-30% |
| | | | | BPADA | BPADA | BPADA | 4,4′-ODA | 4,4′-ODA | 4,4′-ODA |
| PMDA | BPADA | TFDB | HFPDA | 25-75% | 35-65% | 45-55% | 50-90% | 60-80% | 70-80% |
| | | | | PMDA | PMDA | PMDA | TFDB | TFDB | TFDB |
| | | | | 25-75% | 35-65% | 45-55% | 10-50% | 20-40% | 20-30% |
| | | | | BPADA | BPADA | BPADA | HFPDA | HFPDA | HFPDA |
| PMDA | BPADA | FDA | BZDA | 25-75% | 35-65% | 45-55% | 25-75% | 35-65% | 45-55% |
| | | | | PMDA | PMDA | PMDA | FDA | FDA | FDA |
| | | | | 25-75% | 35-65% | 45-55% | 25-75% | 35-65% | 45-55% |
| | | | | BPADA | BPADA | BPADA | BZDA | BZDA | BZDA |
| PMDA | BPADA | FDA | DHBZ | 25-75% | 35-65% | 45-55% | 25-75% | 35-65% | 45-55% |
| | | | | PMDA | PMDA | PMDA | FDA | FDA | FDA |
| | | | | 25-75% | 35-65% | 45-55% | 25-75% | 35-65% | 45-55% |
| | | | | BPADA | BPADA | BPADA | DHBZ | DHBZ | DHBZ |
| PMDA | BPADA | FDA | p-PDA | 25-75% | 35-65% | 45-55% | 25-75% | 35-65% | 45-55% |
| | | | | PMDA | PMDA | PMDA | FDA | FDA | FDA |
| | | | | 25-75% | 35-65% | 45-55% | 25-75% | 35-65% | 45-55% |
| | | | | BPADA | BPADA | BPADA | p-PDA | p-PDA | p-PDA |
| PMDA | BPADA | FDA | m-PDA | 25-75% | 35-65% | 45-55% | 25-75% | 35-65% | 45-55% |
| | | | | PMDA | PMDA | PMDA | FDA | FDA | FDA |
| | | | | 25-75% | 35-65% | 45-55% | 25-75% | 35-65% | 45-55% |
| | | | | BPADA | BPADA | BPADA | m-PDA | m-PDA | m-PDA |
| PMDA | BPADA | FDA | 4,4′-ODA | 25-75% | 35-65% | 45-55% | 25-75% | 35-65% | 45-55% |
| | | | | PMDA | PMDA | PMDA | FDA | FDA | FDA |
| | | | | 25-75% | 35-65% | 45-55% | 25-75% | 35-65% | 45-55% |
| | | | | BPADA | BPADA | BPADA | 4,4′-ODA | 4,4′-ODA | 4,4′-ODA |
| PMDA | BPADA | FDA | HFPDA | 25-75% | 35-65% | 45-55% | 25-75% | 35-65% | 45-55% |
| | | | | PMDA | PMDA | PMDA | FDA | FDA | FDA |
| | | | | 25-75% | 35-65% | 45-55% | 25-75% | 35-65% | 45-55% |
| | | | | BPADA | BPADA | BPADA | HFPDA | HFPDA | HFPDA |
| A-BPDA | S-BPDA | Form. VI | Form. V | 25-75% | 35-65% | 45-55% | 25-75% | 35-65% | 45-55% |
| | | | | A- | A- | A- | Form VI | Form VI | Form VI |
| | | | | BPDA | BPDA | BPDA | 25-75% | 35-65% | 45-55% |
| | | | | 25-75% | 35-65% | 45-55% | Form V | Form V | Form V |
| | | | | S- | S- | S- | | | |
| | | | | BPDA | BPDA | BPDA | | | |
| A-BPDA | S-BPDA | Form. VI | Form. V | 25-75% | 35-65% | 45-55% | 50-90% | 60-80% | 70-80% |
| | | | | A- | A- | A- | Form VI | Form VI | Form VI |
| | | | | BPDA | BPDA | BPDA | 10-50% | 20-40% | 20-30% |
| | | | | 25-75% | 35-65% | 45-55% | Form V | Form V | Form V |
| | | | | S- | S- | S- | | | |
| | | | | BPDA | BPDA | BPDA | | | |
| A-BPDA | S-BPDA | Form. VI | Form. VII | 25-75% | 35-65% | 45-55% | 25-75% | 35-65% | 45-55% |
| | | | | A- | A- | A- | Form VI | Form VI | Form VI |
| | | | | BPDA | BPDA | BPDA | 25-75% | 35-65% | 45-55% |
| | | | | 25-75% | 35-65% | 45-55% | Form VII | Form VII | Form VII |
| | | | | S- | S- | S- | | | |
| | | | | BPDA | BPDA | BPDA | | | |
| A-BPDA | S-BPDA | Form. VI | Form. VII | 25-75% | 35-65% | 45-55% | 50-90% | 60-80% | 70-80% |
| | | | | A- | A- | A- | Form VI | Form VI | Form VI |
| | | | | BPDA | BPDA | BPDA | 10-50% | 20-40% | 20-30% |
| | | | | 25-75% | 35-65% | 45-55% | Form VII | Form VII | Form VII |
| | | | | S- | S- | S- | | | |
| | | | | BPDA | BPDA | BPDA | | | |
| A-BPDA | S-BPDA | TFDB | FDA | 25-75% | 35-65% | 45-55% | 25-75% | 35-65% | 45-55% |
| | | | | A- | A- | A- | TFDB | TFDB | TFDB |
| | | | | BPDA | BPDA | BPDA | 25-75% | 35-65% | 45-55% |
| | | | | 25-75% | 35-65% | 45-55% | FDA | FDA | FDA |
| | | | | S- | S- | S- | | | |
| | | | | BPDA | BPDA | BPDA | | | |
| A-BPDA | S-BPDA | TFDB | BZDA | 25-75% | 35-65% | 45-55% | 25-75% | 35-65% | 45-55% |
| | | | | A- | A- | A- | TFDB | TFDB | TFDB |
| | | | | BPDA | BPDA | BPDA | 25-75% | 35-65% | 45-55% |
| | | | | 25-75% | 35-65% | 45-55% | BZDA | BZDA | BZDA |
| | | | | S- | S- | S- | | | |
| | | | | BPDA | BPDA | BPDA | | | |
| A-BPDA | S-BPDA | TFDB | DHBZ | 25-75% | 35-65% | 45-55% | 25-75% | 35-65% | 45-55% |
| | | | | A- | A- | A- | TFDB | TFDB | TFDB |
| | | | | BPDA | BPDA | BPDA | 25-75% | 35-65% | 45-55% |
| | | | | 25-75% | 35-65% | 45-55% | DHBZ | DHBZ | DHBZ |
| | | | | S- | S- | S- | | | |
| | | | | BPDA | BPDA | BPDA | | | |
| A-BPDA | S-BPDA | TFDB | p-PDA | 25-75% | 35-65% | 45-55% | 25-75% | 35-65% | 45-55% |
| | | | | A- | A- | A- | TFDB | TFDB | TFDB |
| | | | | BPDA | BPDA | BPDA | 25-75% | 35-65% | 45-55% |
| | | | | 25-75% | 35-65% | 45-55% | p-PDA | p-PDA | p-PDA |
| | | | | S- | S- | S- | | | |
| | | | | BPDA | BPDA | BPDA | | | |
| A-BPDA | S-BPDA | TFDB | m-PDA | 25-75% | 35-65% | 45-55% | 25-75% | 35-65% | 45-55% |
| | | | | A- | A- | A- | TFDB | TFDB | TFDB |
| | | | | BPDA | BPDA | BPDA | 25-75% | 35-65% | 45-55% |
| | | | | 25-75% | 35-65% | 45-55% | m-PDA | m-PDA | m-PDA |
| | | | | S- | S- | S- | | | |
| | | | | BPDA | BPDA | BPDA | | | |
| A-BPDA | S-BPDA | TFDB | 4,4′-ODA | 25-75% | 35-65% | 45-55% | 25-75% | 35-65% | 45-55% |
| | | | | A- | A- | A- | TFDB | TFDB | TFDB |
| | | | | BPDA | BPDA | BPDA | 25-75% | 35-65% | 45-55% |
| | | | | 25-75% | 35-65% | 45-55% | 4,4′-ODA | 4,4′-ODA | 4,4′-ODA |
| | | | | S- | S- | S- | | | |
| | | | | BPDA | BPDA | BPDA | | | |
| A-BPDA | S-BPDA | TFDB | HFPDA | 25-75% | 35-65% | 45-55% | 25-75% | 35-65% | 45-55% |
| | | | | A- | A- | A- | TFDB | TFDB | TFDB |
| | | | | BPDA | BPDA | BPDA | 25-75% | 35-65% | 45-55% |
| | | | | 25-75% | 35-65% | 45-55% | HFPDA | HFPDA | HFPDA |
| | | | | S- | S- | S- | | | |
| | | | | BPDA | BPDA | BPDA | | | |
| A-BPDA | S-BPDA | TFDB | FDA | 25-75% | 35-65% | 45-55% | 50-90% | 60-80% | 70-80% |
| | | | | A- | A- | A- | TFDB | TFDB | TFDB |
| | | | | BPDA | BPDA | BPDA | 10-50% | 20-40% | 20-30% |
| | | | | 25-75% | 35-65% | 45-55% | FDA | FDA | FDA |
| | | | | S- | S- | S- | | | |
| | | | | BPDA | BPDA | BPDA | | | |
| A-BPDA | S-BPDA | TFDB | BZDA | 25-75% | 35-65% | 45-55% | 50-90% | 60-80% | 70-80% |
| | | | | A- | A- | A- | TFDB | TFDB | TFDB |
| | | | | BPDA | BPDA | BPDA | 10-50% | 20-40% | 20-30% |
| | | | | 25-75% | 35-65% | 45-55% | BZDA | BZDA | BZDA |
| | | | | S- | S- | S- | | | |
| | | | | BPDA | BPDA | BPDA | | | |
| A-BPDA | S-BPDA | TFDB | DHBZ | 25-75% | 35-65% | 45-55% | 50-90% | 60-80% | 70-80% |
| | | | | A- | A- | A- | TFDB | TFDB | TFDB |
| | | | | BPDA | BPDA | BPDA | 10-50% | 20-40% | 20-30% |
| | | | | 25-75% | 35-65% | 45-55% | DHBZ | DHBZ | DHBZ |
| | | | | S- | S- | S- | | | |
| | | | | BPDA | BPDA | BPDA | | | |
| A-BPDA | S-BPDA | TFDB | p-PDA | 25-75% | 35-65% | 45-55% | 50-90% | 60-80% | 70-80% |
| | | | | A- | A- | A- | TFDB | TFDB | TFDB |
| | | | | BPDA | BPDA | BPDA | 10-50% | 20-40% | 20-30% |
| | | | | 25-75% | 35-65% | 45-55% | p-PDA | p-PDA | p-PDA |
| | | | | S- | S- | S- | | | |
| | | | | BPDA | BPDA | BPDA | | | |
| A-BPDA | S-BPDA | TFDB | m-PDA | 25-75% | 35-65% | 45-55% | 50-90% | 60-80% | 70-80% |
| | | | | A- | A- | A- | TFDB | TFDB | TFDB |
| | | | | BPDA | BPDA | BPDA | 10-50% | 20-40% | 20-30% |
| | | | | 25-75% | 35-65% | 45-55% | m-PDA | m-PDA | m-PDA |
| | | | | S- | S- | S- | | | |
| | | | | BPDA | BPDA | BPDA | | | |
| A-BPDA | S-BPDA | TFDB | 4,4′-ODA | 25-75% | 35-65% | 45-55% | 50-90% | 60-80% | 70-80% |
| | | | | A- | A- | A- | TFDB | TFDB | TFDB |
| | | | | BPDA | BPDA | BPDA | 10-50% | 20-40% | 20-30% |
| | | | | 25-75% | 35-65% | 45-55% | 4,4′-ODA | 4,4′-ODA | 4,4′-ODA |
| | | | | S- | S- | S- | | | |
| | | | | BPDA | BPDA | BPDA | | | |
| A-BPDA | S-BPDA | TFDB | HFPDA | 25-75% | 35-65% | 45-55% | 50-90% | 60-80% | 70-80% |
| | | | | A- | A- | A- | TFDB | TFDB | TFDB |
| | | | | BPDA | BPDA | BPDA | 10-50% | 20-40% | 20-30% |
| | | | | 25-75% | 35-65% | 45-55% | HFPDA | HFPDA | HFPDA |
| | | | | S- | S- | S- | | | |
| | | | | BPDA | BPDA | BPDA | | | |
| A-BPDA | S-BPDA | FDA | BZDA | 25-75% | 35-65% | 45-55% | 25-75% | 35-65% | 45-55% |
| | | | | A- | A- | A- | FDA | FDA | FDA |
| | | | | BPDA | BPDA | BPDA | 25-75% | 35-65% | 45-55% |
| | | | | 25-75% | 35-65% | 45-55% | BZDA | BZDA | BZDA |
| | | | | S- | S- | S- | | | |
| | | | | BPDA | BPDA | BPDA | | | |
| A-BPDA | S-BPDA | FDA | DHBZ | 25-75% | 35-65% | 45-55% | 25-75% | 35-65% | 45-55% |
| | | | | A- | A- | A- | FDA | FDA | FDA |
| | | | | BPDA | BPDA | BPDA | 25-75% | 35-65% | 45-55% |
| | | | | 25-75% | 35-65% | 45-55% | DHBZ | DHBZ | DHBZ |
| | | | | S- | S- | S- | | | |
| | | | | BPDA | BPDA | BPDA | | | |
| A-BPDA | S-BPDA | FDA | p-PDA | 25-75% | 35-65% | 45-55% | 25-75% | 35-65% | 45-55% |
| | | | | A- | A- | A- | FDA | FDA | FDA |
| | | | | BPDA | BPDA | BPDA | 25-75% | 35-65% | 45-55% |
| | | | | 25-75% | 35-65% | 45-55% | p-PDA | p-PDA | p-PDA |
| | | | | S- | S- | S- | | | |
| | | | | BPDA | BPDA | BPDA | | | |
| A-BPDA | S-BPDA | FDA | m-PDA | 25-75% | 35-65% | 45-55% | 25-75% | 35-65% | 45-55% |
| | | | | A- | A- | A- | FDA | FDA | FDA |
| | | | | BPDA | BPDA | BPDA | 25-75% | 35-65% | 45-55% |
| | | | | 25-75% | 35-65% | 45-55% | m-PDA | m-PDA | m-PDA |
| | | | | S- | S- | S- | | | |
| | | | | BPDA | BPDA | BPDA | | | |
| A-BPDA | S-BPDA | FDA | 4,4′-ODA | 25-75% | 35-65% | 45-55% | 25-75% | 35-65% | 45-55% |
| | | | | A- | A- | A- | FDA | FDA | FDA |
| | | | | BPDA | BPDA | BPDA | 25-75% | 35-65% | 45-55% |
| | | | | 25-75% | 35-65% | 45-55% | 4,4′-ODA | 4,4′-ODA | 4,4′-ODA |
| | | | | S- | S- | S- | | | |
| | | | | BPDA | BPDA | BPDA | | | |
| A-BPDA | S-BPDA | FDA | HFPDA | 25-75% | 35-65% | 45-55% | 25-75% | 35-65% | 45-55% |
| | | | | A- | A- | A- | FDA | FDA | FDA |
| | | | | BPDA | BPDA | BPDA | 25-75% | 35-65% | 45-55% |
| | | | | 25-75% | 35-65% | 45-55% | HFPDA | HFPDA | HFPDA |
| | | | | S- | S- | S- | | | |
| | | | | BPDA | BPDA | BPDA | | | |
| A-BPDA | ODPA | Form. VI | Form. V | 25-75% | 35-65% | 45-55% | 25-75% | 35-65% | 45-55% |
| | | | | A- | A- | A- | Form V | Form V | Form V |
| | | | | BPDA | BPDA | BPDA | 25-75% | 35-65% | 45-55% |
| | | | | 25-75% | 35-65% | 45-55% | Form V | Form V | Form V |
| | | | | ODPA | ODPA | ODPA | | | |
| A-BPDA | ODPA | Form. VI | Form. V | 25-75% | 35-65% | 45-55% | 50-90% | 60-80% | 70-80% |
| | | | | A- | A- | A- | Form VI | Form VI | Form VI |
| | | | | BPDA | BPDA | BPDA | 10-50% | 20-40% | 20-30% |
| | | | | 25-75% | 35-65% | 45-55% | Form V | Form V | Form V |
| | | | | ODPA | ODPA | ODPA | | | |
| A-BPDA | ODPA | Form. VI | Form. VII | 25-75% | 35-65% | 45-55% | 25-75% | 35-65% | 45-55% |
| | | | | A- | A- | A- | Form VI | Form VI | Form VI |
| | | | | BPDA | BPDA | BPDA | 25-75% | 35-65% | 45-55% |
| | | | | 25-75% | 35-65% | 45-55% | Form VII | Form VII | Form VII |
| | | | | ODPA | ODPA | ODPA | | | |
| A-BPDA | ODPA | Form. VI | Form. VII | 25-75% | 35-65% | 45-55% | 50-90% | 60-80% | 70-80% |
| | | | | A- | A- | A- | Form VI | Form VI | Form VI |
| | | | | BPDA | BPDA | BPDA | 10-50% | 20-40% | 20-30% |
| | | | | 25-75% | 35-65% | 45-55% | Form VII | Form VII | Form VII |
| | | | | ODPA | ODPA | ODPA | | | |
| A-BPDA | ODPA | TFDB | FDA | 25-75% | 35-65% | 45-55% | 25-75% | 35-65% | 45-55% |
| | | | | A- | A- | A- | TFDB | TFDB | TFDB |
| | | | | BPDA | BPDA | BPDA | 25-75% | 35-65% | 45-55% |
| | | | | 25-75% | 35-65% | 45-55% | FDA | FDA | FDA |
| | | | | ODPA | ODPA | ODPA | | | |
| A-BPDA | ODPA | TFDB | BZDA | 25-75% | 35-65% | 45-55% | 25-75% | 35-65% | 45-55% |
| | | | | A- | A- | A- | TFDB | TFDB | TFDB |
| | | | | BPDA | BPDA | BPDA | 25-75% | 35-65% | 45-55% |
| | | | | 25-75% | 35-65% | 45-55% | BZDA | BZDA | BZDA |
| | | | | ODPA | ODPA | ODPA | | | |
| A-BPDA | ODPA | TFDB | DHBZ | 25-75% | 35-65% | 45-55% | 25-75% | 35-65% | 45-55% |
| | | | | A- | A- | A- | TFDB | TFDB | TFDB |
| | | | | BPDA | BPDA | BPDA | 25-75% | 35-65% | 45-55% |
| | | | | 25-75% | 35-65% | 45-55% | DHBZ | DHBZ | DHBZ |
| | | | | ODPA | ODPA | ODPA | | | |
| A-BPDA | ODPA | TFDB | p-PDA | 25-75% | 35-65% | 45-55% | 25-75% | 35-65% | 45-55% |
| | | | | A- | A- | A- | TFDB | TFDB | TFDB |
| | | | | BPDA | BPDA | BPDA | 25-75% | 35-65% | 45-55% |
| | | | | 25-75% | 35-65% | 45-55% | p-PDA | p-PDA | p-PDA |
| | | | | ODPA | ODPA | ODPA | | | |
| A-BPDA | ODPA | TFDB | m-PDA | 25-75% | 35-65% | 45-55% | 25-75% | 35-65% | 45-55% |
| | | | | A- | A- | A- | TFDB | TFDB | TFDB |
| | | | | BPDA | BPDA | BPDA | 25-75% | 35-65% | 45-55% |
| | | | | 25-75% | 35-65% | 45-55% | m-PDA | m-PDA | m-PDA |
| | | | | ODPA | ODPA | ODPA | | | |
| A-BPDA | ODPA | TFDB | 4,4′-ODA | 25-75% | 35-65% | 45-55% | 25-75% | 35-65% | 45-55% |
| | | | | A- | A- | A- | TFDB | TFDB | TFDB |
| | | | | BPDA | BPDA | BPDA | 25-75% | 35-65% | 45-55% |
| | | | | 25-75% | 35-65% | 45-55% | 4,4′-ODA | 4,4′-ODA | 4,4′-ODA |
| | | | | ODPA | ODPA | ODPA | | | |
| A-BPDA | ODPA | TFDB | HFPDA | 25-75% | 35-65% | 45-55% | 25-75% | 35-65% | 45-55% |
| | | | | A- | A- | A- | TFDB | TFDB | TFDB |
| | | | | BPDA | BPDA | BPDA | 25-75% | 35-65% | 45-55% |
| | | | | 25-75% | 35-65% | 45-55% | HFPDA | HFPDA | HFPDA |
| | | | | ODPA | ODPA | ODPA | | | |
| A-BPDA | ODPA | TFDB | FDA | 25-75% | 35-65% | 45-55% | 50-90% | 60-80% | 70-80% |
| | | | | A- | A- | A- | TFDB | TFDB | TFDB |
| | | | | BPDA | BPDA | BPDA | 10-50% | 20-40% | 20-30% |
| | | | | 25-75% | 35-65% | 45-55% | FDA | FDA | FDA |
| | | | | ODPA | ODPA | ODPA | | | |
| A-BPDA | ODPA | TFDB | BZDA | 25-75% | 35-65% | 45-55% | 50-90% | 60-80% | 70-80% |
| | | | | A- | A- | A- | TFDB | TFDB | TFDB |
| | | | | BPDA | BPDA | BPDA | 10-50% | 20-40% | 20-30% |
| | | | | 25-75% | 35-65% | 45-55% | BZDA | BZDA | BZDA |
| | | | | ODPA | ODPA | ODPA | | | |
| A-BPDA | ODPA | TFDB | DHBZ | 25-75% | 35-65% | 45-55% | 50-90% | 60-80% | 70-80% |
| | | | | A- | A- | A- | TFDB | TFDB | TFDB |
| | | | | BPDA | BPDA | BPDA | 10-50% | 20-40% | 20-30% |
| | | | | 25-75% | 35-65% | 45-55% | DHBZ | DHBZ | DHBZ |
| | | | | ODPA | ODPA | ODPA | | | |
| A-BPDA | ODPA | TFDB | p-PDA | 25-75% | 35-65% | 45-55% | 50-90% | 60-80% | 70-80% |
| | | | | A- | A- | A- | TFDB | TFDB | TFDB |
| | | | | BPDA | BPDA | BPDA | 10-50% | 20-40% | 20-30% |
| | | | | 25-75% | 35-65% | 45-55% | p-PDA | p-PDA | p-PDA |
| | | | | ODPA | ODPA | ODPA | | | |
| A-BPDA | ODPA | TFDB | m-PDA | 25-75% | 35-65% | 45-55% | 50-90% | 60-80% | 70-80% |
| | | | | A- | A- | A- | TFDB | TFDB | TFDB |
| | | | | BPDA | BPDA | BPDA | 10-50% | 20-40% | 20-30% |
| | | | | 25-75% | 35-65% | 45-55% | m-PDA | m-PDA | m-PDA |
| | | | | ODPA | ODPA | ODPA | | | |
| A-BPDA | ODPA | TFDB | 4,4′-ODA | 25-75% | 35-65% | 45-55% | 50-90% | 60-80% | 70-80% |
| | | | | A- | A- | A- | TFDB | TFDB | TFDB |
| | | | | BPDA | BPDA | BPDA | 10-50% | 20-40% | 20-30% |
| | | | | 25-75% | 35-65% | 45-55% | 4,4′-ODA | 4,4′-ODA | 4,4′-ODA |
| | | | | ODPA | ODPA | ODPA | | | |
| A-BPDA | ODPA | TFDB | HFPDA | 25-75% | 35-65% | 45-55% | 50-90% | 60-80% | 70-80% |
| | | | | A- | A- | A- | TFDB | TFDB | TFDB |
| | | | | BPDA | BPDA | BPDA | 10-50% | 20-40% | 20-30% |
| | | | | 25-75% | 35-65% | 45-55% | HFPDA | HFPDA | HFPDA |
| | | | | ODPA | ODPA | ODPA | | | |
| A-BPDA | ODPA | FDA | BZDA | 25-75% | 35-65% | 45-55% | 25-75% | 35-65% | 45-55% |
| | | | | A- | A- | A- | FDA | FDA | FDA |
| | | | | BPDA | BPDA | BPDA | 25-75% | 35-65% | 45-55% |
| | | | | 25-75% | 35-65% | 45-55% | BZDA | BZDA | BZDA |
| | | | | ODPA | ODPA | ODPA | | | |
| A-BPDA | ODPA | FDA | DHBZ | 25-75% | 35-65% | 45-55% | 25-75% | 35-65% | 45-55% |
| | | | | A- | A- | A- | FDA | FDA | FDA |
| | | | | BPDA | BPDA | BPDA | 25-75% | 35-65% | 45-55% |
| | | | | 25-75% | 35-65% | 45-55% | DHBZ | DHBZ | DHBZ |
| | | | | ODPA | ODPA | ODPA | | | |
| A-BPDA | ODPA | FDA | p-PDA | 25-75% | 35-65% | 45-55% | 25-75% | 35-65% | 45-55% |
| | | | | A- | A- | A- | FDA | FDA | FDA |
| | | | | BPDA | BPDA | BPDA | 25-75% | 35-65% | 45-55% |
| | | | | 25-75% | 35-65% | 45-55% | p-PDA | p-PDA | p-PDA |
| | | | | ODPA | ODPA | ODPA | | | |
| A-BPDA | ODPA | FDA | m-PDA | 25-75% | 35-65% | 45-55% | 25-75% | 35-65% | 45-55% |
| | | | | A- | A- | A- | FDA | FDA | FDA |
| | | | | BPDA | BPDA | BPDA | 25-75% | 35-65% | 45-55% |
| | | | | 25-75% | 35-65% | 45-55% | m-PDA | m-PDA | m-PDA |
| | | | | ODPA | ODPA | ODPA | | | |
| A-BPDA | ODPA | FDA | 4,4′-ODA | 25-75% | 35-65% | 45-55% | 25-75% | 35-65% | 45-55% |
| | | | | A- | A- | A- | FDA | FDA | FDA |
| | | | | BPDA | BPDA | BPDA | 25-75% | 35-65% | 45-55% |
| | | | | 25-75% | 35-65% | 45-55% | 4,4′-ODA | 4,4′-ODA | 4,4′-ODA |
| | | | | ODPA | ODPA | ODPA | | | |
| A-BPDA | ODPA | FDA | HFPDA | 25-75% | 35-65% | 45-55% | 25-75% | 35-65% | 45-55% |
| | | | | A- | A- | A- | FDA | FDA | FDA |
| | | | | BPDA | BPDA | BPDA | 25-75% | 35-65% | 45-55% |
| | | | | 25-75% | 35-65% | 45-55% | HFPDA | HFPDA | HFPDA |
| | | | | ODPA | ODPA | ODPA | | | |
| A-BPDA | HQDA | Form. VI | Form. V | 25-75% | 35-65% | 45-55% | 25-75% | 35-65% | 45-55% |
| | | | | A- | A- | A- | Form VI | Form VI | Form VI |
| | | | | BPDA | BPDA | BPDA | 25-75% | 35-65% | 45-55% |
| | | | | 25-75% | 35-65% | 45-55% | Form V | Form V | Form V |
| | | | | HQDA | HQDA | HQDA | | | |
| A-BPDA | HQDA | Form. VI | Form. V | 25-75% | 35-65% | 45-55% | 50-90% | 60-80% | 70-80% |
| | | | | A- | A- | A- | Form VI | Form VI | Form VI |
| | | | | BPDA | BPDA | BPDA | 10-50% | 20-40% | 20-30% |
| | | | | 25-75% | 35-65% | 45-55% | Form V | Form V | Form V |
| | | | | HQDA | HQDA | HQDA | | | |
| A-BPDA | HQDA | Form. VI | Form. VII | 25-75% | 35-65% | 45-55% | 25-75% | 35-65% | 45-55% |
| | | | | A- | A- | A- | Form VI | Form VI | Form VI |
| | | | | BPDA | BPDA | BPDA | 25-75% | 35-65% | 45-55% |
| | | | | 25-75% | 35-65% | 45-55% | Form VII | Form VII | Form VII |
| | | | | HQDA | HQDA | HQDA | | | |
| A-BPDA | HQDA | Form. VI | Form. VII | 25-75% | 35-65% | 45-55% | 50-90% | 60-80% | 70-80% |
| | | | | A- | A- | A- | Form VI | Form VI | Form VI |
| | | | | BPDA | BPDA | BPDA | 10-50% | 20-40% | 20-30% |
| | | | | 25-75% | 35-65% | 45-55% | Form VII | Form VII | Form VII |
| | | | | HQDA | HQDA | HQDA | | | |
| A-BPDA | HQDA | TFDB | FDA | 25-75% | 35-65% | 45-55% | 25-75% | 35-65% | 45-55% |
| | | | | A- | A- | A- | TFDB | TFDB | TFDB |
| | | | | BPDA | BPDA | BPDA | 25-75% | 35-65% | 45-55% |
| | | | | 25-75% | 35-65% | 45-55% | FDA | FDA | FDA |
| | | | | HQDA | HQDA | HQDA | | | |
| A-BPDA | HQDA | TFDB | BZDA | 25-75% | 35-65% | 45-55% | 25-75% | 35-65% | 45-55% |
| | | | | A- | A- | A- | TFDB | TFDB | TFDB |
| | | | | BPDA | BPDA | BPDA | 25-75% | 35-65% | 45-55% |
| | | | | 25-75% | 35-65% | 45-55% | BZDA | BZDA | BZDA |
| | | | | HQDA | HQDA | HQDA | | | |
| A-BPDA | HQDA | TFDB | DHBZ | 25-75% | 35-65% | 45-55% | 25-75% | 35-65% | 45-55% |
| | | | | A- | A- | A- | TFDB | TFDB | TFDB |
| | | | | BPDA | BPDA | BPDA | 25-75% | 35-65% | 45-55% |
| | | | | 25-75% | 35-65% | 45-55% | DHBZ | DHBZ | DHBZ |
| | | | | HQDA | HQDA | HQDA | | | |
| A-BPDA | HQDA | TFDB | p-PDA | 25-75% | 35-65% | 45-55% | 25-75% | 35-65% | 45-55% |
| | | | | A- | A- | A- | TFDB | TFDB | TFDB |
| | | | | BPDA | BPDA | BPDA | 25-75% | 35-65% | 45-55% |
| | | | | 25-75% | 35-65% | 45-55% | p-PDA | p-PDA | p-PDA |
| | | | | HQDA | HQDA | HQDA | | | |
| A-BPDA | HQDA | TFDB | m-PDA | 25-75% | 35-65% | 45-55% | 25-75% | 35-65% | 45-55% |
| | | | | A- | A- | A- | TFDB | TFDB | TFDB |
| | | | | BPDA | BPDA | BPDA | 25-75% | 35-65% | 45-55% |
| | | | | 25-75% | 35-65% | 45-55% | m-PDA | m-PDA | m-PDA |
| | | | | HQDA | HQDA | HQDA | | | |
| A-BPDA | HQDA | TFDB | 4,4′-ODA | 25-75% | 35-65% | 45-55% | 25-75% | 35-65% | 45-55% |
| | | | | A- | A- | A- | TFDB | TFDB | TFDB |
| | | | | BPDA | BPDA | BPDA | 25-75% | 35-65% | 45-55% |
| | | | | 25-75% | 35-65% | 45-55% | 4,4′-ODA | 4,4′-ODA | 4,4′-ODA |
| | | | | HQDA | HQDA | HQDA | | | |
| A-BPDA | HQDA | TFDB | HFPDA | 25-75% | 35-65% | 45-55% | 25-75% | 35-65% | 45-55% |
| | | | | A- | A- | A- | TFDB | TFDB | TFDB |
| | | | | BPDA | BPDA | BPDA | 25-75% | 35-65% | 45-55% |
| | | | | 25-75% | 35-65% | 45-55% | HFPDA | HFPDA | HFPDA |
| | | | | HQDA | HQDA | HQDA | | | |
| A-BPDA | HQDA | TFDB | FDA | 25-75% | 35-65% | 45-55% | 50-90% | 60-80% | 70-80% |
| | | | | A- | A- | A- | TFDB | TFDB | TFDB |
| | | | | BPDA | BPDA | BPDA | 10-50% | 20-40% | 20-30% |
| | | | | 25-75% | 35-65% | 45-55% | FDA | FDA | FDA |
| | | | | HQDA | HQDA | HQDA | | | |
| A-BPDA | HQDA | TFDB | BZDA | 25-75% | 35-65% | 45-55% | 50-90% | 60-80% | 70-80% |
| | | | | A- | A- | A- | TFDB | TFDB | TFDB |
| | | | | BPDA | BPDA | BPDA | 10-50% | 20-40% | 20-30% |
| | | | | 25-75% | 35-65% | 45-55% | BZDA | BZDA | BZDA |
| | | | | HQDA | HQDA | HQDA | | | |
| A-BPDA | HQDA | TFDB | DHBZ | 25-75% | 35-65% | 45-55% | 50-90% | 60-80% | 70-80% |
| | | | | A- | A- | A- | TFDB | TFDB | TFDB |
| | | | | BPDA | BPDA | BPDA | 10-50% | 20-40% | 20-30% |
| | | | | 25-75% | 35-65% | 45-55% | DHBZ | DHBZ | DHBZ |
| | | | | HQDA | HQDA | HQDA | | | |
| A-BPDA | HQDA | TFDB | p-PDA | 25-75% | 35-65% | 45-55% | 50-90% | 60-80% | 70-80% |
| | | | | A- | A- | A- | TFDB | TFDB | TFDB |
| | | | | BPDA | BPDA | BPDA | 10-50% | 20-40% | 20-30% |
| | | | | 25-75% | 35-65% | 45-55% | p-PDA | p-PDA | p-PDA |
| | | | | HQDA | HQDA | HQDA | | | |
| A-BPDA | HQDA | TFDB | m-PDA | 25-75% | 35-65% | 45-55% | 50-90% | 60-80% | 70-80% |
| | | | | A- | A- | A- | TFDB | TFDB | TFDB |
| | | | | BPDA | BPDA | BPDA | 10-50% | 20-40% | 20-30% |
| | | | | 25-75% | 35-65% | 45-55% | m-PDA | m-PDA | m-PDA |
| | | | | HQDA | HQDA | HQDA | | | |
| A-BPDA | HQDA | TFDB | 4,4′-ODA | 25-75% | 35-65% | 45-55% | 50-90% | 60-80% | 70-80% |
| | | | | A- | A- | A- | TFDB | TFDB | TFDB |
| | | | | BPDA | BPDA | BPDA | 10-50% | 20-40% | 20-30% |
| | | | | 25-75% | 35-65% | 45-55% | 4,4′-ODA | 4,4′-ODA | 4,4′-ODA |
| | | | | HQDA | HQDA | HQDA | | | |
| A-BPDA | HQDA | TFDB | HFPDA | 25-75% | 35-65% | 45-55% | 50-90% | 60-80% | 70-80% |
| | | | | A- | A- | A- | TFDB | TFDB | TFDB |
| | | | | BPDA | BPDA | BPDA | 10-50% | 20-40% | 20-30% |
| | | | | 25-75% | 35-65% | 45-55% | HFPDA | HFPDA | HFPDA |
| | | | | HQDA | HQDA | HQDA | | | |
| A-BPDA | HQDA | FDA | BZDA | 25-75% | 35-65% | 45-55% | 25-75% | 35-65% | 45-55% |
| | | | | A- | A- | A- | FDA | FDA | FDA |
| | | | | BPDA | BPDA | BPDA | 25-75% | 35-65% | 45-55% |
| | | | | 25-75% | 35-65% | 45-55% | BZDA | BZDA | BZDA |
| | | | | HQDA | HQDA | HQDA | | | |
| A-BPDA | HQDA | FDA | DHBZ | 25-75% | 35-65% | 45-55% | 25-75% | 35-65% | 45-55% |
| | | | | A- | A- | A- | FDA | FDA | FDA |
| | | | | BPDA | BPDA | BPDA | 25-75% | 35-65% | 45-55% |
| | | | | 25-75% | 35-65% | 45-55% | DHBZ | DHBZ | DHBZ |
| | | | | HQDA | HQDA | HQDA | | | |
| A-BPDA | HQDA | FDA | p-PDA | 25-75% | 35-65% | 45-55% | 25-75% | 35-65% | 45-55% |
| | | | | A- | A- | A- | FDA | FDA | FDA |
| | | | | BPDA | BPDA | BPDA | 25-75% | 35-65% | 45-55% |
| | | | | 25-75% | 35-65% | 45-55% | p-PDA | p-PDA | p-PDA |
| | | | | HQDA | HQDA | HQDA | | | |
| A-BPDA | HQDA | FDA | m-PDA | 25-75% | 35-65% | 45-55% | 25-75% | 35-65% | 45-55% |
| | | | | A- | A- | A- | FDA | FDA | FDA |
| | | | | BPDA | BPDA | BPDA | 25-75% | 35-65% | 45-55% |
| | | | | 25-75% | 35-65% | 45-55% | m-PDA | m-PDA | m-PDA |
| | | | | HQDA | HQDA | HQDA | | | |
| A-BPDA | HQDA | FDA | 4,4′-ODA | 25-75% | 35-65% | 45-55% | 25-75% | 35-65% | 45-55% |
| | | | | A- | A- | A- | FDA | FDA | FDA |
| | | | | BPDA | BPDA | BPDA | 25-75% | 35-65% | 45-55% |
| | | | | 25-75% | 35-65% | 45-55% | 4,4′-ODA | 4,4′-ODA | 4,4′-ODA |
| | | | | HQDA | HQDA | HQDA | | | |
| A-BPDA | HQDA | FDA | HFPDA | 25-75% | 35-65% | 45-55% | 25-75% | 35-65% | 45-55% |
| | | | | A- | A- | A- | FDA | FDA | FDA |
| | | | | BPDA | BPDA | BPDA | 25-75% | 35-65% | 45-55% |
| | | | | 25-75% | 35-65% | 45-55% | HFPDA | HFPDA | HFPDA |
| | | | | HQDA | HQDA | HQDA | | | |
| A-BPDA | BPADA | Form. VI | Form. V | 25-75% | 35-65% | 45-55% | 25-75% | 35-65% | 45-55% |
| | | | | A- | A- | A- | Form VI | Form VI | Form VI |
| | | | | BPDA | BPDA | BPDA | 25-75% | 35-65% | 45-55% |
| | | | | 25-75% | 35-65% | 45-55% | Form V | Form V | Form V |
| | | | | BPADA | BPADA | BPADA | | | |
| A-BPDA | BPADA | Form. VI | Form. V | 25-75% | 35-65% | 45-55% | 50-90% | 60-80% | 70-80% |
| | | | | A- | A- | A- | Form VI | Form VI | Form VI |
| | | | | BPDA | BPDA | BPDA | 10-50% | 20-40% | 20-30% |
| | | | | 25-75% | 35-65% | 45-55% | Form V | Form V | Form V |
| | | | | BPADA | BPADA | BPADA | | | |
| A-BPDA | BPADA | Form. VI | Form. VII | 25-75% | 35-65% | 45-55% | 25-75% | 35-65% | 45-55% |
| | | | | A- | A- | A- | Form VI | Form VI | Form VI |
| | | | | BPDA | BPDA | BPDA | 25-75% | 35-65% | 45-55% |
| | | | | 25-75% | 35-65% | 45-55% | Form VII | Form VII | Form VII |
| | | | | BPADA | BPADA | BPADA | | | |
| A-BPDA | BPADA | Form. VI | Form. VII | 25-75% | 35-65% | 45-55% | 50-90% | 60-80% | 70-80% |
| | | | | A- | A- | A- | Form VI | Form VI | Form VI |
| | | | | BPDA | BPDA | BPDA | 10-50% | 20-40% | 20-30% |
| | | | | 25-75% | 35-65% | 45-55% | Form VII | Form VII | Form VII |
| | | | | BPADA | BPADA | BPADA | | | |
| A-BPDA | BPADA | TFDB | FDA | 25-75% | 35-65% | 45-55% | 25-75% | 35-65% | 45-55% |
| | | | | A- | A- | A- | TFDB | TFDB | TFDB |
| | | | | BPDA | BPDA | BPDA | 25-75% | 35-65% | 45-55% |
| | | | | 25-75% | 35-65% | 45-55% | FDA | FDA | FDA |
| | | | | BPADA | BPADA | BPADA | | | |
| A-BPDA | BPADA | TFDB | BZDA | 25-75% | 35-65% | 45-55% | 25-75% | 35-65% | 45-55% |
| | | | | A- | A- | A- | TFDB | TFDB | TFDB |
| | | | | BPDA | BPDA | BPDA | 25-75% | 35-65% | 45-55% |
| | | | | 25-75% | 35-65% | 45-55% | BZDA | BZDA | BZDA |
| | | | | BPADA | BPADA | BPADA | | | |
| A-BPDA | BPADA | TFDB | DHBZ | 25-75% | 35-65% | 45-55% | 25-75% | 35-65% | 45-55% |
| | | | | A- | A- | A- | TFDB | TFDB | TFDB |
| | | | | BPDA | BPDA | BPDA | 25-75% | 35-65% | 45-55% |
| | | | | 25-75% | 35-65% | 45-55% | DHBZ | DHBZ | DHBZ |
| | | | | BPADA | BPADA | BPADA | | | |
| A-BPDA | BPADA | TFDB | p-PDA | 25-75% | 35-65% | 45-55% | 25-75% | 35-65% | 45-55% |
| | | | | A- | A- | A- | TFDB | TFDB | TFDB |
| | | | | BPDA | BPDA | BPDA | 25-75% | 35-65% | 45-55% |
| | | | | 25-75% | 35-65% | 45-55% | p-PDA | p-PDA | p-PDA |
| | | | | BPADA | BPADA | BPADA | | | |
| A-BPDA | BPADA | TFDB | m-PDA | 25-75% | 35-65% | 45-55% | 25-75% | 35-65% | 45-55% |
| | | | | A- | A- | A- | TFDB | TFDB | TFDB |
| | | | | BPDA | BPDA | BPDA | 25-75% | 35-65% | 45-55% |
| | | | | 25-75% | 35-65% | 45-55% | m-PDA | m-PDA | m-PDA |
| | | | | BPADA | BPADA | BPADA | | | |
| A-BPDA | BPADA | TFDB | 4,4′-ODA | 25-75% | 35-65% | 45-55% | 25-75% | 35-65% | 45-55% |
| | | | | A- | A- | A- | TFDB | TFDB | TFDB |
| | | | | BPDA | BPDA | BPDA | 25-75% | 35-65% | 45-55% |
| | | | | 25-75% | 35-65% | 45-55% | 4,4′-ODA | 4,4′-ODA | 4,4′-ODA |
| | | | | BPADA | BPADA | BPADA | | | |
| A-BPDA | BPADA | TFDB | HFPDA | 25-75% | 35-65% | 45-55% | 25-75% | 35-65% | 45-55% |
| | | | | A- | A- | A- | TFDB | TFDB | TFDB |
| | | | | BPDA | BPDA | BPDA | 25-75% | 35-65% | 45-55% |
| | | | | 25-75% | 35-65% | 45-55% | HFPDA | HFPDA | HFPDA |
| | | | | BPADA | BPADA | BPADA | | | |
| A-BPDA | BPADA | TFDB | FDA | 25-75% | 35-65% | 45-55% | 50-90% | 60-80% | 70-80% |
| | | | | A- | A- | A- | TFDB | TFDB | TFDB |
| | | | | BPDA | BPDA | BPDA | 10-50% | 20-40% | 20-30% |
| | | | | 25-75% | 35-65% | 45-55% | FDA | FDA | FDA |
| | | | | BPADA | BPADA | BPADA | | | |
| A-BPDA | BPADA | TFDB | BZDA | 25-75% | 35-65% | 45-55% | 50-90% | 60-80% | 70-80% |
| | | | | A- | A- | A- | TFDB | TFDB | TFDB |
| | | | | BPDA | BPDA | BPDA | 10-50% | 20-40% | 20-30% |
| | | | | 25-75% | 35-65% | 45-55% | BZDA | BZDA | BZDA |
| | | | | BPADA | BPADA | BPADA | | | |
| A-BPDA | BPADA | TFDB | DHBZ | 25-75% | 35-65% | 45-55% | 50-90% | 60-80% | 70-80% |
| | | | | A- | A- | A- | TFDB | TFDB | TFDB |
| | | | | BPDA | BPDA | BPDA | 10-50% | 20-40% | 20-30% |
| | | | | 25-75% | 35-65% | 45-55% | DHBZ | DHBZ | DHBZ |
| | | | | BPADA | BPADA | BPADA | | | |
| A-BPDA | BPADA | TFDB | p-PDA | 25-75% | 35-65% | 45-55% | 50-90% | 60-80% | 70-80% |
| | | | | A- | A- | A- | TFDB | TFDB | TFDB |
| | | | | BPDA | BPDA | BPDA | 10-50% | 20-40% | 20-30% |
| | | | | 25-75% | 35-65% | 45-55% | p-PDA | p-PDA | p-PDA |
| | | | | BPADA | BPADA | BPADA | | | |
| A-BPDA | BPADA | TFDB | m-PDA | 25-75% | 35-65% | 45-55% | 50-90% | 60-80% | 70-80% |
| | | | | A- | A- | A- | TFDB | TFDB | TFDB |
| | | | | BPDA | BPDA | BPDA | 10-50% | 20-40% | 20-30% |
| | | | | 25-75% | 35-65% | 45-55% | m-PDA | m-PDA | m-PDA |
| | | | | BPADA | BPADA | BPADA | | | |
| A-BPDA | BPADA | TFDB | 4,4′-ODA | 25-75% | 35-65% | 45-55% | 50-90% | 60-80% | 70-80% |
| | | | | A- | A- | A- | TFDB | TFDB | TFDB |
| | | | | BPDA | BPDA | BPDA | 10-50% | 20-40% | 20-30% |
| | | | | 25-75% | 35-65% | 45-55% | 4,4′-ODA | 4,4′-ODA | 4,4′-ODA |
| | | | | BPADA | BPADA | BPADA | | | |
| A-BPDA | BPADA | TFDB | HFPDA | 25-75% | 35-65% | 45-55% | 50-90% | 60-80% | 70-80% |
| | | | | A- | A- | A- | TFDB | TFDB | TFDB |
| | | | | BPDA | BPDA | BPDA | 10-50% | 20-40% | 20-30% |
| | | | | 25-75% | 35-65% | 45-55% | HFPDA | HFPDA | HFPDA |
| | | | | BPADA | BPADA | BPADA | | | |
| A-BPDA | BPADA | FDA | BZDA | 25-75% | 35-65% | 45-55% | 25-75% | 35-65% | 45-55% |
| | | | | A- | A- | A- | FDA | FDA | FDA |
| | | | | BPDA | BPDA | BPDA | 25-75% | 35-65% | 45-55% |
| | | | | 25-75% | 35-65% | 45-55% | BZDA | BZDA | BZDA |
| | | | | BPADA | BPADA | BPADA | | | |
| A-BPDA | BPADA | FDA | DHBZ | 25-75% | 35-65% | 45-55% | 25-75% | 35-65% | 45-55% |
| | | | | A- | A- | A- | FDA | FDA | FDA |
| | | | | BPDA | BPDA | BPDA | 25-75% | 35-65% | 45-55% |
| | | | | 25-75% | 35-65% | 45-55% | DHBZ | DHBZ | DHBZ |
| | | | | BPADA | BPADA | BPADA | | | |
| A-BPDA | BPADA | FDA | p-PDA | 25-75% | 35-65% | 45-55% | 25-75% | 35-65% | 45-55% |
| | | | | A- | A- | A- | FDA | FDA | FDA |
| | | | | BPDA | BPDA | BPDA | 25-75% | 35-65% | 45-55% |
| | | | | 25-75% | 35-65% | 45-55% | p-PDA | p-PDA | p-PDA |
| | | | | BPADA | BPADA | BPADA | | | |
| A-BPDA | BPADA | FDA | m-PDA | 25-75% | 35-65% | 45-55% | 25-75% | 35-65% | 45-55% |
| | | | | A- | A- | A- | FDA | FDA | FDA |
| | | | | BPDA | BPDA | BPDA | 25-75% | 35-65% | 45-55% |
| | | | | 25-75% | 35-65% | 45-55% | m-PDA | m-PDA | m-PDA |
| | | | | BPADA | BPADA | BPADA | | | |
| A-BPDA | BPADA | FDA | 4,4′-ODA | 25-75% | 35-65% | 45-55% | 25-75% | 35-65% | 45-55% |
| | | | | A- | A- | A- | FDA | FDA | FDA |
| | | | | BPDA | BPDA | BPDA | 25-75% | 35-65% | 45-55% |
| | | | | 25-75% | 35-65% | 45-55% | 4,4′-ODA | 4,4′-ODA | 4,4′-ODA |
| | | | | BPADA | BPADA | BPADA | | | |
| A-BPDA | BPADA | FDA | HFPDA | 25-75% | 35-65% | 45-55% | 25-75% | 35-65% | 45-55% |
| | | | | A- | A- | A- | FDA | FDA | FDA |
| | | | | BPDA | BPDA | BPDA | 25-75% | 35-65% | 45-55% |
| | | | | 25-75% | 35-65% | 45-55% | HFPDA | HFPDA | HFPDA |
| | | | | BPADA | BPADA | BPADA | | | |
| S-BPDA | ODPA | Form. VI | Form. V | 25-75% | 35-65% | 45-55% | 25-75% | 35-65% | 45-55% |
| | | | | S- | S- | S- | Form VI | Form VI | Form VI |
| | | | | BPDA | BPDA | BPDA | 25-75% | 35-65% | 45-55% |
| | | | | 25-75% | 35-65% | 45-55% | Form V | Form V | Form V |
| | | | | ODPA | ODPA | ODPA | | | |
| S-BPDA | ODPA | Form. VI | Form. V | 25-75% | 35-65% | 45-55% | 50-90% | 60-80% | 70-80% |
| | | | | S- | S- | S- | Form VI | Form VI | Form VI |
| | | | | BPDA | BPDA | BPDA | 10-50% | 20-40% | 20-30% |
| | | | | 25-75% | 35-65% | 45-55% | Form V | Form V | Form V |
| | | | | ODPA | ODPA | ODPA | | | |
| S-BPDA | ODPA | Form. VI | Form. VII | 25-75% | 35-65% | 45-55% | 25-75% | 35-65% | 45-55% |
| | | | | S- | S- | S- | Form VI | Form VI | Form VI |
| | | | | BPDA | BPDA | BPDA | 25-75% | 35-65% | 45-55% |
| | | | | 25-75% | 35-65% | 45-55% | Form VII | Form VII | Form VII |
| | | | | ODPA | ODPA | ODPA | | | |
| S-BPDA | ODPA | Form. VI | Form. VII | 25-75% | 35-65% | 45-55% | 50-90% | 60-80% | 70-80% |
| | | | | S- | S- | S- | Form VI | Form VI | Form VI |
| | | | | BPDA | BPDA | BPDA | 10-50% | 20-40% | 20-30% |
| | | | | 25-75% | 35-65% | 45-55% | Form VII | Form VII | Form VII |
| | | | | ODPA | ODPA | ODPA | | | |
| S-BPDA | ODPA | TFDB | FDA | 25-75% | 35-65% | 45-55% | 25-75% | 35-65% | 45-55% |
| | | | | S- | S- | S- | TFDB | TFDB | TFDB |
| | | | | BPDA | BPDA | BPDA | 25-75% | 35-65% | 45-55% |
| | | | | 25-75% | 35-65% | 45-55% | FDA | FDA | FDA |
| | | | | ODPA | ODPA | ODPA | | | |
| S-BPDA | ODPA | TFDB | BZDA | 25-75% | 35-65% | 45-55% | 25-75% | 35-65% | 45-55% |
| | | | | S- | S- | S- | TFDB | TFDB | TFDB |
| | | | | BPDA | BPDA | BPDA | 25-75% | 35-65% | 45-55% |
| | | | | 25-75% | 35-65% | 45-55% | BZDA | BZDA | BZDA |
| | | | | ODPA | ODPA | ODPA | | | |
| S-BPDA | ODPA | TFDB | DHBZ | 25-75% | 35-65% | 45-55% | 25-75% | 35-65% | 45-55% |
| | | | | S- | S- | S- | TFDB | TFDB | TFDB |
| | | | | BPDA | BPDA | BPDA | 25-75% | 35-65% | 45-55% |
| | | | | 25-75% | 35-65% | 45-55% | DHBZ | DHBZ | DHBZ |
| | | | | ODPA | ODPA | ODPA | | | |
| S-BPDA | ODPA | TFDB | p-PDA | 25-75% | 35-65% | 45-55% | 25-75% | 35-65% | 45-55% |
| | | | | S- | S- | S- | TFDB | TFDB | TFDB |
| | | | | BPDA | BPDA | BPDA | 25-75% | 35-65% | 45-55% |
| | | | | 25-75% | 35-65% | 45-55% | p-PDA | p-PDA | p-PDA |
| | | | | ODPA | ODPA | ODPA | | | |
| S-BPDA | ODPA | TFDB | m-PDA | 25-75% | 35-65% | 45-55% | 25-75% | 35-65% | 45-55% |
| | | | | S- | S- | S- | TFDB | TFDB | TFDB |
| | | | | BPDA | BPDA | BPDA | 25-75% | 35-65% | 45-55% |
| | | | | 25-75% | 35-65% | 45-55% | m-PDA | m-PDA | m-PDA |
| | | | | ODPA | ODPA | ODPA | | | |
| S-BPDA | ODPA | TFDB | 4,4′-ODA | 25-75% | 35-65% | 45-55% | 25-75% | 35-65% | 45-55% |
| | | | | S- | S- | S- | TFDB | TFDB | TFDB |
| | | | | BPDA | BPDA | BPDA | 25-75% | 35-65% | 45-55% |
| | | | | 25-75% | 35-65% | 45-55% | 4,4′-ODA | 4,4′-ODA | 4,4′-ODA |
| | | | | ODPA | ODPA | ODPA | | | |
| S-BPDA | ODPA | TFDB | HFPDA | 25-75% | 35-65% | 45-55% | 25-75% | 35-65% | 45-55% |
| | | | | S- | S- | S- | TFDB | TFDB | TFDB |
| | | | | BPDA | BPDA | BPDA | 25-75% | 35-65% | 45-55% |
| | | | | 25-75% | 35-65% | 45-55% | HFPDA | HFPDA | HFPDA |
| | | | | ODPA | ODPA | ODPA | | | |
| S-BPDA | ODPA | TFDB | FDA | 25-75% | 35-65% | 45-55% | 50-90% | 60-80% | 70-80% |
| | | | | S- | S- | S- | TFDB | TFDB | TFDB |
| | | | | BPDA | BPDA | BPDA | 10-50% | 20-40% | 20-30% |
| | | | | 25-75% | 35-65% | 45-55% | FDA | FDA | FDA |
| | | | | ODPA | ODPA | ODPA | | | |
| S-BPDA | ODPA | TFDB | BZDA | 25-75% | 35-65% | 45-55% | 50-90% | 60-80% | 70-80% |
| | | | | S- | S- | S- | TFDB | TFDB | TFDB |
| | | | | BPDA | BPDA | BPDA | 10-50% | 20-40% | 20-30% |
| | | | | 25-75% | 35-65% | 45-55% | BZDA | BZDA | BZDA |
| | | | | ODPA | ODPA | ODPA | | | |
| S-BPDA | ODPA | TFDB | DHBZ | 25-75% | 35-65% | 45-55% | 50-90% | 60-80% | 70-80% |
| | | | | S- | S- | S- | TFDB | TFDB | TFDB |
| | | | | BPDA | BPDA | BPDA | 10-50% | 20-40% | 20-30% |
| | | | | 25-75% | 35-65% | 45-55% | DHBZ | DHBZ | DHBZ |
| | | | | ODPA | ODPA | ODPA | | | |
| S-BPDA | ODPA | TFDB | p-PDA | 25-75% | 35-65% | 45-55% | 50-90% | 60-80% | 70-80% |
| | | | | S- | S- | S- | TFDB | TFDB | TFDB |
| | | | | BPDA | BPDA | BPDA | 10-50% | 20-40% | 20-30% |
| | | | | 25-75% | 35-65% | 45-55% | p-PDA | p-PDA | p-PDA |
| | | | | ODPA | ODPA | ODPA | | | |
| S-BPDA | ODPA | TFDB | m-PDA | 25-75% | 35-65% | 45-55% | 50-90% | 60-80% | 70-80% |
| | | | | S- | S- | S- | TFDB | TFDB | TFDB |
| | | | | BPDA | BPDA | BPDA | 10-50% | 20-40% | 20-30% |
| | | | | 25-75% | 35-65% | 45-55% | m-PDA | m-PDA | m-PDA |
| | | | | ODPA | ODPA | ODPA | | | |
| S-BPDA | ODPA | TFDB | 4,4′-ODA | 25-75% | 35-65% | 45-55% | 50-90% | 60-80% | 70-80% |
| | | | | S- | S- | S- | TFDB | TFDB | TFDB |
| | | | | BPDA | BPDA | BPDA | 10-50% | 20-40% | 20-30% |
| | | | | 25-75% | 35-65% | 45-55% | 4,4′-ODA | 4,4′-ODA | 4,4′-ODA |
| | | | | ODPA | ODPA | ODPA | | | |
| S-BPDA | ODPA | TFDB | HFPDA | 25-75% | 35-65% | 45-55% | 50-90% | 60-80% | 70-80% |
| | | | | S- | S- | S- | TFDB | TFDB | TFDB |
| | | | | BPDA | BPDA | BPDA | 10-50% | 20-40% | 20-30% |
| | | | | 25-75% | 35-65% | 45-55% | HFPDA | HFPDA | HFPDA |
| | | | | ODPA | ODPA | ODPA | | | |
| S-BPDA | ODPA | FDA | BZDA | 25-75% | 35-65% | 45-55% | 25-75% | 35-65% | 45-55% |
| | | | | S- | S- | S- | FDA | FDA | FDA |
| | | | | BPDA | BPDA | BPDA | 25-75% | 35-65% | 45-55% |
| | | | | 25-75% | 35-65% | 45-55% | BZDA | BZDA | BZDA |
| | | | | ODPA | ODPA | ODPA | | | |
| S-BPDA | ODPA | FDA | DHBZ | 25-75% | 35-65% | 45-55% | 25-75% | 35-65% | 45-55% |
| | | | | S- | S- | S- | FDA | FDA | FDA |
| | | | | BPDA | BPDA | BPDA | 25-75% | 35-65% | 45-55% |
| | | | | 25-75% | 35-65% | 45-55% | DHBZ | DHBZ | DHBZ |
| | | | | ODPA | ODPA | ODPA | | | |
| S-BPDA | ODPA | FDA | p-PDA | 25-75% | 35-65% | 45-55% | 25-75% | 35-65% | 45-55% |
| | | | | S- | S- | S- | FDA | FDA | FDA |
| | | | | BPDA | BPDA | BPDA | 25-75% | 35-65% | 45-55% |
| | | | | 25-75% | 35-65% | 45-55% | p-PDA | p-PDA | p-PDA |
| | | | | ODPA | ODPA | ODPA | | | |
| S-BPDA | ODPA | FDA | m-PDA | 25-75% | 35-65% | 45-55% | 25-75% | 35-65% | 45-55% |
| | | | | S- | S- | S- | FDA | FDA | FDA |
| | | | | BPDA | BPDA | BPDA | 25-75% | 35-65% | 45-55% |
| | | | | 25-75% | 35-65% | 45-55% | m-PDA | m-PDA | m-PDA |
| | | | | ODPA | ODPA | ODPA | | | |
| S-BPDA | ODPA | FDA | 4,4′-ODA | 25-75% | 35-65% | 45-55% | 25-75% | 35-65% | 45-55% |
| | | | | S- | S- | S- | FDA | FDA | FDA |
| | | | | BPDA | BPDA | BPDA | 25-75% | 35-65% | 45-55% |
| | | | | 25-75% | 35-65% | 45-55% | 4,4′-ODA | 4,4′-ODA | 4,4′-ODA |
| | | | | ODPA | ODPA | ODPA | | | |
| S-BPDA | ODPA | FDA | HFPDA | 25-75% | 35-65% | 45-55% | 25-75% | 35-65% | 45-55% |
| | | | | S- | S- | S- | FDA | FDA | FDA |
| | | | | BPDA | BPDA | BPDA | 25-75% | 35-65% | 45-55% |
| | | | | 25-75% | 35-65% | 45-55% | HFPDA | HFPDA | HFPDA |
| | | | | ODPA | ODPA | ODPA | | | |
| S-BPDA | HQDA | Form. VI | Form. V | 25-75% | 35-65% | 45-55% | 25-75% | 35-65% | 45-55% |
| | | | | S- | S- | S- | Form VI | Form VI | Form VI |
| | | | | BPDA | BPDA | BPDA | 25-75% | 35-65% | 45-55% |
| | | | | 25-75% | 35-65% | 45-55% | Form V | Form V | Form V |
| | | | | HQDA | HQDA | HQDA | | | |
| S-BPDA | HQDA | Form. VI | Form. V | 25-75% | 35-65% | 45-55% | 50-90% | 60-80% | 70-80% |
| | | | | S- | S- | S- | Form VI | Form VI | Form VI |
| | | | | BPDA | BPDA | BPDA | 10-50% | 20-40% | 20-30% |
| | | | | 25-75% | 35-65% | 45-55% | Form V | Form V | Form V |
| | | | | HQDA | HQDA | HQDA | | | |
| S-BPDA | HQDA | Form. VI | Form. VII | 25-75% | 35-65% | 45-55% | 25-75% | 35-65% | 45-55% |
| | | | | S- | S- | S- | Form VI | Form VI | Form VI |
| | | | | BPDA | BPDA | BPDA | 25-75% | 35-65% | 45-55% |
| | | | | 25-75% | 35-65% | 45-55% | Form VII | Form VII | Form VII |
| | | | | HQDA | HQDA | HQDA | | | |
| S-BPDA | HQDA | Form. VI | Form. VII | 25-75% | 35-65% | 45-55% | 50-90% | 60-80% | 70-80% |
| | | | | S- | S- | S- | Form VI | Form VI | Form VI |
| | | | | BPDA | BPDA | BPDA | 10-50% | 20-40% | 20-30% |
| | | | | 25-75% | 35-65% | 45-55% | Form VII | Form VII | Form VII |
| | | | | HQDA | HQDA | HQDA | | | |
| S-BPDA | HQDA | TFDB | FDA | 25-75% | 35-65% | 45-55% | 25-75% | 35-65% | 45-55% |
| | | | | S- | S- | S- | TFDB | TFDB | TFDB |
| | | | | BPDA | BPDA | BPDA | 25-75% | 35-65% | 45-55% |
| | | | | 25-75% | 35-65% | 45-55% | FDA | FDA | FDA |
| | | | | HQDA | HQDA | HQDA | | | |
| S-BPDA | HQDA | TFDB | BZDA | 25-75% | 35-65% | 45-55% | 25-75% | 35-65% | 45-55% |
| | | | | S- | S- | S- | TFDB | TFDB | TFDB |
| | | | | BPDA | BPDA | BPDA | 25-75% | 35-65% | 45-55% |
| | | | | 25-75% | 35-65% | 45-55% | BZDA | BZDA | BZDA |
| | | | | HQDA | HQDA | HQDA | | | |
| S-BPDA | HQDA | TFDB | DHBZ | 25-75% | 35-65% | 45-55% | 25-75% | 35-65% | 45-55% |
| | | | | S- | S- | S- | TFDB | TFDB | TFDB |
| | | | | BPDA | BPDA | BPDA | 25-75% | 35-65% | 45-55% |
| | | | | 25-75% | 35-65% | 45-55% | DHBZ | DHBZ | DHBZ |
| | | | | HQDA | HQDA | HQDA | | | |
| S-BPDA | HQDA | TFDB | p-PDA | 25-75% | 35-65% | 45-55% | 25-75% | 35-65% | 45-55% |
| | | | | S- | S- | S- | TFDB | TFDB | TFDB |
| | | | | BPDA | BPDA | BPDA | 25-75% | 35-65% | 45-55% |
| | | | | 25-75% | 35-65% | 45-55% | p-PDA | p-PDA | p-PDA |
| | | | | HQDA | HQDA | HQDA | | | |
| S-BPDA | HQDA | TFDB | m-PDA | 25-75% | 35-65% | 45-55% | 25-75% | 35-65% | 45-55% |
| | | | | S- | S- | S- | TFDB | TFDB | TFDB |
| | | | | BPDA | BPDA | BPDA | 25-75% | 35-65% | 45-55% |
| | | | | 25-75% | 35-65% | 45-55% | m-PDA | m-PDA | m-PDA |
| | | | | HQDA | HQDA | HQDA | | | |
| S-BPDA | HQDA | TFDB | 4,4′-ODA | 25-75% | 35-65% | 45-55% | 25-75% | 35-65% | 45-55% |
| | | | | S- | S- | S- | TFDB | TFDB | TFDB |
| | | | | BPDA | BPDA | BPDA | 25-75% | 35-65% | 45-55% |
| | | | | 25-75% | 35-65% | 45-55% | 4,4′-ODA | 4,4′-ODA | 4,4′-ODA |
| | | | | HQDA | HQDA | HQDA | | | |
| S-BPDA | HQDA | TFDB | HFPDA | 25-75% | 35-65% | 45-55% | 25-75% | 35-65% | 45-55% |
| | | | | S- | S- | S- | TFDB | TFDB | TFDB |
| | | | | BPDA | BPDA | BPDA | 25-75% | 35-65% | 45-55% |
| | | | | 25-75% | 35-65% | 45-55% | HFPDA | HFPDA | HFPDA |
| | | | | HQDA | HQDA | HQDA | | | |
| S-BPDA | HQDA | TFDB | FDA | 25-75% | 35-65% | 45-55% | 50-90% | 60-80% | 70-80% |
| | | | | S- | S- | S- | TFDB | TFDB | TFDB |
| | | | | BPDA | BPDA | BPDA | 10-50% | 20-40% | 20-30% |
| | | | | 25-75% | 35-65% | 45-55% | FDA | FDA | FDA |
| | | | | HQDA | HQDA | HQDA | | | |
| S-BPDA | HQDA | TFDB | BZDA | 25-75% | 35-65% | 45-55% | 50-90% | 60-80% | 70-80% |
| | | | | S- | S- | S- | TFDB | TFDB | TFDB |
| | | | | BPDA | BPDA | BPDA | 10-50% | 20-40% | 20-30% |
| | | | | 25-75% | 35-65% | 45-55% | BZDA | BZDA | BZDA |
| | | | | HQDA | HQDA | HQDA | | | |
| S-BPDA | HQDA | TFDB | DHBZ | 25-75% | 35-65% | 45-55% | 50-90% | 60-80% | 70-80% |
| | | | | S- | S- | S- | TFDB | TFDB | TFDB |
| | | | | BPDA | BPDA | BPDA | 10-50% | 20-40% | 20-30% |
| | | | | 25-75% | 35-65% | 45-55% | DHBZ | DHBZ | DHBZ |
| | | | | HQDA | HQDA | HQDA | | | |
| S-BPDA | HQDA | TFDB | p-PDA | 25-75% | 35-65% | 45-55% | 50-90% | 60-80% | 70-80% |
| | | | | S- | S- | S- | TFDB | TFDB | TFDB |
| | | | | BPDA | BPDA | BPDA | 10-50% | 20-40% | 20-30% |
| | | | | 25-75% | 35-65% | 45-55% | p-PDA | p-PDA | p-PDA |
| S-BPDA | HQDA | TFDB | m-PDA | 25-75% | 35-65% | 45-55% | 50-90% | 60-80% | 70-80% |
| | | | | S- | S- | S- | TFDB | TFDB | TFDB |
| | | | | BPDA | BPDA | BPDA | 10-50% | 20-40% | 20-30% |
| | | | | 25-75% | 35-65% | 45-55% | m-PDA | m-PDA | m-PDA |
| | | | | HQDA | HQDA | HQDA | | | |
| S-BPDA | HQDA | TFDB | 4,4′-ODA | 25-75% | 35-65% | 45-55% | 50-90% | 60-80% | 70-80% |
| | | | | S- | S- | S- | TFDB | TFDB | TFDB |
| | | | | BPDA | BPDA | BPDA | 10-50% | 20-40% | 20-30% |
| | | | | 25-75% | 35-65% | 45-55% | 4,4′-ODA | 4,4′-ODA | 4,4′-ODA |
| | | | | HQDA | HQDA | HQDA | | | |
| S-BPDA | HQDA | TFDB | HFPDA | 25-75% | 35-65% | 45-55% | 50-90% | 60-80% | 70-80% |
| | | | | S- | S- | S- | TFDB | TFDB | TFDB |
| | | | | BPDA | BPDA | BPDA | 10-50% | 20-40% | 20-30% |
| | | | | 25-75% | 35-65% | 45-55% | HFPDA | HFPDA | HFPDA |
| | | | | HQDA | HQDA | HQDA | | | |
| S-BPDA | HQDA | FDA | BZDA | 25-75% | 35-65% | 45-55% | 25-75% | 35-65% | 45-55% |
| | | | | S- | S- | S- | FDA | FDA | FDA |
| | | | | BPDA | BPDA | BPDA | 25-75% | 35-65% | 45-55% |
| | | | | 25-75% | 35-65% | 45-55% | BZDA | BZDA | BZDA |
| | | | | HQDA | HQDA | HQDA | | | |
| S-BPDA | HQDA | FDA | DHBZ | 25-75% | 35-65% | 45-55% | 25-75% | 35-65% | 45-55% |
| | | | | S- | S- | S- | FDA | FDA | FDA |
| | | | | BPDA | BPDA | BPDA | 25-75% | 35-65% | 45-55% |
| | | | | 25-75% | 35-65% | 45-55% | DHBZ | DHBZ | DHBZ |
| | | | | HQDA | HQDA | HQDA | | | |
| S-BPDA | HQDA | FDA | p-PDA | 25-75% | 35-65% | 45-55% | 25-75% | 35-65% | 45-55% |
| | | | | S- | S- | S- | FDA | FDA | FDA |
| | | | | BPDA | BPDA | BPDA | 25-75% | 35-65% | 45-55% |
| | | | | 25-75% | 35-65% | 45-55% | p-PDA | p-PDA | p-PDA |
| | | | | HQDA | HQDA | HQDA | | | |
| S-BPDA | HQDA | FDA | m-PDA | 25-75% | 35-65% | 45-55% | 25-75% | 35-65% | 45-55% |
| | | | | S- | S- | S- | FDA | FDA | FDA |
| | | | | BPDA | BPDA | BPDA | 25-75% | 35-65% | 45-55% |
| | | | | 25-75% | 35-65% | 45-55% | m-PDA | m-PDA | m-PDA |
| | | | | HQDA | HQDA | HQDA | | | |
| S-BPDA | HQDA | FDA | 4,4′-ODA | 25-75% | 35-65% | 45-55% | 25-75% | 35-65% | 45-55% |
| | | | | S- | S- | S- | FDA | FDA | FDA |
| | | | | BPDA | BPDA | BPDA | 25-75% | 35-65% | 45-55% |
| | | | | 25-75% | 35-65% | 45-55% | 4,4′-ODA | 4,4′-ODA | 4,4′-ODA |
| | | | | HQDA | HQDA | HQDA | | | |
| S-BPDA | HQDA | FDA | HFPDA | 25-75% | 35-65% | 45-55% | 25-75% | 35-65% | 45-55% |
| | | | | S- | S- | S- | FDA | FDA | FDA |
| | | | | BPDA | BPDA | BPDA | 25-75% | 35-65% | 45-55% |
| | | | | 25-75% | 35-65% | 45-55% | HFPDA | HFPDA | HFPDA |
| | | | | HQDA | HQDA | HQDA | | | |
| S-BPDA | BPADA | Form. VI | Form. V | 25-75% | 35-65% | 45-55% | 25-75% | 35-65% | 45-55% |
| | | | | S- | S- | S- | Form VI | Form VI | Form VI |
| | | | | BPDA | BPDA | BPDA | 25-75% | 35-65% | 45-55% |
| | | | | 25-75% | 35-65% | 45-55% | Form V | Form V | Form V |
| | | | | BPADA | BPADA | BPADA | | | |
| S-BPDA | BPADA | Form. VI | Form. V | 25-75% | 35-65% | 45-55% | 50-90% | 60-80% | 70-80% |
| | | | | S- | S- | S- | Form VI | Form VI | Form VI |
| | | | | BPDA | BPDA | BPDA | 10-50% | 20-40% | 20-30% |
| | | | | 25-75% | 35-65% | 45-55% | Form V | Form IV | Form V |
| | | | | BPADA | BPADA | BPADA | | | |
| S-BPDA | BPADA | Form. VI | Form. VII | 25-75% | 35-65% | 45-55% | 25-75% | 35-65% | 45-55% |
| | | | | S- | S- | S- | Form VI | Form VI | Form VI |
| | | | | BPDA | BPDA | BPDA | 25-75% | 35-65% | 45-55% |
| | | | | 25-75% | 35-65% | 45-55% | Form VII | Form VII | Form VII |
| | | | | BPADA | BPADA | BPADA | | | |
| S-BPDA | BPADA | Form. VI | Form. VII | 25-75% | 35-65% | 45-55% | 50-90% | 60-80% | 70-80% |
| | | | | S- | S- | S- | Form VI | Form VI | Form VI |
| | | | | BPDA | BPDA | BPDA | 10-50% | 20-40% | 20-30% |
| | | | | 25-75% | 35-65% | 45-55% | Form VII | Form VII | Form VII |
| | | | | BPADA | BPADA | BPADA | | | |
| S-BPDA | BPADA | TFDB | FDA | 25-75% | 35-65% | 45-55% | 25-75% | 35-65% | 45-55% |
| | | | | S- | S- | S- | TFDB | TFDB | TFDB |
| | | | | BPDA | BPDA | BPDA | 25-75% | 35-65% | 45-55% |
| | | | | 25-75% | 35-65% | 45-55% | FDA | FDA | FDA |
| | | | | BPADA | BPADA | BPADA | | | |
| S-BPDA | BPADA | TFDB | BZDA | 25-75% | 35-65% | 45-55% | 25-75% | 35-65% | 45-55% |
| | | | | S- | S- | S- | TFDB | TFDB | TFDB |
| | | | | BPDA | BPDA | BPDA | 25-75% | 35-65% | 45-55% |
| | | | | 25-75% | 35-65% | 45-55% | BZDA | BZDA | BZDA |
| | | | | BPADA | BPADA | BPADA | | | |
| S-BPDA | BPADA | TFDB | DHBZ | 25-75% | 35-65% | 45-55% | 25-75% | 35-65% | 45-55% |
| | | | | S- | S- | S- | TFDB | TFDB | TFDB |
| | | | | BPDA | BPDA | BPDA | 25-75% | 35-65% | 45-55% |
| | | | | 25-75% | 35-65% | 45-55% | DHBZ | DHBZ | DHBZ |
| | | | | BPADA | BPADA | BPADA | | | |
| S-BPDA | BPADA | TFDB | p-PDA | 25-75% | 35-65% | 45-55% | 25-75% | 35-65% | 45-55% |
| | | | | S- | S- | S- | TFDB | TFDB | TFDB |
| | | | | BPDA | BPDA | BPDA | 25-75% | 35-65% | 45-55% |
| | | | | 25-75% | 35-65% | 45-55% | p-PDA | p-PDA | p-PDA |
| | | | | BPADA | BPADA | BPADA | | | |
| S-BPDA | BPADA | TFDB | m-PDA | 25-75% | 35-65% | 45-55% | 25-75% | 35-65% | 45-55% |
| | | | | S- | S- | S- | TFDB | TFDB | TFDB |
| | | | | BPDA | BPDA | BPDA | 25-75% | 35-65% | 45-55% |
| | | | | 25-75% | 35-65% | 45-55% | m-PDA | m-PDA | m-PDA |
| | | | | BPADA | BPADA | BPADA | | | |
| S-BPDA | BPADA | TFDB | 4,4′-ODA | 25-75% | 35-65% | 45-55% | 25-75% | 35-65% | 45-55% |
| | | | | S- | S- | S- | TFDB | TFDB | TFDB |
| | | | | BPDA | BPDA | BPDA | 25-75% | 35-65% | 45-55% |
| | | | | 25-75% | 35-65% | 45-55% | 4,4′-ODA | 4,4′-ODA | 4,4′-ODA |
| | | | | BPADA | BPADA | BPADA | | | |
| S-BPDA | BPADA | TFDB | HFPDA | 25-75% | 35-65% | 45-55% | 25-75% | 35-65% | 45-55% |
| | | | | S- | S- | S- | TFDB | TFDB | TFDB |
| | | | | BPDA | BPDA | BPDA | 25-75% | 35-65% | 45-55% |
| | | | | 25-75% | 35-65% | 45-55% | HFPDA | HFPDA | HFPDA |
| | | | | BPADA | BPADA | BPADA | | | |
| S-BPDA | BPADA | TFDB | FDA | 25-75% | 35-65% | 45-55% | 50-90% | 60-80% | 70-80% |
| | | | | S- | S- | S- | TFDB | TFDB | TFDB |
| | | | | BPDA | BPDA | BPDA | 10-50% | 20-40% | 20-30% |
| | | | | 25-75% | 35-65% | 45-55% | FDA | FDA | FDA |
| | | | | BPADA | BPADA | BPADA | | | |
| S-BPDA | BPADA | TFDB | BZDA | 25-75% | 35-65% | 45-55% | 50-90% | 60-80% | 70-80% |
| | | | | S- | S- | S- | TFDB | TFDB | TFDB |
| | | | | BPDA | BPDA | BPDA | 10-50% | 20-40% | 20-30% |
| | | | | 25-75% | 35-65% | 45-55% | BZDA | BZDA | BZDA |
| | | | | BPADA | BPADA | BPADA | | | |
| S-BPDA | BPADA | TFDB | DHBZ | 25-75% | 35-65% | 45-55% | 50-90% | 60-80% | 70-80% |
| | | | | S- | S- | S- | TFDB | TFDB | TFDB |
| | | | | BPDA | BPDA | BPDA | 10-50% | 20-40% | 20-30% |
| | | | | 25-75% | 35-65% | 45-55% | DHBZ | DHBZ | DHBZ |
| | | | | BPADA | BPADA | BPADA | | | |
| S-BPDA | BPADA | TFDB | p-PDA | 25-75% | 35-65% | 45-55% | 50-90% | 60-80% | 70-80% |
| | | | | S- | S- | S- | TFDB | TFDB | TFDB |
| | | | | BPDA | BPDA | BPDA | 10-50% | 20-40% | 20-30% |
| | | | | 25-75% | 35-65% | 45-55% | p-PDA | p-PDA | p-PDA |
| | | | | BPADA | BPADA | BPADA | | | |
| S-BPDA | BPADA | TFDB | m-PDA | 25-75% | 35-65% | 45-55% | | | |
| | | | | 50-90% | 60-80% | 70-80% | | | |
| | | | | S- | S- | S- | TFDB | TFDB | TFDB |
| | | | | BPDA | BPDA | BPDA | 10-50% | 20-40% | 20-30% |
| | | | | 25-75% | 35-65% | 45-55% | m-PDA | m-PDA | m-PDA |
| | | | | BPADA | BPADA | BPADA | | | |
| S-BPDA | BPADA | TFDB | 4,4′-ODA | 25-75% | 35-65% | 45-55% | 50-90% | 60-80% | 70-80% |
| | | | | S- | S- | S- | TFDB | TFDB | TFDB |
| | | | | BPDA | BPDA | BPDA | 10-50% | 20-40% | 20-30% |
| | | | | 25-75% | 35-65% | 45-55% | 4,4′-ODA | 4,4′-ODA | 4,4′-ODA |
| | | | | BPADA | BPADA | BPADA | | | |
| S-BPDA | BPADA | TFDB | HFPDA | 25-75% | 35-65% | 45-55% | 50-90% | 60-80% | 70-80% |
| | | | | S- | S- | S- | TFDB | TFDB | TFDB |
| | | | | BPDA | BPDA | BPDA | 10-50% | 20-40% | 20-30% |
| | | | | 25-75% | 35-65% | 45-55% | HFPDA | HFPDA | HFPDA |
| | | | | BPADA | BPADA | BPADA | | | |
| S-BPDA | BPADA | FDA | BZDA | 25-75% | 35-65% | 45-55% | 25-75% | 35-65% | 45-55% |
| | | | | S- | S- | S- | FDA | FDA | FDA |
| | | | | BPDA | BPDA | BPDA | 25-75% | 35-65% | 45-55% |
| | | | | 25-75% | 35-65% | 45-55% | BZDA | BZDA | BZDA |
| | | | | BPADA | BPADA | BPADA | | | |
| S-BPDA | BPADA | FDA | DHBZ | 25-75% | 35-65% | 45-55% | 25-75% | 35-65% | 45-55% |
| | | | | S- | S- | S- | FDA | FDA | FDA |
| | | | | BPDA | BPDA | BPDA | 25-75% | 35-65% | 45-55% |
| | | | | 25-75% | 35-65% | 45-55% | DHBZ | DHBZ | DHBZ |
| | | | | BPADA | BPADA | BPADA | | | |
| S-BPDA | BPADA | FDA | p-PDA | 25-75% | 35-65% | 45-55% | 25-75% | 35-65% | 45-55% |
| | | | | S- | S- | S- | FDA | FDA | FDA |
| | | | | BPDA | BPDA | BPDA | 25-75% | 35-65% | 45-55% |
| | | | | 25-75% | 35-65% | 45-55% | p-PDA | p-PDA | p-PDA |
| | | | | BPADA | BPADA | BPADA | | | |
| S-BPDA | BPADA | FDA | m-PDA | 25-75% | 35-65% | 45-55% | 25-75% | 35-65% | 45-55% |
| | | | | S- | S- | S- | FDA | FDA | FDA |
| | | | | BPDA | BPDA | BPDA | 25-75% | 35-65% | 45-55% |
| | | | | 25-75% | 35-65% | 45-55% | m-PDA | m-PDA | m-PDA |
| | | | | BPADA | BPADA | BPADA | | | |
| S-BPDA | BPADA | FDA | 4,4′-ODA | 25-75% | 35-65% | 45-55% | 25-75% | 35-65% | 45-55% |
| | | | | S- | S- | S- | FDA | FDA | FDA |
| | | | | BPDA | BPDA | BPDA | 25-75% | 35-65% | 45-55% |
| | | | | 25-75% | 35-65% | 45-55% | 4,4′-ODA | 4,4′-ODA | 4,4′-ODA |
| | | | | BPADA | BPADA | BPADA | | | |
| S-BPDA | BPADA | FDA | HFPDA | 25-75% | 35-65% | 45-55% | 25-75% | 35-65% | 45-55% |
| | | | | S- | S- | S- | FDA | FDA | FDA |
| | | | | BPDA | BPDA | BPDA | 25-75% | 35-65% | 45-55% |
| | | | | 25-75% | 35-65% | 45-55% | HFPDA | HFPDA | HFPDA |
| | | | | BPADA | BPADA | BPADA | | | |
| ODPA | HQDA | Form. VI | Form. V | 25-75% | 35-65% | 45-55% | 25-75% | 35-65% | 45-55% |
| | | | | ODPA | ODPA | ODPA | Form VI | Form VI | Form VI |
| | | | | 25-75% | 35-65% | 45-55% | 25-75% | 35-65% | 45-55% |
| | | | | HQDA | HQDA | HQDA | Form V | Form V | Form V |
| ODPA | HQDA | Form. VI | Form. V | 25-75% | 35-65% | 45-55% | 50-90% | 60-80% | 70-80% |
| | | | | ODPA | ODPA | ODPA | Form VI | Form VI | Form VI |
| | | | | 25-75% | 35-65% | 45-55% | 10-50% | 20-40% | 20-30% |
| | | | | HQDA | HQDA | HQDA | Form V | Form V | Form V |
| ODPA | HQDA | Form. VI | Form. VII | 25-75% | 35-65% | 45-55% | 25-75% | 35-65% | 45-55% |
| | | | | ODPA | ODPA | ODPA | Form VI | Form VI | Form VI |
| | | | | 25-75% | 35-65% | 45-55% | 25-75% | 35-65% | 45-55% |
| | | | | HQDA | HQDA | HQDA | Form VII | Form VII | Form VII |
| ODPA | HQDA | Form. VI | Form. VII | 25-75% | 35-65% | 45-55% | 50-90% | 60-80% | 70-80% |
| | | | | ODPA | ODPA | ODPA | Form VI | Form VI | Form VI |
| | | | | 25-75% | 35-65% | 45-55% | 10-50% | 20-40% | 20-30% |
| | | | | HQDA | HQDA | HQDA | Form VII | Form VII | Form VII |
| ODPA | HQDA | TFDB | FDA | 25-75% | 35-65% | 45-55% | 25-75% | 35-65% | 45-55% |
| | | | | ODPA | ODPA | ODPA | TFDB | TFDB | TFDB |
| | | | | 25-75% | 35-65% | 45-55% | 25-75% | 35-65% | 45-55% |
| | | | | HQDA | HQDA | HQDA | FDA | FDA | FDA |
| ODPA | HQDA | TFDB | BZDA | 25-75% | 35-65% | 45-55% | 25-75% | 35-65% | 45-55% |
| | | | | ODPA | ODPA | ODPA | TFDB | TFDB | TFDB |
| | | | | 25-75% | 35-65% | 45-55% | 25-75% | 35-65% | 45-55% |
| | | | | HQDA | HQDA | HQDA | BZDA | BZDA | BZDA |
| ODPA | HQDA | TFDB | DHBZ | 25-75% | 35-65% | 45-55% | 25-75% | 35-65% | 45-55% |
| | | | | ODPA | ODPA | ODPA | TFDB | TFDB | TFDB |
| | | | | 25-75% | 35-65% | 45-55% | 25-75% | 35-65% | 45-55% |
| | | | | HQDA | HQDA | HQDA | DHBZ | DHBZ | DHBZ |
| ODPA | HQDA | TFDB | p-PDA | 25-75% | 35-65% | 45-55% | 25-75% | 35-65% | 45-55% |
| | | | | ODPA | ODPA | ODPA | TFDB | TFDB | TFDB |
| | | | | 25-75% | 35-65% | 45-55% | 25-75% | 35-65% | 45-55% |
| | | | | HQDA | HQDA | HQDA | p-PDA | p-PDA | p-PDA |
| ODPA | HQDA | TFDB | m-PDA | 25-75% | 35-65% | 45-55% | 25-75% | 35-65% | 45-55% |
| | | | | ODPA | ODPA | ODPA | TFDB | TFDB | TFDB |
| | | | | 25-75% | 35-65% | 45-55% | 25-75% | 35-65% | 45-55% |
| | | | | HQDA | HQDA | HQDA | m-PDA | m-PDA | m-PDA |
| ODPA | HQDA | TFDB | 4,4′-ODA | 25-75% | 35-65% | 45-55% | 25-75% | 35-65% | 45-55% |
| | | | | ODPA | ODPA | ODPA | TFDB | TFDB | TFDB |
| | | | | 25-75% | 35-65% | 45-55% | 25-75% | 35-65% | 45-55% |
| | | | | HQDA | HQDA | HQDA | 4,4′-ODA | 4,4′-ODA | 4,4′-ODA |
| ODPA | HQDA | TFDB | HFPDA | 25-75% | 35-65% | 45-55% | 25-75% | 35-65% | 45-55% |
| | | | | ODPA | ODPA | ODPA | TFDB | TFDB | TFDB |
| | | | | 25-75% | 35-65% | 45-55% | 25-75% | 35-65% | 45-55% |
| | | | | HQDA | HQDA | HQDA | HFPDA | HFPDA | HFPDA |
| ODPA | HQDA | TFDB | FDA | 25-75% | 35-65% | 45-55% | 50-90% | 60-80% | 70-80% |
| | | | | ODPA | ODPA | ODPA | TFDB | TFDB | TFDB |
| | | | | 25-75% | 35-65% | 45-55% | 10-50% | 20-40% | 20-30% |
| | | | | HQDA | HQDA | HQDA | FDA | FDA | FDA |
| ODPA | HQDA | TFDB | BZDA | 25-75% | 35-65% | 45-55% | 50-90% | 60-80% | 70-80% |
| | | | | ODPA | ODPA | ODPA | TFDB | TFDB | TFDB |
| | | | | 25-75% | 35-65% | 45-55% | 10-50% | 20-40% | 20-30% |
| | | | | HQDA | HQDA | HQDA | BZDA | BZDA | BZDA |
| ODPA | HQDA | TFDB | DHBZ | 25-75% | 35-65% | 45-55% | 50-90% | 60-80% | 70-80% |
| | | | | ODPA | ODPA | ODPA | TFDB | TFDB | TFDB |
| | | | | 25-75% | 35-65% | 45-55% | 10-50% | 20-40% | 20-30% |
| | | | | HQDA | HQDA | HQDA | DHBZ | DHBZ | DHBZ |
| ODPA | HQDA | TFDB | p-PDA | 25-75% | 35-65% | 45-55% | 50-90% | 60-80% | 70-80% |
| | | | | ODPA | ODPA | ODPA | TFDB | TFDB | TFDB |
| | | | | 25-75% | 35-65% | 45-55% | 10-50% | 20-40% | 20-30% |
| | | | | HQDA | HQDA | HQDA | p-PDA | p-PDA | p-PDA |
| ODPA | HQDA | TFDB | m-PDA | 25-75% | 35-65% | 45-55% | 50-90% | 60-80% | 70-80% |
| | | | | ODPA | ODPA | ODPA | TFDB | TFDB | TFDB |
| | | | | 25-75% | 35-65% | 45-55% | 10-50% | 20-40% | 20-30% |
| | | | | HQDA | HQDA | HQDA | m-PDA | m-PDA | m-PDA |
| ODPA | HQDA | TFDB | 4,4′-ODA | 25-75% | 35-65% | 45-55% | 50-90% | 60-80% | 70-80% |
| | | | | ODPA | ODPA | ODPA | TFDB | TFDB | TFDB |
| | | | | 25-75% | 35-65% | 45-55% | 10-50% | 20-40% | 20-30% |
| | | | | HQDA | HQDA | HQDA | 4,4′-ODA | 4,4′-ODA | 4,4′-ODA |
| ODPA | HQDA | TFDB | HFPDA | 25-75% | 35-65% | 45-55% | 50-90% | 60-80% | 70-80% |
| | | | | ODPA | ODPA | ODPA | TFDB | TFDB | TFDB |
| | | | | 25-75% | 35-65% | 45-55% | 10-50% | 20-40% | 20-30% |
| | | | | HQDA | HQDA | HQDA | HFPDA | HFPDA | HFPDA |
| ODPA | HQDA | FDA | BZDA | 25-75% | 35-65% | 45-55% | 25-75% | 35-65% | 45-55% |
| | | | | ODPA | ODPA | ODPA | FDA | FDA | FDA |
| | | | | 25-75% | 35-65% | 45-55% | 25-75% | 35-65% | 45-55% |
| | | | | HQDA | HQDA | HQDA | BZDA | BZDA | BZDA |
| ODPA | HQDA | FDA | DHBZ | 25-75% | 35-65% | 45-55% | 25-75% | 35-65% | 45-55% |
| | | | | ODPA | ODPA | ODPA | FDA | FDA | FDA |
| | | | | 25-75% | 35-65% | 45-55% | 25-75% | 35-65% | 45-55% |
| | | | | HQDA | HQDA | HQDA | DHBZ | DHBZ | DHBZ |
| ODPA | HQDA | FDA | p-PDA | 25-75% | 35-65% | 45-55% | 25-75% | 35-65% | 45-55% |
| | | | | ODPA | ODPA | ODPA | FDA | FDA | FDA |
| | | | | 25-75% | 35-65% | 45-55% | 25-75% | 35-65% | 45-55% |
| | | | | HQDA | HQDA | HQDA | p-PDA | p-PDA | p-PDA |
| ODPA | HQDA | FDA | m-PDA | 25-75% | 35-65% | 45-55% | 25-75% | 35-65% | 45-55% |
| | | | | ODPA | ODPA | ODPA | FDA | FDA | FDA |
| | | | | 25-75% | 35-65% | 45-55% | 25-75% | 35-65% | 45-55% |
| | | | | HQDA | HQDA | HQDA | m-PDA | m-PDA | m-PDA |
| ODPA | HQDA | FDA | 4,4′-ODA | 25-75% | 35-65% | 45-55% | 25-75% | 35-65% | 45-55% |
| | | | | ODPA | ODPA | ODPA | FDA | FDA | FDA |
| | | | | 25-75% | 35-65% | 45-55% | 25-75% | 35-65% | 45-55% |
| | | | | HQDA | HQDA | HQDA | 4,4′-ODA | 4,4′-ODA | 4,4′-ODA |
| ODPA | HQDA | FDA | HFPDA | 25-75% | 35-65% | 45-55% | 25-75% | 35-65% | 45-55% |
| | | | | ODPA | ODPA | ODPA | FDA | FDA | FDA |
| | | | | 25-75% | 35-65% | 45-55% | 25-75% | 35-65% | 45-55% |
| | | | | HQDA | HQDA | HQDA | HFPDA | HFPDA | HFPDA |
| ODPA | BPADA | Form. VI | Form. V | 25-75% | 35-65% | 45-55% | 25-75% | 35-65% | 45-55% |
| | | | | ODPA | ODPA | ODPA | Form VI | Form VI | Form VI |
| | | | | 25-75% | 35-65% | 45-55% | 25-75% | 35-65% | 45-55% |
| | | | | BPADA | BPADA | BPADA | Form V | Form V | Form V |
| ODPA | BPADA | Form. VI | Form. V | 25-75% | 35-65% | 45-55% | 50-90% | 60-80% | 70-80% |
| | | | | ODPA | ODPA | ODPA | Form VI | Form VI | Form VI |
| | | | | 25-75% | 35-65% | 45-55% | 10-50% | 20-40% | 20-30% |
| | | | | BPADA | BPADA | BPADA | Form V | Form V | Form V |
| ODPA | BPADA | Form. VI | Form. VII | 25-75% | 35-65% | 45-55% | 25-75% | 35-65% | 45-55% |
| | | | | ODPA | ODPA | ODPA | Form VI | Form VI | Form VI |
| | | | | 25-75% | 35-65% | 45-55% | 25-75% | 35-65% | 45-55% |
| | | | | BPADA | BPADA | BPADA | Form VII | Form VII | Form VII |
| ODPA | BPADA | Form. VI | Form. VII | 25-75% | 35-65% | 45-55% | 50-90% | 60-80% | 70-80% |
| | | | | ODPA | ODPA | ODPA | Form VI | Form V | Form VI |
| | | | | 25-75% | 35-65% | 45-55% | 10-50% | 20-40% | 20-30% |
| | | | | BPADA | BPADA | BPADA | Form VII | Form VII | Form VII |
| ODPA | BPADA | TFDB | FDA | 25-75% | 35-65% | 45-55% | 25-75% | 35-65% | 45-55% |
| | | | | ODPA | ODPA | ODPA | TFDB | TFDB | TFDB |
| | | | | 25-75% | 35-65% | 45-55% | 25-75% | 35-65% | 45-55% |
| | | | | BPADA | BPADA | BPADA | FDA | FDA | FDA |
| ODPA | BPADA | TFDB | BZDA | 25-75% | 35-65% | 45-55% | 25-75% | 35-65% | 45-55% |
| | | | | ODPA | ODPA | ODPA | TFDB | TFDB | TFDB |
| | | | | 25-75% | 35-65% | 45-55% | 25-75% | 35-65% | 45-55% |
| | | | | BPADA | BPADA | BPADA | BZDA | BZDA | BZDA |
| ODPA | BPADA | TFDB | DHBZ | 25-75% | 35-65% | 45-55% | 25-75% | 35-65% | 45-55% |
| | | | | ODPA | ODPA | ODPA | TFDB | TFDB | TFDB |
| | | | | 25-75% | 35-65% | 45-55% | 25-75% | 35-65% | 45-55% |
| | | | | BPADA | BPADA | BPADA | DHBZ | DHBZ | DHBZ |
| ODPA | BPADA | TFDB | p-PDA | 25-75% | 35-65% | 45-55% | 25-75% | 35-65% | 45-55% |
| | | | | ODPA | ODPA | ODPA | TFDB | TFDB | TFDB |
| | | | | 25-75% | 35-65% | 45-55% | 25-75% | 35-65% | 45-55% |
| | | | | BPADA | BPADA | BPADA | p-PDA | p-PDA | p-PDA |
| ODPA | BPADA | TFDB | m-PDA | 25-75% | 35-65% | 45-55% | 25-75% | 35-65% | 45-55% |
| | | | | ODPA | ODPA | ODPA | TFDB | TFDB | TFDB |
| | | | | 25-75% | 35-65% | 45-55% | 25-75% | 35-65% | 45-55% |
| | | | | BPADA | BPADA | BPADA | m-PDA | m-PDA | m-PDA |
| ODPA | BPADA | TFDB | 4,4′-ODA | 25-75% | 35-65% | 45-55% | 25-75% | 35-65% | 45-55% |
| | | | | ODPA | ODPA | ODPA | TFDB | TFDB | TFDB |
| | | | | 25-75% | 35-65% | 45-55% | 25-75% | 35-65% | 45-55% |
| | | | | BPADA | BPADA | BPADA | 4,4′-ODA | 4,4′-ODA | 4,4′-ODA |
| ODPA | BPADA | TFDB | HFPDA | 25-75% | 35-65% | 45-55% | 25-75% | 35-65% | 45-55% |
| | | | | ODPA | ODPA | ODPA | TFDB | TFDB | TFDB |
| | | | | 25-75% | 35-65% | 45-55% | 25-75% | 35-65% | 45-55% |
| | | | | BPADA | BPADA | BPADA | HFPDA | HFPDA | HFPDA |
| ODPA | BPADA | TFDB | FDA | 25-75% | 35-65% | 45-55% | 50-90% | 60-80% | 70-80% |
| | | | | ODPA | ODPA | ODPA | TFDB | TFDB | TFDB |
| | | | | 25-75% | 35-65% | 45-55% | 10-50% | 20-40% | 20-30% |
| | | | | BPADA | BPADA | BPADA | FDA | FDA | FDA |
| ODPA | BPADA | TFDB | BZDA | 25-75% | 35-65% | 45-55% | 50-90% | 60-80% | 70-80% |
| | | | | ODPA | ODPA | ODPA | TFDB | TFDB | TFDB |
| | | | | 25-75% | 35-65% | 45-55% | 10-50% | 20-40% | 20-30% |
| | | | | BPADA | BPADA | BPADA | BZDA | BZDA | BZDA |
| ODPA | BPADA | TFDB | DHBZ | 25-75% | 35-65% | 45-55% | 50-90% | 60-80% | 70-80% |
| | | | | ODPA | ODPA | ODPA | TFDB | TFDB | TFDB |
| | | | | 25-75% | 35-65% | 45-55% | 10-50% | 20-40% | 20-30% |
| | | | | BPADA | BPADA | BPADA | DHBZ | DHBZ | DHBZ |
| ODPA | BPADA | TFDB | p-PDA | 25-75% | 35-65% | 45-55% | 50-90% | 60-80% | 70-80% |
| | | | | ODPA | ODPA | ODPA | TFDB | TFDB | TFDB |
| | | | | 25-75% | 35-65% | 45-55% | 10-50% | 20-40% | 20-30% |
| | | | | BPADA | BPADA | BPADA | p-PDA | p-PDA | p-PDA |
| ODPA | BPADA | TFDB | m-PDA | 25-75% | 35-65% | 45-55% | 50-90% | 60-80% | 70-80% |
| | | | | ODPA | ODPA | ODPA | TFDB | TFDB | TFDB |
| | | | | 25-75% | 35-65% | 45-55% | 10-50% | 20-40% | 20-30% |
| | | | | BPADA | BPADA | BPADA | m-PDA | m-PDA | m-PDA |
| ODPA | BPADA | TFDB | 4,4′-ODA | 25-75% | 35-65% | 45-55% | 50-90% | 60-80% | 70-80% |
| | | | | ODPA | ODPA | ODPA | TFDB | TFDB | TFDB |
| | | | | 25-75% | 35-65% | 45-55% | 10-50% | 20-40% | 20-30% |
| | | | | BPADA | BPADA | BPADA | 4,4′-ODA | 4,4′-ODA | 4,4′-ODA |
| ODPA | BPADA | TFDB | HFPDA | 25-75% | 35-65% | 45-55% | 50-90% | 60-80% | 70-80% |
| | | | | ODPA | ODPA | ODPA | TFDB | TFDB | TFDB |
| | | | | 25-75% | 35-65% | 45-55% | 10-50% | 20-40% | 20-30% |
| | | | | BPADA | BPADA | BPADA | HFPDA | HFPDA | HFPDA |
| ODPA | BPADA | FDA | BZDA | 25-75% | 35-65% | 45-55% | 25-75% | 35-65% | 45-55% |
| | | | | ODPA | ODPA | ODPA | FDA | FDA | FDA |
| | | | | 25-75% | 35-65% | 45-55% | 25-75% | 35-65% | 45-55% |
| | | | | BPADA | BPADA | BPADA | BZDA | BZDA | BZDA |
| ODPA | BPADA | FDA | DHBZ | 25-75% | 35-65% | 45-55% | 25-75% | 35-65% | 45-55% |
| | | | | ODPA | ODPA | ODPA | FDA | FDA | FDA |
| | | | | 25-75% | 35-65% | 45-55% | 25-75% | 35-65% | 45-55% |
| | | | | BPADA | BPADA | BPADA | DHBZ | DHBZ | DHBZ |
| ODPA | BPADA | FDA | p-PDA | 25-75% | 35-65% | 45-55% | 25-75% | 35-65% | 45-55% |
| | | | | ODPA | ODPA | ODPA | FDA | FDA | FDA |
| | | | | 25-75% | 35-65% | 45-55% | 25-75% | 35-65% | 45-55% |
| | | | | BPADA | BPADA | BPADA | p-PDA | p-PDA | p-PDA |
| ODPA | BPADA | FDA | m-PDA | 25-75% | 35-65% | 45-55% | 25-75% | 35-65% | 45-55% |
| | | | | ODPA | ODPA | ODPA | FDA | FDA | FDA |
| | | | | 25-75% | 35-65% | 45-55% | 25-75% | 35-65% | 45-55% |
| | | | | BPADA | BPADA | BPADA | m-PDA | m-PDA | m-PDA |
| ODPA | BPADA | FDA | 4,4′-ODA | 25-75% | 35-65% | 45-55% | 25-75% | 35-65% | 45-55% |
| | | | | ODPA | ODPA | ODPA | FDA | FDA | FDA |
| | | | | 25-75% | 35-65% | 45-55% | 25-75% | 35-65% | 45-55% |
| | | | | BPADA | BPADA | BPADA | 4,4′-ODA | 4,4′-ODA | 4,4′-ODA |
| ODPA | BPADA | FDA | HFPDA | 25-75% | 35-65% | 45-55% | 25-75% | 35-65% | 45-55% |
| | | | | ODPA | ODPA | ODPA | FDA | FDA | FDA |
| | | | | 25-75% | 35-65% | 45-55% | 25-75% | 35-65% | 45-55% |
| | | | | BPADA | BPADA | BPADA | HFPDA | HFPDA | HFPDA |
| HQDA | BPADA | Form. VI | Form. V | 25-75% | 35-65% | 45-55% | 25-75% | 35-65% | 45-55% |
| | | | | HQDA | HQDA | HQDA | Form VI | Form VI | Form VI |
| | | | | 25-75% | 35-65% | 45-55% | 25-75% | 35-65% | 45-55% |
| | | | | BPADA | BPADA | BPADA | Form V | Form V | Form V |
| HQDA | BPADA | Form. VI | Form. V | 25-75% | 35-65% | 45-55% | 50-90% | 60-80% | 70-80% |
| | | | | HQDA | HQDA | HQDA | Form VI | Form VI | Form VI |
| | | | | 25-75% | 35-65% | 45-55% | 10-50% | 20-40% | 20-30% |
| | | | | BPADA | BPADA | BPADA | Form V | Form V | Form V |
| HQDA | BPADA | Form. VI | Form. VII | 25-75% | 35-65% | 45-55% | 25-75% | 35-65% | 45-55% |
| | | | | HQDA | HQDA | HQDA | Form VI | Form VI | Form VI |
| | | | | 25-75% | 35-65% | 45-55% | 25-75% | 35-65% | 45-55% |
| | | | | BPADA | BPADA | BPADA | Form VII | Form VII | Form VII |
| HQDA | BPADA | Form. VI | Form. VII | 25-75% | 35-65% | 45-55% | 50-90% | 60-80% | 70-80% |
| | | | | HQDA | HQDA | HQDA | Form VI | Form VI | Form VI |
| | | | | 25-75% | 35-65% | 45-55% | 10-50% | 20-40% | 20-30% |
| | | | | BPADA | BPADA | BPADA | Form VII | Form VII | Form VII |
| HQDA | BPADA | TFDB | FDA | 25-75% | 35-65% | 45-55% | 25-75% | 35-65% | 45-55% |
| | | | | HQDA | HQDA | HQDA | TFDB | TFDB | TFDB |
| | | | | 25-75% | 35-65% | 45-55% | 25-75% | 35-65% | 45-55% |
| | | | | BPADA | BPADA | BPADA | FDA | FDA | FDA |
| HQDA | BPADA | TFDB | BZDA | 25-75% | 35-65% | 45-55% | 25-75% | 35-65% | 45-55% |
| | | | | HQDA | HQDA | HQDA | TFDB | TFDB | TFDB |
| | | | | 25-75% | 35-65% | 45-55% | 25-75% | 35-65% | 45-55% |
| | | | | BPADA | BPADA | BPADA | BZDA | BZDA | BZDA |
| HQDA | BPADA | TFDB | DHBZ | 25-75% | 35-65% | 45-55% | 25-75% | 35-65% | 45-55% |
| | | | | HQDA | HQDA | HQDA | TFDB | TFDB | TFDB |
| | | | | 25-75% | 35-65% | 45-55% | 25-75% | 35-65% | 45-55% |
| | | | | BPADA | BPADA | BPADA | DHBZ | DHBZ | DHBZ |
| HQDA | BPADA | TFDB | p-PDA | 25-75% | 35-65% | 45-55% | 25-75% | 35-65% | 45-55% |
| | | | | HQDA | HQDA | HQDA | TFDB | TFDB | TFDB |
| | | | | 25-75% | 35-65% | 45-55% | 25-75% | 35-65% | 45-55% |
| | | | | BPADA | BPADA | BPADA | p-PDA | p-PDA | p-PDA |
| HQDA | BPADA | TFDB | m-PDA | 25-75% | 35-65% | 45-55% | 25-75% | 35-65% | 45-55% |
| | | | | HQDA | HQDA | HQDA | TFDB | TFDB | TFDB |
| | | | | 25-75% | 35-65% | 45-55% | 25-75% | 35-65% | 45-55% |
| | | | | BPADA | BPADA | BPADA | m-PDA | m-PDA | m-PDA |
| HQDA | BPADA | TFDB | 4,4′-ODA | 25-75% | 35-65% | 45-55% | 25-75% | 35-65% | 45-55% |
| | | | | HQDA | HQDA | HQDA | TFDB | TFDB | TFDB |
| | | | | 25-75% | 35-65% | 45-55% | 25-75% | 35-65% | 45-55% |
| | | | | BPADA | BPADA | BPADA | 4,4′-ODA | 4,4′-ODA | 4,4′-ODA |
| HQDA | BPADA | TFDB | HFPDA | 25-75% | 35-65% | 45-55% | 25-75% | 35-65% | 45-55% |
| | | | | HQDA | HQDA | HQDA | TFDB | TFDB | TFDB |
| | | | | 25-75% | 35-65% | 45-55% | 25-75% | 35-65% | 45-55% |
| | | | | BPADA | BPADA | BPADA | HFPDA | HFPDA | HFPDA |
| HQDA | BPADA | TFDB | FDA | 25-75% | 35-65% | 45-55% | 50-90% | 60-80% | 70-80% |
| | | | | HQDA | HQDA | HQDA | TFDB | TFDB | TFDB |
| | | | | 25-75% | 35-65% | 45-55% | 10-50% | 20-40% | 20-30% |
| | | | | BPADA | BPADA | BPADA | FDA | FDA | FDA |
| HQDA | BPADA | TFDB | BZDA | 25-75% | 35-65% | 45-55% | 50-90% | 60-80% | 70-80% |
| | | | | HQDA | HQDA | HQDA | TFDB | TFDB | TFDB |
| | | | | 25-75% | 35-65% | 45-55% | 10-50% | 20-40% | 20-30% |
| | | | | BPADA | BPADA | BPADA | BZDA | BZDA | BZDA |
| HQDA | BPADA | TFDB | DHBZ | 25-75% | 35-65% | 45-55% | 50-90% | 60-80% | 70-80% |
| | | | | HQDA | HQDA | HQDA | TFDB | TFDB | TFDB |
| | | | | 25-75% | 35-65% | 45-55% | 10-50% | 20-40% | 20-30% |
| | | | | BPADA | BPADA | BPADA | DHBZ | DHBZ | DHBZ |
| HQDA | BPADA | TFDB | p-PDA | 25-75% | 35-65% | 45-55% | 50-90% | 60-80% | 70-80% |
| | | | | HQDA | HQDA | HQDA | TFDB | TFDB | TFDB |
| | | | | 25-75% | 35-65% | 45-55% | 10-50% | 20-40% | 20-30% |
| | | | | BPADA | BPADA | BPADA | p-PDA | p-PDA | p-PDA |
| HQDA | BPADA | TFDB | m-PDA | 25-75% | 35-65% | 45-55% | 50-90% | 60-80% | 70-80% |
| | | | | HQDA | HQDA | HQDA | TFDB | TFDB | TFDB |
| | | | | 25-75% | 35-65% | 45-55% | 10-50% | 20-40% | 20-30% |
| | | | | BPADA | BPADA | BPADA | m-PDA | m-PDA | m-PDA |
| HQDA | BPADA | TFDB | 4,4′-ODA | 25-75% | 35-65% | 45-55% | 50-90% | 60-80% | 70-80% |
| | | | | HQDA | HQDA | HQDA | TFDB | TFDB | TFDB |
| | | | | 25-75% | 35-65% | 45-55% | 10-50% | 20-40% | 20-30% |
| | | | | BPADA | BPADA | BPADA | 4,4′-ODA | 4,4′-ODA | 4,4′-ODA |
| HQDA | BPADA | TFDB | HFPDA | 25-75% | 35-65% | 45-55% | 50-90% | 60-80% | 70-80% |
| | | | | HQDA | HQDA | HQDA | TFDB | TFDB | TFDB |
| | | | | 25-75% | 35-65% | 45-55% | 10-50% | 20-40% | 20-30% |
| | | | | BPADA | BPADA | BPADA | HFPDA | HFPDA | HFPDA |
| HQDA | BPADA | FDA | BZDA | 25-75% | 35-65% | 45-55% | 25-75% | 35-65% | 45-55% |
| | | | | HQDA | HQDA | HQDA | FDA | FDA | FDA |
| | | | | 25-75% | 35-65% | 45-55% | 25-75% | 35-65% | 45-55% |
| | | | | BPADA | BPADA | BPADA | BZDA | BZDA | BZDA |
| HQDA | BPADA | FDA | DHBZ | 25-75% | 35-65% | 45-55% | 25-75% | 35-65% | 45-55% |
| | | | | HQDA | HQDA | HQDA | FDA | FDA | FDA |
| | | | | 25-75% | 35-65% | 45-55% | 25-75% | 35-65% | 45-55% |
| | | | | BPADA | BPADA | BPADA | DHBZ | DHBZ | DHBZ |
| HQDA | BPADA | FDA | p-PDA | 25-75% | 35-65% | 45-55% | 25-75% | 35-65% | 45-55% |
| | | | | HQDA | HQDA | HQDA | FDA | FDA | FDA |
| | | | | 25-75% | 35-65% | 45-55% | 25-75% | 35-65% | 45-55% |
| | | | | BPADA | BPADA | BPADA | p-PDA | p-PDA | p-PDA |
| HQDA | BPADA | FDA | m-PDA | 25-75% | 35-65% | 45-55% | 25-75% | 35-65% | 45-55% |
| | | | | HQDA | HQDA | HQDA | FDA | FDA | FDA |
| | | | | 25-75% | 35-65% | 45-55% | 25-75% | 35-65% | 45-55% |
| | | | | BPADA | BPADA | BPADA | m-PDA | m-PDA | m-PDA |
| HQDA | BPADA | FDA | 4,4′-ODA | 25-75% | 35-65% | 45-55% | 25-75% | 35-65% | 45-55% |
| | | | | HQDA | HQDA | HQDA | FDA | FDA | FDA |
| | | | | 25-75% | 35-65% | 45-55% | 25-75% | 35-65% | 45-55% |
| | | | | BPADA | BPADA | BPADA | 4,4′-ODA | 4,4′-ODA | 4,4′-ODA |
| HQDA | BPADA | FDA | HFPDA | 25-75% | 35-65% | 45-55% | 25-75% | 35-65% | 45-55% |
| | | | | HQDA | HQDA | HQDA | FDA | FDA | FDA |
| | | | | 25-75% | 35-65% | 45-55% | 25-75% | 35-65% | 45-55% |
| | | | | BPADA | BPADA | BPADA | HFPDA | HFPDA | HFPDA |

The polyimide polymers of the present disclosure can comprise the above mole percentages of the aromatic dianhydride monomers and the above mole percentages of the aromatic diamine monomers. The polyimide polymers of the present disclosure can consist essentially of the above mole percentages of the aromatic dianhydride monomers and the above mole percentages of the aromatic diamine monomers. The polyimide polymers of the present disclosure can consist of the above mole percentages of the aromatic dianhydride monomers and the above mole percentages of the aromatic diamine monomers.

### Additional Monomers

The polyimide polymer may optionally further include cyclobutane-1,2,3,4-tetracarboxylic dianhydride, which may provide sites for crosslinking through cyclobutane group.

The polyimide polymer may optionally further include monoanhydride or monoamine to control the final molecular weight of the polymer and provide potential further crosslinking properties. The monoanhydride may include maleic anhydride. The monoamine may include theynylphenyl amine.

### Process

The preparation of the polyimide polymer is carried out in two chemical steps. First the aromatic diamine component(s) and the aromatic dianhydride component(s) are polymerized by a condensation reaction to provide the polyamic acid precursor, followed by imidization. The aromatic diamine component(s) and the aromatic dianhydride component(s) are used in approximately equimolar proportions.

The aromatic diamine component(s) and the aromatic dianhydride component(s) are polymerized in a polar organic solvent such as N-methyl-2-pyrrolidone (NMP), dimethylacetamide (DMAc) and dimethylformamide (DMF) to obtain a polyimide precursor solution (polyamic acid solution). The polymerization by polycondensation of the aromatic anhydride(s) and the aromatic diamine(s) takes place quite readily at room temperature. Because the reaction is exothermic, the temperature of a batch reaction system may be raised substantially. Accordingly, it may be preferred to prepare a solution of either the aromatic anhydride(s) or the aromatic diamine(s) and then slowly add the other component to the solution in order to control the temperature. The polymerization may be performed at a temperature between about 15° C. to about 100° C., and more preferably at about 15° C. to about 40° C., with a reaction time from about 6 hours to about 36 hours, or a reaction time from about 12 hours to about 30 hours.

The polyimide precursor may be isolated and purified from the polyimide precursor solution, for example by precipitation from the solvent or evaporation of the solvent, followed by rinsing of the precursor polymer, etc. The polyimide precursor may then be re-dissolved in the same solvent or in a different solvent to perform the imidization reaction. Alternatively and preferably, the polymerization reaction and the imidization reaction are performed in the same solvent without the isolation of the polyimide precursor.

The imidization of the polyimide precursor is preferably performed in solution, and most preferably in the same solvent as the polymerization. The imidization reaction may be performed in a polar organic solvent such as NMP, DMAc and DMF. A base is added to catalyze the imidization reaction. Preferably, the base is an amine base, such as triethylamine, diisopropyl amine, pyridine, dimethylaminopyridine, and the like. Additionally, a dehydrating agent may be added to remove water liberated from the imidization. Dehydrating agents are known in the art and include chemical dehydrating agents that react with water such as anhydrides, or physical dehydrating agents such as molecular sieves. Alternatively, the water liberated by the imidization reaction may be removed from the reaction by co-distillation with an appropriate solvent.

### Coating Composition and Methods

The polyimide polymers of the disclosure may be dissolved in organic solvents to form a coating solution of the polyimide polymer. Preferred organic solvents include NMP, DMAc, DMF, DMSO, THF, dioxane, and mixtures thereof.

The polyimide polymer coating compositions in accordance with the present disclosure may be applied as a liquid directly to suitable substrates by conventional coating means. Techniques for producing such coatings include conventional methods of casting, dipping, spraying and painting.

Following application of the polyimide polymer coating composition, the solvent is removed and the polyimide is (optionally) cured by heating. In some embodiments, the polyimide is heated to a temperature as low as 350° C., 375° C., 400° C., or 425° C., or as high as 450° C., 475° C., 500° C., 525° C., or 550° C., or to any temperature within any range defined between any two of the foregoing values, such 350° C. to 550° C., 375° C. to 525° C., 400° C. to 500° C., 425° C. to 475° C., or 350° C. to 450° C., for example. In some embodiments, the polyimide is heated to a temperature no greater than about 350° C. It has been found that a temperature of 350° C. is sufficient for curing the polyimide, according to some embodiments of this disclosure.

In some embodiments, the heating of the polyimide may be performed for as little as 3 hours, 3.5 hours, 4 hours, 4.5 hours, or 5 hours, or as much as 6 hours, 7 hours, 8 hours, 9 hours, or 10 hours, or for a time within any range defined between any two of the foregoing values, such as 3 hours to 10 hours, 3.5 hours to 9 hours, 4 hours to 8 hours, 4.5 hours to 7 hours, 5 hours to 6 hours, or 3 hours to 3.5 hours, for example. It has been found that a time of 3.5 hours is sufficient for curing the polyimide, according to some embodiments of this disclosure.

As used herein, the phrase “within any range defined between any two of the foregoing values” literally means that any range may be selected from any two of the values listed prior to such phrase regardless of whether the values are in the lower part of the listing or in the higher part of the listing. For example, a pair of values may be selected from two lower values, two higher values, or a lower value and a higher value.

### Flexible Display Device and Method of Making

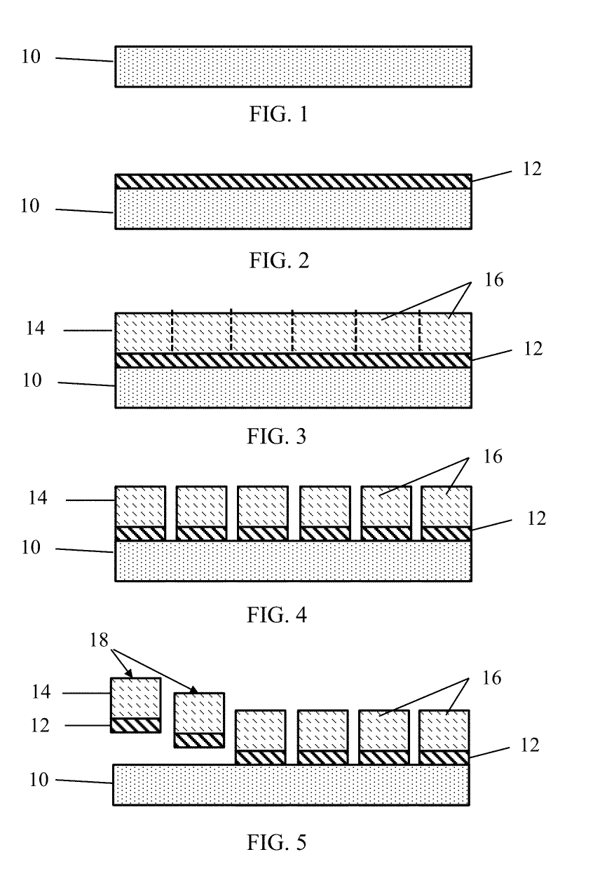

FIGS. 1-5 are schematic cross-sections illustrating a method for making a flexible display device, according to some embodiments of this disclosure. FIG. 1 shows a substrate 10. In some embodiments, the substrate 10 is a glass substrate. In some other embodiments, the substrate 10 can be a quartz, sapphire, or silicon-based substrate. The substrate 10 can be relatively thick in comparison to subsequent layers because the substrate 10 is not part of the flexible display device and the extra thickness provides the rigidity necessary for reliable processing on automated production systems. In some embodiments, the substrate 10 can be cleaned by ultrasonic cleaning in a series of three solvents, such as distilled water, chloroform, and acetone, for example. After cleaning, the substrate 10 can be dried in an oven.

FIG. 2 shows the substrate 10 after a polyimide polymer layer 12 has been formed on the substrate 10 of FIG. 1. The polyimide polymer layer 12 can be formed by dissolving any of the polyimide polymers of the disclosure in organic solvents to form a coating solution of the polyimide polymer, and then coating the substrate with the polyimide solution, as described above. Once the substrate 10 is coated by the polyimide solution, the coating of the polyimide solution can be heated to evaporate the organic solvent and form the polyimide polymer layer 12. It is understood that evaporating the organic solvent encompasses evaporation of substantially all to all of the organic solvent, recognizing that in some embodiments, a residue of the organic solvent may remain.

Heating of the coated polyimide solution can be as described above. For example, in some embodiments, the heating can include: baking on a hot plate at a temperature of 75° C. to 80° C. for 25 to 35 minutes, baking in an oven at a temperature of 95° C. to 105° C. for 55 to 65, minutes 245° C. to 255° C. for 55 to 65 minutes, and then baking in the oven at a temperature of 345° C. to 350° C. for 55 to 65 minutes. In some embodiments, the heating can include baking on a hot plate at a temperature of 75° C. to 80° C. for 25 to 35 minutes, baking in an oven at a temperature of 245° C. to 255° C. for 55 to 65 minutes, and then baking in the oven at a temperature of 345° C. to 350° C. for 55 to 65 minutes. In some embodiments, the hot plate baking can be in an air ambient, while the oven baking is in a nitrogen environment. In some embodiments, the oven can ramp to the next temperature at rate of as low as 2° C./minute, 3° C./minute, 4° C./minute or 5° C./minute, or as high as 6° C./minute, 7° C./minute, 8° C./minute, 9° C./minute, 10° C./minute, or 12° C./minute, or within any range defined between any two of the foregoing values, such as 2° C./minute to 12° C./minute, 4° C./minute to 8° C./minute, or 5° C./minute to 10° C./minute, for example.

FIG. 3 shows the substrate 10 and the polyimide polymer layer 12 of FIG. 2 after a display device layer 14 has been formed on the polyimide polymer layer 12. The display device layer 14 can include circuitry for one or more individual display devices. In the embodiment shown in FIG. 3, the display device layer 14 includes circuitry for a plurality of display devices 16. The display device layer 14 can be formed by processes well known in the art to construct, for example OLED display devices, based on low-temperature polycrystalline silicon (LTPS) technology, or oxide semiconductor technology, and including various deposition, patterning, etching, and encapsulating process steps.

Once the display device layer 14 is complete, the individual display devices 16 can be separated from each other. FIG. 4 shows the substrate 10, the polyimide polymer layer 12, and the display device layer 14 of FIG. 3 after singulation of the plurality of display devices 16 by dicing through the display device layer 14 and the polyimide polymer layer 12. The dicing can be between each of the plurality of display devices 16 as shown in FIG. 4. In some embodiments, the dicing may continue partially into the substrate 10.

After dicing, the individual display devices 16 with the polyimide polymer layer 12 can be removed from the substrate 10 by delamination at an interface between the substrate 10 and the polyimide polymer layer 12, to form a plurality of flexible display devices 18, as shown in FIG. 5. Each of the plurality of flexible display devices 18 includes the polyimide polymer layer 12, which serves as a flexible backing layer, and the display device 16 disposed on the polyimide polymer layer 12. In some embodiments, the display device 16 is disposed directly on the polyimide polymer layer 12. In some other embodiments, there can be other layers disposed between the display device 16 and the polyimide polymer layer 12, such as a silicon layer, a silicon oxide layer, a silicon nitride layer, or any combination thereof.

In some embodiments, the delamination after dicing can include shining a laser beam, such as that provided by an excimer laser, through the substrate 10. The wavelength of the laser beam is such that there is little, if any, interaction between the laser beam and the substrate 10. That is, the substrate 10 can be substantially transparent with respect to the laser beam. However, the polyimide polymer layer 12 is typically not transparent with respect to the laser beam. The resulting interaction between the laser beam and the polyimide polymer layer 12 can results in the vaporization of a portion of the polyimide polymer layer 12 in contact with and adjacent to the substrate 10, delaminating the remaining polyimide polymer layer 12 from the substrate 10. By properly controlling the energy supplied by the excimer laser (e.g. by exposure time and intensity), the vaporized portion of the polyimide polymer layer 12 is small enough to delaminate the polyimide polymer layer 12, while leaving a substantial portion of the polyimide polymer layer 12 intact to serve as the flexible backing layer of the flexible display device 18. Delamination by laser beam can be effective, but can be expensive due to the cost of the excimer laser. In addition, the variable nature of the relatively thick substrate 10 can result in varying transparency with respect to the laser beam, leading to non-uniformity of the delamination and/or the resulting flexible display devices 18.

Alternatively, in some embodiments, the delamination after dicing can be done by mechanical means. This is possible because the polyimide polymers of the disclosure used to form the polyimide polymer layer 12 do not adhere as strongly to the substrate 10, when compared to prior art polyimide polymer layers. The prior art polyimide layers are formed by coating a substrate with a solution including polyamic acid, and then baking the coating at temperatures exceeding 400° C. to imidized the coating to form the polyimide polymer. Not wishing to be bound by any theory, it is believed that some of the acid groups of the polyamic acid chemically bond with the hydroxyl groups of the substrate during the high-temperature bake, for example, when the substrate is a glass substrate. These chemical bonds may strongly adhere the polyimide polymer layer to the substrate. Mechanical delamination means may be ineffective at overcoming this strong adhesion, thus requiring laser delamination, as described above. In embodiments of the present disclosure, bonding from polyamic acid to the substrate 10 is substantially eliminated as it is the polyimide polymer itself that is coated onto the substrate 10, and not the polyamic acid. By substantially eliminated, is recognized that embodiments include polyimide polymer that may include a residue of polyamic acid.

In some embodiments, mechanical means for delaminating after dicing can include immersing the substrate 10 with the polyimide polymer layer 12 and the display device layer 14 into water. In some embodiments, after singulation, the substrate 10 with the polyimide polymer layer 12 and the display device layer 14 is immersed into distilled water at room temperature for about an hour. After about an hour, edges of the polyimide polymer layer 12 with the display device layer 14 can begin to warp as they separate from the substrate 10. The polyimide polymer layer 12 with the display device layer 14 can be peeled off of the substrate 10, starting at the warped edges. In some embodiments, a piece of paper or a thin plastic sheet may be used to help peel the polyimide polymer layer 12 with the display device layer 14 from the substrate 10.

### Physical and Chemical Properties

The coating composition of the polyimide polymer (with concentration 15% in NMP) may have a viscosity of between about 200 to about 20,000 mPa·s, or between about 1000 to about 10,000 mPa·s, or between about 3000 to about 7000 mPa·s, or between about 3000 to about 5000 mPa·s. Viscosity is measured on an AR2000ex Rotational Rheometer (provided by TA Instruments) at 25° C. using D2196-10 Standard Test Methods for Rheological Properties of Non-Newtonian Materials.

The polyimide polymers of the present disclosure have a high degree of imidization. Accordingly, in preferred aspects, the percentage of imide linkages in the polyimide polymer backbone to the total linkages (imide+acid amide) in the polyimide polymer backbone is greater than about 90%, or greater than about 95%, or greater than about 98%, or greater than about 99%.

The polyimide polymers of the present disclosure have a high solubility in polar aprotic organic solvents. Accordingly, in preferred aspects, the polyimide polymers have a solubility in NMP of greater than about 20% by weight.

According to preferred aspects, the present disclosure provides polyimide polymers as described in the previous paragraphs wherein the polymer has a number average molecular weight of greater than about 10,000 Daltons, or greater than about 20,000 Daltons, or greater than about 30,000 Daltons, or greater than about 50,000 Daltons. The polyimide polymers as described in the previous paragraphs has a number average molecular weight of less than 500,000 Daltons, or less than 300,000 Daltons, or less than about 200,000 Daltons, or less than 100,000 Daltons. Molecular weight is determined by GPC (gel permeation chromatography) on Waters 2695/2414 GPC (provided by Waters) at 40° C. with THF as the eluant. The method is described in MODERN SIZE-EXCLUSION LIQUID CHROMATOGRAPHY Practice of Gel Permeation and Gel Filtration Chromatography SECOND EDITION Andre M. Striegel, Wallace W. Yau, Joseph J. Kirkland and Donald D. Bly, 2009 by John Wiley & Sons, Inc.

According to preferred aspects, the present disclosure provides films of the polyimide polymers as described in the previous paragraphs that have a low coefficient of thermal expansion (CTE). Accordingly, in preferred aspects, the polyimide polymer films have a CTE of less than about 20 ppm, or less than about 12 ppm, or less than about 10 ppm, or less than about 8 ppm, or less than about 6 ppm, or less than about 5 ppm. The CTE is measured with TMA (Thermal Mechanical Analysis) by TA-Q400 provided by TA Instruments.

The films comprising the polyimide polymer as described herein have high thermal stability. The thermal stability is measured by weight loss by a TGA (Thermo-gravimetric Analysis) non-isothermal test with 10° C./min ramp-up to 800° C. under a nitrogen environment. In the TGA curve, the weight loss is less than about 1% at 500° C., or less than about 1% at 520° C., or less than about 1% at 550° C., or less than about 1% at 580° C. Additionally, thermal stability is measured by weight loss in a TGA isothermal test under nitrogen environment. The weight loss by the isothermal test is less than about 2%, or less than about 1.5%, or less than about 1%, or less than about 0.8%, or less than about 0.5%, after iso-thermal 450° C. for 60 minutes. Both non-isothermal and isothermal TGA instruments are Q500 provided by TA Instruments. The thermal stability may also be judged by Tg (glass transition temperature) measured by DMA (Dynamic Mechanical Analysis) with 4° C./min ramp-up to 500° C. under nitrogen environment. Preferably, the Tg is higher than about 200° C., or higher than about 250° C., or higher than about 300° C., or higher than about 330° C., or higher than about 350° C., or higher than about 370° C., or higher than about 400° C. The DMA test tool is Q800 provided by TA instruments.

The polyimide polymer film has a high Tg (glass transition temperature) measured by DMA (Dynamic Mechanical Analysis) with 4° C./min ramp-up to 500° C. under nitrogen environment. The Tg is higher than 200° C., or higher than 250° C., or higher than 300° C., or higher than 330° C., or higher than 350° C., or higher than 370° C., or higher than 400° C. The DMA test tool is Q800 provided by TA instruments.

### ASPECTS OF THE DISCLOSURE

Aspect 1: A polyimide polymer comprising monomers (a), (b), (c) and optionally (d):

(a) one or more aromatic dianhydrides represented by the formula I:

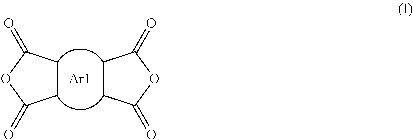

wherein
Ar1 is selected from the group consisting of:

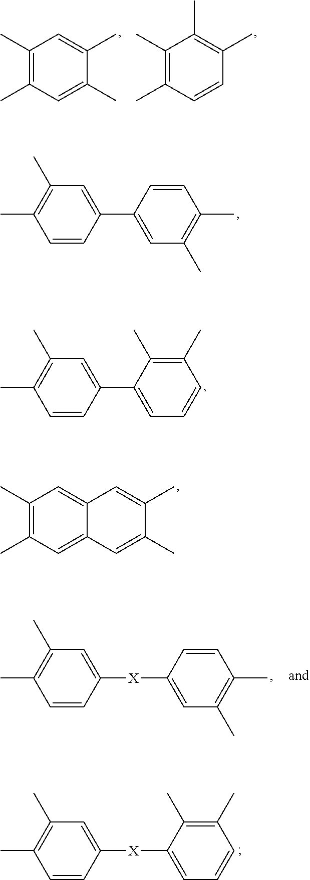

wherein X is selected from the group consisting of —CH₂—, —C(CH₃)₂—, —C(CF₃)₂—, —O—, —C(═O)—, —SO₂—,

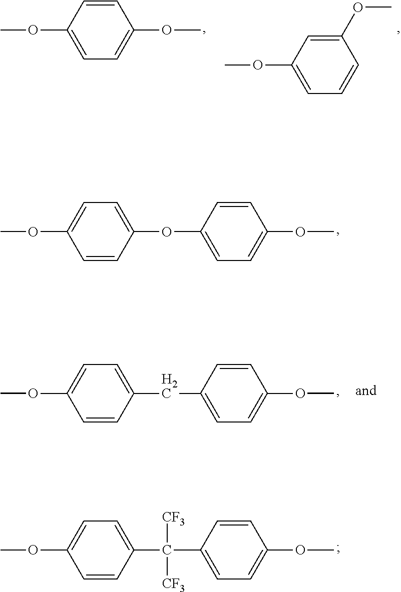

(b) one or more aromatic diamines having the formula V:

H₂N-Ar5-NH₂ (V)

wherein Ar5 is selected from the group consisting of:

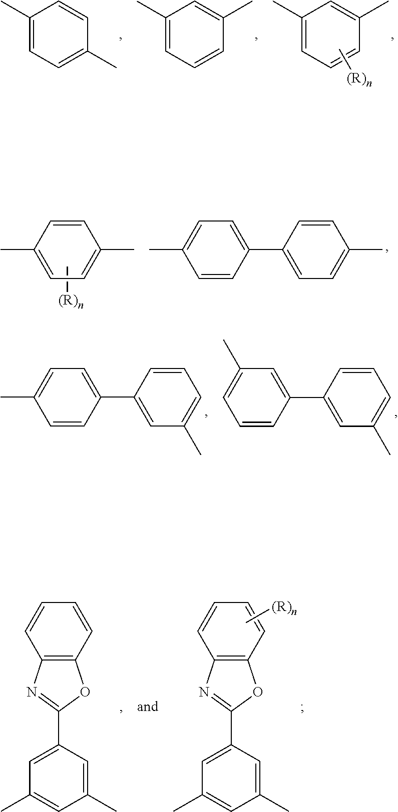

wherein
each R is independently selected from the group consisting of F, Cl, and CF₃; and
n is 0, 1 or 2;
(c) one or more aromatic diamines having the formula VI

H₂N-Ar6-NH₂ (VI)

wherein Ar6 is selected from the group consisting of:

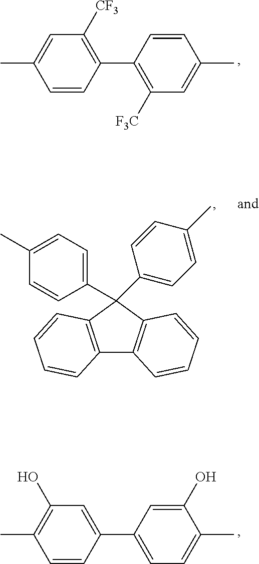

and
(d) optionally one or more aromatic diamines having the formula VII:

H₂N-Ar7-NH₂ (VII)

wherein Ar7 is selected from the group consisting of:

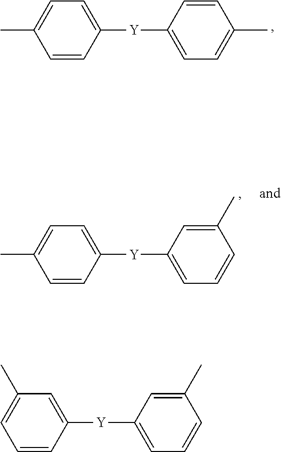

wherein
Y is selected from the group consisting of —CH₂—, —C(CH₃)₂—, —C(CF₃)₂—, —O—, —C(═O)—, —SO₂—,

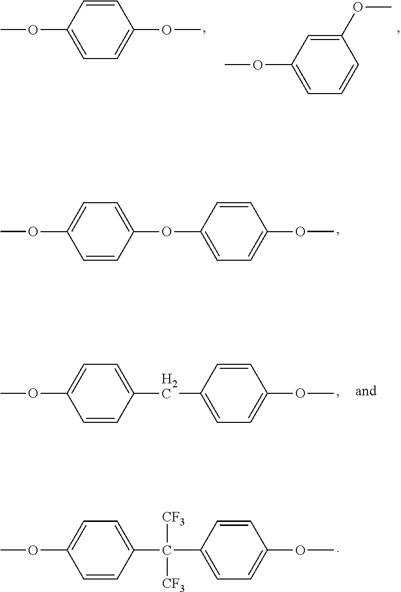

Aspect 2: A polyimide polymer comprising monomers (a), (b), and optionally (c):

(a) one or more aromatic dianhydrides represented by the formula I:

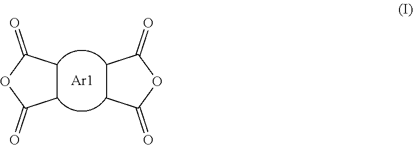

wherein
Ar1 is selected from the group consisting of:

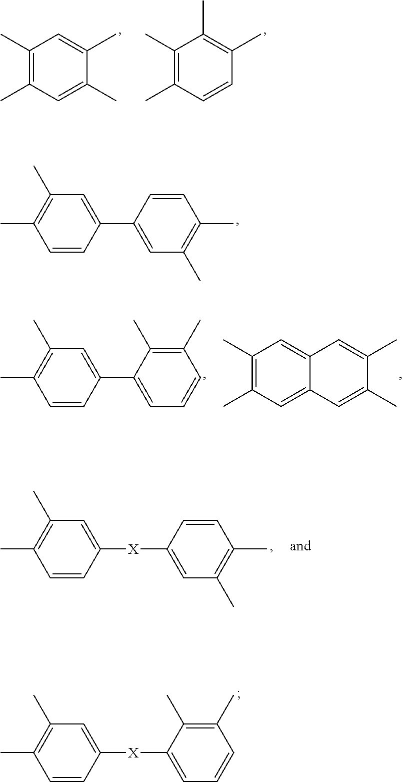

wherein X is selected from the group consisting of —CH₂—, —C(CH₃)₂—, —C(CF₃)₂—, —O—, —C(═O)—, —SO₂—,

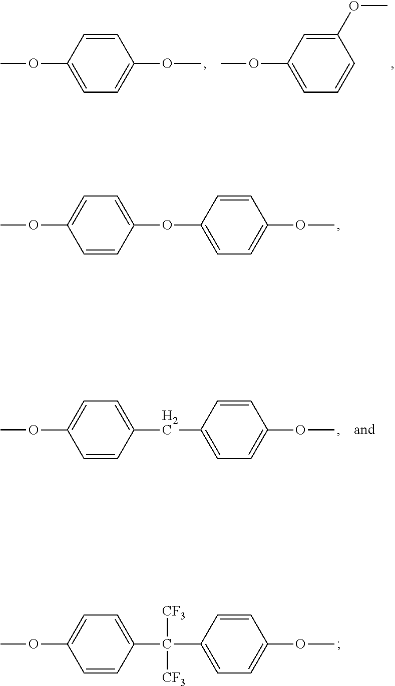

(b) one or more aromatic diamines having the formula VI

H₂N-Ar6-NH₂ (VI)

wherein Ar6 is selected from the group consisting of:

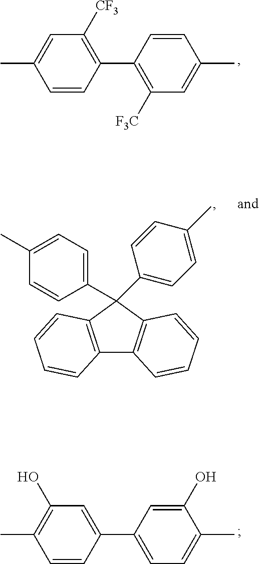

and
(c) optionally one or more aromatic diamines having the formula VII:

H₂N-Ar7-NH₂ (VII)

wherein Ar7 is selected from the group consisting of:

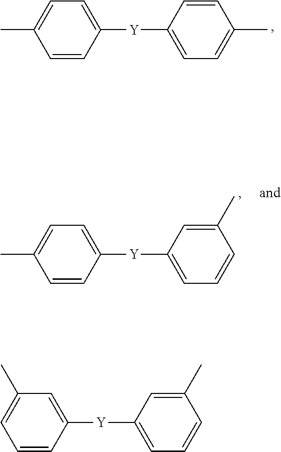

wherein
Y is selected from the group consisting of —CH₂—, —C(CH₃)₂—, —C(CF₃)₂—, —O—, —C(═O)—, —SO₂—,

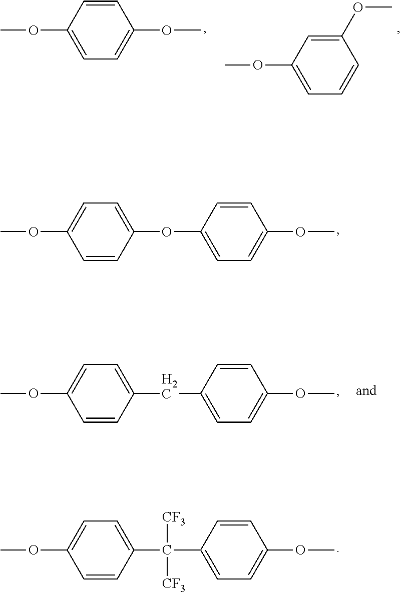

Aspect 3. A polyimide polymer comprising monomers (a), (b), and optionally (c):

(a) one or more aromatic dianhydrides represented by the formula I:

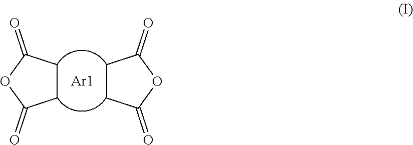

wherein
Ar1 is selected from the group consisting of:

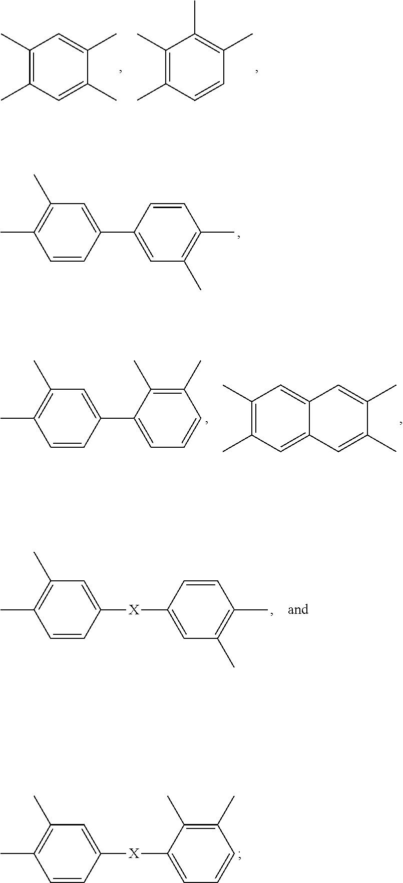

wherein X is selected from the group consisting of —CH₂—, —C(CH₃)₂—, —C(CF₃)₂—, —O—, —C(═O)—, —SO₂—,

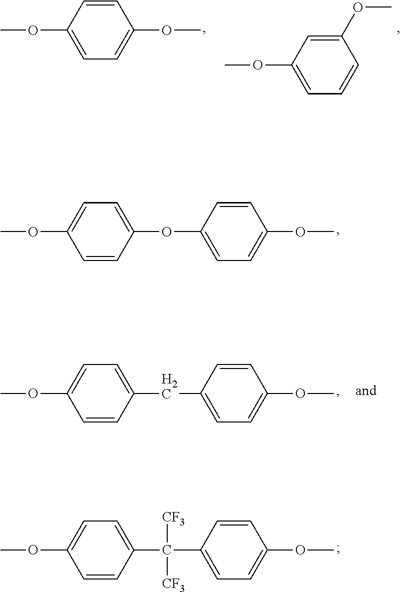

(b) two or more aromatic diamines having the formula VI

H₂N-Ar6-NH₂ (VI)

wherein Ar6 is selected from the group consisting of:

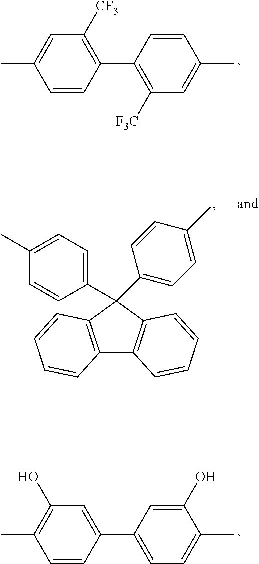

and
(c) optionally one or more aromatic diamines having the formula VII:

H₂N-Ar7-NH₂ (VII)

wherein Ar7 is selected from the group consisting of:

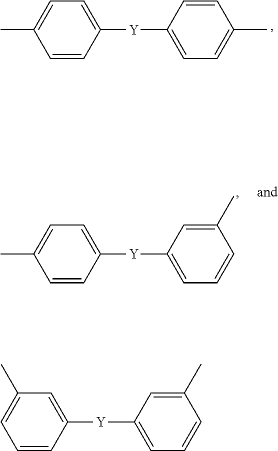

wherein
Y is selected from the group consisting of —CH₂—, —C(CH₃)₂—, —C(CF₃)₂—, —O—, —C(═O)—, —SO₂—,

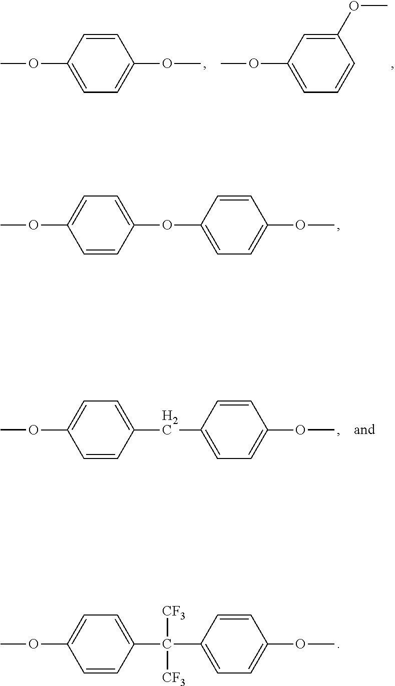

Aspect 4: The polyimide polymer according to aspect 1, 2 or 3, wherein the aromatic anhydride comprises a combination of PMDA and an additional aromatic dianhydride having the Formula II:

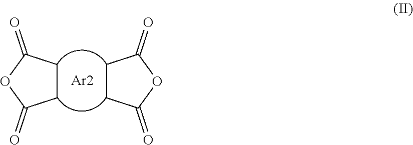

wherein Ar2 is a selected from the group consisting of:

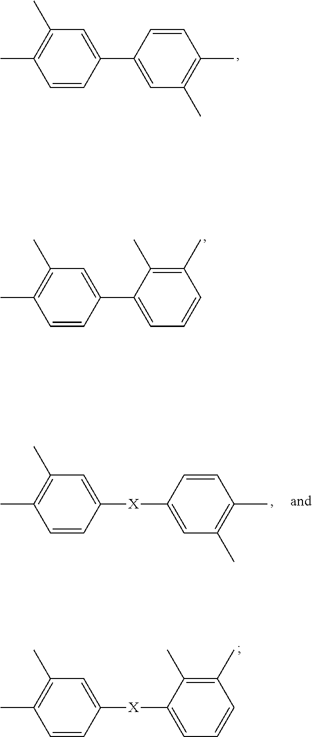

wherein X is selected from the group consisting of —CH₂—, —C(CH₃)₂—, —C(CF₃)₂—, —O—, —C(═O)—, —SO₂—,

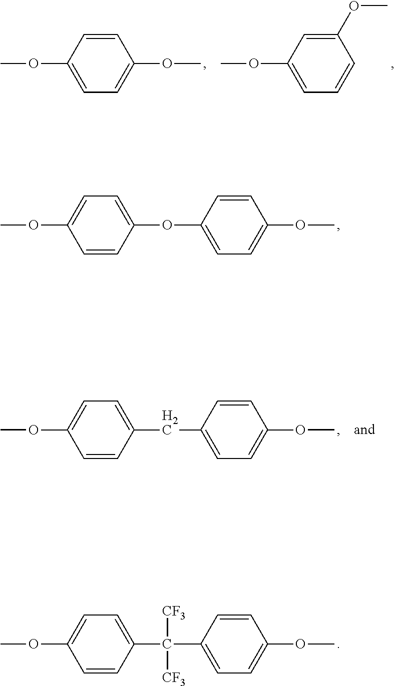

Aspect 5: The polyimide polymer according to aspect 4, wherein the aromatic dianhydride monomers comprise from about 20 mol % to about 80 mol % PMDA and about 20 mol % to about 80 mol % of an aromatic dianhydride having the Formula II, based on the total amount of dianhydride in the polyimide.

Aspect 6: The polyimide polymer according to aspect 4, wherein the aromatic dianhydride monomers comprise from about 30 mol % to about 70 mol % PMDA and about 30 mol % to about 70 mol % of an aromatic dianhydride having the Formula II, based on the total amount of dianhydride in the polyimide;

Aspect 7: The polyimide polymer according to aspect 4, wherein the aromatic dianhydride monomers comprise from about 40 mol % to about 60 mol % PMDA and about 40 mol % to about 60 mol % of an aromatic dianhydride having the Formula II, based on the total amount of dianhydride in the polyimide;

Aspect 8: The polyimide polymer according to aspect 4, wherein the aromatic dianhydride monomers comprise from about 45 mol % to about 55 mol % PMDA and about 45 mol % to about 55 mol % of an aromatic dianhydride having the Formula II, based on the total amount of dianhydride in the polyimide.

Aspect 9: The polyimide polymer according to any one of aspects 4 to 8, wherein the aromatic dianhydride of Formula II is selected from one or more of s-BPDA (3,3′,4,4′-biphenyltetracarboxylic dianhydride), a-BPDA (2,3,3′,4′-biphenyltetracarboxylic dianhydride), BPTA (3,3′,4,4′-benzophenone tetracarboxylic dianhydride), ODPA (diphenyl ether tetracarboxylic acid dianhydride), HQDA (hydroquinone diphthalic anhydride), BPADA (4,4′-(4,4′-isopropylidenediphenoxy)bis-(phthalic anhydride), and HFPDPA (4,4′-(Hexafluoroisopropylidene)diphthalic anhydride).

Aspect 10: The polyimide polymer according to any one of aspects 4 to 9, wherein the aromatic dianhydride of Formula II is s-BPDA (3,3′,4,4′-biphenyltetracarboxylic dianhydride).

Aspect 11: The polyimide polymer according to any one of aspects 4 to 9, wherein the aromatic dianhydride of Formula II is a-BPDA (2,3,3′,4′-biphenyltetracarboxylic dianhydride).

Aspect 12: The polyimide polymer according to any one of the aspects 1 to 3, wherein the aromatic dianhydride is a combination of two or more aromatic dianhydrides having the Formula II:

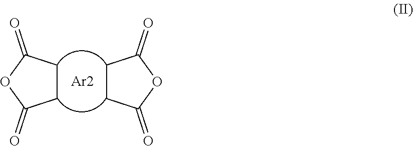

wherein Ar2 is a selected from the group consisting of:

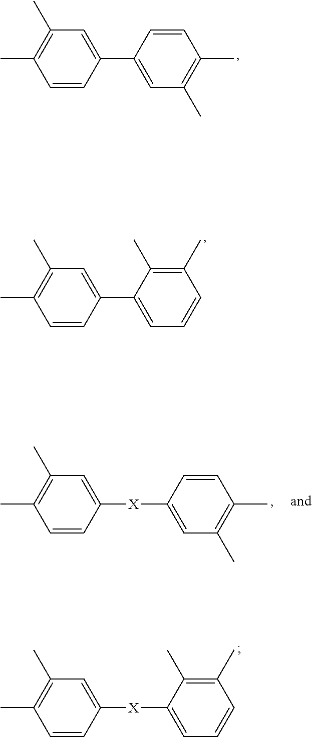

wherein X is selected from the group consisting of —CH₂—, —C(CH₃)₂—, —C(CF₃)₂—, —O—, —C(═O)—, —SO₂—,

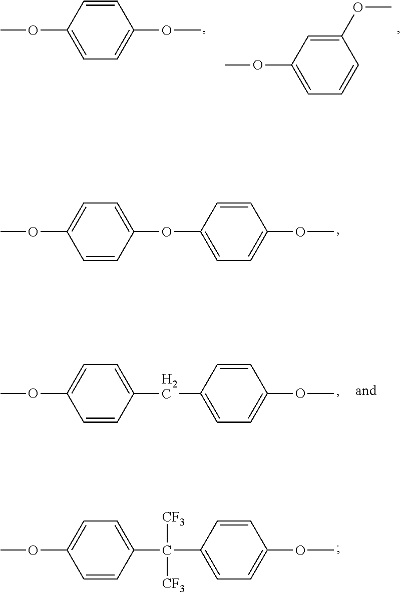

Aspect 13: The polyimide polymer according to any one of the aspects 1 to 3, wherein the aromatic dianhydride is selected from one or more of the group consisting of s-BPDA (3,3′,4,4′-biphenyltetracarboxylic dianhydride), a-BPDA (2,3,3′,4′-biphenyltetracarboxylic dianhydride), BPDA (3,3′,4,4′-benzophenone tetracarboxylic dianhydride), PMDA (pyromellitic dianhydride), ODPA (diphenyl ether tetracarboxylic acid dianhydride), HQDA, BPADA, and HFPDPA (4,4′-(Hexafluoroisopropylidene)diphthalic anhydride).

Aspect 14: The polyimide polymer according to aspect 12, wherein the two or more aromatic dianhydrides having the Formula II are selected from s-BPDA (3,3′,4,4′-biphenyltetracarboxylic dianhydride), a-BPDA (2,3,3′,4′-biphenyltetracarboxylic dianhydride), BPDA (3,3′,4,4′-benzophenone tetracarboxylic dianhydride), ODPA (diphenyl ether tetracarboxylic acid dianhydride), HQDA, BPADA, and HFPDPA (4,4′-(Hexafluoroisopropylidene)diphthalic anhydride).

Aspect 15: The polyimide polymer according to aspect 12, wherein the two or more aromatic dianhydrides having the Formula II are selected from s-BPDA (3,3′,4,4′-biphenyltetracarboxylic dianhydride), and a-BPDA (2,3,3′,4′-biphenyltetracarboxylic dianhydride).

Aspect 16: The polyimide polymer according to any one of aspects 1 to 15, wherein the aromatic diamine monomers comprise from about 20 mol % to about 80 mol % of an aromatic diamine of Formula IV and about 20 mol % to about 80 mol % of an aromatic diamine having the Formula V, based on the total amount of diamine in the polyimide.

Aspect 17: The polyimide polymer according to any one of aspects 1 to 15, wherein the aromatic diamine monomers comprise from about 30 mol % to about 70 mol % of an aromatic diamine of Formula IV and about 30 mol % to about 70 mol % of an aromatic diamine having the Formula V, based on the total amount of diamine in the polyimide.

Aspect 18: The polyimide polymer according to any one of aspects 1 to 15, wherein the aromatic diamine monomers comprise from about 40 mol % to about 60 mol % of an aromatic diamine of Formula IV and about 40 mol % to about 60 mol % of an aromatic diamine having the Formula V, based on the total amount of diamine in the polyimide.

Aspect 19: The polyimide polymer according to any one of aspects 1 to 15, wherein the aromatic diamine monomers comprise from about 45 mol % to about 55 mol % of an aromatic diamine of Formula IV and about 45 mol % to about 55 mol % of an aromatic diamine having the Formula V, based on the total amount of diamine in the polyimide.

Aspect 20: The polyimide polymer according to any one of aspects 1 to 15, wherein the aromatic diamine monomers comprise from about 10 mol % to about 50 mol % of an aromatic diamine of Formula IV and about 50 mol % to about 90 mol % of an aromatic diamine having the Formula V, based on the total amount of diamine in the polyimide.

Aspect 21: The polyimide polymer according to any one of aspects 1 to 15, wherein the aromatic diamine monomers comprise from about 20 mol % to about 40 mol % of an aromatic diamine of Formula IV and about 60 mol % to about 80 mol % of an aromatic diamine having the Formula V, based on the total amount of diamine in the polyimide.

Aspect 22: The polyimide polymer according to any one of aspects 1 to 15, wherein the aromatic diamine monomers comprise from about 15 mol % to about 25 mol % of an aromatic diamine of Formula IV and about 75 mol % to about 85 mol % of an aromatic diamine having the Formula V, based on the total amount of diamine in the polyimide;

Aspect 23: The polyimide polymer according to any one of aspects 1 to 15, wherein the aromatic diamine monomers comprise from about 20 mol % to about 30 mol % of an aromatic diamine of Formula IV and about 70 mol % to about 80 mol % of an aromatic diamine having the Formula V, based on the total amount of diamine in the polyimide.

Aspect 24: The polyimide polymer according to any one of aspects 1 to 15, wherein the aromatic diamine monomers comprise from about 10 mol % to about 45 mol % of an aromatic diamine of Formula IV, about 10 mol % to about 45 mol % of an aromatic diamine having the Formula V, and about 10 mol % to about 45 mol % of an aromatic diamine having the Formula VI, based on the total amount of diamine in the polyimide.

Aspect 25: The polyimide polymer according to any one of aspects 1 to 15, wherein the aromatic diamine monomers comprise from about 20 mol % to about 40 mol % of an aromatic diamine of Formula IV, about 20 mol % to about 40 mol % of an aromatic diamine having the Formula V, and about 20 mol % to about 40 mol % of an aromatic diamine having the Formula VI, based on the total amount of diamine in the polyimide.

Aspect 26: The polyimide polymer according to any one of aspects 1 to 15, wherein the aromatic diamine monomers comprise from about 10 mol % to about 30 mol % of an aromatic diamine of Formula IV, about 40 mol % to about 80 mol % of an aromatic diamine having the Formula V, about 10 mol % to about 30 mol % of an aromatic diamine having the Formula VI, based on the total amount of diamine in the polyimide.

Aspect 27: The polyimide polymer according to any one of aspects 1 to 15, wherein the aromatic diamine monomers comprise from about 10 mol % to about 25 mol % of an aromatic diamine of Formula IV, about 50 mol % to about 75 mol % of an aromatic diamine having the Formula V, about 10 mol % to about 25 mol % of an aromatic diamine having the Formula VI, based on the total amount of diamine in the polyimide.

Aspect 28: The polyimide polymer according to any one of aspects 1 to 15, wherein the aromatic diamine monomers comprise from about 10 mol % to about 20 mol % of an aromatic diamine of Formula IV, about 60 mol % to about 70 mol % of an aromatic diamine having the Formula V, about 10 mol % to about 20 mol % of an aromatic diamine having the Formula VI, based on the total amount of diamine in the polyimide.

Aspect 29: The polyimide polymer according to any one of aspects 1 to 28, wherein the aromatic diamine having the Formula V comprises at least one of FDA and TFDB.

Aspect 30: The polyimide polymer according to any one of aspects 1 to 28 wherein the aromatic diamine having the Formula V comprises both of FDA and TFDB.

Aspect 31: The polyimide polymer according to any one of aspects 1 to 30, wherein the aromatic diamine having the Formula V is FDA.

Aspect 32: The polyimide polymer according to any one of aspects 1 to 30, wherein the aromatic diamine having the Formula V is TFDB.

Aspect 33: The polyimide polymer according to any one of aspects 1 to 30, wherein the aromatic diamine having the Formula VI is 4,4′-ODA.

Aspect 34: A polyimide polymer comprising monomers (a), (b), and (c):

(a) one or more aromatic dianhydrides represented by the formula I:

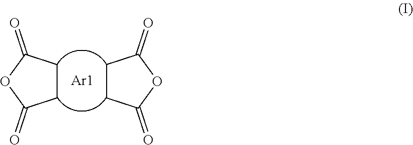

wherein
Ar1 is selected from the group consisting of:

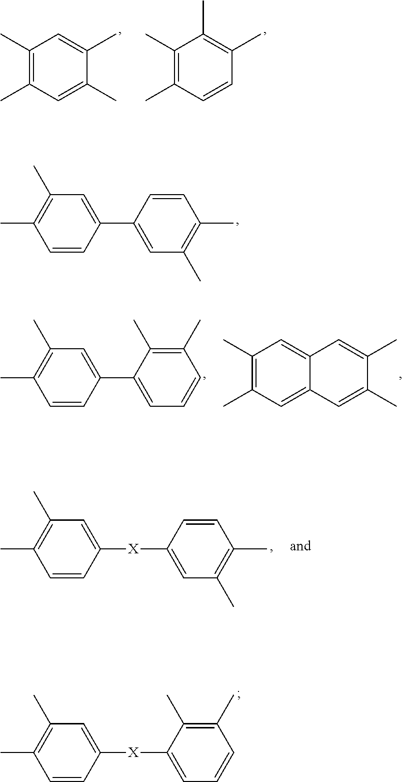

wherein X is selected from the group consisting of —CH₂—, —C(CH₃)₂—, —C(CF₃)₂—, —O—, —C(═O)—, —SO₂—,

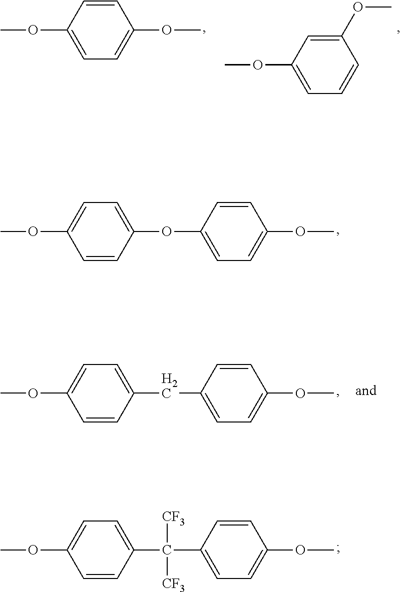

(b) one or more aromatic diamines having the formula IV:

H₂N-Ar4-NH₂ (IV)

wherein Ar4 is selected from the group consisting of:

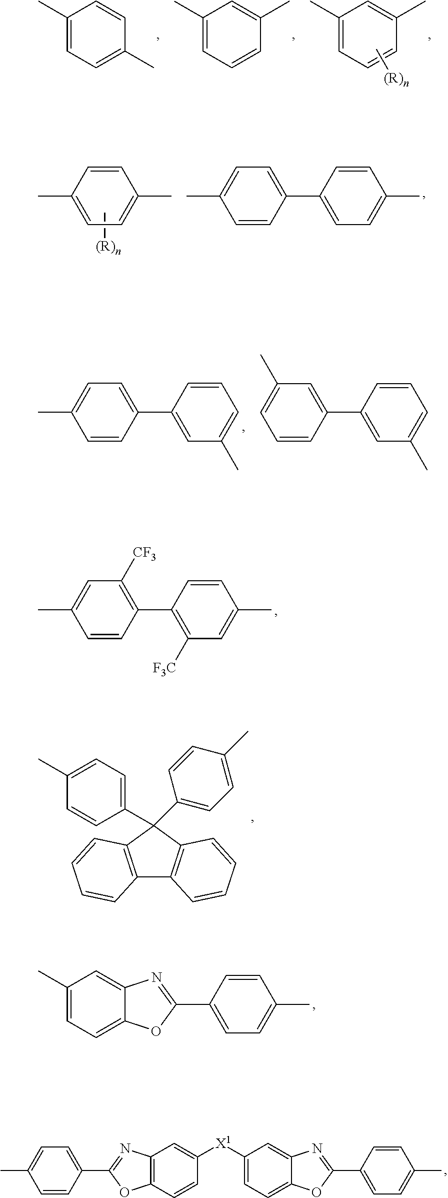

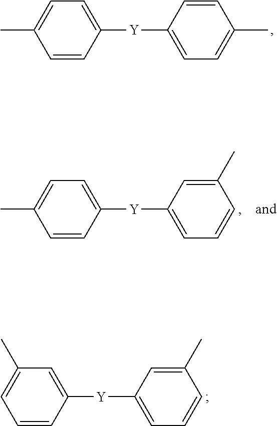

wherein
each R is independently selected from the group consisting of F, Cl, and CF₃;
each n independently selected from is 0, 1 or 2;
X₁ is selected from the group consisting of a chemical single bond, —CH₂—, and —O—;
each Y is independently selected from the group consisting of —CH₂—, —C(CH₃)₂—, —C(CF₃)₂—, —O—, —C(═O)—, —SO₂—,

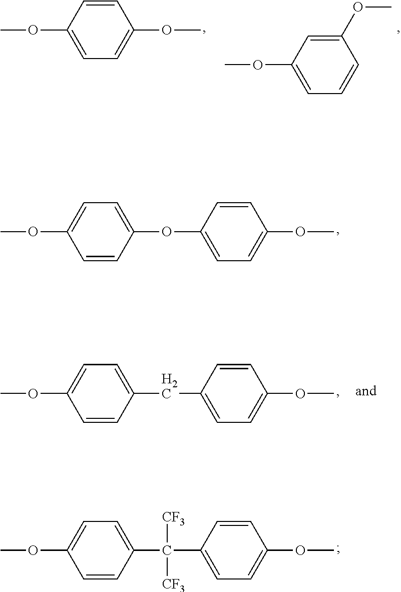

and
(c) one or more aromatic diamines having the formula VIII

H₂N-Ar8-NH₂ (VIII)

wherein Ar8 is selected from the group consisting of:

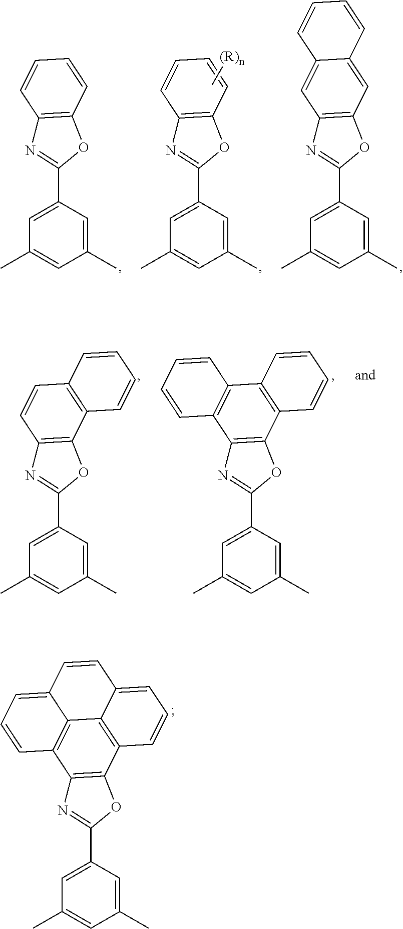

wherein
each R is independently selected from the group consisting of F, Cl, and CF₃; and
n is 0, 1 or 2.

Aspect 35: The polyimide polymer according to aspect 34, wherein the aromatic diamine monomers comprise from about 20 mol % to about 80 mol % of an aromatic diamine of Formula IV and about 20 mol % to about 80 mol % of an aromatic diamine having the Formula VIII, based on the total amount of diamine in the polyimide.

Aspect 36: The polyimide polymer according to aspect 34, wherein the aromatic diamine monomers comprise from about 30 mol % to about 70 mol % of an aromatic diamine of Formula IV and about 30 mol % to about 70 mol % of an aromatic diamine having the Formula VIII, based on the total amount of diamine in the polyimide.

Aspect 37: The polyimide polymer according to aspect 34, wherein the aromatic diamine monomers comprise from about 40 mol % to about 60 mol % of an aromatic diamine of Formula IV and about 40 mol % to about 60 mol % of an aromatic diamine having the Formula VIII, based on the total amount of diamine in the polyimide.

Aspect 38: The polyimide polymer according to aspect 34, wherein the aromatic diamine monomers comprise from about 45 mol % to about 55 mol % of an aromatic diamine of Formula IV and about 45 mol % to about 55 mol % of an aromatic diamine having the Formula VIII, based on the total amount of diamine in the polyimide.

Aspect 39: The polyimide polymer according to aspect 34, wherein the aromatic diamine monomers comprise from about 10 mol % to about 50 mol % of an aromatic diamine of Formula VIII and about 50 mol % to about 90 mol % of an aromatic diamine having the Formula IV, based on the total amount of diamine in the polyimide.

Aspect 40: The polyimide polymer according to aspect 34, wherein the aromatic diamine monomers comprise from about 20 mol % to about 40 mol % of an aromatic diamine of Formula VIII and about 60 mol % to about 80 mol % of an aromatic diamine having the Formula IV, based on the total amount of diamine in the polyimide,

Aspect 41: The polyimide polymer according to aspect 34, wherein the aromatic diamine monomers comprise from about 15 mol % to about 25 mol % of an aromatic diamine of Formula VIII and about 75 mol % to about 85 mol % of an aromatic diamine having the Formula IV, based on the total amount of diamine in the polyimide.

Aspect 42: The polyimide polymer according to aspect 34, wherein the aromatic diamine monomers comprise from about 20 mol % to about 30 mol % of an aromatic diamine of Formula VIII and about 70 mol % to about 80 mol % of an aromatic diamine having the Formula IV, based on the total amount of diamine in the polyimide.

Aspect 43: A polyimide polymer comprising monomers (a), (b), optionally (c), and optionally (d):

(a) one or more aromatic dianhydrides represented by the formula I:

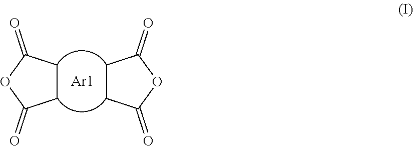

wherein
Ar1 is selected from the group consisting of:

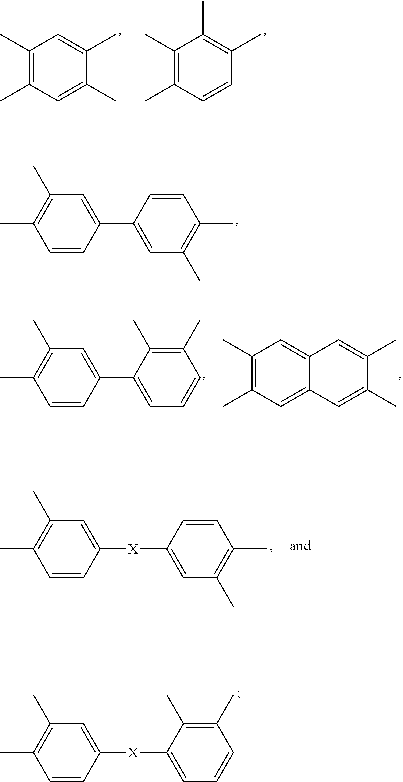

wherein X is selected from the group consisting of —CH₂—, —C(CH₃)₂—, —C(CF₃)₂—, —O—, —C(═O)—, —SO₂—,

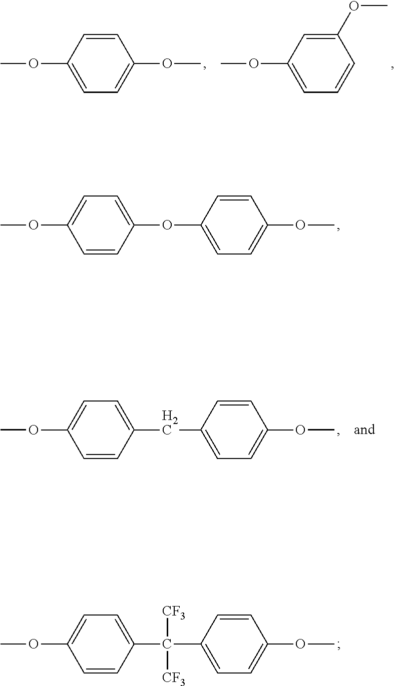

(b) one or more aromatic diamines having the formula VIII

H₂N-Ar8-NH₂ (VIII)

wherein Ar8 is selected from the group consisting of:

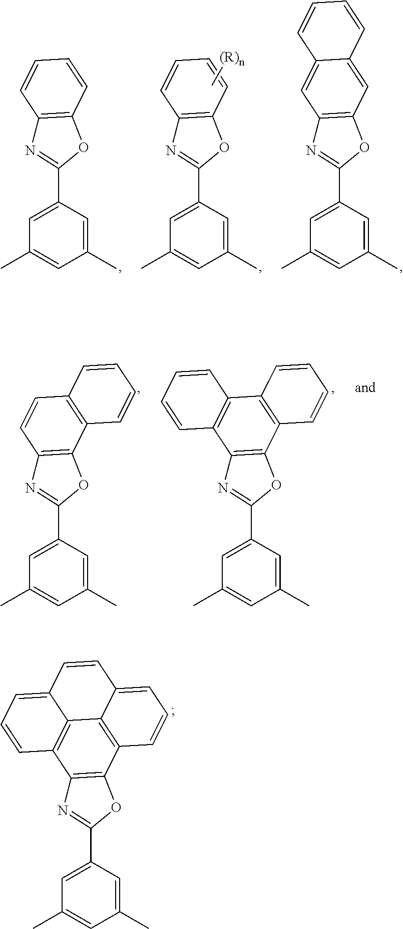

wherein
each R is independently selected from the group consisting of F, Cl, and CF₃; and
n is 0, 1 or 2; and
(c) optionally, one or more aromatic diamines having the formula VI

H₂N-Ar6-NH₂ (VI)

wherein Ar6 is selected from the group consisting of:

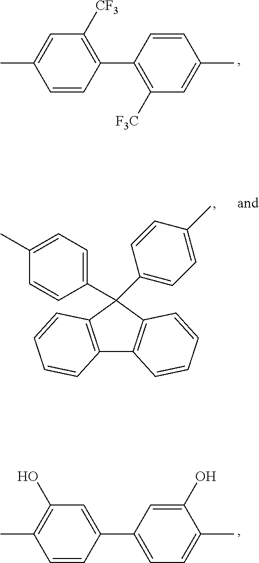

and
(d) optionally, one or more aromatic diamines having the formula VII:

H₂N-Ar7-NH₂ (VII)

wherein Ar7 is selected from the group consisting of:

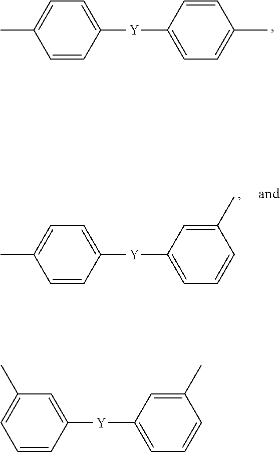

wherein
Y is selected from the group consisting of —CH₂—, —C(CH₃)₂—, —C(CF₃)₂—, —O—, —C(═O)—, —SO₂—,

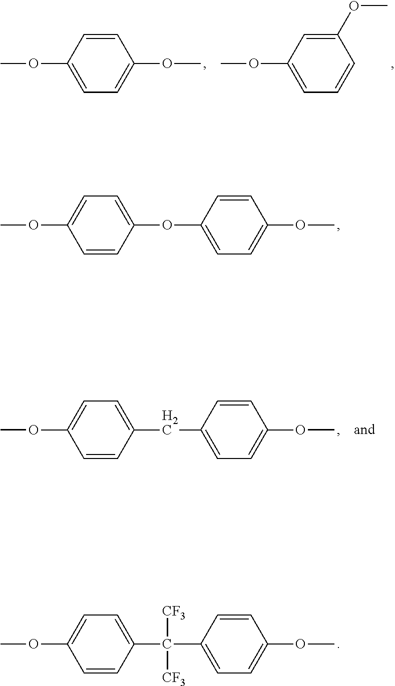

Aspect 44: The polyimide polymer according to aspect 43, wherein the aromatic diamine monomers comprise from about 20 mol % to about 80 mol % of an aromatic diamine of Formula VI and about 20 mol % to about 80 mol % of an aromatic diamine having the Formula VIII, based on the total amount of diamine in the polyimide.

Aspect 45: The polyimide polymer according to aspect 43, wherein the aromatic diamine monomers comprise from about 30 mol % to about 70 mol % of an aromatic diamine of Formula VI and about 30 mol % to about 70 mol % of an aromatic diamine having the Formula VIII, based on the total amount of diamine in the polyimide.

Aspect 46: The polyimide polymer according to aspect 43, wherein the aromatic diamine monomers comprise from about 40 mol % to about 60 mol % of an aromatic diamine of Formula VI and about 40 mol % to about 60 mol % of an aromatic diamine having the Formula VIII, based on the total amount of diamine in the polyimide.

Aspect 47: The polyimide polymer according to aspect 43, wherein the aromatic diamine monomers comprise from about 45 mol % to about 55 mol % of an aromatic diamine of Formula VI and about 45 mol % to about 55 mol % of an aromatic diamine having the Formula VIII, based on the total amount of diamine in the polyimide.

Aspect 48: The polyimide polymer according to aspect 43, wherein the aromatic diamine monomers comprise from about 10 mol % to about 50 mol % of an aromatic diamine of Formula VIII and about 50 mol % to about 90 mol % of an aromatic diamine having the Formula VI, based on the total amount of diamine in the polyimide.

Aspect 49: The polyimide polymer according to aspect 43, wherein the aromatic diamine monomers comprise from about 20 mol % to about 40 mol % of an aromatic diamine of Formula VIII and about 60 mol % to about 80 mol % of an aromatic diamine having the Formula VI, based on the total amount of diamine in the polyimide.

Aspect 50: The polyimide polymer according to aspect 43, wherein the aromatic diamine monomers comprise from about 15 mol % to about 25 mol % of an aromatic diamine of Formula VIII and about 75 mol % to about 85 mol % of an aromatic diamine having the Formula VI, based on the total amount of diamine in the polyimide.

Aspect 51: The polyimide polymer according to aspect 43, wherein the aromatic diamine monomers comprise from about 20 mol % to about 30 mol % of an aromatic diamine of Formula VIII and about 70 mol % to about 80 mol % of an aromatic diamine having the Formula VI, based on the total amount of diamine in the polyimide.

Aspect 52: The polyimide polymer according to aspect 43, wherein the aromatic diamine monomers comprise from about 10 mol % to about 45 mol % of an aromatic diamine of Formula VIII, about 10 mol % to about 45 mol % of an aromatic diamine having the Formula VI, and about 10 mol % to about 45 mol % of an aromatic diamine having the Formula VII, based on the total amount of diamine in the polyimide.

Aspect 53: The polyimide polymer according to aspect 43, wherein the aromatic diamine monomers comprise from about 20 mol % to about 40 mol % of an aromatic diamine of Formula VIII, about 20 mol % to about 40 mol % of an aromatic diamine having the Formula VI, and about 20 mol % to about 40 mol % of an aromatic diamine having the Formula VII, based on the total amount of diamine in the polyimide.

Aspect 54: The polyimide polymer according to aspect 43, wherein the aromatic diamine monomers comprise from about 10 mol % to about 30 mol % of an aromatic diamine of Formula VIII, about 40 mol % to about 80 mol % of an aromatic diamine having the Formula VI, and about 10 mol % to about 30 mol % of an aromatic diamine having the Formula VII, based on the total amount of diamine in the polyimide.

Aspect 55: The polyimide polymer according to aspect 43, wherein the aromatic diamine monomers comprise from about 10 mol % to about 25 mol % of an aromatic diamine of Formula VIII, about 50 mol % to about 75 mol % of an aromatic diamine having the Formula VI, and about 10 mol % to about 25 mol % of an aromatic diamine having the Formula VII, based on the total amount of diamine in the polyimide.

Aspect 56: The polyimide polymer according to aspect 43, wherein the aromatic diamine monomers comprise from about 10 mol % to about 20 mol % of an aromatic diamine of Formula VIII, about 60 mol % to about 70 mol % of an aromatic diamine having the Formula VI, and about 10 mol % to about 20 mol % of an aromatic diamine having the Formula VII, based on the total amount of diamine in the polyimide.

Aspect 57: The polyimide polymer according to any one of aspects 34 to 56, wherein the aromatic anhydride comprises a combination of PMDA and an additional aromatic dianhydrides having the Formula II:

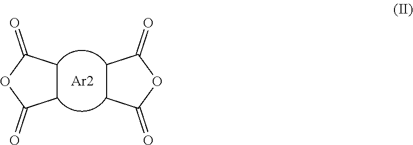

wherein Ar2 is a selected from the group consisting of:

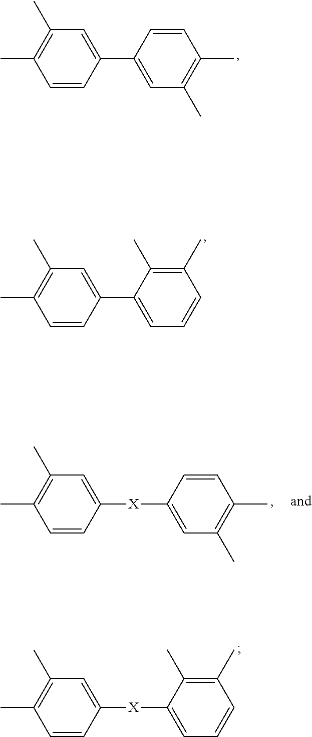

wherein X is selected from the group consisting of —CH₂—, —C(CH₃)₂—, —C(CF₃)₂—, —O—, —C(═O)—, —SO₂—,

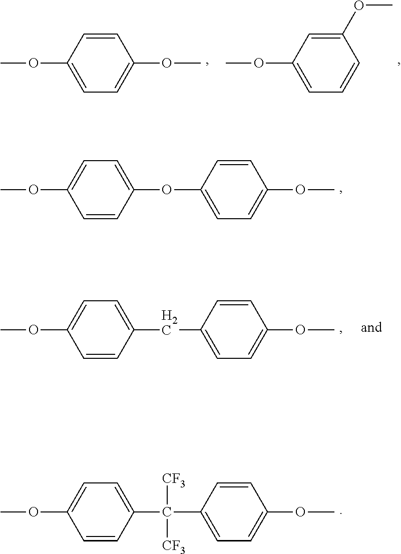

Aspect 58: The polyimide polymer according to aspect 57, wherein the aromatic dianhydride monomers comprise from about 20 mol % to about 80 mol % PMDA and about 20 mol % to about 80 mol % of an aromatic dianhydride having the Formula II, based on the total amount of dianhydride in the polyimide.

Aspect 59: The polyimide polymer according to aspect 57, wherein the aromatic dianhydride monomers comprise from about 30 mol % to about 70 mol % PMDA and about 30 mol % to about 70 mol % of an aromatic dianhydride having the Formula II, based on the total amount of dianhydride in the polyimide;

Aspect 60: The polyimide polymer according to aspect 57, wherein the aromatic dianhydride monomers comprise from about 40 mol % to about 60 mol % PMDA and about 40 mol % to about 60 mol % of an aromatic dianhydride having the Formula II, based on the total amount of dianhydride in the polyimide;

Aspect 61: The polyimide polymer according to aspect 57, wherein the aromatic dianhydride monomers comprise from about 45 mol % to about 55 mol % PMDA and about 45 mol % to about 55 mol % of an aromatic dianhydride having the Formula II, based on the total amount of dianhydride in the polyimide.

Aspect 62: The polyimide polymer according to any one of aspects 57 to 61, wherein the aromatic dianhydride of Formula II is selected from one or more of s-BPDA (3,3′,4,4′-biphenyltetracarboxylic dianhydride), a-BPDA (2,3,3′,4′-biphenyltetracarboxylic dianhydride), BPTA (3,3′,4,4′-benzophenone tetracarboxylic dianhydride), ODPA (diphenyl ether tetracarboxylic acid dianhydride), HQDA (hydroquinone diphthalic anhydride), BPADA (4,4′-(4,4′-isopropylidenediphenoxy)bis-(phthalic anhydride), and HFPDPA (4,4′-(Hexafluoroisopropylidene)diphthalic anhydride).

Aspect 63: The polyimide polymer according to any one of aspects 57 to 61, wherein the aromatic dianhydride of Formula II is s-BPDA (3,3′,4,4′-biphenyltetracarboxylic dianhydride).

Aspect 64: The polyimide polymer according to any one of aspects 4 to 9, wherein the aromatic dianhydride of Formula II is a-BPDA (2,3,3′,4′-biphenyltetracarboxylic dianhydride).

Aspect 65: The polyimide polymer according to any one of the aspects 34 to 56, wherein the aromatic dianhydride is a combination of two or more aromatic dianhydrides having the Formula II:

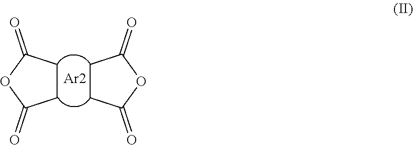

wherein Ar2 is a selected from the group consisting of:

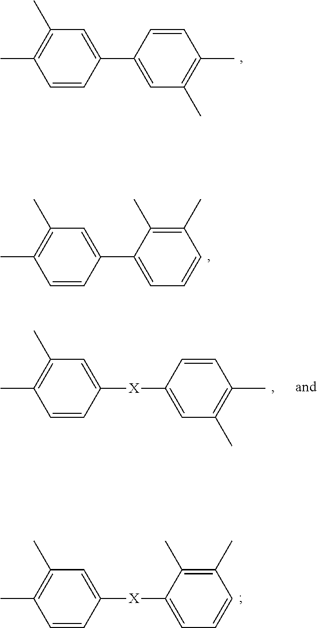

wherein X is selected from the group consisting of —CH₂—, —C(CH₃)₂—, —C(CF₃)₂—, —O—, —C(═O)—, —SO₂—,

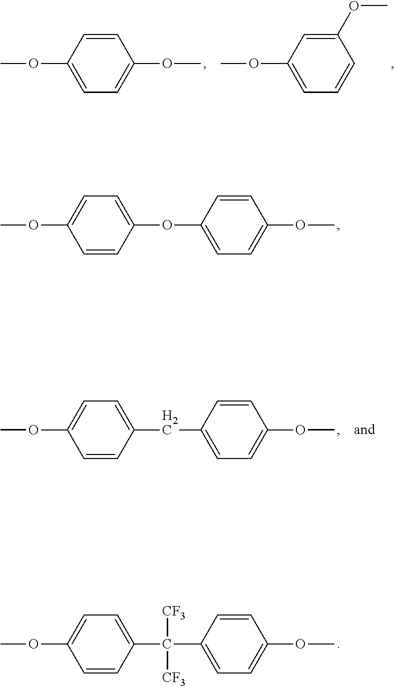

Aspect 66: The polyimide polymer according to any one of the aspects 34 to 56, wherein the aromatic dianhydride is selected from one or more of the group consisting of s-BPDA (3,3′,4,4′-biphenyltetracarboxylic dianhydride), a-BPDA (2,3,3′,4′-biphenyltetracarboxylic dianhydride), BPDA (3,3′,4,4′-benzophenone tetracarboxylic dianhydride), PMDA (pyromellitic dianhydride), ODPA (diphenyl ether tetracarboxylic acid dianhydride), HQDA, BPADA, and HFPDPA (4,4′-(Hexafluoroisopropylidene)diphthalic anhydride).

Aspect 67: The polyimide polymer according to any one of the aspects 34 to 56, wherein the two or more aromatic dianhydrides having the Formula II are selected from s-BPDA (3,3′,4,4′-biphenyltetracarboxylic dianhydride), a-BPDA (2,3,3′,4′-biphenyltetracarboxylic dianhydride), BPDA (3,3′,4,4′-benzophenone tetracarboxylic dianhydride), ODPA (diphenyl ether tetracarboxylic acid dianhydride), HQDA, BPADA, and HFPDPA (4,4′-(Hexafluoroisopropylidene)diphthalic anhydride).

Aspect 68: The polyimide polymer according to any one of the aspects 34 to 56, wherein the two or more aromatic dianhydrides having the Formula II are selected from s-BPDA (3,3′,4,4′-biphenyltetracarboxylic dianhydride), and a-BPDA (2,3,3′,4′-biphenyltetracarboxylic dianhydride).

Aspect 69: A polyimide polymer comprising any one of the monomer compositions as provided in Table 1.

Aspect 70: A polyimide polymer comprising any one of the monomer compositions as provided in Table 2.

Aspect 71: A polyimide polymer comprising any one of the monomer compositions as provided in Table 3.

Aspect 72: A polyimide polymer comprising any one of the monomer compositions as provided in Table 4.

Aspect 73: A polyimide polymer comprising any one of the monomer compositions as provided in Table 5.

Aspect 74: The polyimide polymer according to any one of aspects 1 to 73, wherein the percentage of imide linkages in the polyimide polymer backbone to the total linkages (imide+acid amide) in the polyimide polymer backbone is greater than about 90%.

Aspect 75: The polyimide polymer according to any one of aspects 1 to 73, wherein the percentage of imide linkages in the polyimide polymer backbone to the total linkages (imide+acid amide) in the polyimide polymer backbone is greater than about 95%.

Aspect 76: The polyimide polymer according to any one of aspects 1 to 73, wherein the percentage of imide linkages in the polyimide polymer backbone to the total linkages (imide+acid amide) in the polyimide polymer backbone is greater than about 98%.

Aspect 77: The polyimide polymer according to any one of aspects 1 to 73, wherein the percentage of imide linkages in the polyimide polymer backbone to the total linkages (imide+acid amide) in the polyimide polymer backbone is greater than about 99%.

Aspect 78: The polyimide polymer according to any one of aspects 1 to 77, wherein the polyimide polymer have a solubility in NMP of greater than about 20% by weight.

Aspect 79: The polyimide polymer according to any one of aspects 1 to 78, wherein the polyimide polymer has a CTE of less than about 12 ppm.

Aspect 80: The polyimide polymer according to any one of aspects 1 to 78, wherein the polyimide polymer has a CTE of less than about 10 ppm.

Aspect 81: The polyimide polymer according to any one of aspects 1 to 78, wherein the polyimide polymer has a CTE of less than about 8 ppm.

Aspect 82: The polyimide polymer according to any one of aspects 1 to 78, wherein the polyimide polymer has a CTE of less than about 6 ppm.

Aspect 83: The polyimide polymer according to any one of aspects 1 to 78, wherein the polyimide polymer has a CTE of less than about 5 ppm.

Aspect 84: The polyimide polymer according to any one of aspects 1 to 83, wherein the polyimide polymer has a weight loss of about 1% or less at 500° C. based on non-isothermal TGA.

Aspect 85: The polyimide polymer according to any one of aspects 1 to 83, wherein the polyimide polymer has a weight loss of about 1% or less at 520° C. based on non-isothermal TGA.

Aspect 86: The polyimide polymer according to any one of aspects 1 to 83, wherein the polyimide polymer has a weight loss of about 1% or less at 550° C. based on non-isothermal TGA.

Aspect 87: The polyimide polymer according to any one of aspects 1 to 83, wherein the polyimide polymer has a weight loss of about 1% or less at 450° C. based on non-isothermal TGA.

Aspect 88: The polyimide polymer according to any one of aspects 1 to 87, wherein the polyimide polymer has a weight loss of about 3% or less at 450° C. for 60 minutes based on isothermal TGA.

Aspect 89: The polyimide polymer according to any one of aspects 1 to 87, wherein the polyimide polymer has a weight loss of about 2% or less at 450° C. for 60 minutes based on isothermal TGA.

Aspect 90: The polyimide polymer according to any one of aspects 1 to 87, wherein the polyimide polymer has a weight loss of about 1% or less at 450° C. for 60 minutes based on isothermal TGA.

Aspect 91: The polyimide polymer according to any one of aspects 1 to 87, wherein the polyimide polymer has a weight loss of about 0.5% or less at 450° C. for 60 minutes based on isothermal TGA.

Aspect 92: The polyimide polymer according to any one of aspects 1 to 91, wherein the polyimide polymer has a Tg of about 350° C. or higher based on DMA.

Aspect 93: The polyimide polymer according to any one of aspects 1 to 91, wherein the polyimide polymer has a Tg of about 300° C. or higher based on DMA.

Aspect 94: The polyimide polymer according to any one of aspects 1 to 91, wherein the polyimide polymer has a Tg of about 250° C. or higher based on DMA.

Aspect 95: The polyimide polymer according to any one of aspects 1 to 91, wherein the polyimide polymer has a Tg of about 200° C. or higher based on DMA.

The following non-limiting examples serve to illustrate certain embodiments of the disclosure but are not to be construed as limiting. Variations and additional or alternative embodiments will be readily apparent to the skilled artisan on the basis of the disclosure provided herein.

### EXAMPLES

BPDA: 3,4,3′,4′-Biphenyltetracarboxylic dianhydride, 2420-87-3

PMDA: Pyromellitic dianhydride, 89-32-7

a-BPDA: 2,3,3′,4-biphenyltetracarboxylic dianhydride, 36978-41-3

BZDA: 5-Benzooxazol-2-yl-benzene-1,3-diamine, 56629-40-4

TFDB: 2,2′-Bis(trifluoromethyl)-[1,1′-biphenyl]-4,4′-diamine, 341-58-2

FDA: 4,4′-(9-Fluorenylidene)dianiline, 15499-84-0

ODA: 4,4′-Diaminodiphenyl ether, 101-80-4

DHBZ: 3,3′-Dihydroxybenzidine, 2373-98-0

### Example 1—Formation of a Polyimide Polymer from BZDA, FDA, and BPDa Monomers

In a 250 ml flask with mechanical stirrer and nitrogen purged, 50 ml dry NMP was added. Then 2.2525 g 5-Benzooxazol-2-yl-benzene-1,3-diamine (BZDA) was added into the flask and dissolved. Afterwards, 3.4845 g 4,4′-(9-Fluorenylidene)dianiline (FDA) was added into the flask. Next, 5.8844 g BPDA was added into the flask with fierce stirring. The polymerization was maintained under 20° C. for 24 hrs. A mixture of Et3N (2.79 g) and Ac20 (3.78 g) was added slowly into the flask to catalyze the imidization. The imidization process lasted for another 24 hrs. Then a highly viscous solution was obtained. With another 100 ml NMP was added to dilute the solution, this solution was poured into 500 ml ethanol slowly then polymer powder was precipitated. After filtrated and washed with fresh ethanol twice, the powder was dried under 200° C. in vacuum for 24 hrs.

### Example 2—Formation of a Polyimide Polymer from FDA, BPDA, and PMDA Monomers

In a 250 ml flask with mechanical stirrer and nitrogen purged, 50 ml dry DMAc was added. Then 6.969 g FDA was added into the flask then dissolved in solvent. Next, 2.9422 g BPDA and 2.1812 g PMDA were added into the flask in sequence. The polymerization was maintained under 20° C. for 24 hrs. A mixture of Et3N (1.39 g) and Ac20 (1.89 g) was added slowly into the flask to catalyze the imidization. The imidization process lasted for another 24 hrs. Another 100 ml DMAc was added to dilute the solution, this solution was poured into 500 ml isopropanol slowly then precipitated powder was obtained. After filtrated and washed with fresh isopropanol twice, the powder was dried under 200° C. in vacuum for 24 hrs.

### Example 3—Formation of a Polyimide Polymer from TFDB, ODA, BPDA, and a-BPDA Monomers

In a 250 ml flask with mechanical stirrer and nitrogen inlet and outlet, 50 ml dry m-cresol was added. Then 3.2023 g TFDB and 2.0024 g ODA was added into the flask then dissolved in solvent. Next, 2.9422 g BPDA and 2.9422 g a-BPDA were added into the flask consecutively. The polymerization was maintained under 20° C. for 4 hrs. Then 12 ml of xylene was added to the solution to form an azeotrope, and 4 drops of isoquinoline were added into the solution to catalyze the reaction. Afterwards, the solution was heating to 200° C. gradually within 60 mins. Meanwhile, a small amount of water/xylene azeotrope was distilled out and separated with Dean-Stark apparatus. The solution was maintained at 200° C. for 4 hrs and cooling down to the room temperature. Another 100 ml m-cresol was added to dilute the solution. Then the solution was poured into 500 ml isopropanol slowly with fierce stirring then precipitated powder was obtained. After filtrated and washed with fresh isopropanol twice, the powder was dried under 200° C. in vacuum for 24 hrs.

### Example 4—Formation of a Polyimide Polymer from TFDB, DHBZ, BPDA and PMDA Monomers

In a 250 ml flask with mechanical stirrer and nitrogen inlet and outlet 50 ml dry m-cresol was added. Then 3.2023 g TFDB and 2.1624 g DHBZ was added into the flask then dissolved in solvent. Next, 2.9422 g BPDA and 2.1812 g PMDA were added into the flask consecutively. The polymerization was maintained under 20° C. for 4 hrs. Then 12 ml of xylene was added to the solution to form an azeotrope, and 4 drops of isoquinoline were added into the solution to catalyze the reaction. Afterwards, the solution was heating to 200° C. gradually within 60 mins. Meanwhile, a small amount of water/xylene azeotrope was distilled out and separated with Dean-Stark apparatus. The solution was maintained at 200° C. for 4 hrs and cooling down to the room temperature. Another 100 ml m-cresol was added to dilute the solution. Then the solution was poured into 500 ml isopropanol slowly then precipitated powder was obtained. After filtrated and washed with fresh isopropanol twice, the powder was dried under 200° C. in vacuum for 24 hrs.

### Example 5—Formation of a Polyimide Polymer Layer

The polyimide powder received from example 1 was dissolved into NMP with a concentration of 15 weight percent (wt. %). The solution was casted with slit die coater with a slot of 400 μm on a quartz plate. Then the plate was put in 80° C. oven with N₂ purge. The temperature of oven was gradually increased to 350° C. within 40 min., then maintained under 350° C. for 60 min. Afterwards, heating was stopped and the plate was taken out from the oven until the temperature was lower than 80° C. The polyimide film was peeled off from the plate by immersing the plate in deionized water.

Polyimide solutions prepared from polyimide powder of examples 2 and 3 can be casted and cured according to the same process described in example 5.

### Example 6—Formation of a Polyimide Polymer Layer

The polyimide powder received from example 4 was dissolved into NMP with a concentration of 15 wt. %. The solution was casted with slit die coater with a slot of 400 m on a quartz plate. Then the plate was put in 80° C. oven with N₂ purge. The temperature of the oven was gradually increased to 350° C. within 40 min then maintained under 350° C. for 30 min. Next, the temperature of the oven was increased to 450° C. within 15 min. then maintained under 450° C. for 30 min. Afterwards, heating was stopped and the plate was taken out from the oven until the temperature was lower than 80° C. The polyimide film was peeled off from the plate by immersing the plate in deionized water.

### Example 7—Formation of a Polyimide Polymer Substrate for Flexible Display Device Manufacturing

The polyimide powder received from example 4 was dissolved into NMP with a concentration of 13 wt. % to for a polyimide solution. The polyimide solution was filtered through a 20,000-mesh stainless steel mesh. The polyimide solution was degassed under vacuum. A 200 mm×200 mm glass substrate was ultrasonic cleaned for 15 min. in each of three solvents: distilled water, chloroform and acetone. The cleaned glass substrate was dried in oven at 60° C. for 60 min. The glass substrate was placed on a customized holder on a spin coater. 15 mL of polyimide solution was poured slowly onto the center of the glass and spun at 200 rpm for 20 s, and then at 500-1000 rpm for 30 s to produce wet film with a thickness of 5-20 m. The wet film was dried on a hot plate at 80° C. for 60 min. The film was further cured in a N₂ ambient in an oven by heating the oven to 100±5° C. at 5° C./min., maintaining the oven at 100° C. for 60±5 min., heating the oven to 250±5° C. at 10° C./min., maintaining the oven at 250° C. for 60±5 min., heating the oven to 350±5° C. at 10° C./min., and maintaining the oven at 350° C. 60±5 min. After heating, the oven was cooled down to room temperature at 5° C./min.

A TFT array layer, OLED layers and thin film encapsulation (TFE) were successfully built upon the polyimide polymer layer on the glass substrate using a general flexible display fabrication process.

Some properties of the polyimide solution, the polyimide film on the glass substrate, and the polyimide film peeled off the substrate with the flexible display device have been characterized. The characterization results are summarized in Table 6 below. The solids content was characterized by a solid content analyzer. The viscosity was characterized using a Brookfield DV-II viscometer at 25° C. The film thickness was characterized using a step gauge analyzer. T_{g} was characterized using a TA instruments Q800 dynamic mechanical analyzer. The internal stress was characterized by a stress analyzer.

The thickness of the film was tested by profiler. The 9 points uniformity of the film was analyzed by comparing the thickness of 9 evenly distributed points of the film with the formula:

$$Uniformity = \frac{Max - Min}{Max + Min} \times 100 \% .$$

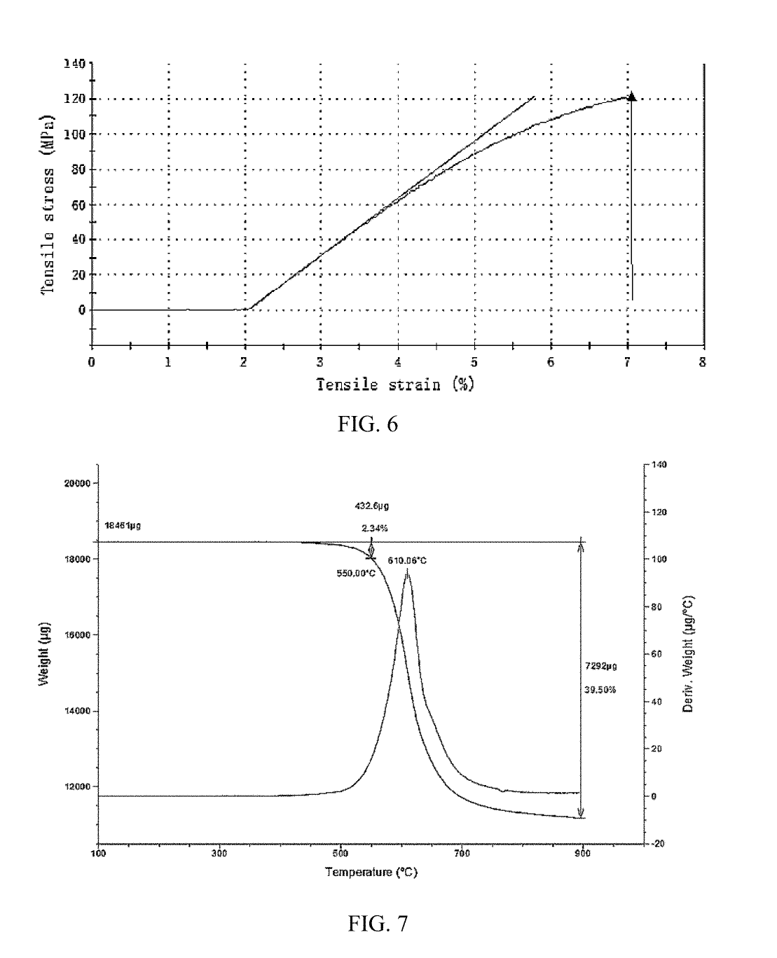

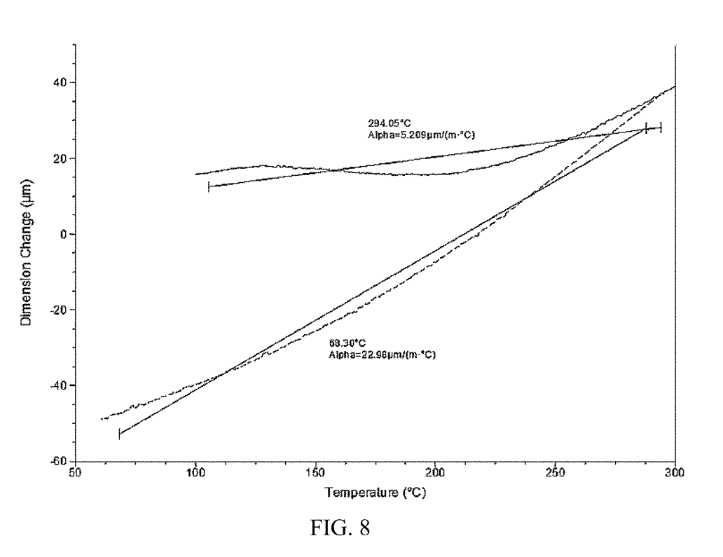

The tensile properties of polyimide film were characterized by an Instron 5567 universal testing machine. FIG. 6 is a stress-strain curve of the polyimide film. T_{d} was characterized using a TA instrument Q5500 thermal gravimetric analyzer. FIG. 7 is a thermal gravimetric analysis profile of the polyimide film. The coefficient of thermal expansion was characterized using TA instrument Q400 thermal mechanical analyzer. FIG. 8 is a thermal mechanical analysis profile of the polyimide film.

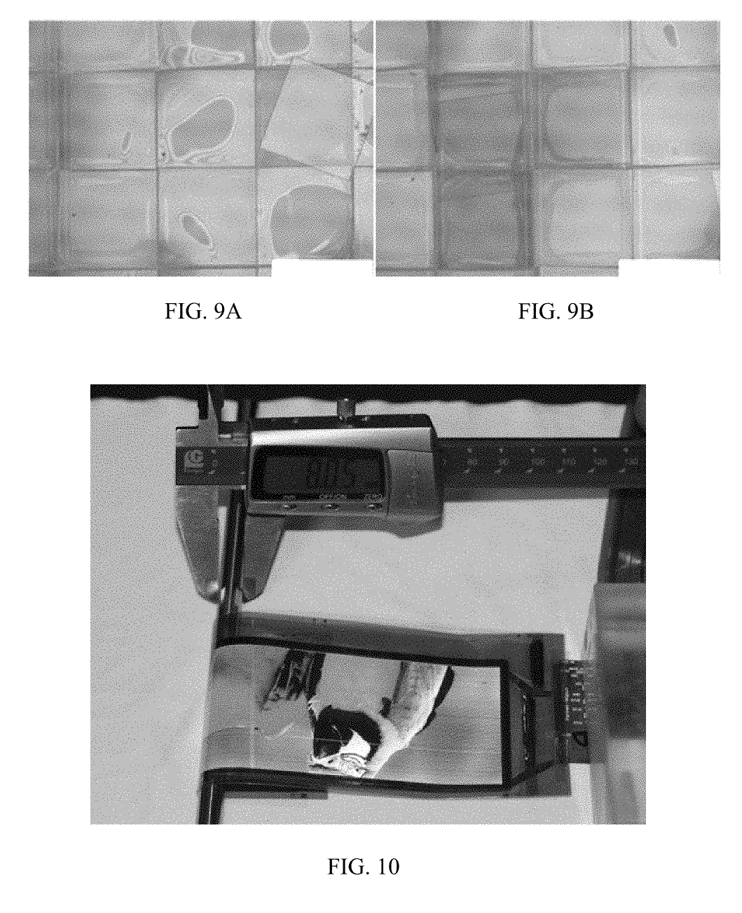

The delamination of the polyimide from the glass substrate was based on a crosscut adhesion test following ASTM D3359. The glass substrate with the polyimide film was cross-cut into 100 squares, each square about 1 mm by 1 mm. The adhesion of each of the 100 squares was examined under a microscope. FIGS. 9A and 9B are micrographs of the crosscut adhesion test results for the polyimide film. The results showed that all the squares were fully or partially delaminated or debonded from the substrate. Subsequent pulling on the film from an adhesive tape fully removed all of the polyimide film squares for an adhesion rating of 0B per ASTM D3359.

After the final flexible display fabricated, the bending radius was tested by bending the power on display device over rod with different radius and check whether the crack generated or the color pixels damaged. FIG. 10 is a photograph of the bending radius test of the flexible display device. The results show that at the 4 mm radius the display works well.

TABLE 6
Characteristics of the Polyimide Solution, the Polyimide Film and
the Flexible Display

| Characterization Item | | Result |
|---|---|---|
| Polyimide | Solids content | 13 wt. % |
| Solution | Solvent | NMP |
| | Viscosity | 2600 cPs |
| Polyimide Film on | Internal stress | 10.3-14.6 MPa |
| Glass Substrate | | |
| Polyimide Film | Thickness | 15 μm |
| Peeled From | Tensile strength | 121.3 MPa |
| Glass Substrate | Elongation at break | 5.0% |
| | Young's Modulus | 3200 MPa |
| | T_{g} | 480° C. |
| | T_{d} (1%) | 500° C. |
| | CTE (100-350° C.) | 5.2 ppm/° C. |
| | Debonding | 100% |
| | Chemical resistance | −1.7%-6.4% |
| | shape change | |
| | 9 points uniformity | 7.2% |
| Flexible Display | Size | 42 mm × 126 mm (5.2 inch) |
| Device | Resolution | 200 × RGB × 600 |
| | Pixels density | 121 ppi |
| | OLED pixel array | RGB |
| | Brightness | 324.3 cd/m² |
| | Brightness contrast | 32430:1 |
| | Power | 1.185 W |
| | Color gamut | 91% NTSC |
| | Bending radius | 4 mm |

The chemical resistance property was tested by immersing the films in test solutions for 15 min. each and measuring the film thickness before and after immersion to determine a change in thickness. It can be desirable that the change in thickness be less than 10%, for some flexible display device applications. The test solutions were: a Mo/Al etchant solution (solution of H₃PO₄, HAc, HNO₃, and H₂O), an alkaline solution (5 wt. % NaOH aqueous solution), acetone, a photoresist solvent (propylene glycol methyl ether acetate (PGMEA)), a developer solution (2.38 wt. % aqueous tetramethyl ammonium hydroxide (TMAH)), and a stripper solvent (dimethylsulfoxide and monoethanolamine in ratio of 7:3). The results are shown in Table 7 below. As shown in Table 7, the change in thickness is less than 10% for all chemicals tested.

TABLE 7
Chemical Resistance of the Polyimide Film

| | Thickness |
|---|---|
| Test Solution | Change |
| Mo/Al Etchant Solution | 6.45% |
| Alkaline Solution | −1.71% |
| Acetone | 5.75% |
| Photoresist Solvent | 2.07% |
| Developer Solution | −0.02% |
| Stripper Solution | 4.31% |

1. A polyimide polymer comprising:
one or more aromatic dianhydride monomers according to a formula: 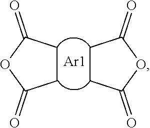
wherein Ar1 is selected from the group consisting of: 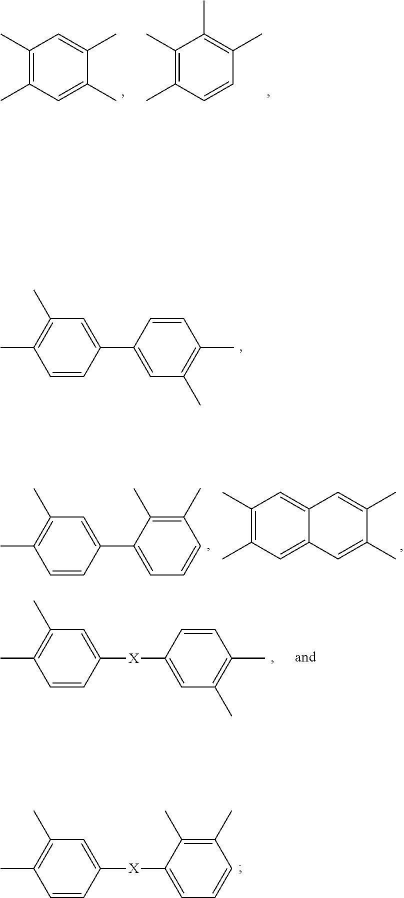
wherein X is selected from the group consisting of —CH₂—, —C(CH₃)₂—, —C(CF₃)₂—, —O—, —C(═O)—, —SO₂—, 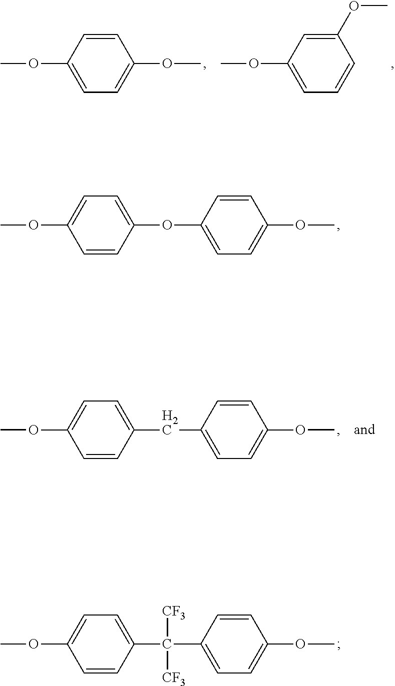
and
one or more aromatic diamine monomers according to at least one of:
a formula:
H₂N-Ar6-NH₂
and a formula:
H₂N-Ar8-NH₂,
wherein Ar6 is selected from the group consisting of: 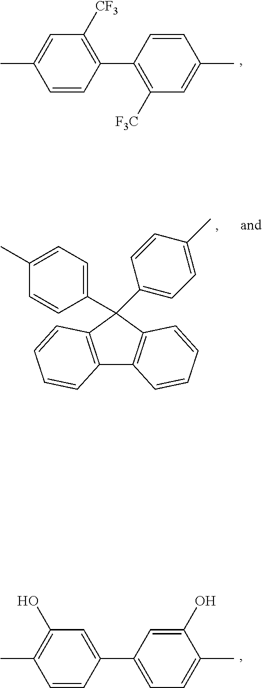
and Ar8 is selected from the group consisting of: 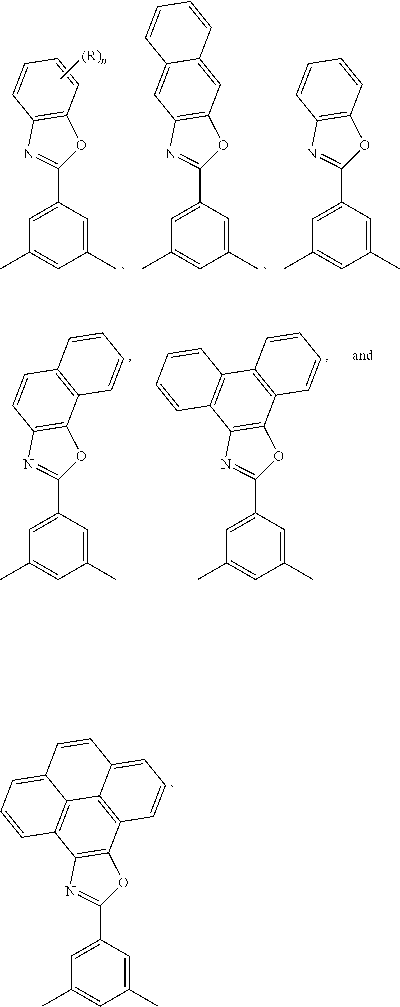
wherein each R is independently selected from the group consisting of F, Cl, and CF₃; and n is 0, 1 or 2.

2. The polyimide polymer of claim 1, wherein the one or more aromatic diamine monomers have a formula of:
H₂N-Ar6-NH₂
wherein Ar6 is selected from the group consisting of:

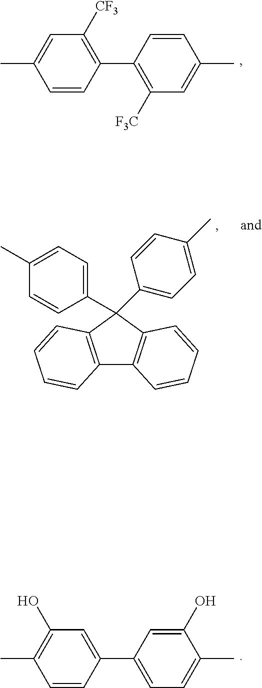

3. The polyimide polymer of claim 2, further including one or more aromatic diamine monomers have a formula of:
H₂N-Ar5-NH₂
wherein Ar5 is selected from the group consisting of: 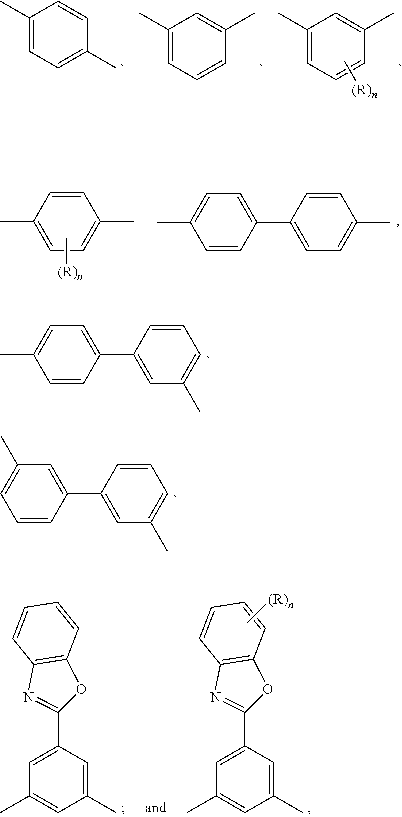
wherein each R is independently selected from the group consisting of F, Cl, and CF₃; and n is 0, 1 or 2.

4. The polyimide polymer of claim 2, wherein the aromatic diamine monomer includes at least one of: (4,4′-(9-fluorenylidene)dianiline and (2,2′-bis(trifluoromethyl)benzidine.

5. The polyimide polymer of claim 1, wherein the one or more aromatic diamine monomers have a formula of:
H₂N-Ar8-NH₂
wherein Ar8 is selected from the group consisting of: 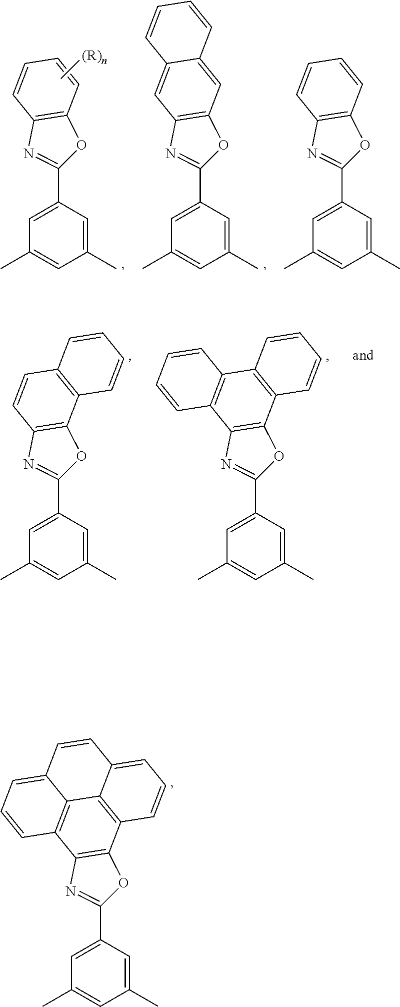
wherein each R is independently selected from the group consisting of F, Cl, and CF₃; and n is 0, 1 or 2.

6. The polyimide polymer of claim 5, further including one or more aromatic diamine monomers have a formula of:
H₂N-Ar4-NH₂
wherein Ar4 is selected from the group consisting of: 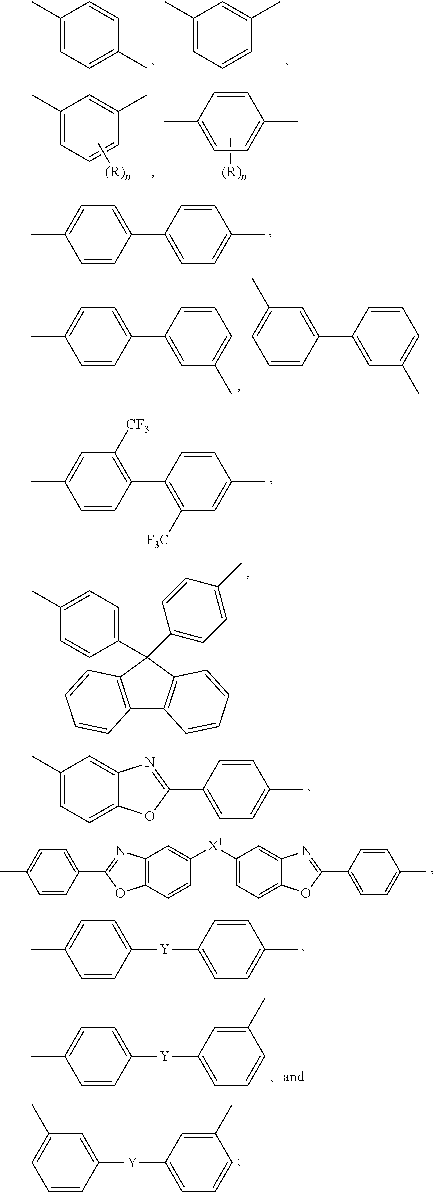
wherein each R is independently selected from the group consisting of F, Cl, and CF₃; each n independently selected from is 0, 1 or 2; X₁ is selected from the group consisting of a chemical single bond, —CH₂—, and —O—; and each Y is independently selected from the group consisting of —CH₂—, —C(CH₃)₂—, —C(CF₃)₂—, —O—, —C(═O)—, —SO₂—,

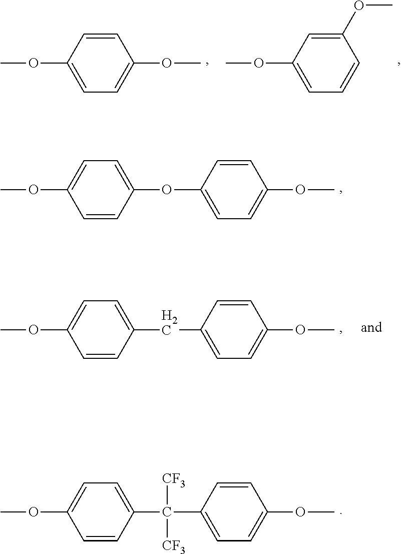

7. The polyimide polymer of claim 6, wherein the one or more aromatic diamine monomers having a formula of:
H₂N-Ar4-NH₂
includes 4,4′-diaminodiphenyl ether.

8. The polyimide polymer of claim 1, further including one or more aromatic diamine monomers have a formula of:
H₂N-Ar7-NH₂
wherein Ar7 is selected from the group consisting of: 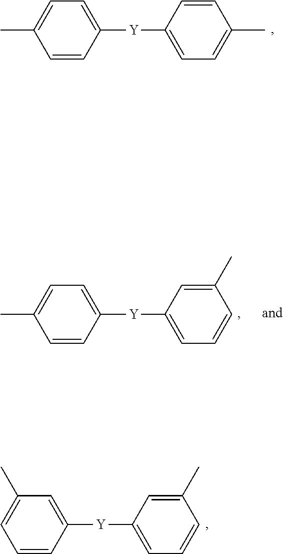
wherein Y is selected from the group consisting of —CH₂—, —C(CH₃)₂—, —C(CF₃)₂—, —O—, —C(═O)—, —SO₂—,

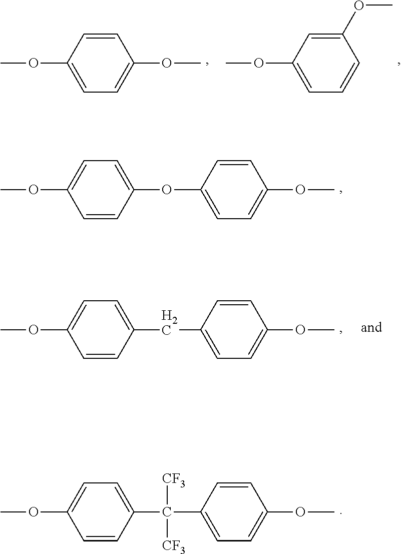

9. The polyimide polymer of claim 1, wherein the one or more aromatic dianhydride monomers include pyromellitic dianhydride and one or more additional aromatic dianhydride monomers having the formula: 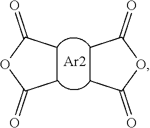
wherein Ar2 is a selected from the group consisting of: 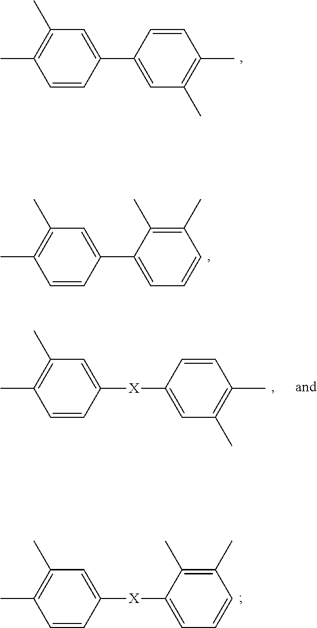
wherein X is selected from the group consisting of —CH₂—, —C(CH₃)₂—, —C(CF₃)₂—, —O—, —C(═O)—, —SO₂—,

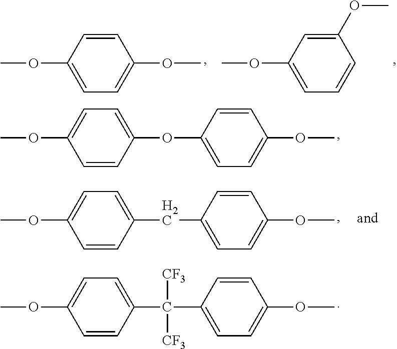

10. The polyimide polymer of claim 9, wherein the one or more additional aromatic dianhydride monomers are selected from the group consisting of: 3,3′,4,4′-biphenyltetracarboxylic dianhydride; 2,3,3′,4′-biphenyltetracarboxylic dianhydride; 3,3′,4,4′-benzophenone tetracarboxylic dianhydride; diphenyl ether tetracarboxylic acid dianhydride; hydroquinone diphthalic anhydride; 4,4′-(4,4′-isopropylidenediphenoxy)bis-(phthalic anhydride); and 4,4′-(hexafluoroisoproylidene)diphthalic anhydride, and mixtures thereof.

11. A method for making a flexible display device, the method comprising:
preparing a polyimide solution including a polyimide polymer dissolved in a solvent;
coating a substrate with the polyimide solution;
heating the coated substrate and the coating of polyimide solution to evaporate the solvent and form a cured polyimide layer;
forming a display device layer on the cured polyimide layer, the display device layer defining at least one display device;
dicing through the display device layer and through the cured polyimide layer; and
delaminating the cured polyimide layer together with the display device layer from the substrate to form the flexible display device.

12. The method of claim 11, wherein the solvent includes at least one of: N-methyl-2-pyrrolidone, dimethylacetamide, dimethylformamide, dimethyl sulfoxide, tetrahydrofuran, acetone diethyl acetate, and mixtures thereof.

13. The method of claim 11, wherein the heating is to a temperature not greater than 350° C.

14. The method of claim 13, wherein the heating includes:
baking on a hot plate at a temperature of 75° C. to 80° C. for 25 to 35 minutes;
baking in an oven at a temperature of 75° C. to 80° C. for 25 to 35 minutes;
baking in the oven at a temperature of 95° C. to 105° C. for 55 to 65 minutes;
baking in the oven at a temperature of 195° C. to 205° C. for 25 to 35 minutes;
baking in the oven at a temperature of 245° C. to 255° C. for 25 to 35 minutes;
baking in the oven at a temperature of 295° C. to 305° C. for 25 to 35 minutes; and
baking in the oven at a temperature of 345° C. to 350° C. for 25 to 35 minutes.

15. The method of claim 11, wherein the polyimide polymer includes:
one or more aromatic dianhydride monomers according to a formula: 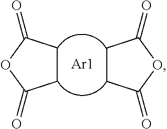
wherein Ar1 is selected from the group consisting of: 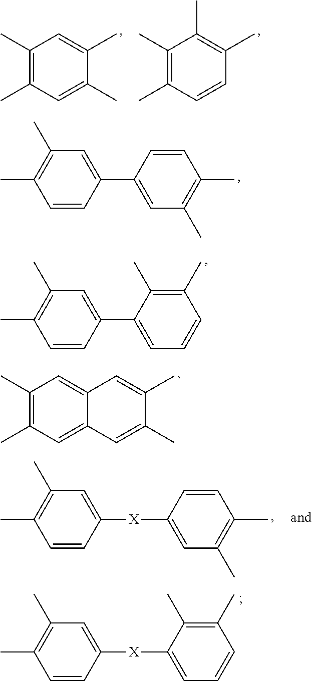
wherein X is selected from the group consisting of —CH₂—, —C(CH₃)₂—, —C(CF₃)₂—, —O—, —C(═O)—, —SO₂—, 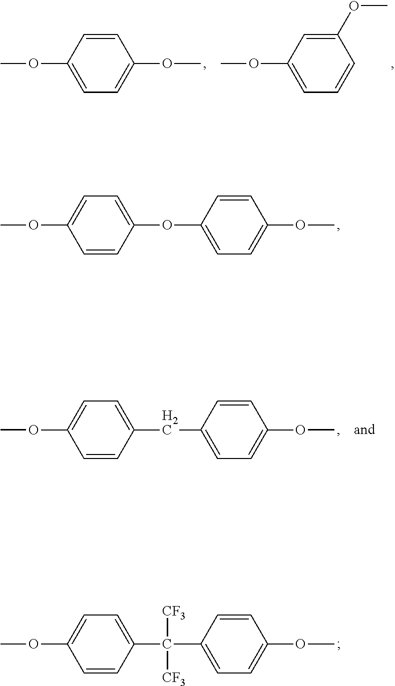
and
one or more aromatic diamine monomers according to at least one of: a formula:
H₂N-Ar6-NH₂
and a formula:
H₂N-Ar8-NH₂,
wherein Ar6 is selected from the group consisting of: 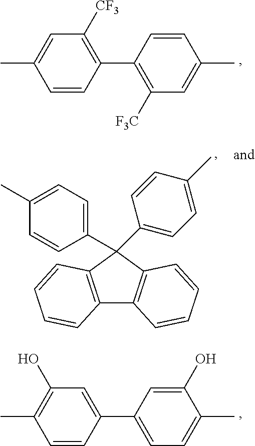
and Ar8 is selected from the group consisting of: 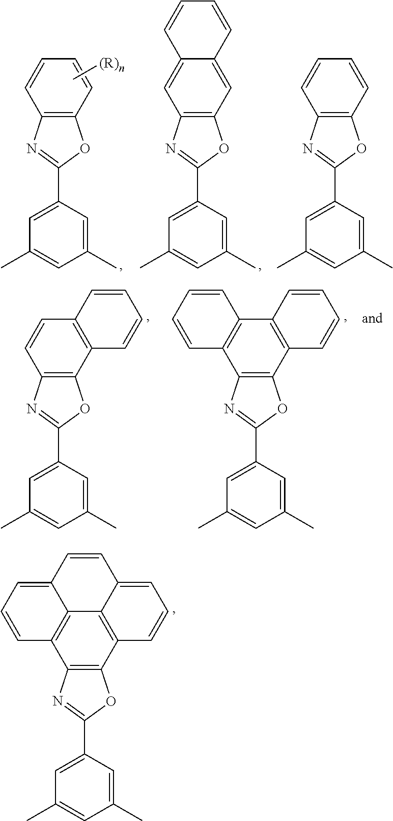
wherein each R is independently selected from the group consisting of F, Cl, and CF₃; and n is 0, 1 or 2.

16. The method of claim 15, wherein the one or more aromatic diamine monomers include at least one of: (4,4′-(9-fluorenylidene)dianiline and (2,2′-bis(trifluoromethyl)benzidine.

17. The method of claim 15, wherein the one or more aromatic dianhydride monomers include pyromellitic dianhydride and one or more additional aromatic dianhydride monomers having the formula: 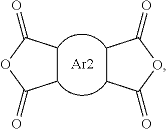
wherein Ar2 is a selected from the group consisting of: 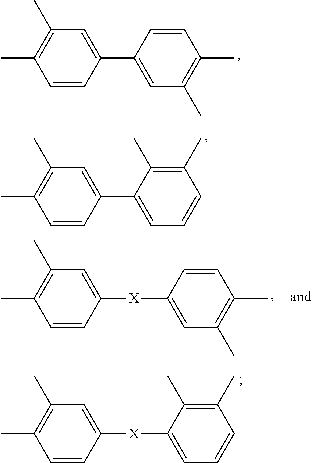
wherein X is selected from the group consisting of —CH₂—, —C(CH₃)₂—, —C(CF₃)₂—, —O—, —C(═O)—, —SO₂—,

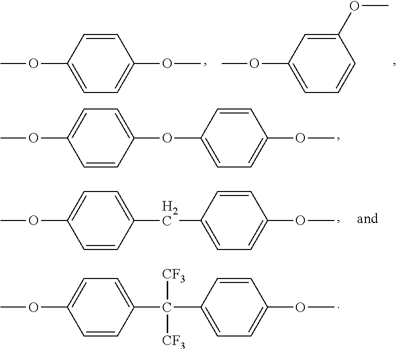

18. A flexible display device comprising:
a polyimide polymer backing layer; and
a display device disposed on the polyimide backing layer, wherein the polyimide polymer includes:
one or more aromatic dianhydride monomers according to a formula: 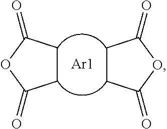
wherein Ar1 is selected from the group consisting of: 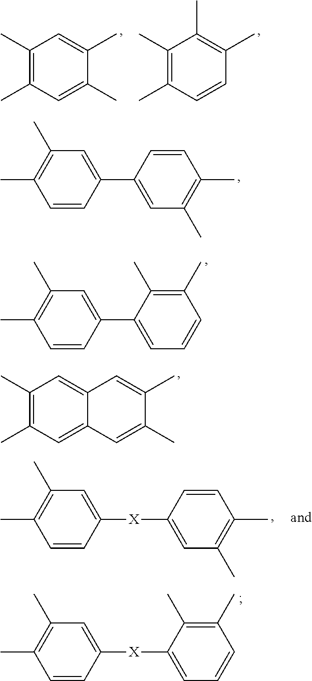
wherein X is selected from the group consisting of —CH₂—, —C(CH₃)₂—, —C(CF₃)₂—, —O—, —C(═O)—, —SO₂—, 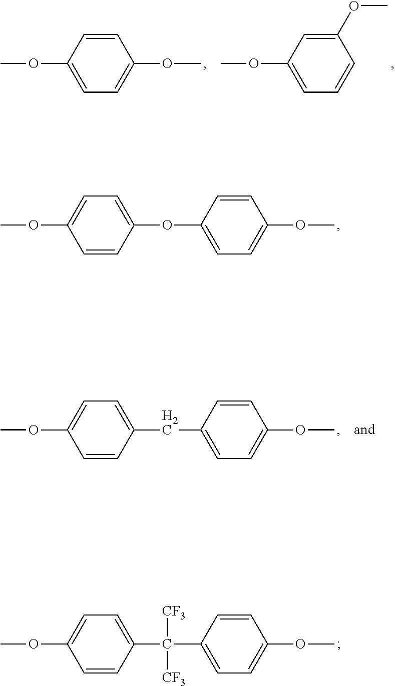
and
one or more aromatic diamine monomers according to at least one of:
a formula:
H₂N-Ar6-NH₂
and a formula:
H₂N-Ar8-NH₂,
wherein Ar6 is selected from the group consisting of: 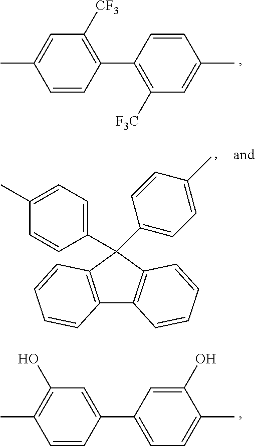
and Ar8 is selected from the group consisting of: 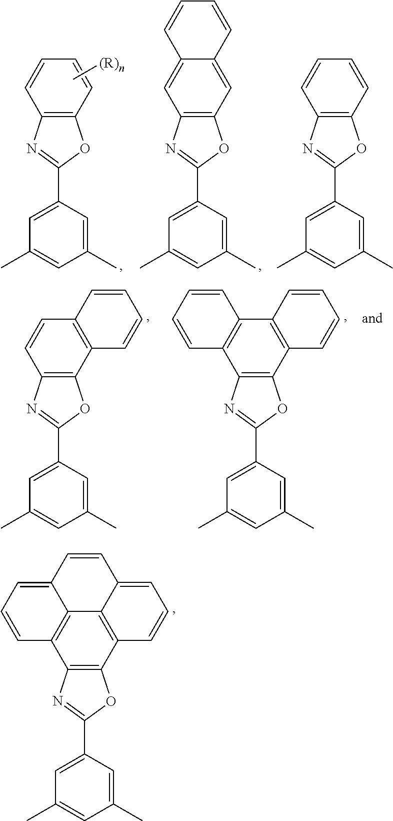
wherein each R is independently selected from the group consisting of F, Cl, and CF₃; and n is 0, 1 or 2.

19. The flexible display device of claim 18, wherein the one or more aromatic diamine monomers include at least one of: (4,4′-(9-fluorenylidene)dianiline and (2,2′-bis(trifluoromethyl)benzidine.

20. The flexible display device of claim 18, wherein the one or more aromatic dianhydride monomers include pyromellitic dianhydride and one or more additional aromatic dianhydride monomers having the formula: 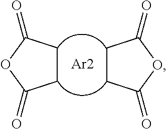
wherein Ar2 is a selected from the group consisting of: 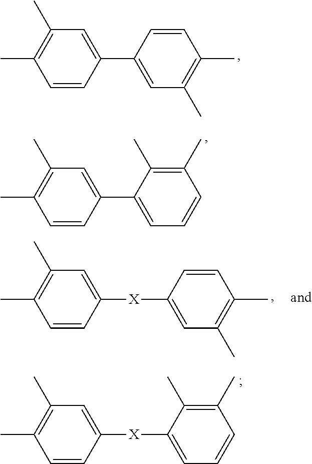
wherein X is selected from the group consisting of —CH₂—, —C(CH₃)₂—, —C(CF₃)₂—, —O—, —C(═O)—, —SO₂—, [chemical structure]
